(19) United States
(12) Patent Application Publication
(10) Pub. No.: US 2026/0235950 A1
(43) Pub. Date: Aug. 13, 2026

(54) CHEMICALLY AMPLIFIED RESIST COMPOSITION AND PATTERN FORMING PROCESS

(71) Applicant: Shin-Etsu Chemical Co., Ltd., Tokyo (JP)

(72) Inventor: Masahiro Fukushima, Joetsu-shi (JP)

(73) Assignee: Shin-Etsu Chemical Co., Ltd., Tokyo (JP)

(21) Appl. No.: 19/531,911

(22) Filed: Feb. 6, 2026

(30) Foreign Application Priority Data
Feb. 13, 2025 (JP) 2025-021264

(51) Int. Cl. G03F 7/004; C08F 212/14; G03F 7/039; G03F 7/32

(52) U.S. Cl. CPC G03F 7/0045; C08F 212/24; G03F 7/0392; G03F 7/0397; G03F 7/322

(57) ABSTRACT

A chemically amplified resist composition is provided comprising (A) a polymer comprising repeat units having a cyclic acetal structure fused to an aromatic ring, (B) a photoacid generator containing a fluoroalkane sulfonic acid anion having an iodized or iodized/brominated aromatic ring structure, and (C) an organic solvent. The resist composition exhibits a high solvent solubility, sensitivity, and contrast and forms patterns having improved lithography properties including LWR, CDU, EL and DOF as well as collapse resistance and etch resistance.

### CROSS-REFERENCE TO RELATED APPLICATION

This non-provisional application claims priority under 35 U.S.C. § 119(a) on Patent Application No. 2025-021264 filed in Japan on Feb. 13, 2025, the entire contents of which are hereby incorporated by reference.

### TECHNICAL FIELD

This invention relates to a chemically amplified resist composition and a pattern forming process.

### BACKGROUND ART

To meet the demand for higher integration density and operating speed of LSIs, the effort to reduce the pattern rule is in rapid progress. The wide-spreading flash memory market and the demand for increased storage capacities drive forward the miniaturization technology. As the advanced miniaturization technology, manufacturing of microelectronic devices at the 65-nm node by the ArF lithography has been implemented in a mass scale. Manufacturing of 45-nm node devices by the next generation ArF immersion lithography is approaching to the verge of high-volume application. The candidates for the next generation 32-nm node include ultra-high NA lens immersion lithography using a liquid having a higher refractive index than water in combination with a high refractive index lens and a high refractive index resist film, EUV lithography of wavelength 13.5 nm, and double patterning version of the ArF lithography, on which active research efforts have been made.

As the pattern feature size is reduced, approaching to the diffraction limit of light, light contrast lowers. In the case of positive resist film, a lowering of light contrast leads to reductions of resolution and focus margin of hole and trench patterns.

With the miniaturization of pattern size, the line width roughness (LWR) of line patterns and the critical dimension uniformity (CDU) of hole patterns are regarded significant. It is pointed out that these factors are affected by the segregation or agglomeration of a base polymer and acid generator and the diffusion of generated acid. There is a tendency that as the resist film becomes thinner, LWR becomes greater. A film thickness reduction to comply with the progress of size reduction causes a degradation of LWR, which becomes a serious problem.

The EUV lithography resist must meet high sensitivity, high resolution and low LWR at the same time. As the acid diffusion distance is reduced, LWR is reduced, but sensitivity becomes lower. For example, as the PEB temperature is lowered, the outcome is a reduced LWR, but a lower sensitivity. As the amount of quencher added is increased, the outcome is a reduced LWR, but a lower sensitivity. It is necessary to overcome the tradeoff relation between sensitivity and LWR.

With the aim to suppress acid diffusion, Patent Document 1 discloses a resist compound comprising repeat units derived from an onium salt of a polymerizable unsaturated bond-containing sulfonic acid. Since the so-called polymer-bound acid generator is capable of generating a polymer type sulfonic acid upon exposure, it is characterized by a very short distance of acid diffusion. Sensitivity may be enhanced by increasing a proportion of the acid generator. In the case of addition type acid generators, as the amount of acid generator added is increased, a higher sensitivity is achievable, but the acid diffusion distance is also increased. Since the acid diffusion is non-uniform, an increase of acid diffusion leads to degraded LWR or CDU. With respect to a balance of sensitivity, LWR and CDU, the polymer-bound acid generator is regarded as having a high potential.

Since iodine atoms are highly absorptive to EUV of wavelength 13.5 nm, they generate secondary electrons upon light exposure. This effect is noteworthy in the EUV lithography. Patent Document 2 describes a photoacid generator having an iodized anion. Patent Document 3 describes a photoacid generator having an iodized anion and containing a polymerizable group. Although the lithography performance is improved to some extent, the solubility of iodine-containing compounds in organic solvents is not so high, accompanied with a concern about precipitation in the solvent.

Patent Documents 4 and 5 disclose resist compositions comprising a polymer obtained by copolymerizing a polymerizable group-containing salicylic acid or protected one thereof with another monomer. Patent Document 6 describes a polymer obtained from a dihydroxystyrene monomer in which two adjacent hydroxy groups are protected with a cyclic acetal. Salicylic acid is structured to have hydroxy and carboxy groups on adjacent carbon atoms on an aromatic ring, with the substituent groups forming a hydrogen bond. For this reason, despite two polar groups included, salicylic acid is relatively highly soluble in organic solvents and relatively easily copolymerizable with other monomers. However, salicylic acid polymers are still unsatisfactory in performance as resist material. There is a need for a resist material which is useful in forming small-size patterns.

### CITATION LIST

Patent Document 1: JP 4425776
Patent Document 2: JP 6720926
Patent Document 3: JP 6973274
Patent Document 4: JP-A 2023-131926
Patent Document 5: WO 2023/162837
Patent Document 6: JP 7203133

### SUMMARY OF THE INVENTION

In the field of chemically amplified resist compositions using acids as the catalyst, it is desired to develop a resist composition exhibiting a high sensitivity, reduced LWR of line patterns, and improved CDU of hole patterns, and etch resistance after pattern formation.

An object of the invention is to provide a chemically amplified resist composition which, when processed by photolithography using high-energy radiation such as KrF excimer laser, ArF excimer laser, EB or EUV, exhibits a satisfactory solvent solubility, high sensitivity, high contrast, and improved lithography properties including LWR, CDU, EL, and DOF as well as resistance to pattern collapse and etch resistance in small-size pattern formation. Another object of the invention is to provide a pattern forming process using the resist composition.

The inventor has found that using a polymer comprising repeat units having a cyclic acetal structure fused to an aromatic ring and a photoacid generator containing a fluoroalkane sulfonic acid anion having an aromatic ring structure substituted with iodine or iodine and bromine, a chemically amplified resist composition exhibiting a high sensitivity, high contrast, high resolution, and improved lithography properties including LWR, CDU, EL and DOF as well as etch resistance after pattern formation is constructed.

In one aspect, the invention provides a chemically amplified resist composition comprising
(A) a polymer comprising repeat units having the formula (a1) and being free of repeat units adapted to generate acid upon light exposure,
(B) a photoacid generator containing a fluoroalkane sulfonic acid anion having an aromatic ring structure substituted with iodine or iodine and bromine, and
(C) an organic solvent.

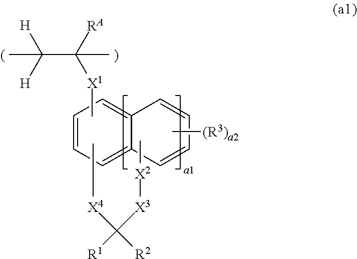

Herein a1 is 0 or 1, a2 is 0, 1, 2 or 3 when a1=0 and a2 is 0, 1, 2, 3, 4 or 5 when a1=1,
R^{A} is hydrogen, fluorine, methyl or trifluoromethyl,
X¹ is a single bond, *—C(═O)—O— or *—C(═O)—N(H)—, * designates a point of attachment to the carbon atom in the backbone,
X² is a single bond, a C₁-C₄ aliphatic hydrocarbylene group, carbonyl, sulfonyl or a group obtained by combining the foregoing,
X³ and X⁴ are each independently oxygen or sulfur, with the proviso that X² and X⁴ are attached to adjacent carbon atoms on the aromatic ring,
R¹ and R² are each independently hydrogen or a C₁-C₂₀ hydrocarbyl group which may contain a heteroatom, R¹ and R² may bond together to form a ring with the carbon atom to which they are attached,
R³ is halogen, hydroxy, cyano, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbyloxycarbonyl group which may contain a heteroatom, C₁-C₂₀ hydrocarbylthio group which may contain a heteroatom, or —N(R^{3A})(R^{3B}), wherein R^{3A} and R^{3B} are each independently hydrogen or a C₁-C₆ hydrocarbyl group; when a2 is 2 or more, a plurality of R³ may be identical or different and a plurality of R³ may bond together to form a ring with the carbon atoms in the aromatic ring to which they are attached.

Preferably, both X³ and X⁴ are oxygen. Also preferably, X² is carbonyl.

In a preferred embodiment, the photoacid generator has the formula (1).

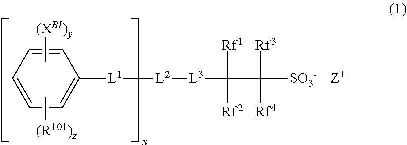

Herein x is 1, 2 or 3, y is 1, 2, 3, 4 or 5, z is 0, 1, 2 or 3, and 1≤y+z≤5,
X^{BI} is iodine when y is 1, and X^{BI} is iodine or bromine, at least one being iodine, when y is 2, 3, 4 or 5,
L¹ is a single bond, ether bond, ester bond, sulfonate ester bond, sulfonamide bond, amide bond, carbonate bond, carbamate bond, or a C₁-C₆ saturated hydrocarbylene group, some —CH₂— in the hydrocarbylene group may be replaced by an ether bond, ester bond, sulfonate ester bond, sulfonamide bond, amide bond, carbonate bond, or carbamate bond,
L² is a single bond or a C₁-C₂₀ hydrocarbylene group which may contain a heteroatom when x is 1, L² is a C₁-C₂₀ (x+1)-valent hydrocarbon group which may contain a heteroatom when x is 2 or 3,
L³ is a single bond, ether bond, ester bond, sulfonate ester bond, carbonate bond or carbamate bond,
R¹⁰¹ is hydroxy, carboxy, fluorine, chlorine, pentafluorosulfanyl, a C₁-C₂₀ hydrocarbyl group, C₁-C₂₀ hydrocarbyloxy group, C₁-C₂₀ hydrocarbylthio group, C₂-C₂₀ hydrocarbylcarbonyl group, C₂-C₂₀ hydrocarbyloxycarbonyl group, C₂-C₂₀ hydrocarbylcarbonyloxy group, C₁-C₂₀ hydrocarbylsulfonyloxy group, —N(R^{101A})(R^{101B}), —N(R^{101C})—C(═O)—R^{101D} or —N(R^{101C})—C(═O)—O—R^{101D}, the hydrocarbyl, hydrocarbyloxy, hydrocarbylthio, hydrocarbylcarbonyl, hydrocarbyloxycarbonyl, hydrocarbylcarbonyloxy, and hydrocarbylsulfonyloxy groups may contain at least one moiety selected from fluorine, chlorine, bromine, iodine, hydroxy, amino, ester bond and ether bond, R^{101A} and R^{101B} are each independently hydrogen or a C₁-C₆ saturated hydrocarbyl group, R^{101C} is hydrogen or a C₁-C₆ saturated hydrocarbyl group which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety, R^{101D} is a C₁-C₁₆ aliphatic hydrocarbyl group, C₆-C₁₂ aryl group or C₇-C₁₅ aralkyl group, which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety,
Rf¹ to Rf⁴ are each independently hydrogen, fluorine or trifluoromethyl, at least one being fluorine or trifluoromethyl, Rf¹ and Rf² may bond together to form a carbonyl group, and
Z⁺ is an onium cation.

In a preferred embodiment, Z⁺ is a sulfonium cation having the formula (Z-1) or iodonium cation having the formula (Z-2).

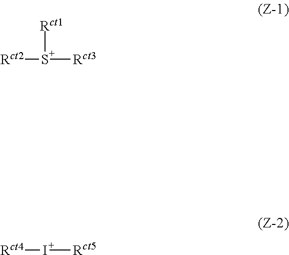

Herein R^{ct1} to R^{ct5} are each independently halogen or a C₁-C₃₀ hydrocarbyl group which may contain a heteroatom, R^{ct1} and R^{ct2} may bond together to form a ring with the sulfur atom to which they are attached.

In another preferred embodiment, Z⁺ is a sulfonium cation having the formula (Z-3).

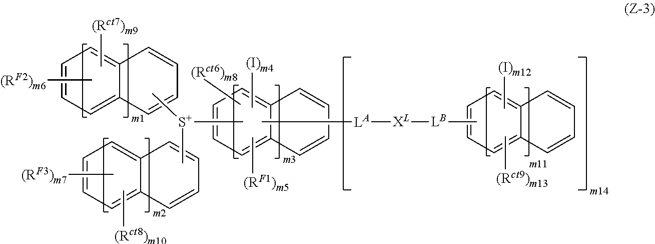

Herein m1 is 0 or 1, m2 is 0 or 1, m3 is 0 or 1, m4 is 0, 1, 2, 3 or 4, m5 is 0, 1, 2, 3 or 4, m6 is 0, 1, 2, 3, 4, 5 or 6, m7 is 0, 1, 2, 3, 4, 5 or 6, m8 is 0, 1 or 2, m9 is 0, 1 or 2, m10 is 0, 1 or 2, m1 is 0 or 1, m12 is 0, 1, 2, 3 or 4, m13 is 0, 1 or 2, m14 is 0, 1 or 2, m1 to m14 are in the range: 0≤m6+m9≤4 when m1=0, 0≤m6+m9≤6 when m1=1, 0≤m7+m10≤4 when m2=0, 0≤m7+m10≤6 when m2=1, 1≤m4+m5+m8+m14≤4 when m3=0, 1≤m4+m5+m8+m14≤6 when m3=1, 0≤m12+m13≤4 when m11=0, 0≤m12+m13≤6 when m11=1, and m4+m12≥1,
R^{F1} to R^{F3} are each independently fluorine, a C₁-C₆ fluorinated saturated hydrocarbyl group, C₁-C₆ fluorinated saturated hydrocarbyloxy group, or C₁-C₆ fluorinated saturated hydrocarbylthio group; when m5 is 2, 3 or 4, a plurality of R^{F1} may be identical or different; when m6 is 2, 3, 4, 5 or 6, a plurality of R^{F2} may be identical or different; when m7 is 2, 3, 4, 5 or 6, a plurality of R^{F3} may be identical or different,
R^{ct6} to R^{ct9} are halogen other than iodine and fluorine, nitro, cyano, a C₁-C₂₀ hydrocarbyl group which may contain a heteroatom, C₁-C₂₀ hydrocarbyloxy group which may contain a heteroatom, or C₁-C₂₀ hydrocarbylthio group which may contain a heteroatom; when m8=2, two R^{ct6} may be identical or different and bond together to form a ring with the carbon atoms to which they are attached; when m9=2, two R^{ct7} may be identical or different and bond together to form a ring with the carbon atoms to which they are attached; when m10=2, two R^{ct8} may be identical or different and bond together to form a ring with the carbon atoms to which they are attached; when m13=2, two R^{ct9} may be identical or different and bond together to form a ring with the carbon atoms to which they are attached,
the aromatic rings directly bonded to S⁺ in the sulfonium cation may bond together to form a ring with S⁺,
L^{A} and L^{B} are each independently a single bond, ether bond, ester bond, amide bond, sulfonate ester bond, sulfonamide bond, carbonate bond or carbamate bond, and
X^{L} is a single bond or a C₁-C₄₀ hydrocarbylene group which may contain a heteroatom.

In a preferred embodiment, the polymer comprises repeat units of at least one type selected from repeat units having the formula (a2) and repeat units having the formula (a3).

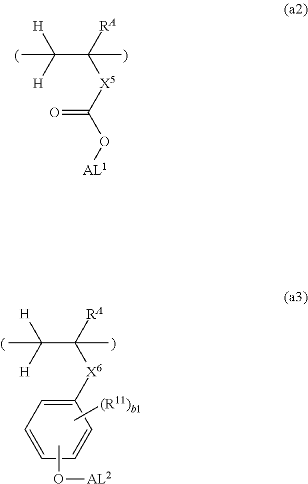

Herein R^{A} is each independently hydrogen, fluorine, methyl or trifluoromethyl,
X⁵ is a single bond, phenylene group, naphthylene group or *—C(═O)—O—X⁵—, the phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen, X⁵¹ is a C₁-C₁₀ saturated hydrocarbylene group, phenylene group or naphthylene group, the saturated hydrocarbylene group may contain hydroxy, ether bond, ester bond or lactone ring,
X⁶ is a single bond, *—C(═O)—O— or *—C(═O)—N(H)—,
* designates a point of attachment to the carbon atom in the backbone,
R¹¹ is halogen, cyano, hydroxy, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when b1 is 2, 3 or 4, a plurality of R¹¹ may be identical or different,
AL¹ and AL² are each independently an acid labile group, and
b1 is 0, 1, 2, 3 or 4.

In a preferred embodiment, the polymer further comprises repeat units having the formula (b).

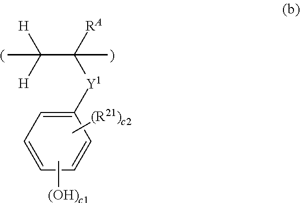

Herein R^{A} is hydrogen, fluorine, methyl or trifluoromethyl,
Y¹ is a single bond, *—C(═O)—O— or *—C(═O)—N(H)—,
* designates a point of attachment to the carbon atom in the backbone,
R²¹ is halogen, carboxy, nitro, cyano, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when c2 is 2, 3 or 4, a plurality of R²¹ may be identical or different,
c1 is 1, 2, 3 or 4, c2 is 0, 1, 2, 3 or 4, and 1≤c1+c2≤5.

The polymer may further comprise repeat units having the formula (c).

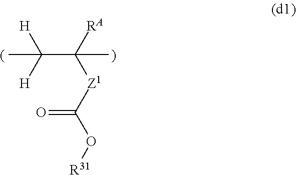

Herein R^{A} is hydrogen, fluorine, methyl or trifluoromethyl,
Z¹ is a single bond, phenylene group, naphthylene group, *—C(═O)—Z¹¹— or *—C(═O)—N(H)—Z¹¹—, the phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen, * designates a point of attachment to the carbon atom in the backbone, Z¹¹ is a C₁-C₁₀ saturated hydrocarbylene group, phenylene group or naphthylene group, the saturated hydrocarbylene group may contain hydroxy, ether bond, ester bond or lactone ring, and
R³¹ is hydrogen or a C₁-C₂₀ group containing at least one structure selected from hydroxy other than phenolic hydroxy, cyano, carbonyl, carboxy, ether bond, ester bond, sulfonate ester bond, carbonate bond, lactone ring, sultone ring and carboxylic anhydride (—C(═O)—O—C(═O)—).

The resist composition may further comprise (D) a quencher, (E) another acid generator, and/or (F) a surfactant.

In another aspect, the invention provides a pattern forming process comprising the steps of applying the chemically amplified resist composition defined herein onto a substrate to form a resist film thereon, exposing the resist film to high-energy radiation, and developing the exposed resist film in a developer.

Typically, the high-energy radiation is ArF excimer laser of wavelength 193 nm, KrF excimer laser of wavelength 248 nm, EB or EUV of wavelength 3 to 15 nm.

### Advantageous Effects of the Invention

When a resist pattern is formed from the chemically amplified resist composition of the invention, a high sensitivity, acid diffusion control ability, and improved lithography properties including LWR, CDU, MEF, EL and DOF are obtained. The invention is also effective for preventing the small-size pattern from collapsing during formation and minimizing development defects. The resist pattern is fully resistant to etching.

### DESCRIPTION OF THE PREFERRED EMBODIMENT

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, Me stands for methyl, Ac for acetyl. Both the broken line (---) and the asterisk (*) designate a point of attachment or valence bond. As used herein, the term “fluorinated” refers to a fluorine-substituted or fluorine-containing compound or group, and “iodized” refers to an iodine-substituted or iodine-containing compound or group. The terms “group” and “moiety” are interchangeable.

The abbreviations and acronyms have the following meaning.
EB: electron beam
EUV: extreme ultraviolet
Mw: weight average molecular weight
Mn: number average molecular weight
Mw/Mn: molecular weight distribution or dispersity
GPC: gel permeation chromatography
PEB: post-exposure bake
PAG: photoacid generator
LWR: line width roughness
EL: exposure latitude
MEF: mask error enhancement factor
DOF: depth of focus
CDU: critical dimension uniformity

### [Chemically Amplified Resist Composition]

### (A) Base Polymer

One embodiment of the invention is a chemically amplified resist composition comprising (A) a base polymer. The base polymer contains a polymer comprising repeat units having the formula (a1), also referred to as repeat units (a1).

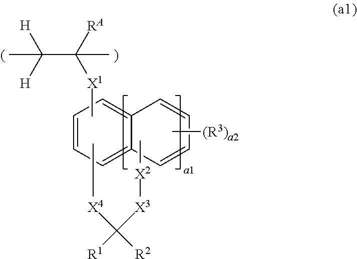

In formula (a1), a1 is 0 or 1. The relevant structure is a benzene ring when a1=0 and a naphthalene ring when a1=1. From the aspect of solvent solubility, the benzene ring corresponding to a1=0 is preferred. The subscript a2 is 0, 1, 2 or 3 when a1=0 and a2 is 0, 1, 2, 3, 4 or 5 when a1=1. It is preferred from the aspect of reactant availability that a2 be 0, 1, 2 or 3, more preferably 0, 1 or 2.

In formula (a1), R^{A} is hydrogen, fluorine, methyl or trifluoromethyl, preferably hydrogen or methyl, most preferably hydrogen.

In formula (a1), X¹ is a single bond, *—C(═O)—O— or *—C(═O)—N(H)—, wherein * designates a point of attachment to the carbon atom in the backbone. X¹ is preferably a single bond or *—C(═O)—O—, most preferably a single bond.

In formula (a1), X² is a single bond, a C₁-C₄ aliphatic hydrocarbylene group, carbonyl, sulfonyl or a group obtained by combining the foregoing. X² is preferably a single bond, carbonyl or sulfonyl from the aspect of reactant availability and more preferably a single bond or carbonyl from the aspect of a polar group formed after reaction.

In formula (a1), X³ and X⁴ are each independently oxygen or sulfur, with the proviso that X² and X⁴ are attached to adjacent carbon atoms on the aromatic ring. X³ and X⁴ may be identical or different. It is preferred from the aspect of reactivity that both X³ and X⁴ be oxygen.

In formula (a1), R¹ and R² are each independently hydrogen or a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, isobutyl, sec-butyl, tert-butyl, n-pentyl, n-hexyl, n-octyl, n-nonyl, n-decyl, undecyl, dodecyl, tridecyl, tetradecyl, pentadecyl, heptadecyl, octadecyl, nonadecyl, and icosyl; C₃-C₂₀ cyclic saturated hydrocarbyl groups such as cyclopropyl, cyclopentyl, cyclohexyl, cylopropylmethyl, 4-methylcyclohexyl, cyclohexylmethyl, norbornyl, and adamantyl; C₂-C₂₀ alkenyl groups such as vinyl, 1-propenyl, 2-propenyl, butenyl, and hexenyl; C₃-C₂₀ cyclic unsaturated hydrocarbyl groups such as cyclohexenyl; C₆-C₂₀ aryl groups such as phenyl and naphthyl; C₇-C₂₀ aralkyl groups such as benzyl, 1-phenylethyl, and 2-phenylethyl, and combinations thereof. In the hydrocarbyl group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

R¹ and R² may bond together to form a ring with the carbon atom to which they are attached. Examples of the ring include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

In formula (a1), R³ is halogen, hydroxy, cyano, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbyloxycarbonyl group which may contain a heteroatom, C₁-C₂₀ hydrocarbylthio group which may contain a heteroatom, or —N(R^{3A})(R^{3B}). R^{3A} and R^{3B} are each independently hydrogen or a C₁-C₆ hydrocarbyl group. Suitable halogen atoms include fluorine, chlorine, bromine and iodine, with fluorine and iodine being preferred. The hydrocarbyl group and hydrocarbyl moiety in the hydrocarbyloxy, hydrocarbyloxycarbonyl and hydrocarbylthio groups may be saturated or unsaturated and straight, branched or cyclic. Examples thereof are as exemplified above for the hydrocarbyl group R¹ and R². In the hydrocarbyl group, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety. When a2 is 2 or more, a plurality of R³ may be identical or different.

When a2 is 2 or more, a plurality of R³ may bond together to form a ring with the carbon atoms on the aromatic ring to which they are attached. Examples of the ring include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

Examples of repeat unit (a1) are shown below, but not limited thereto. Herein R^{A} is as defined above. The positions of attachment of substituent groups on the aromatic ring are interchangeable.

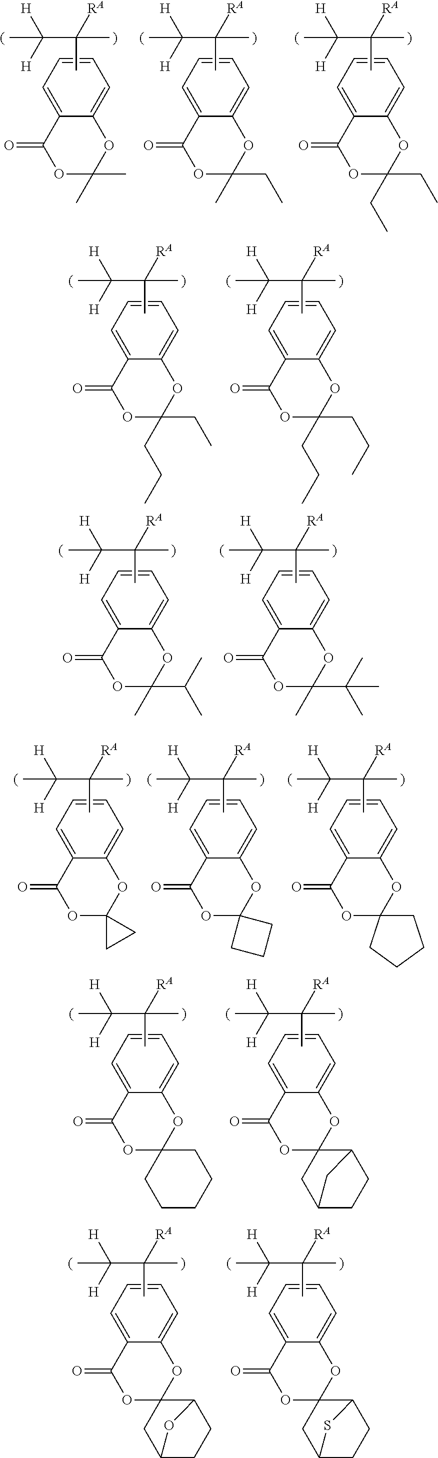

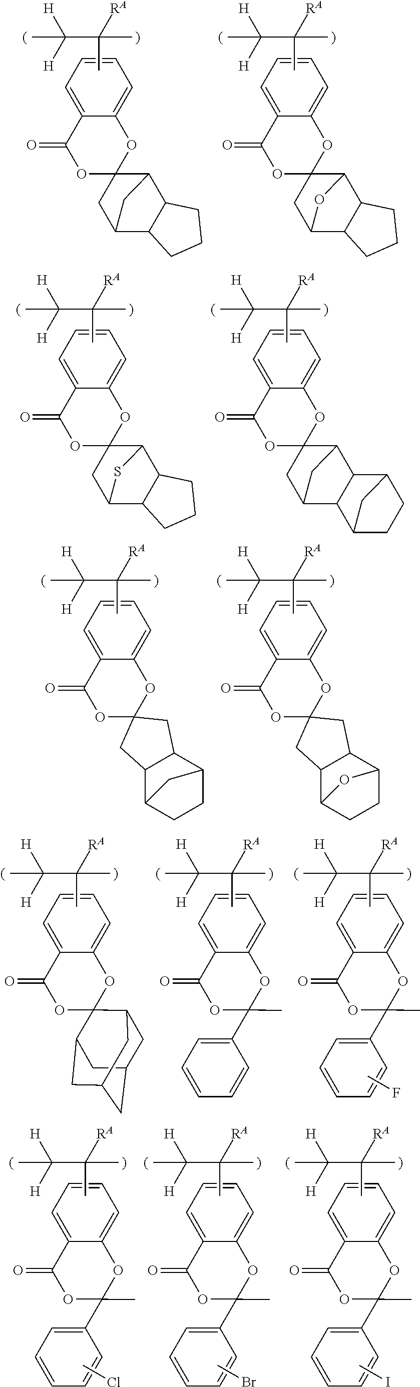

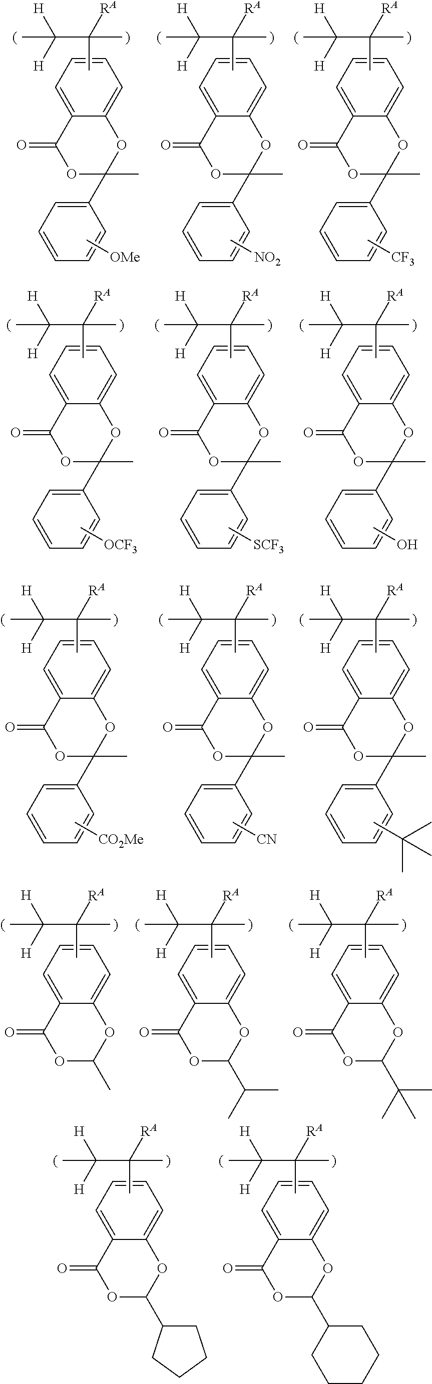

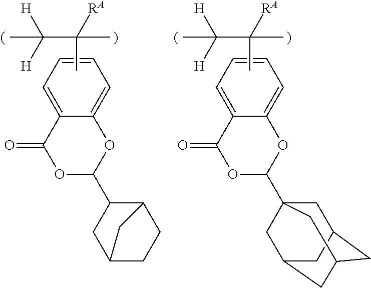

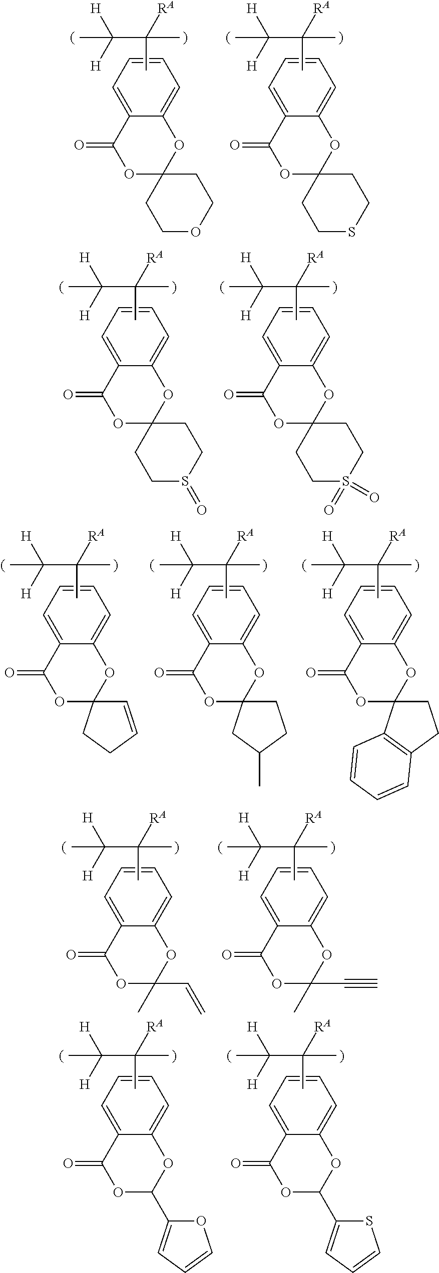

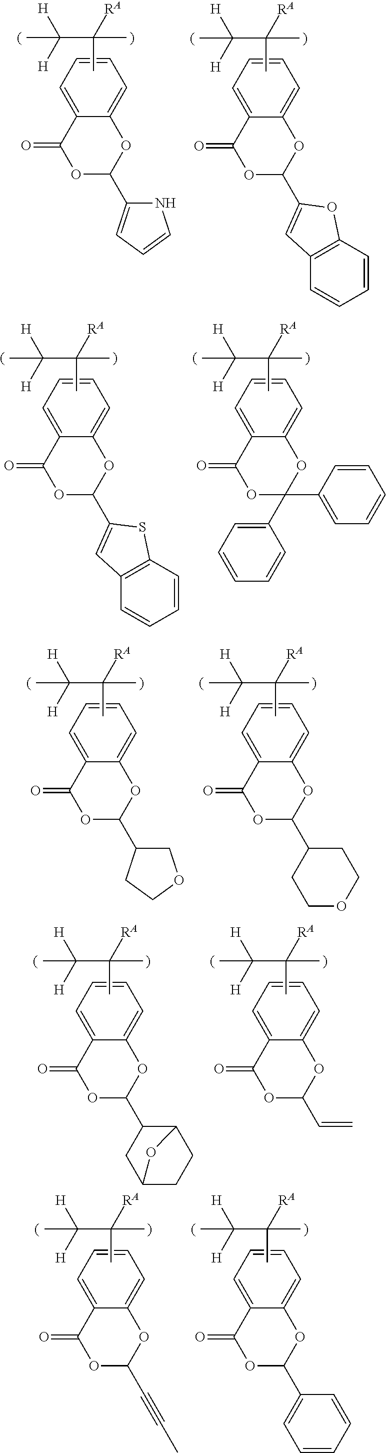

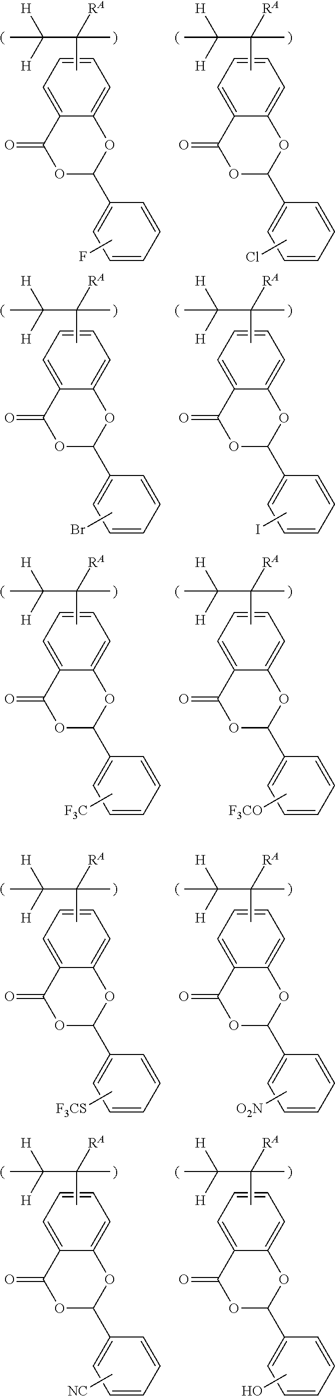

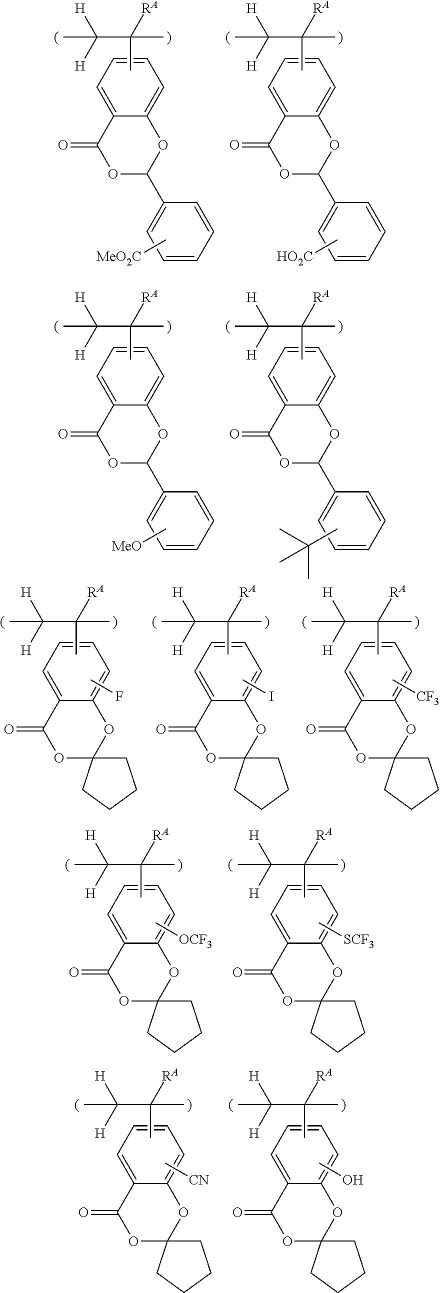

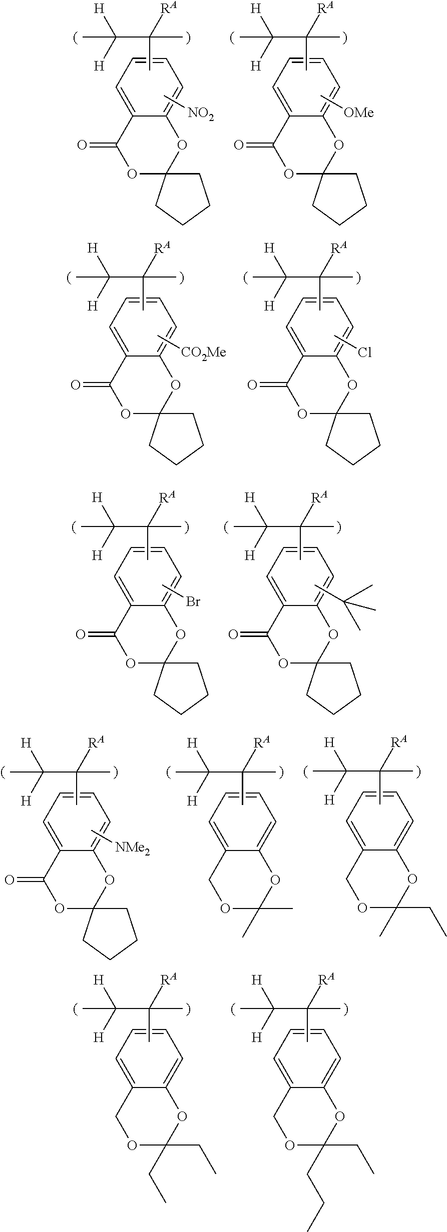

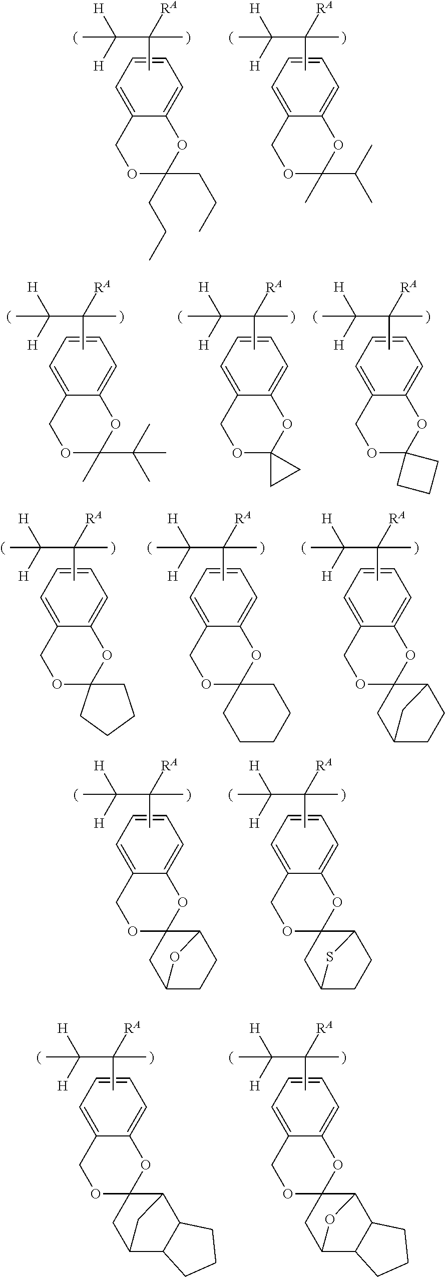

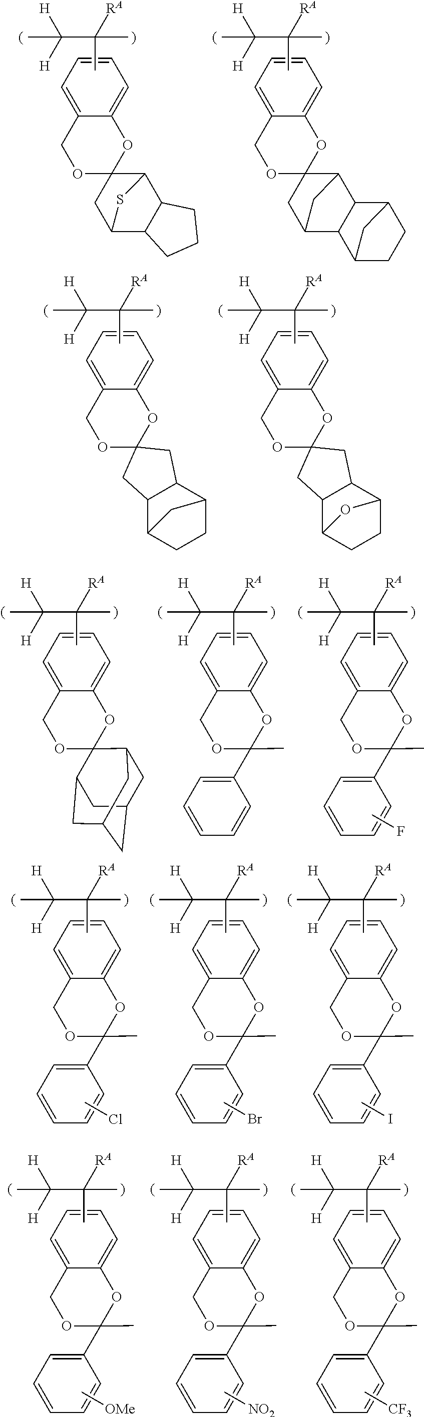

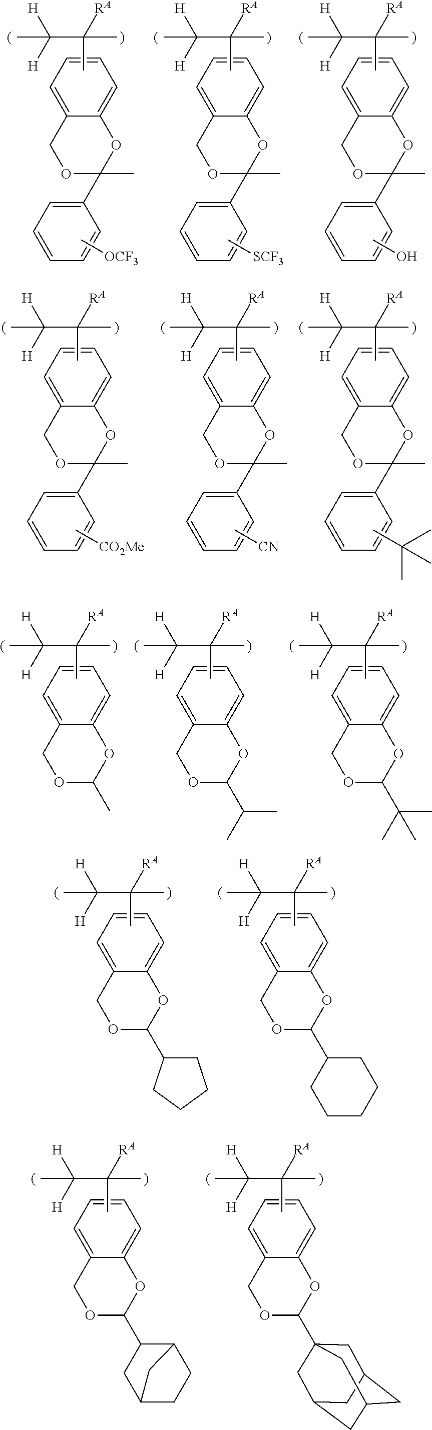

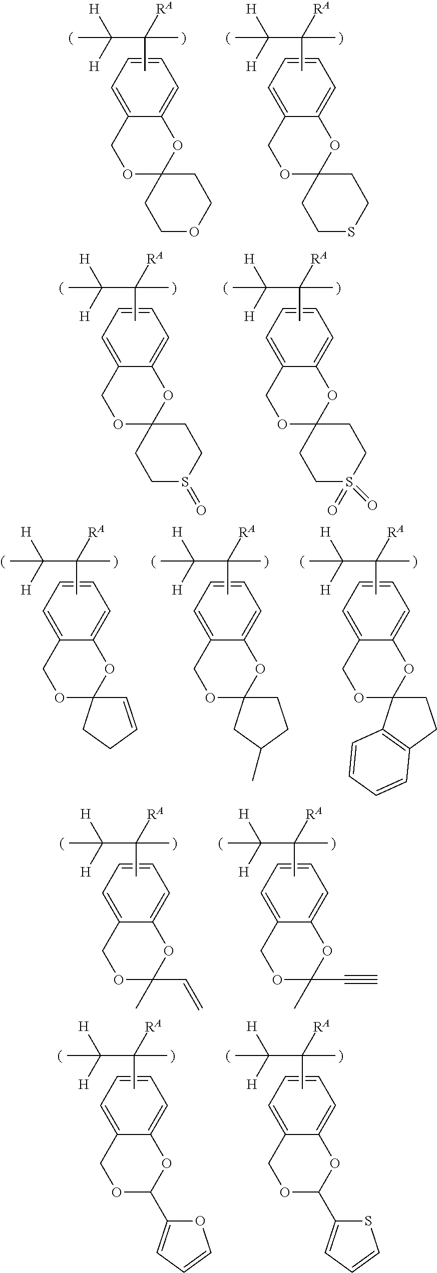

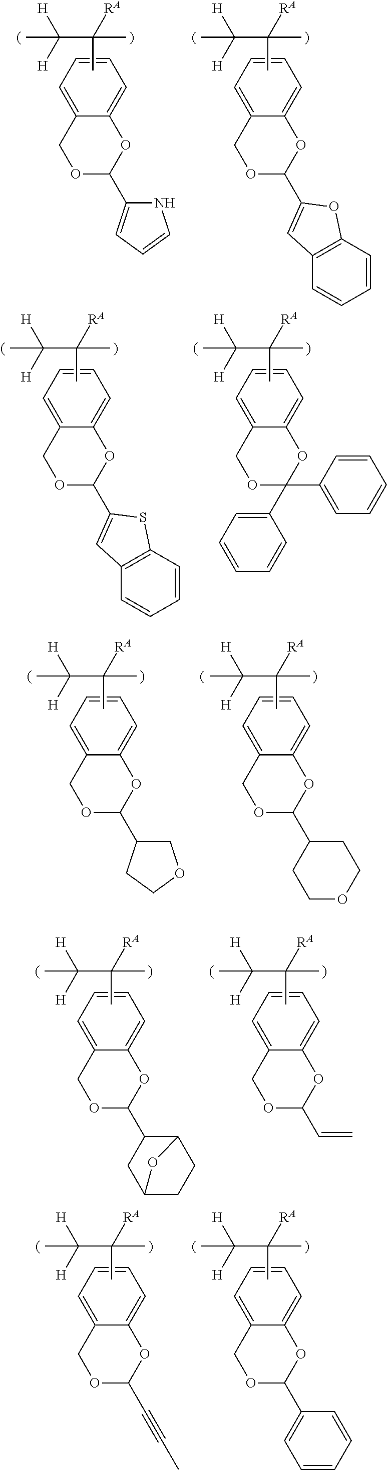

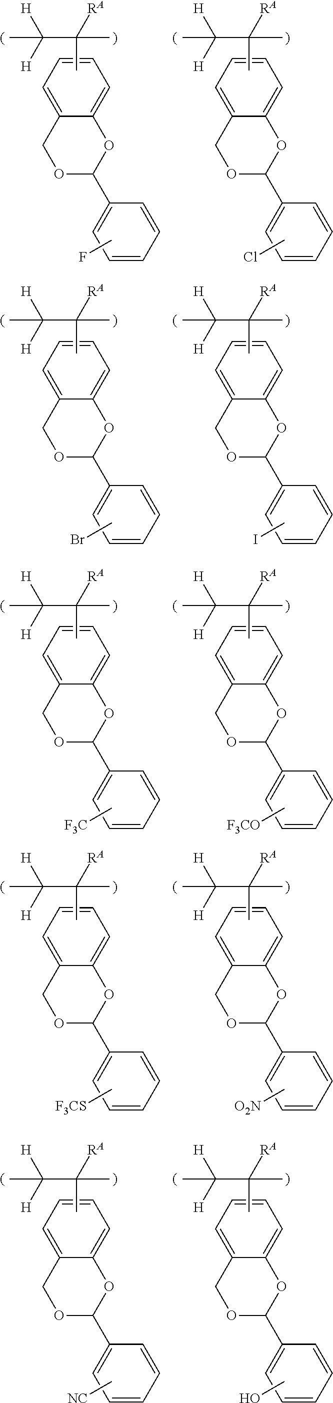

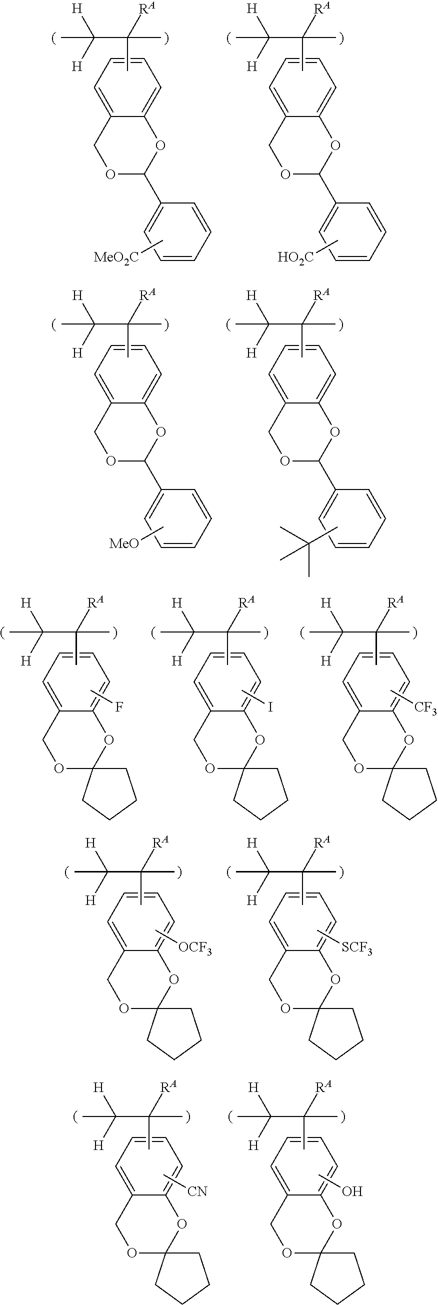

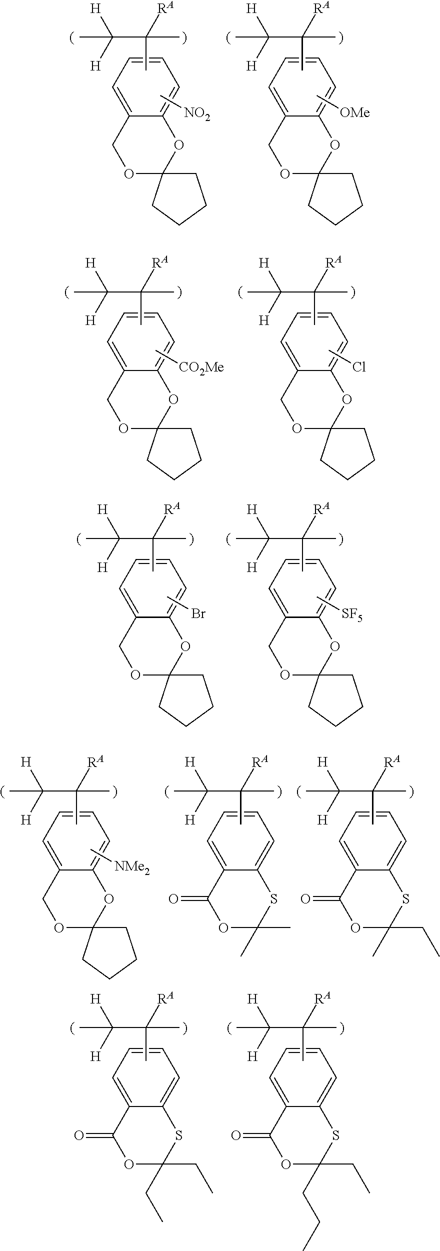

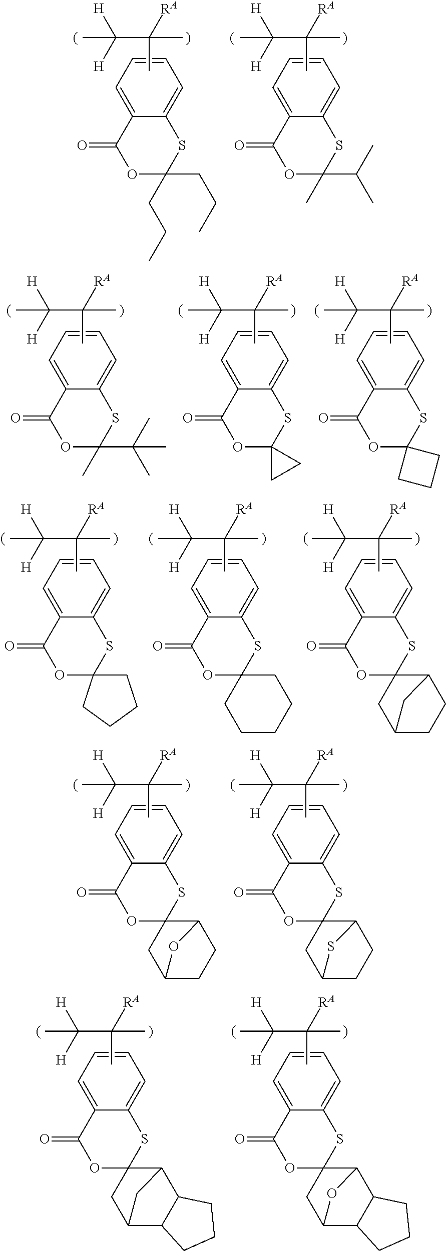

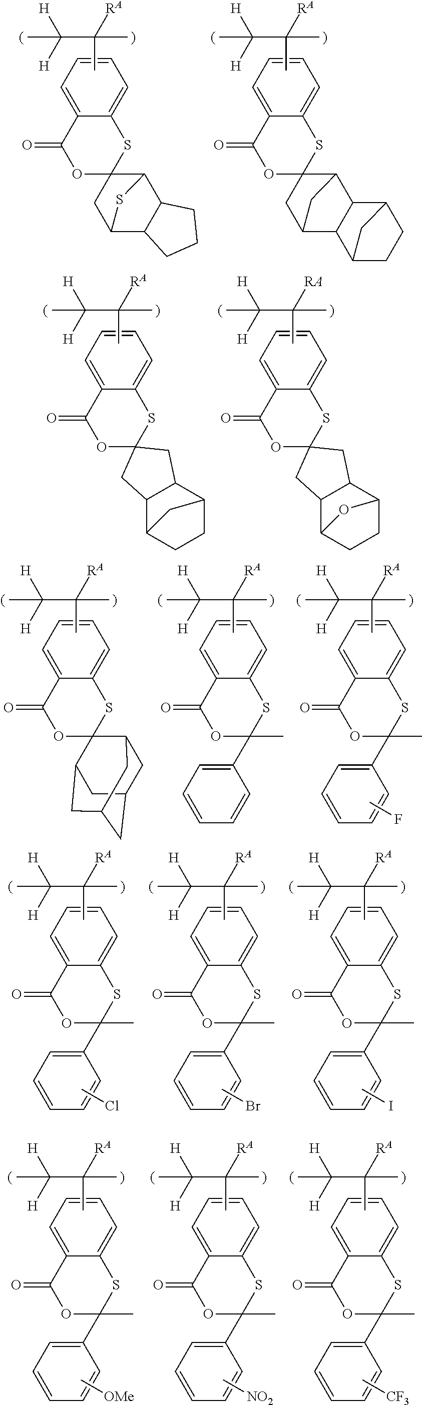

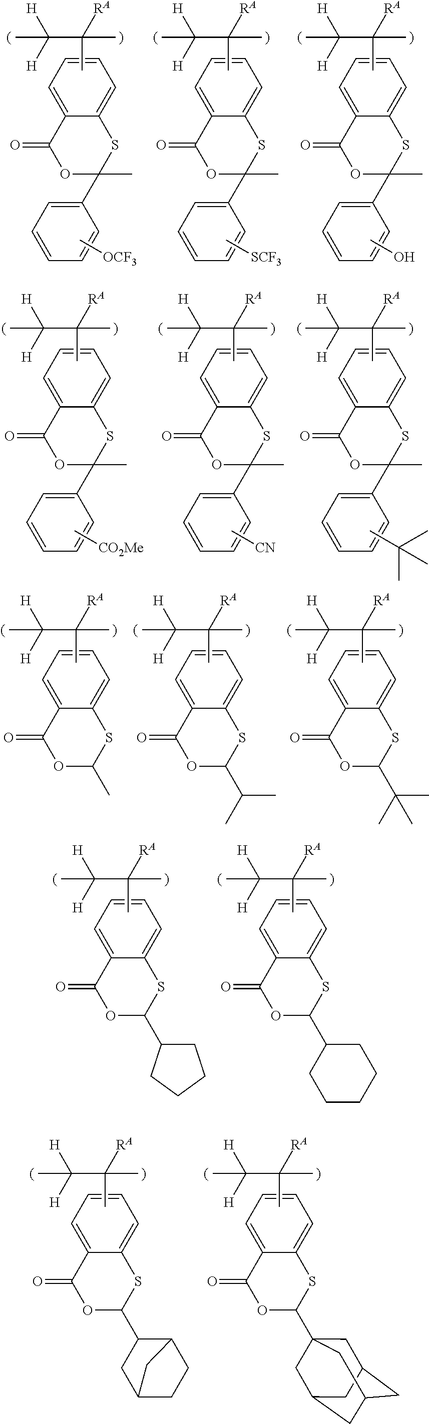

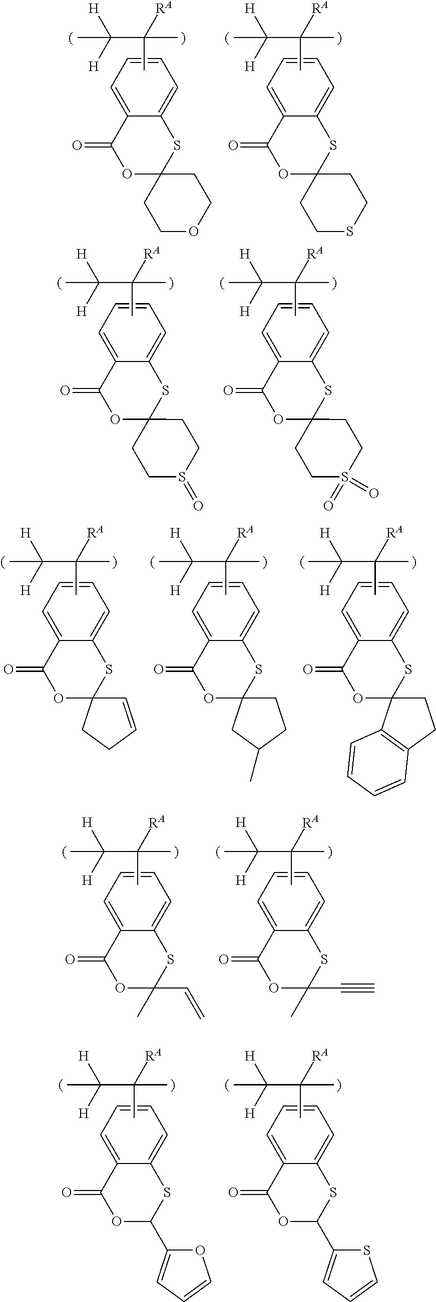

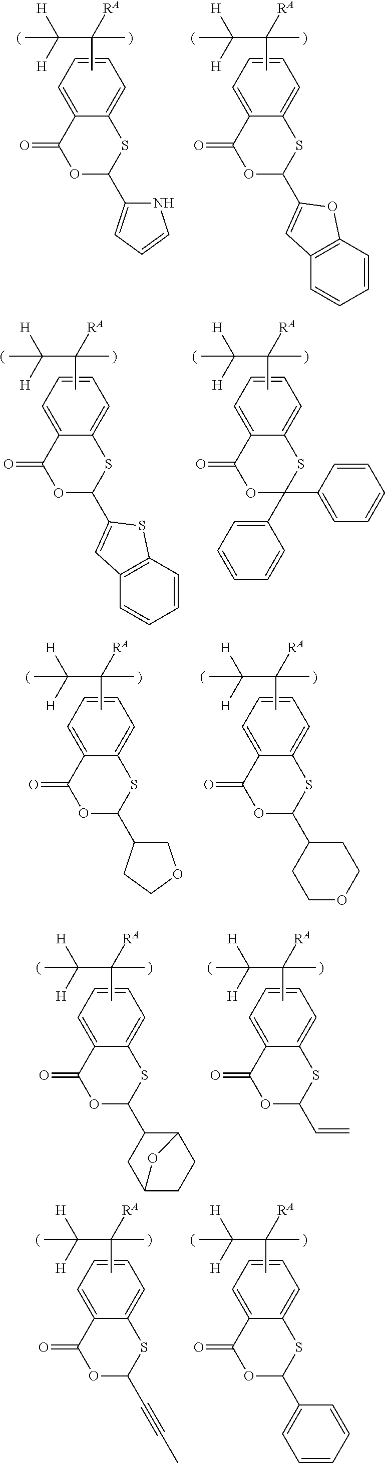

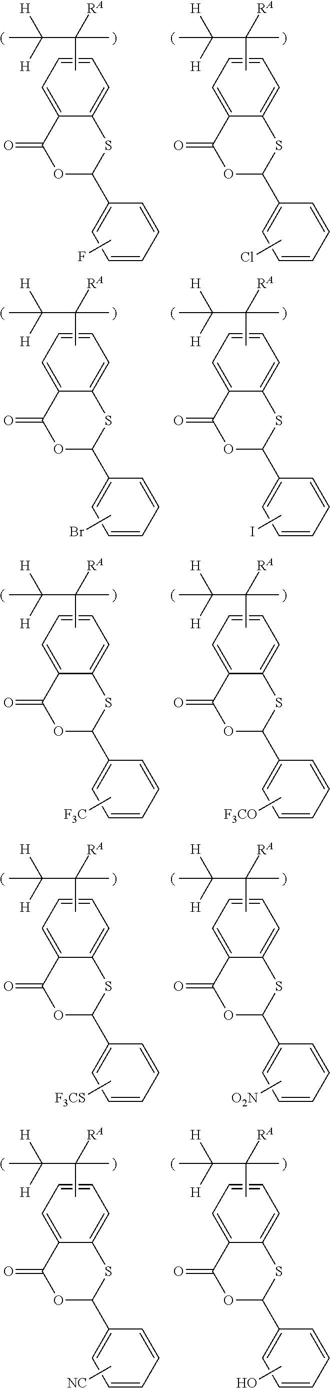

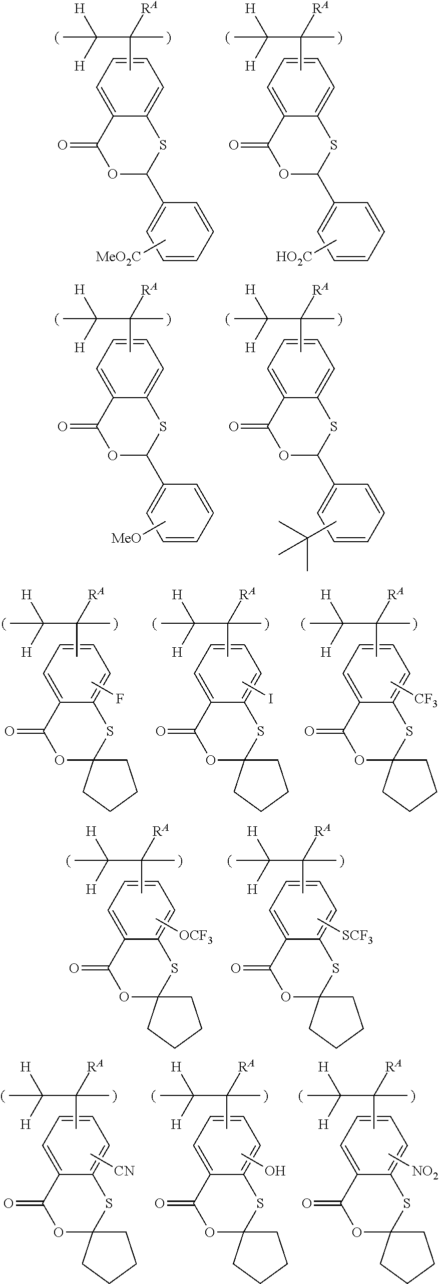

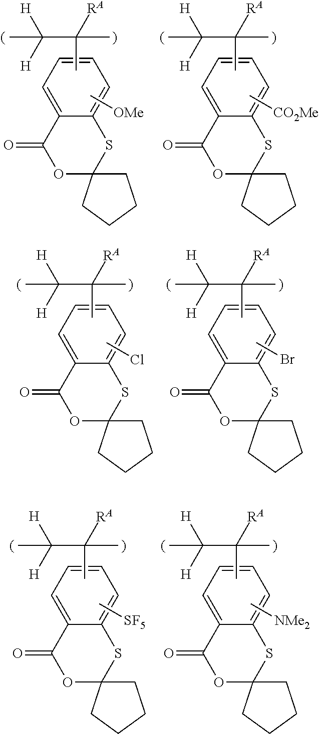

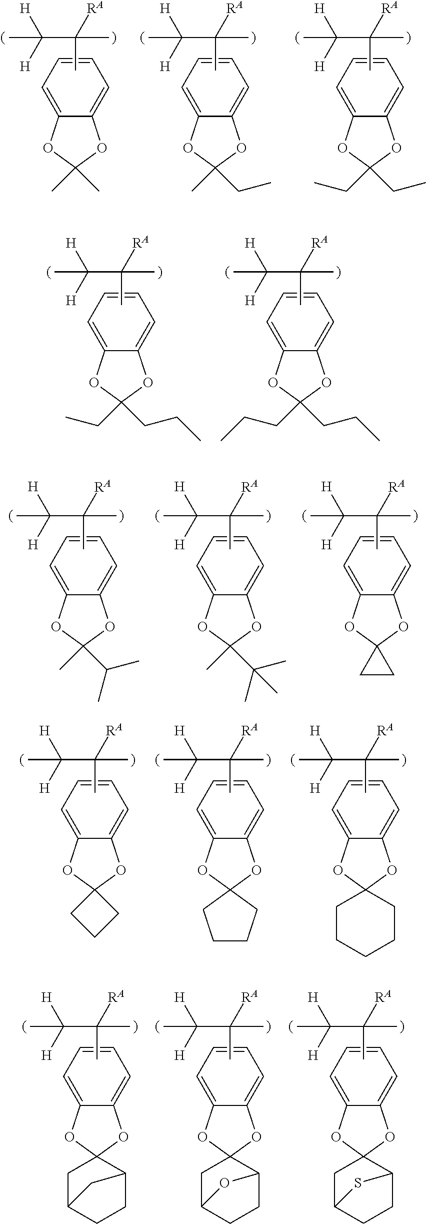

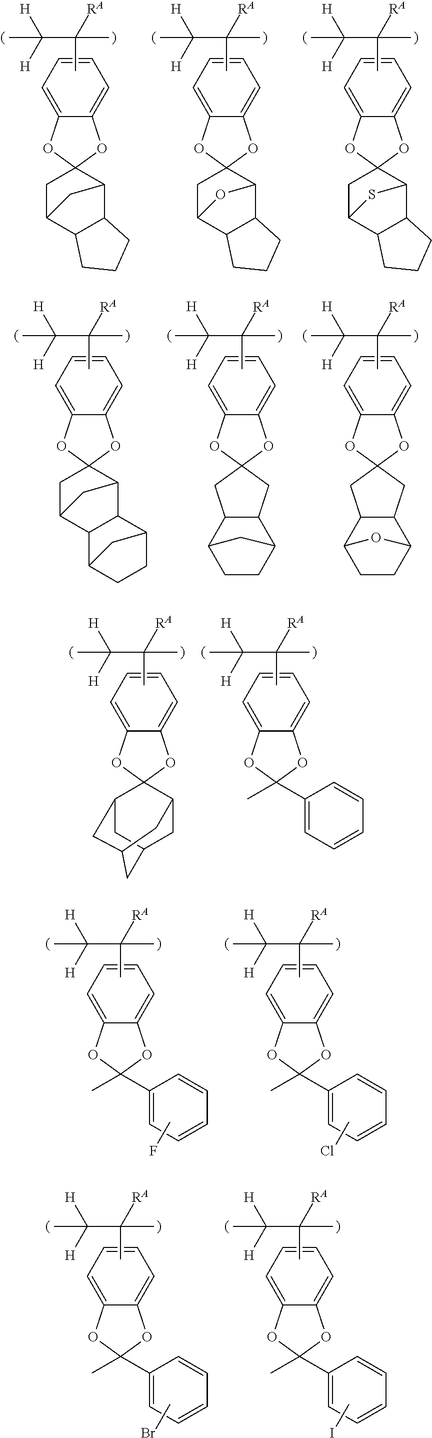

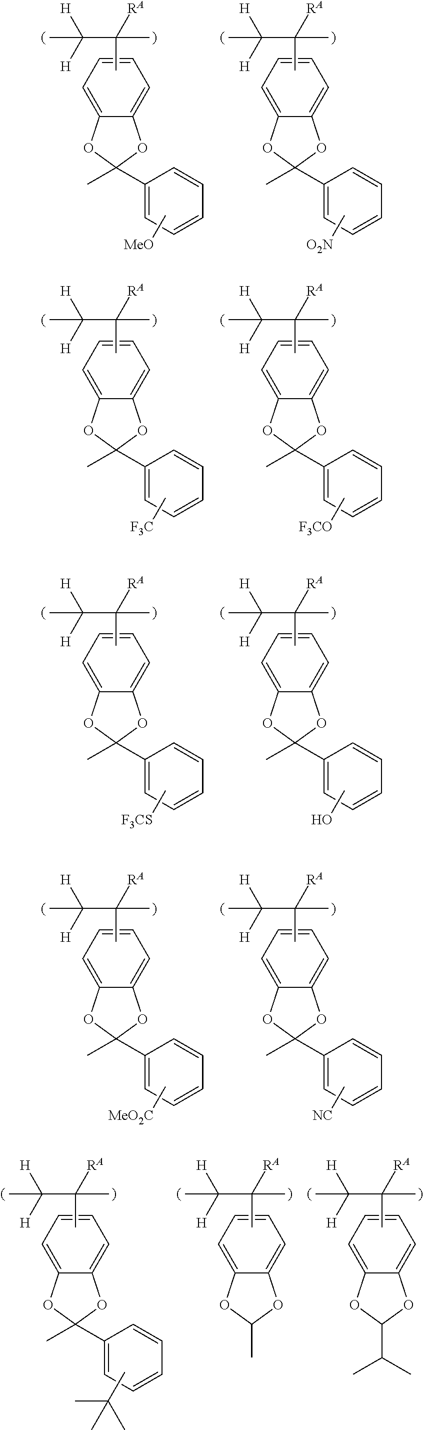

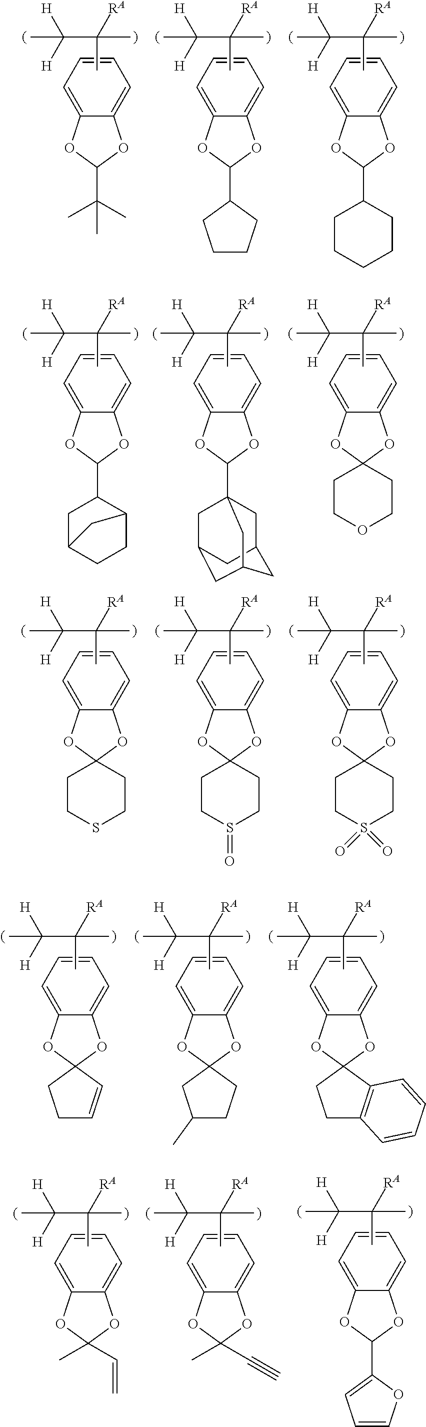

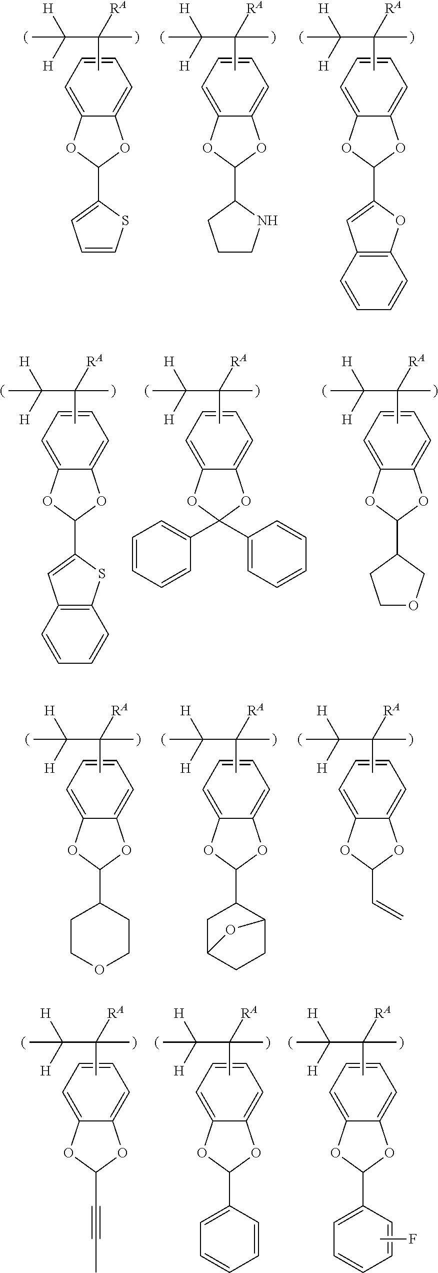

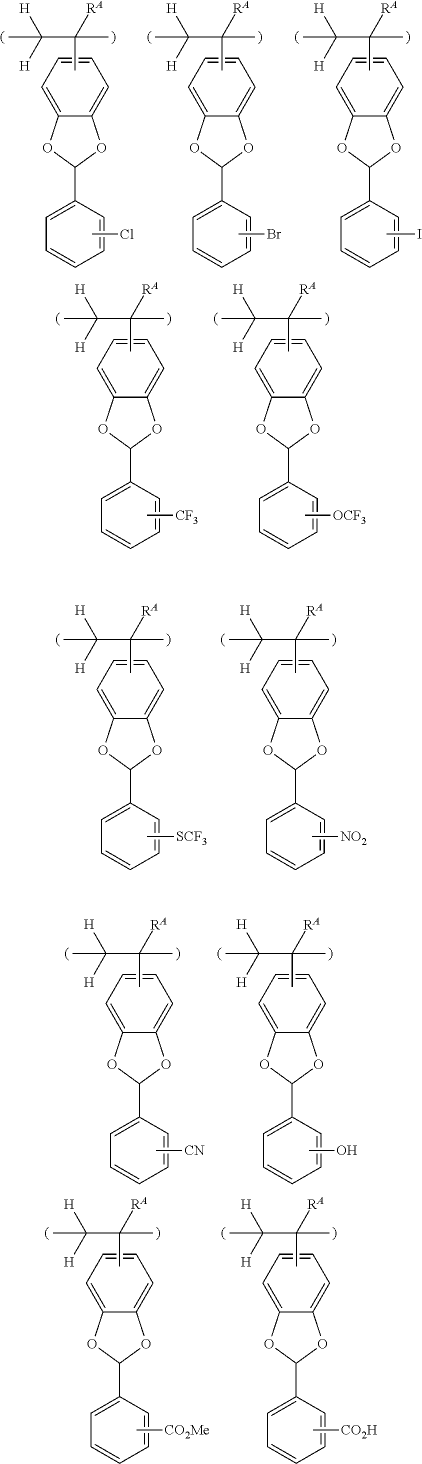

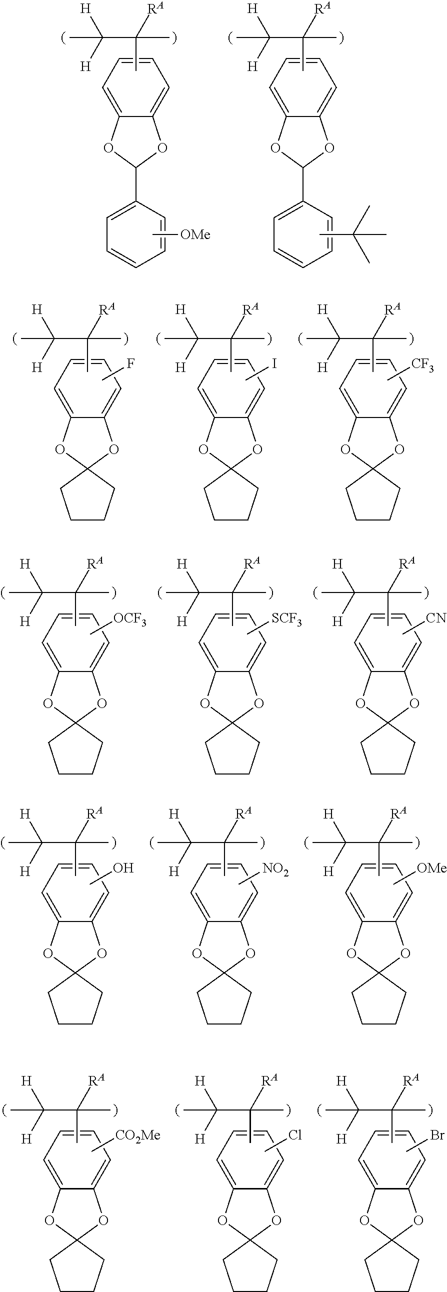

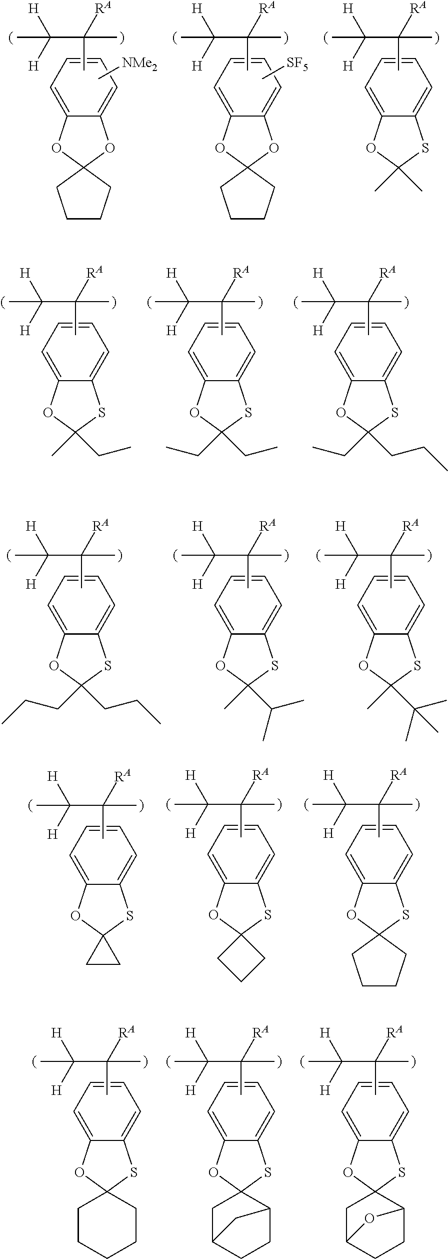

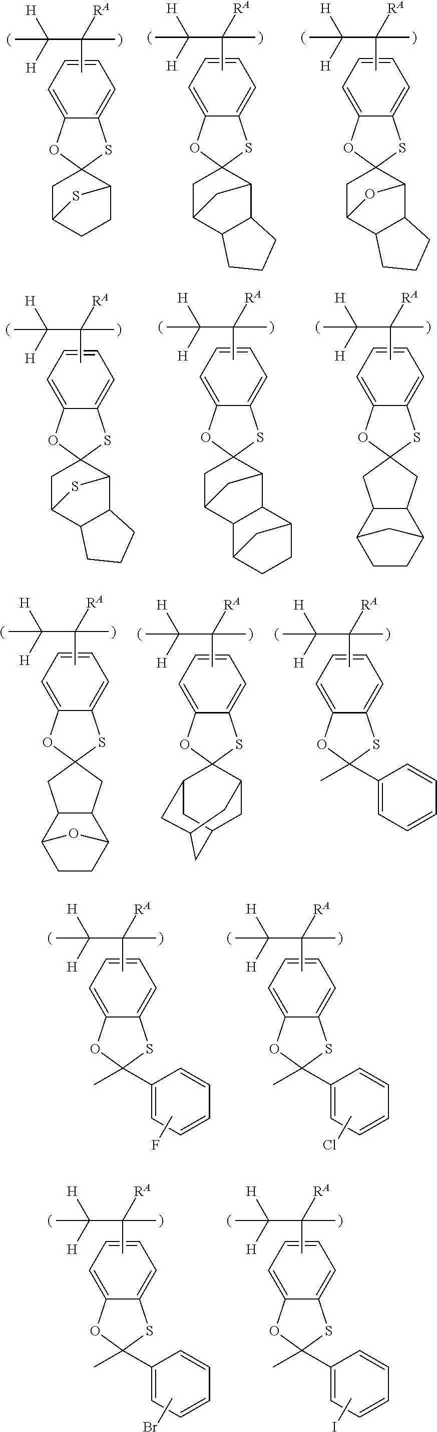

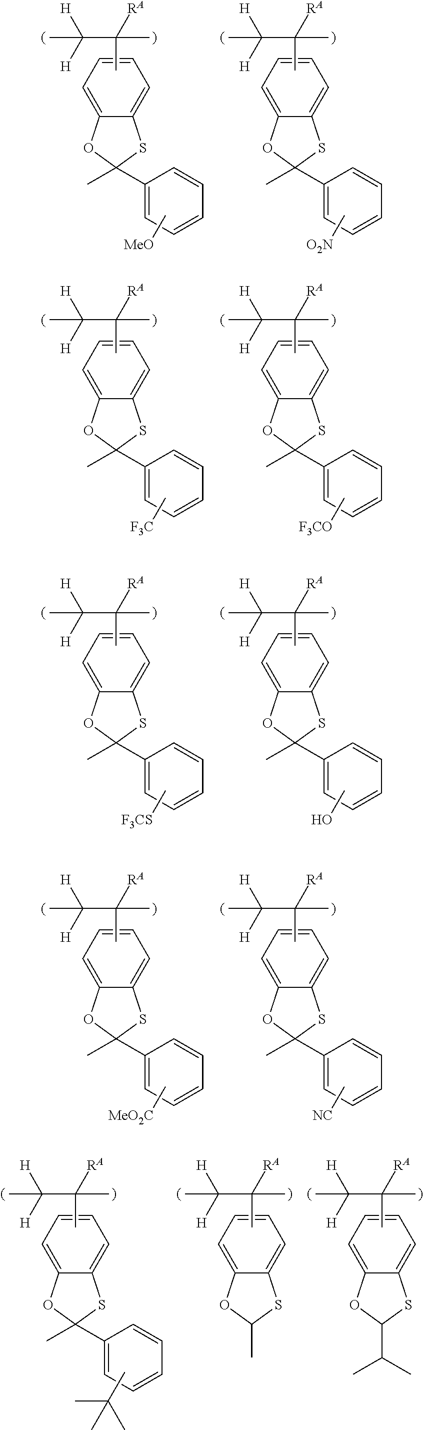

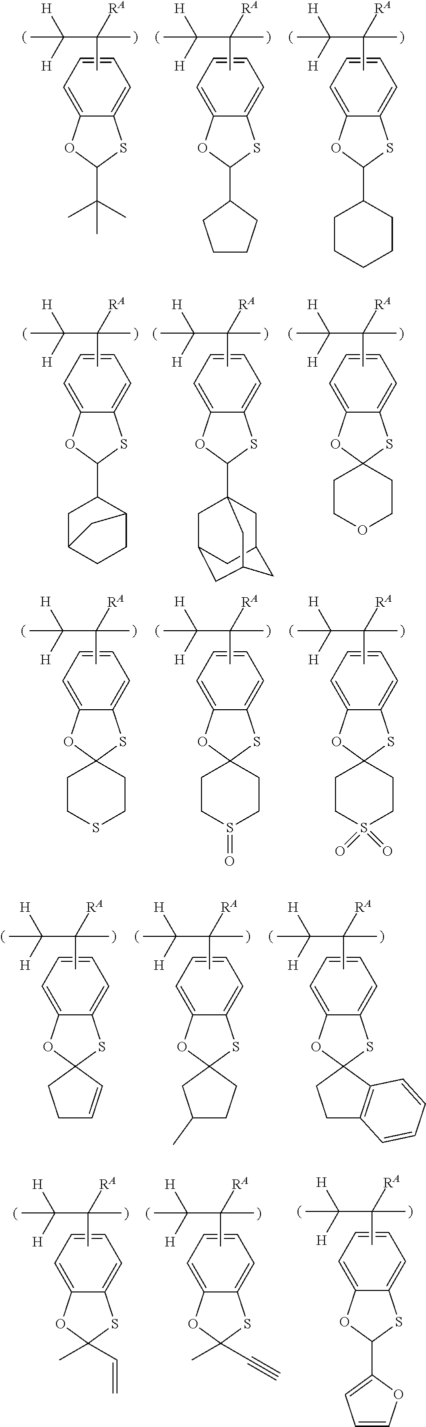

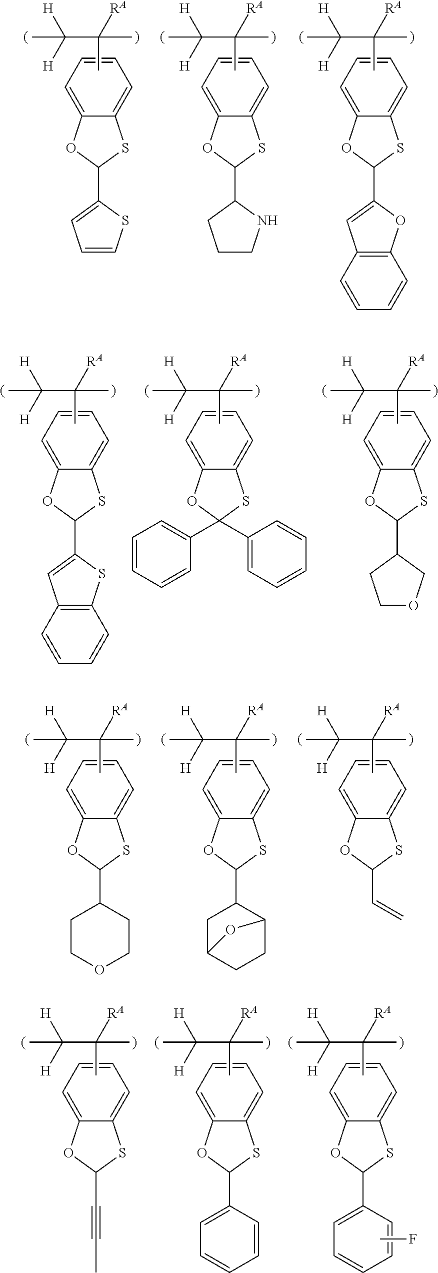

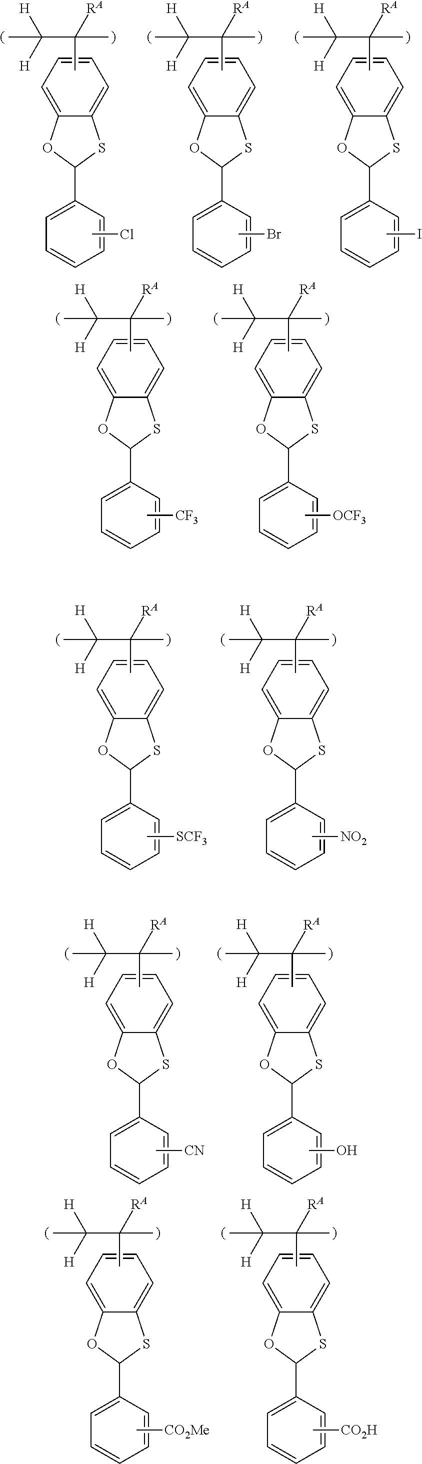

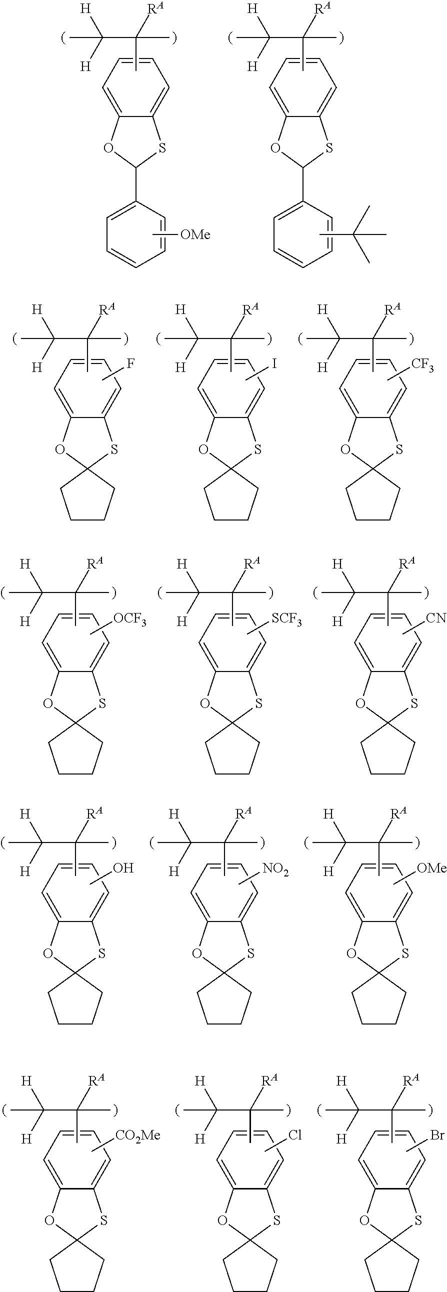

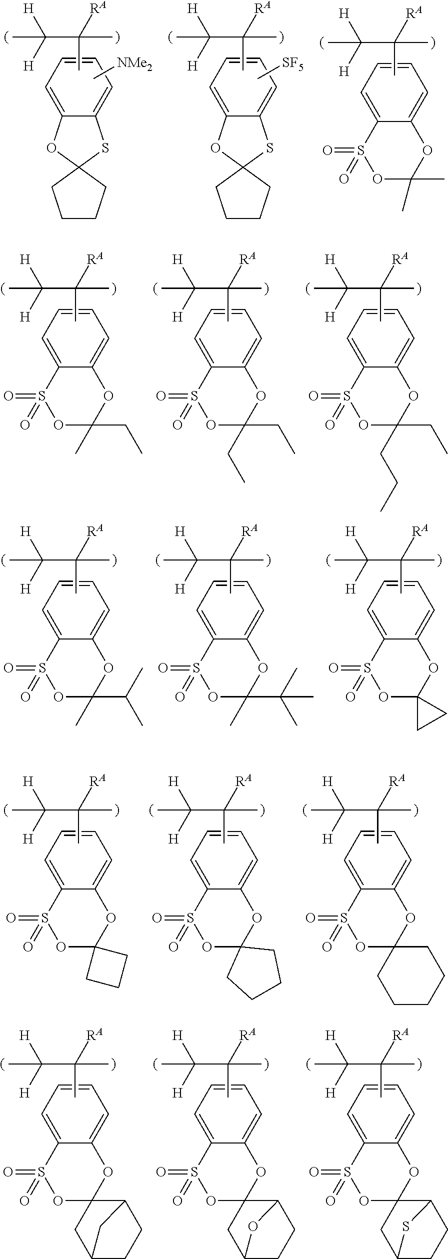

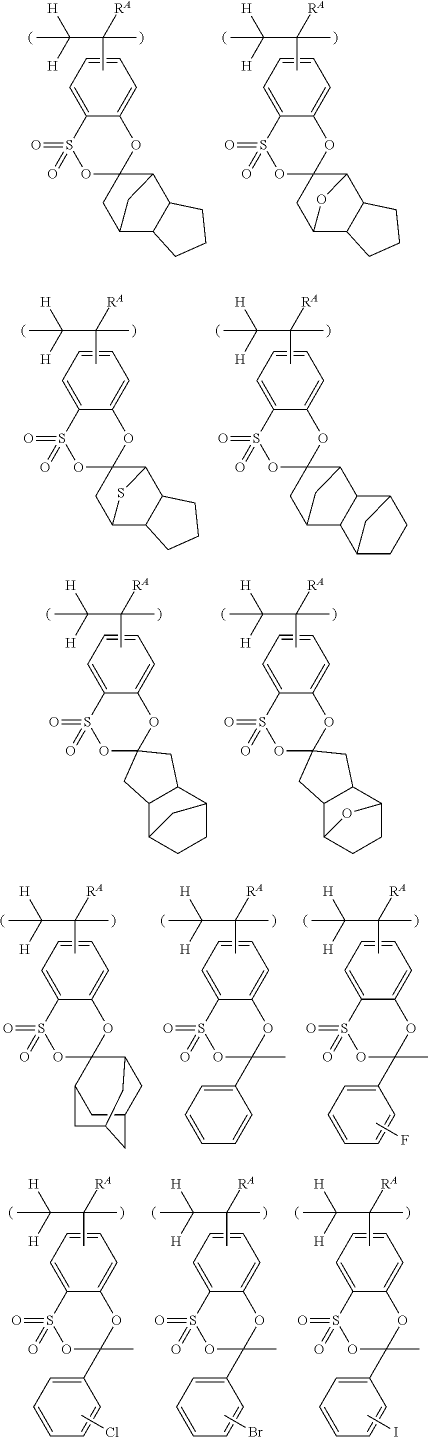

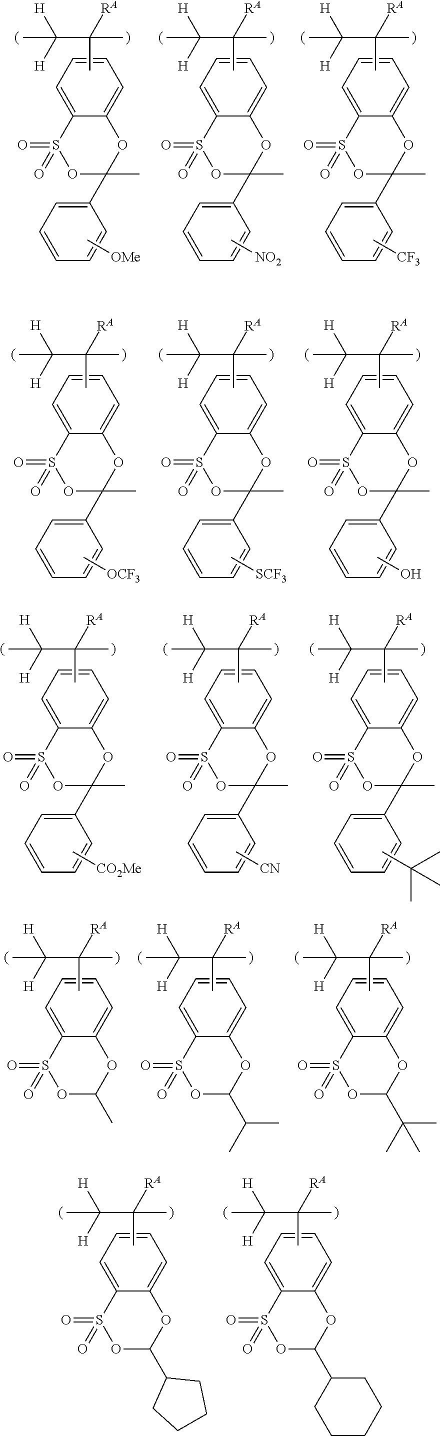

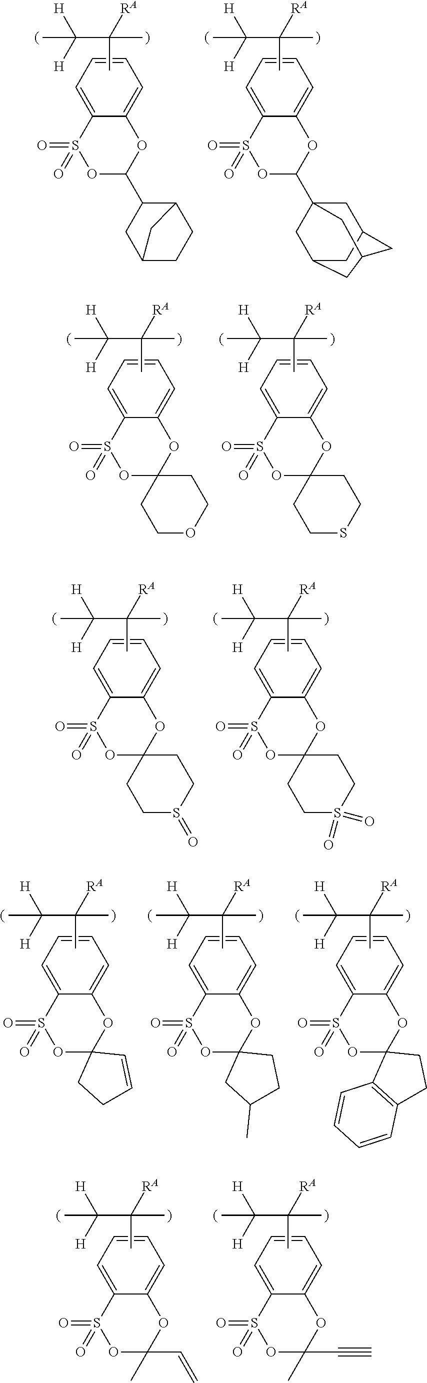

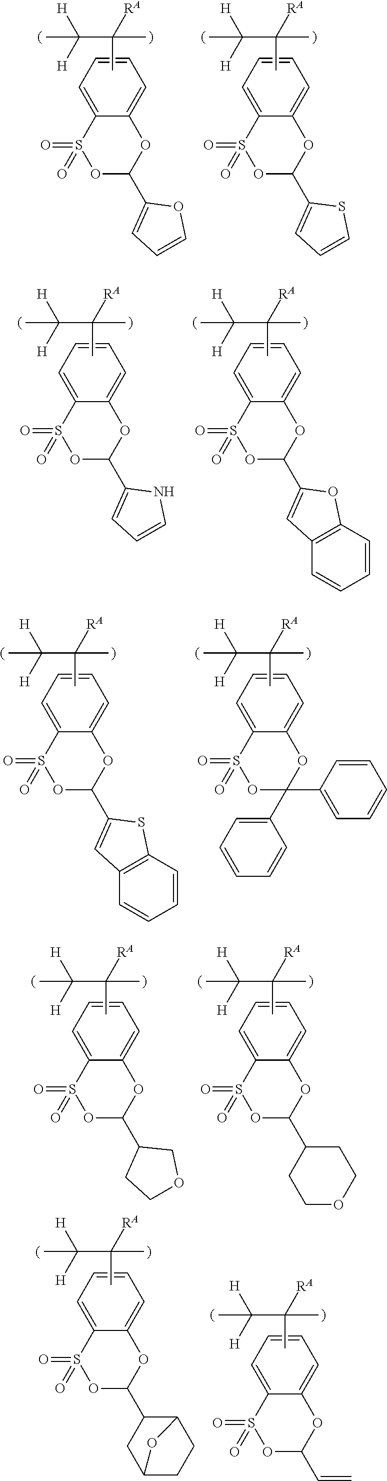

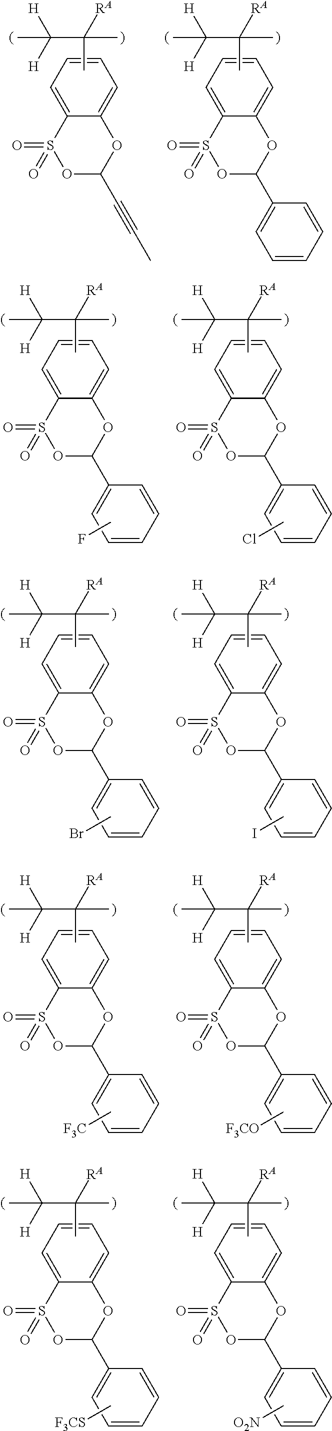

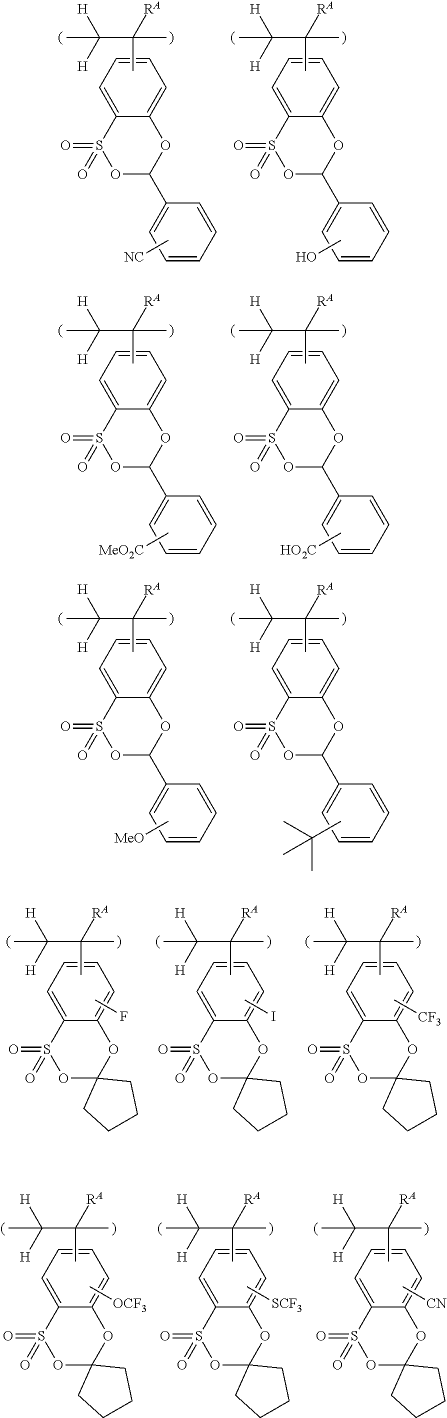

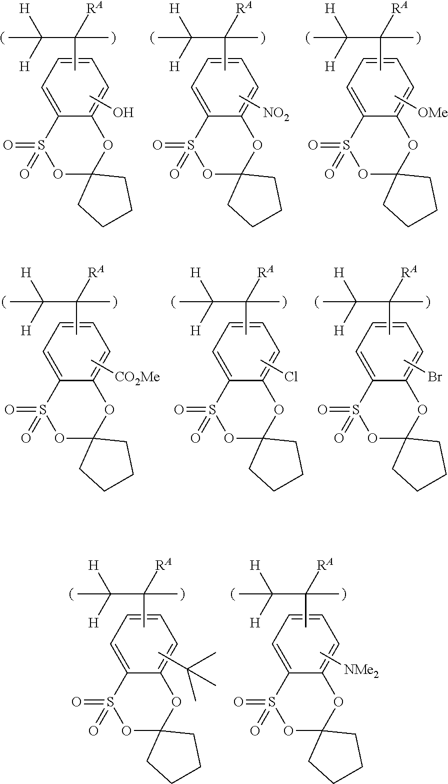

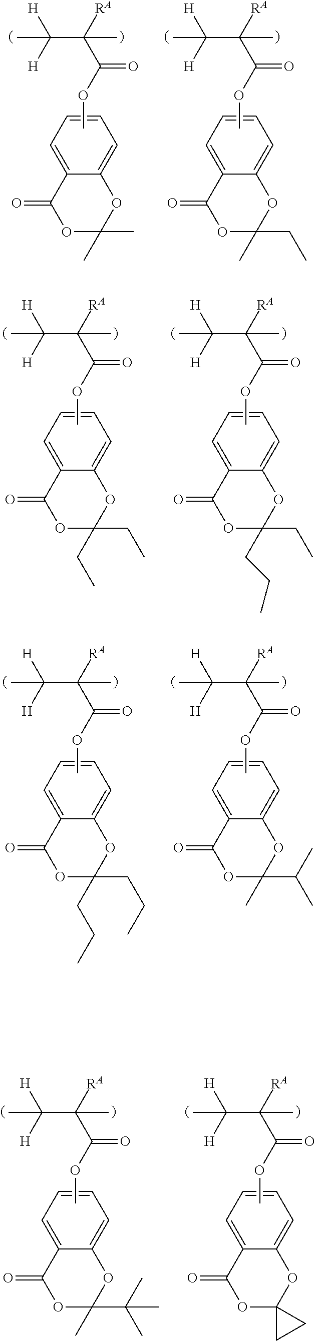

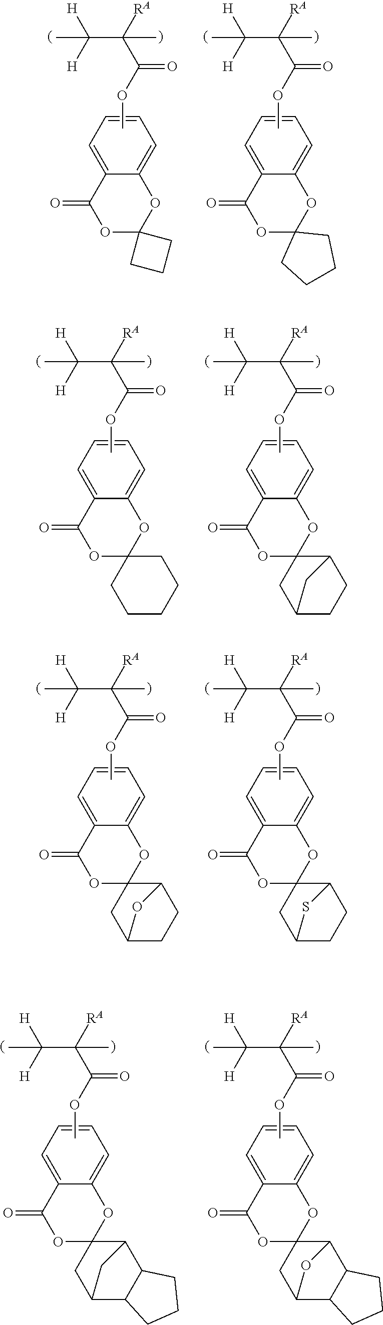

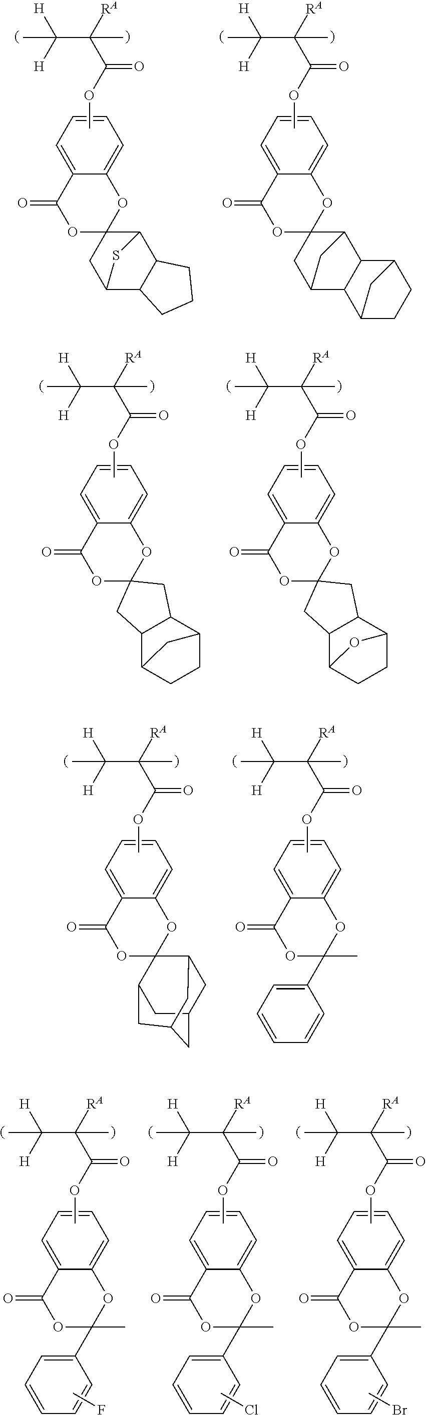

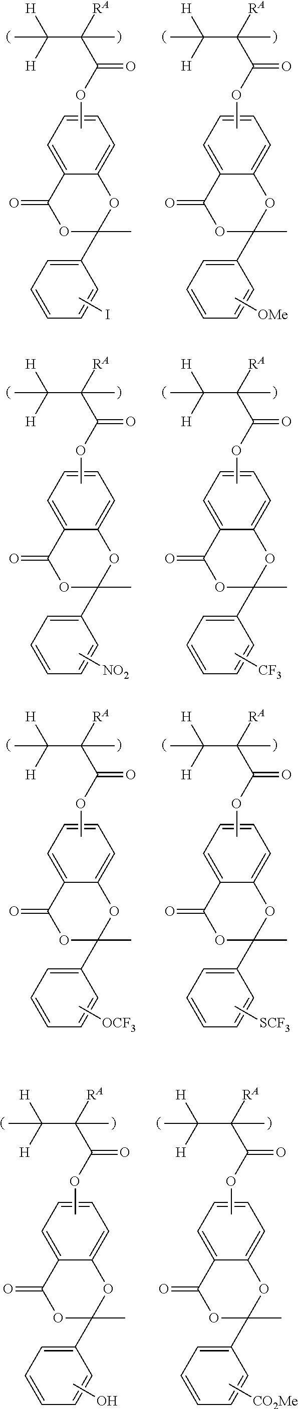

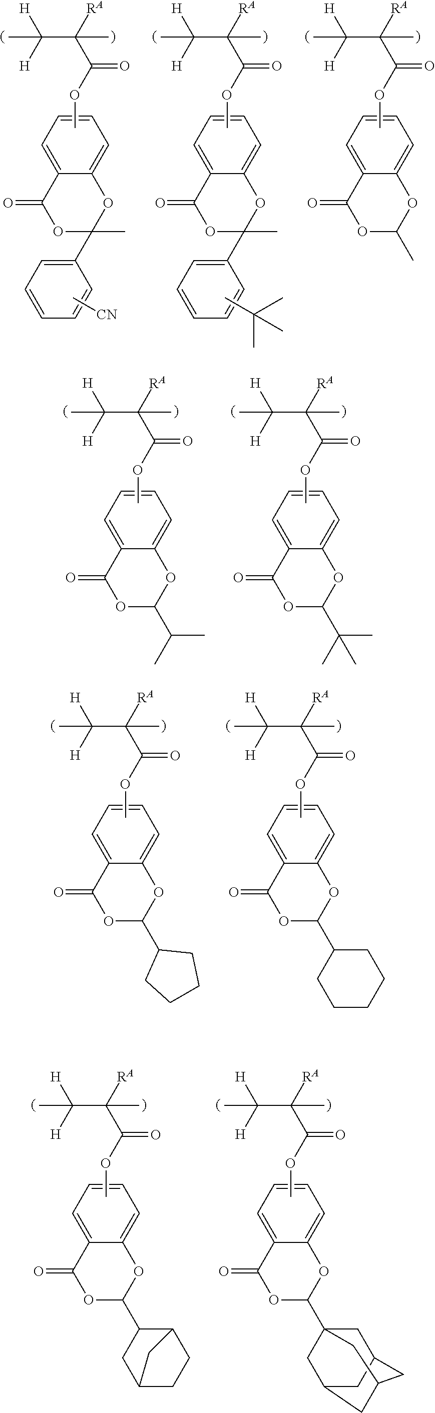

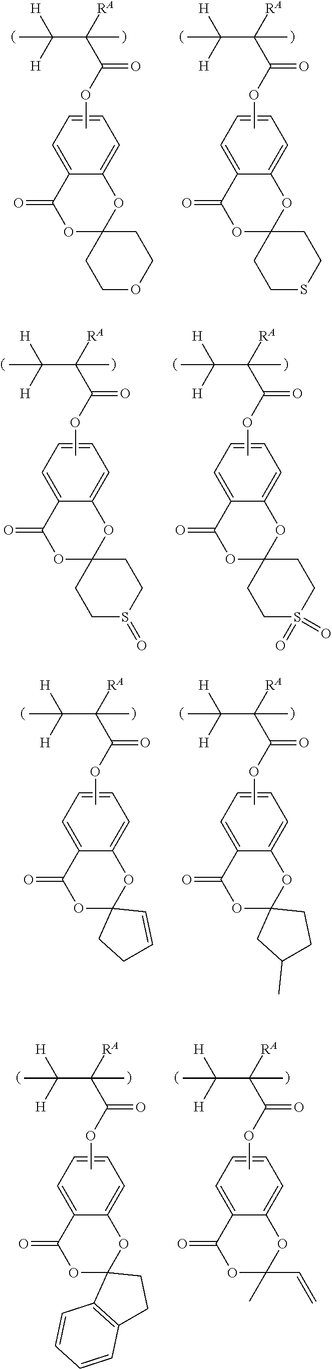

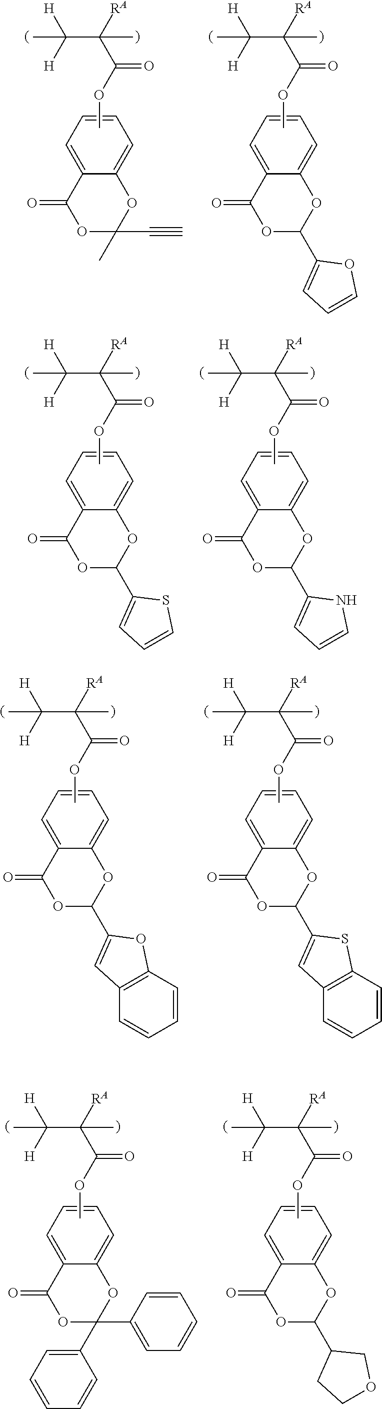

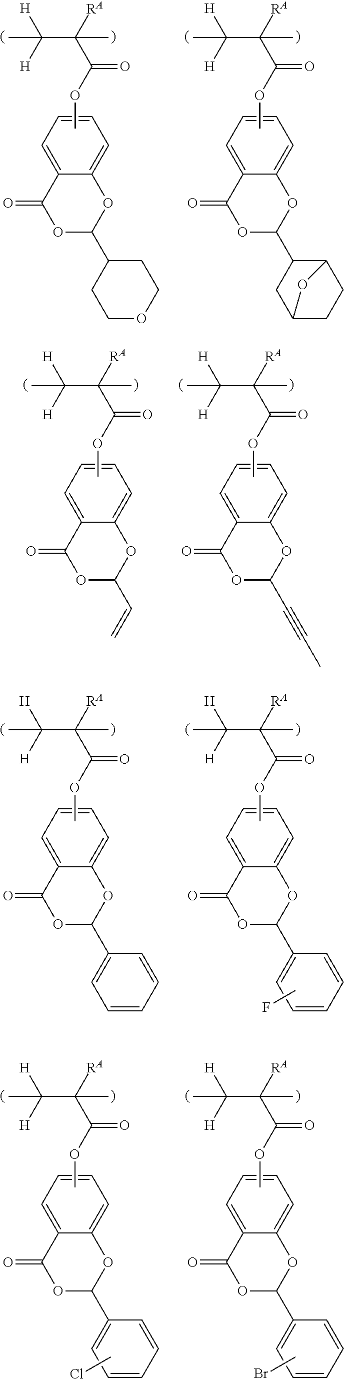

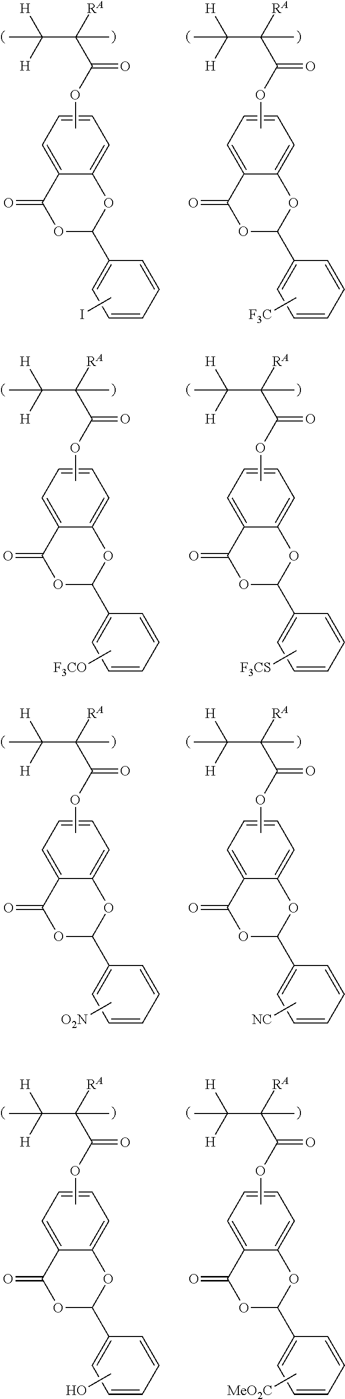

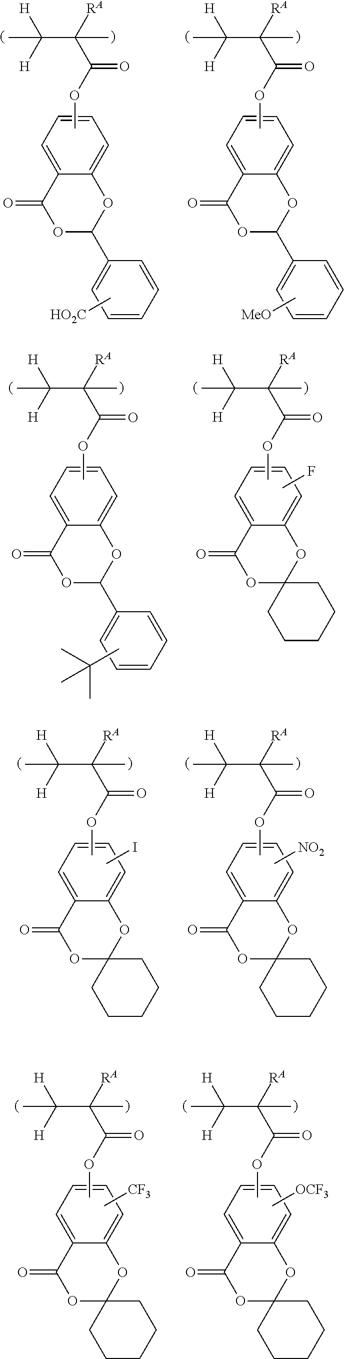

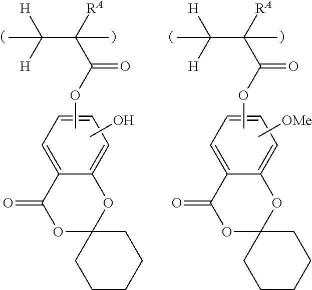

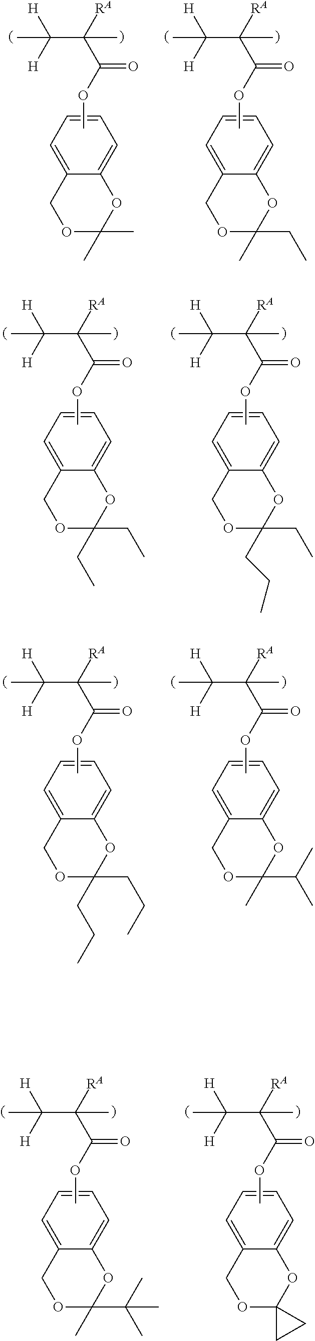

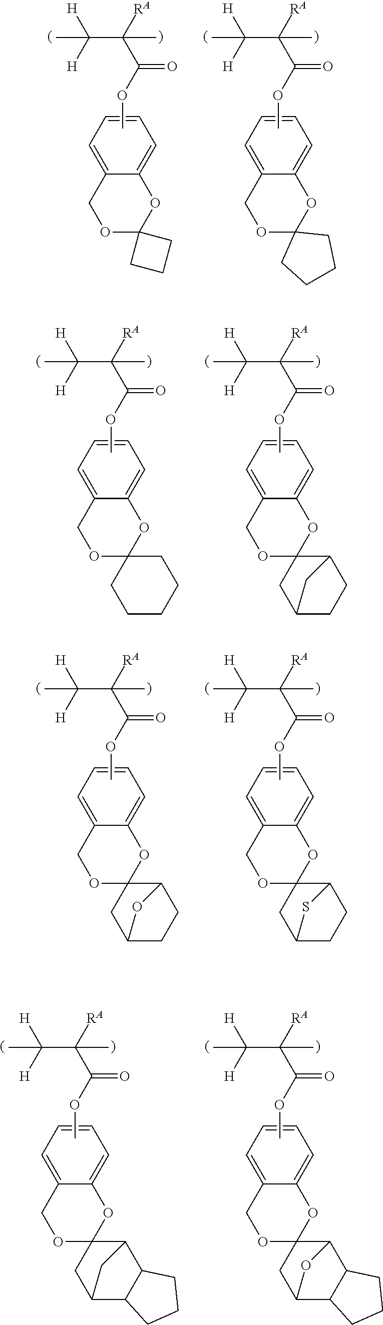

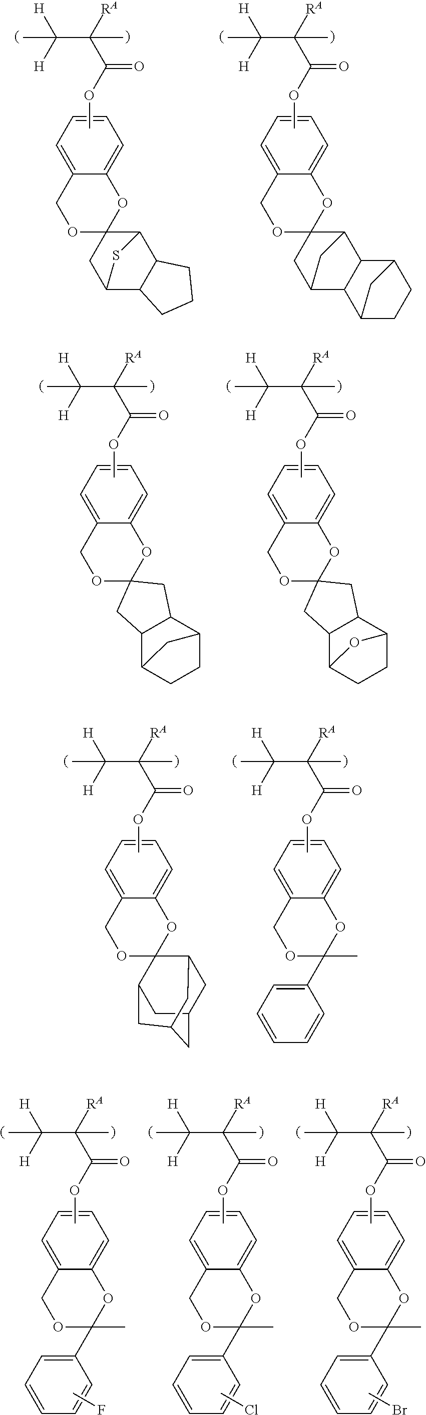

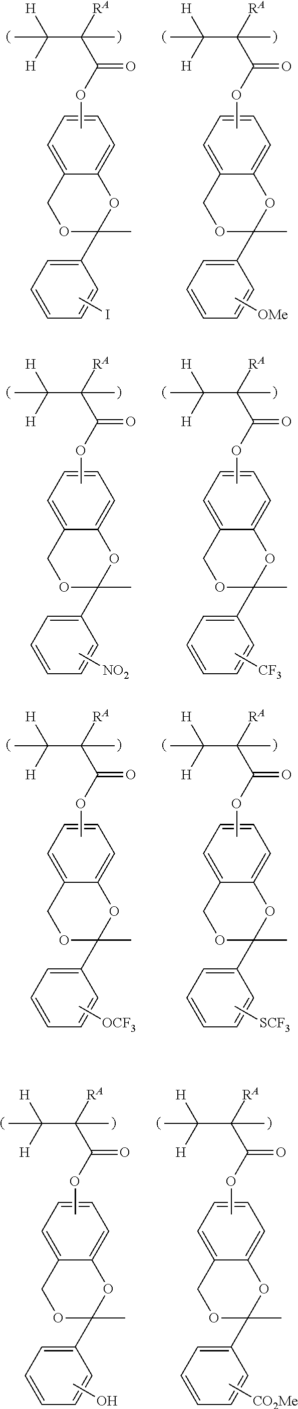

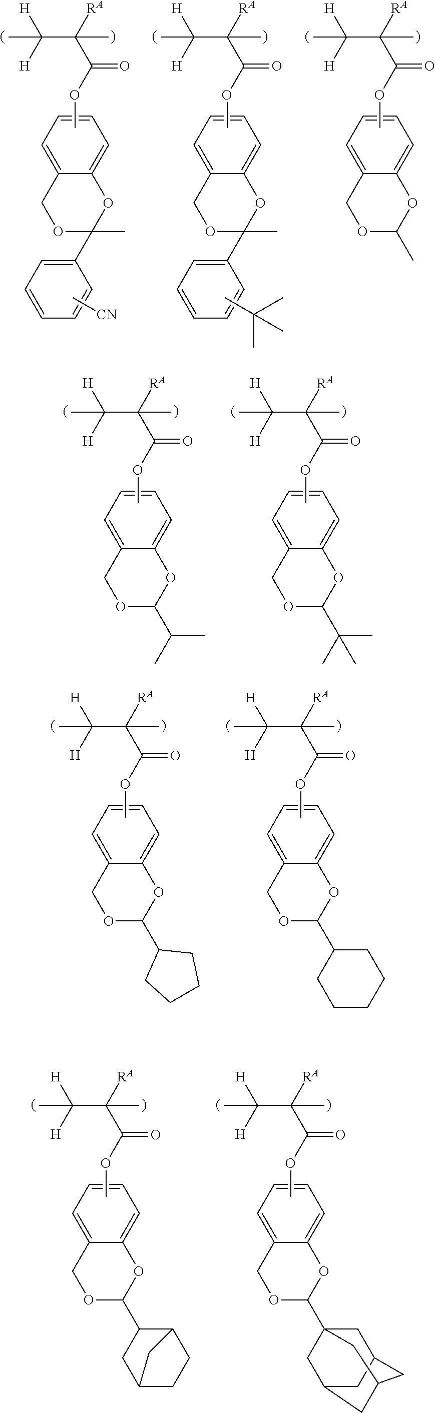

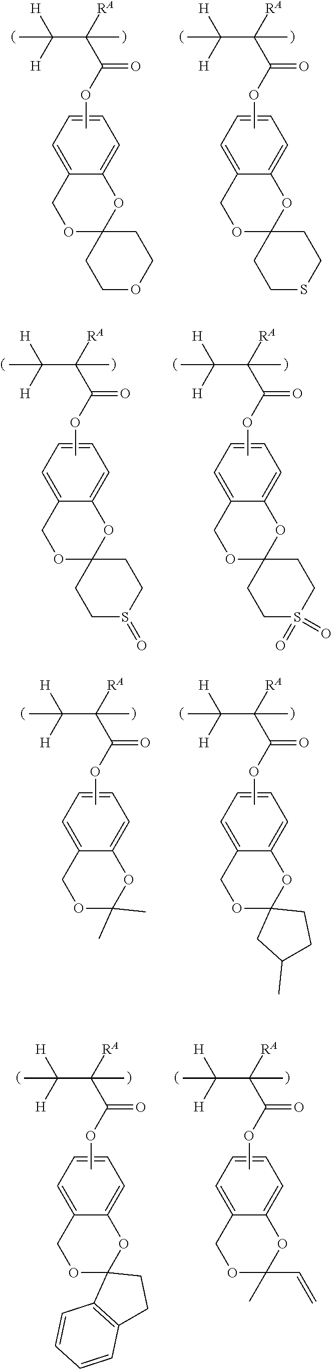

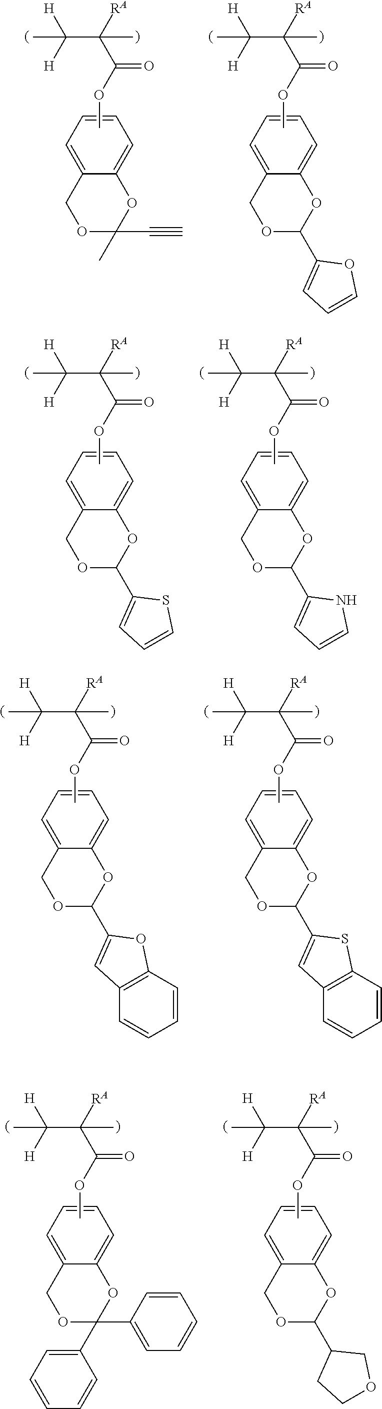

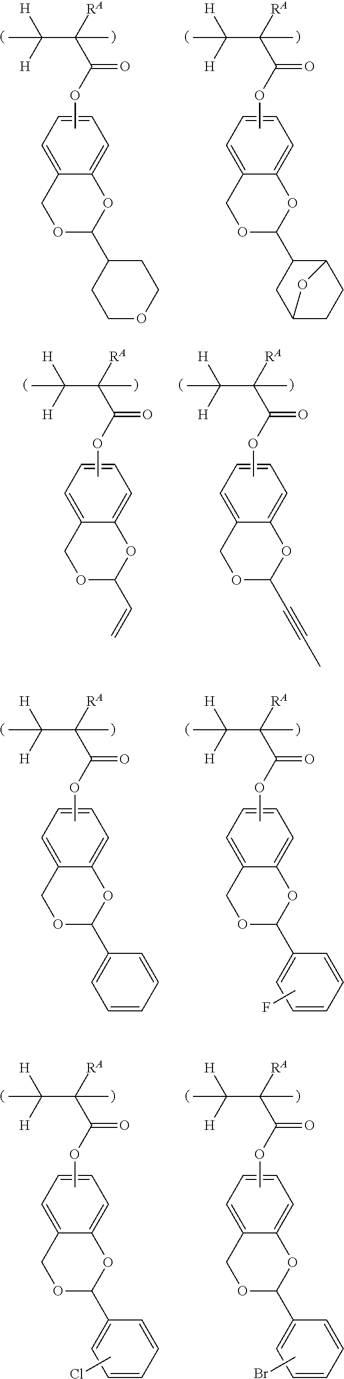

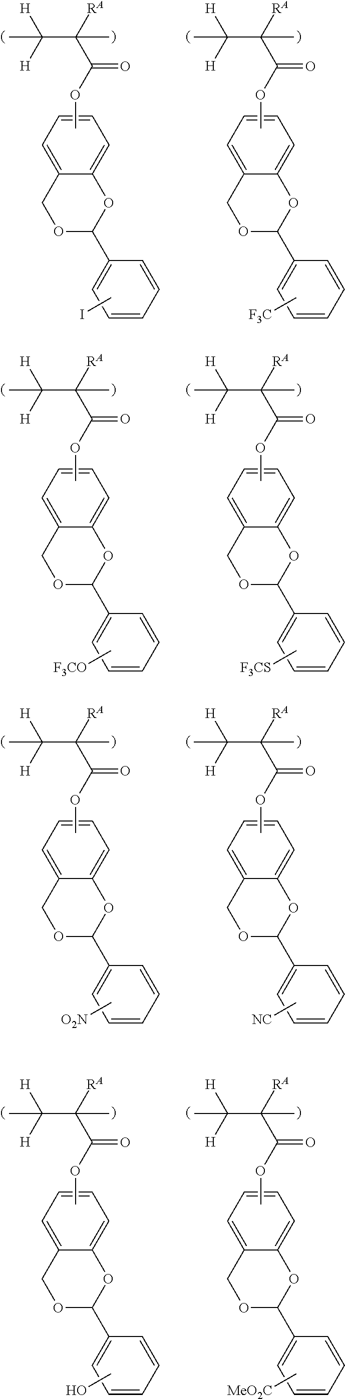

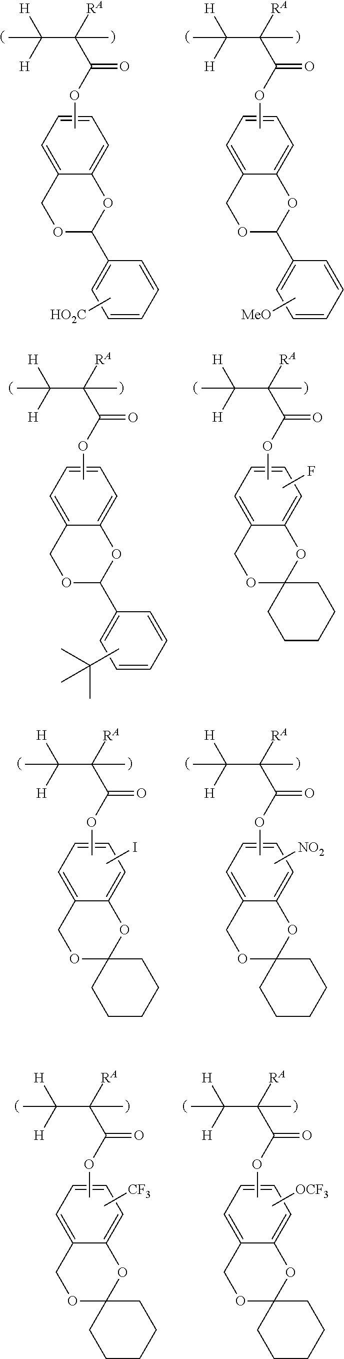

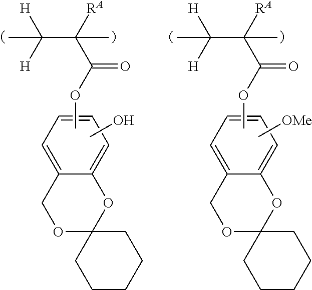

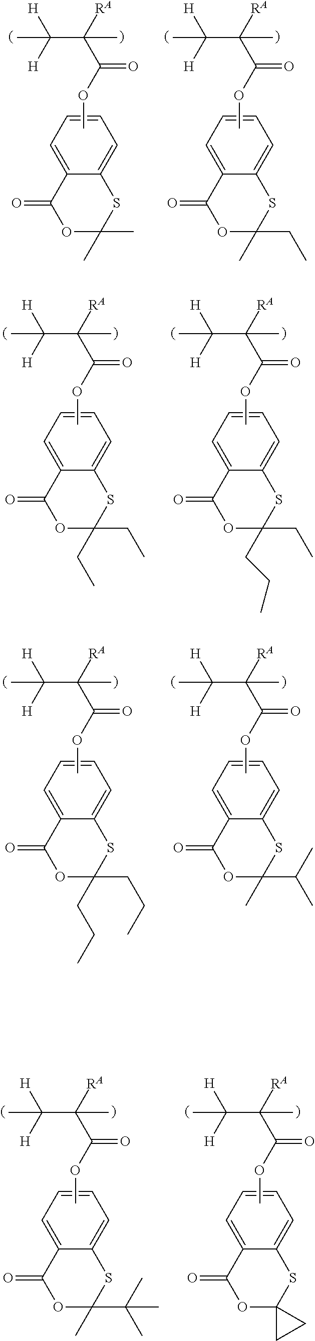

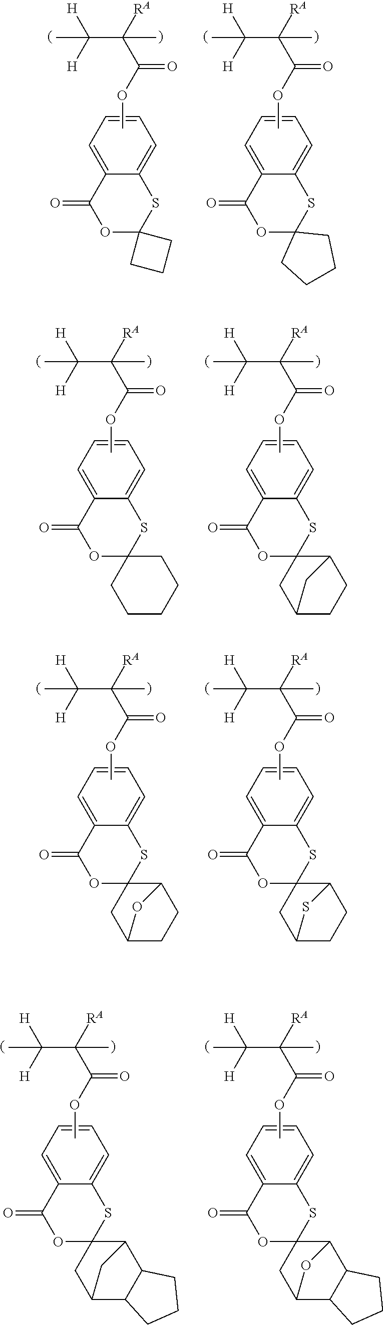

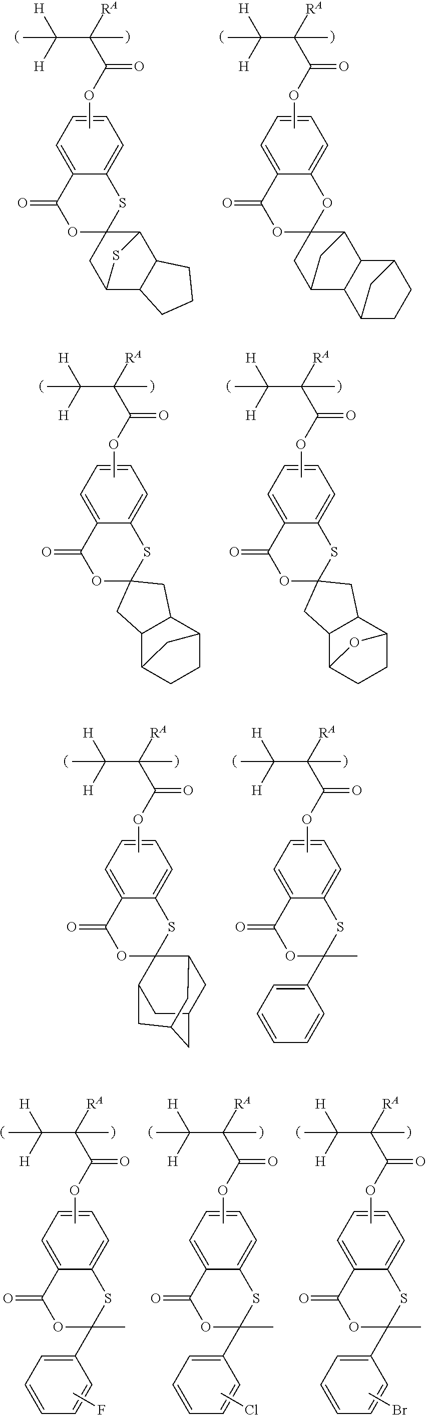

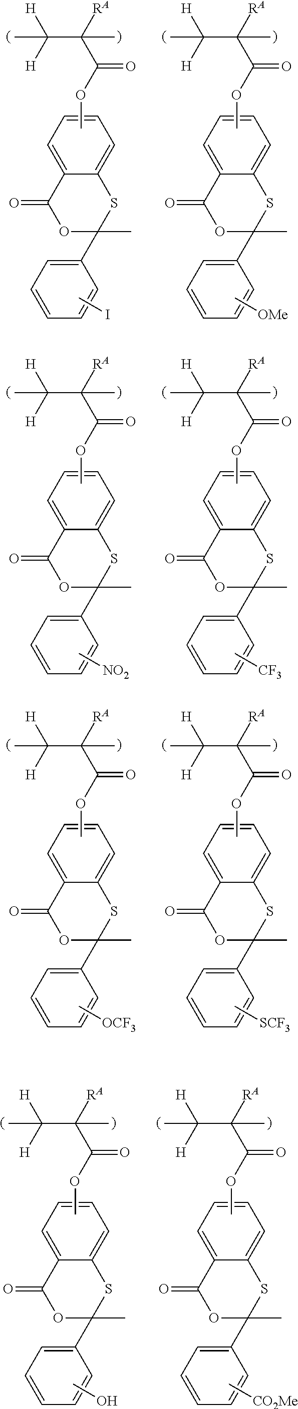

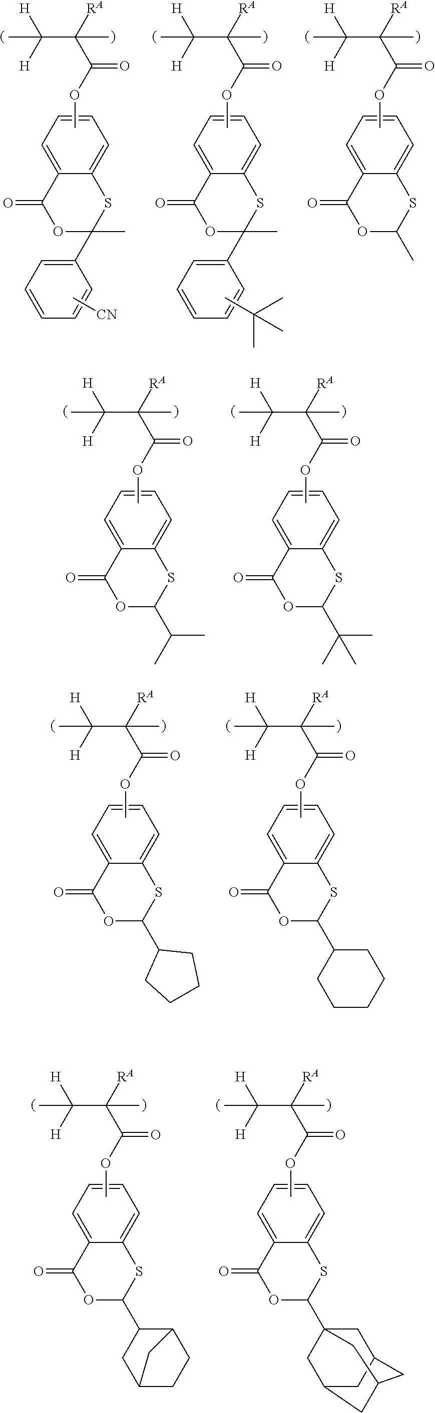

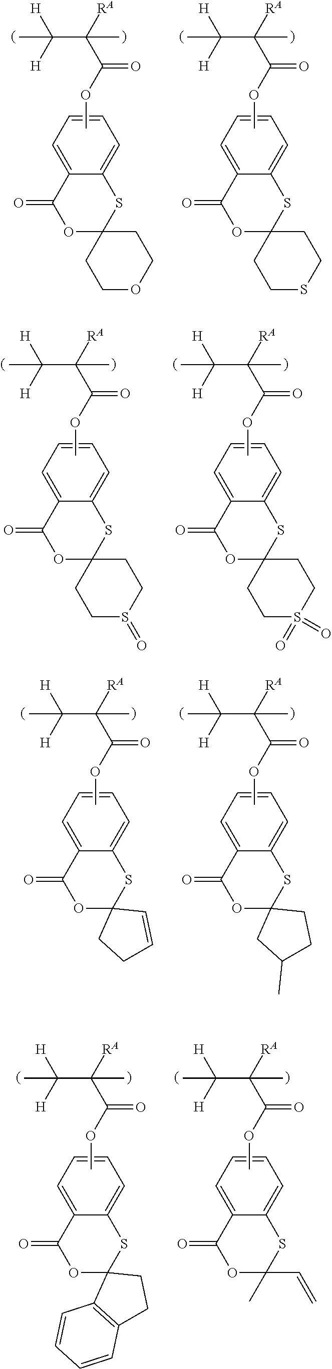

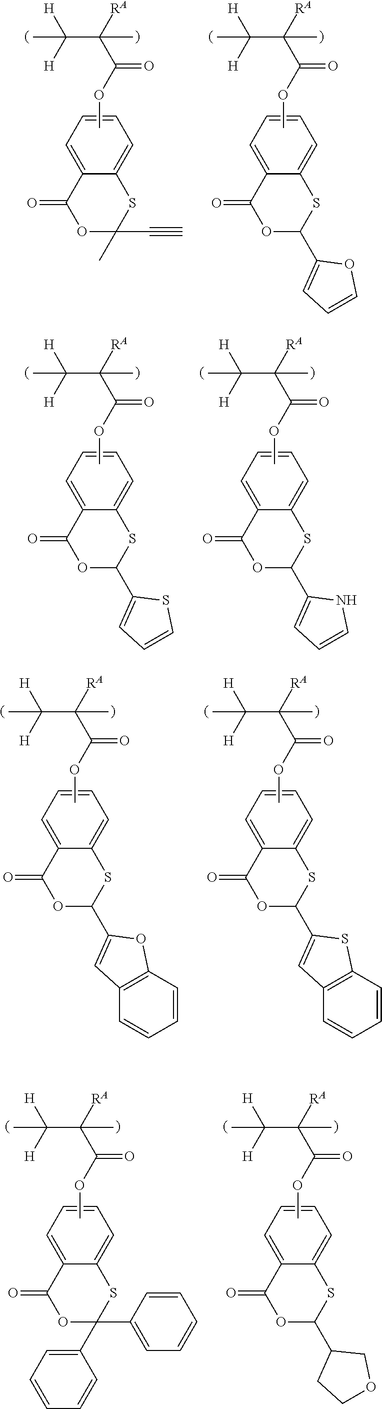

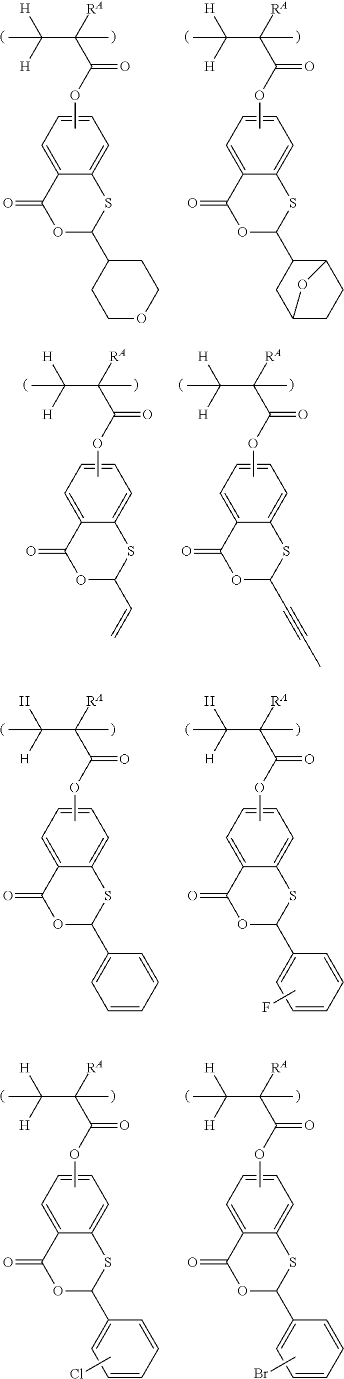

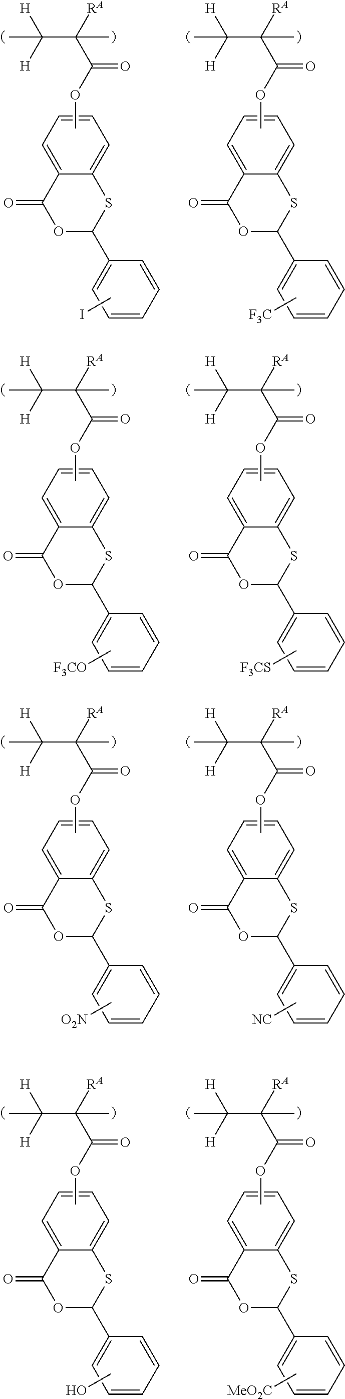

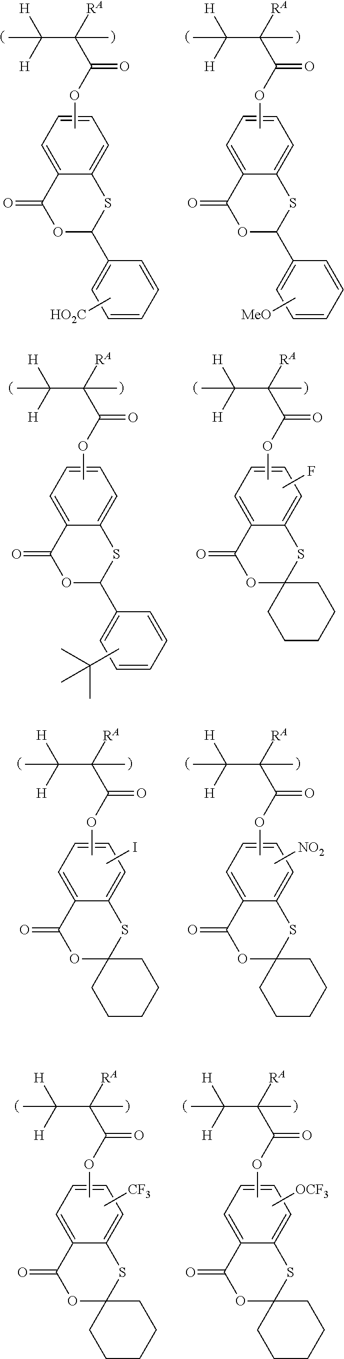

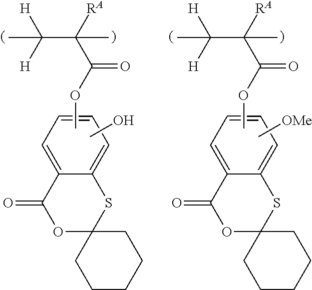

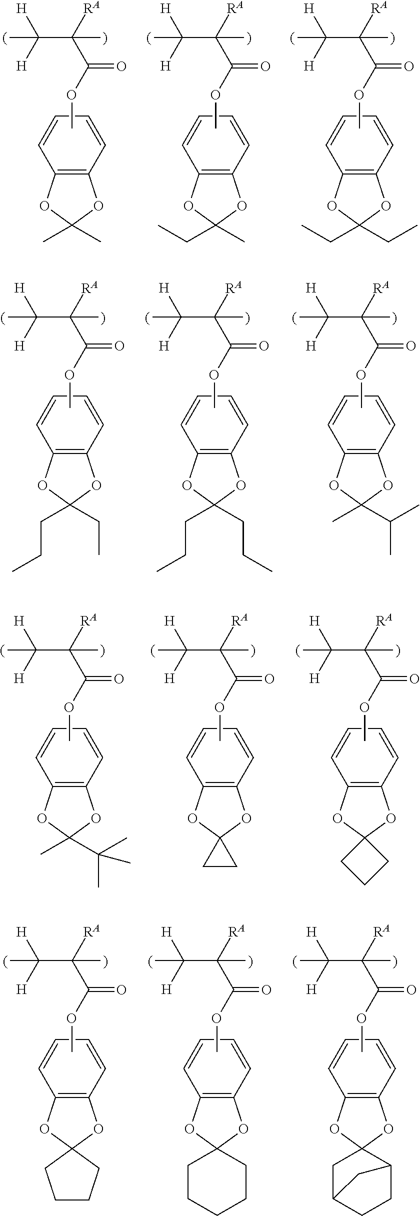

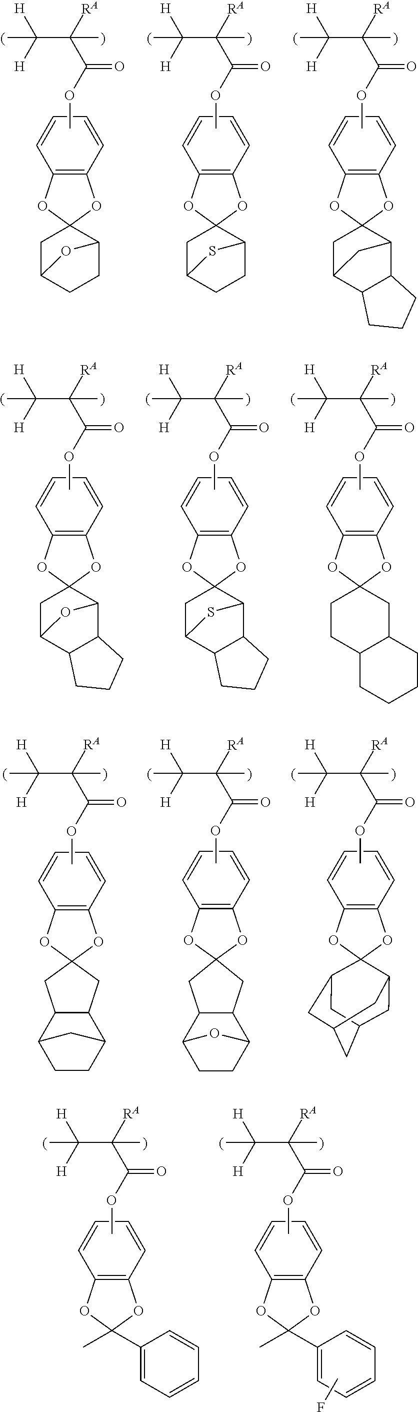

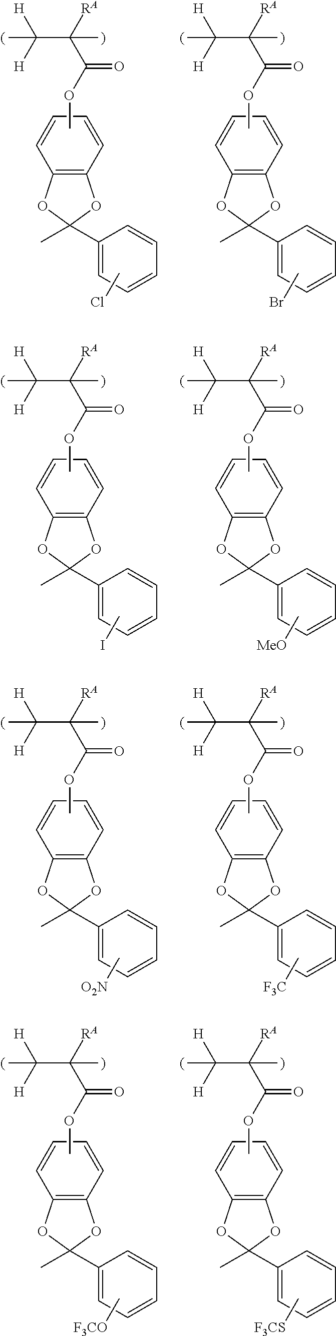

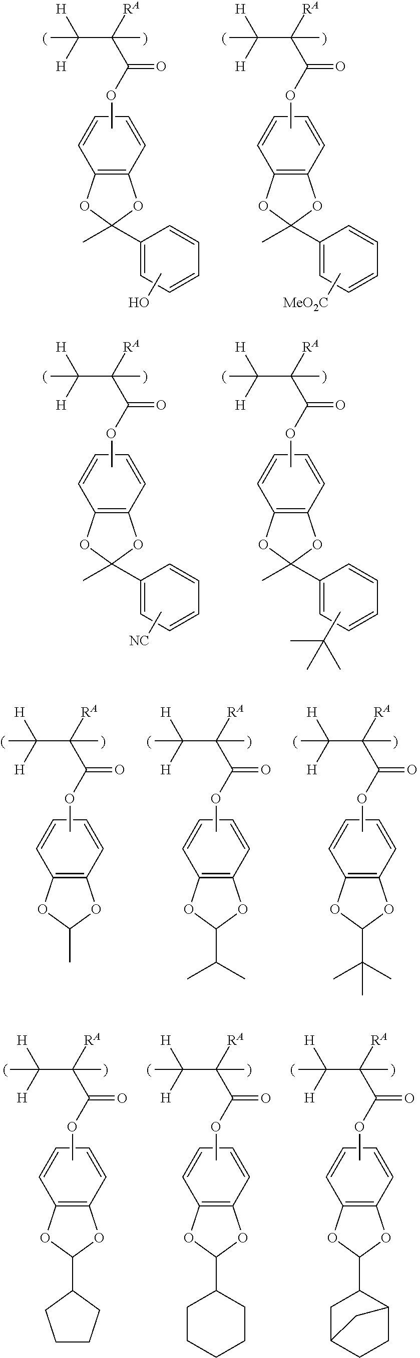

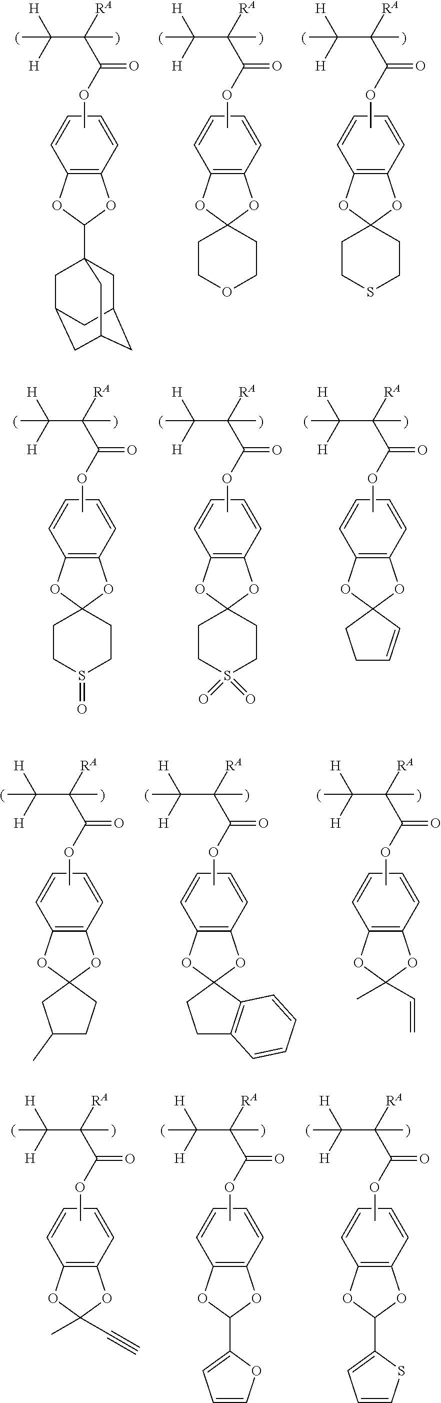

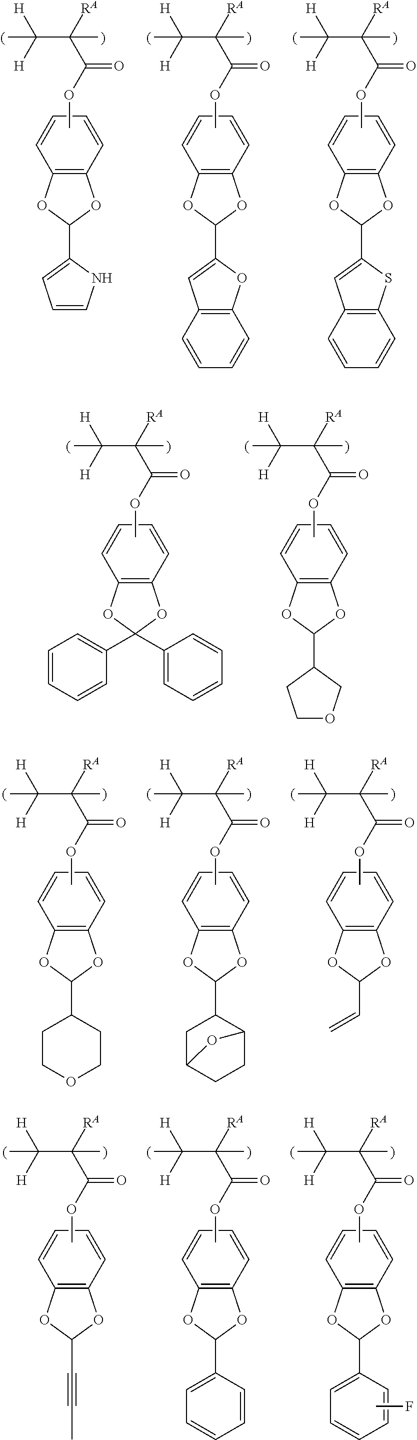

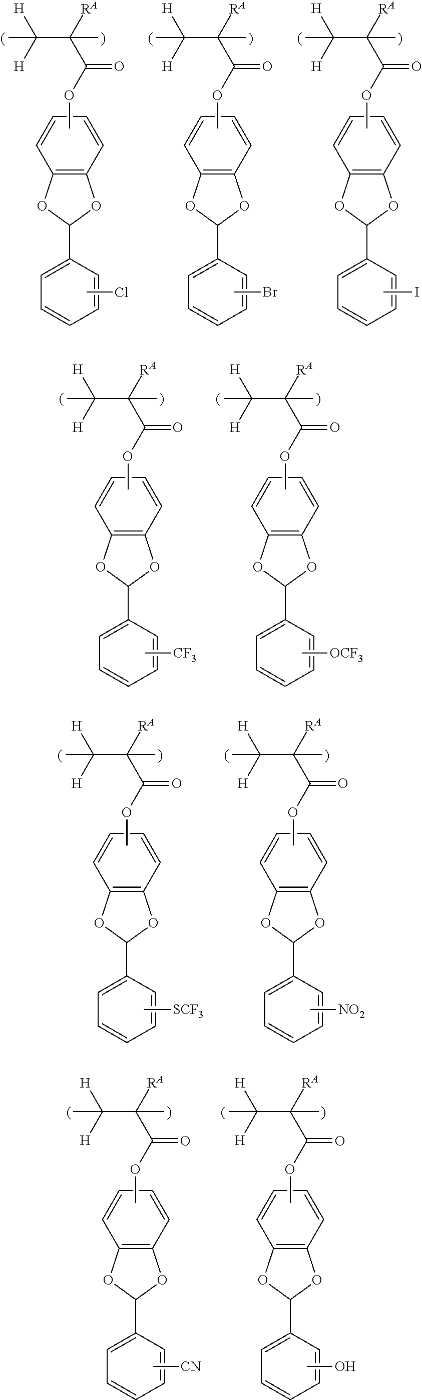

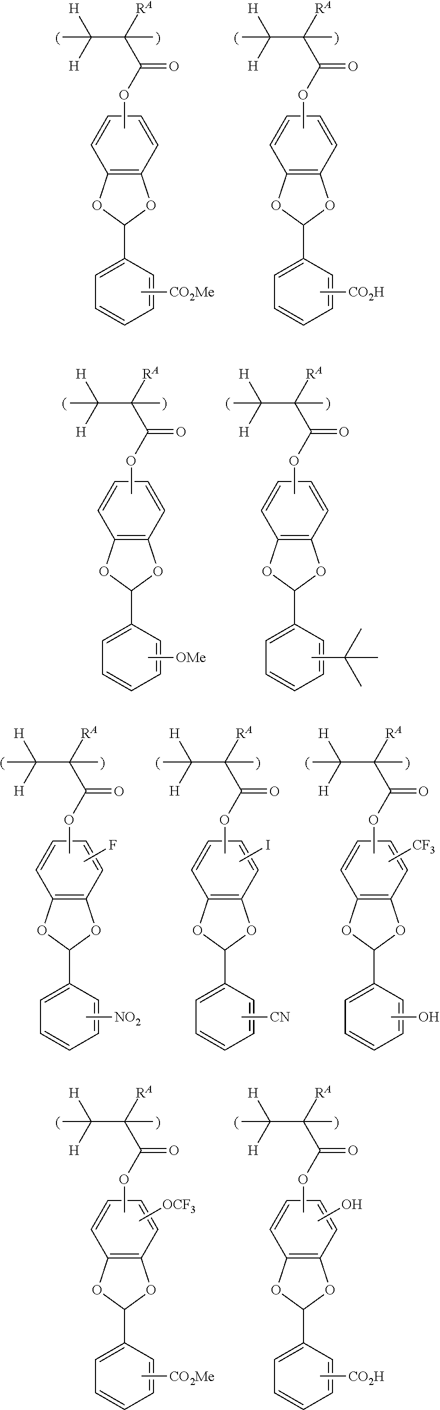

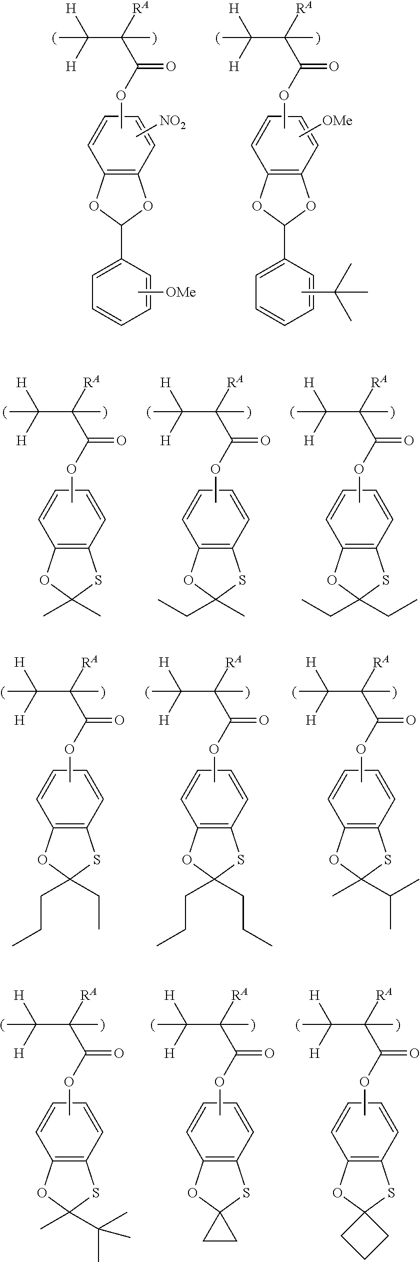

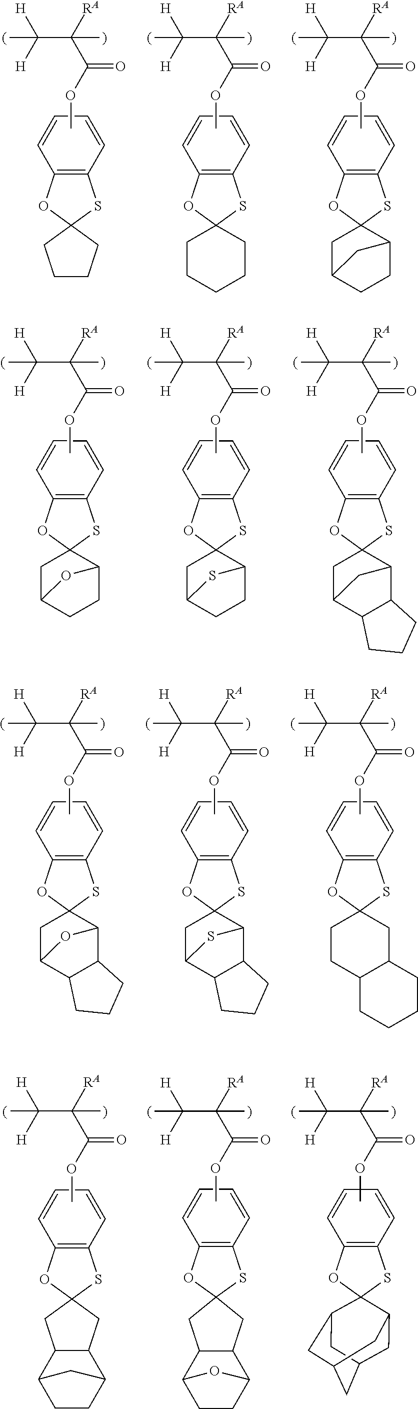

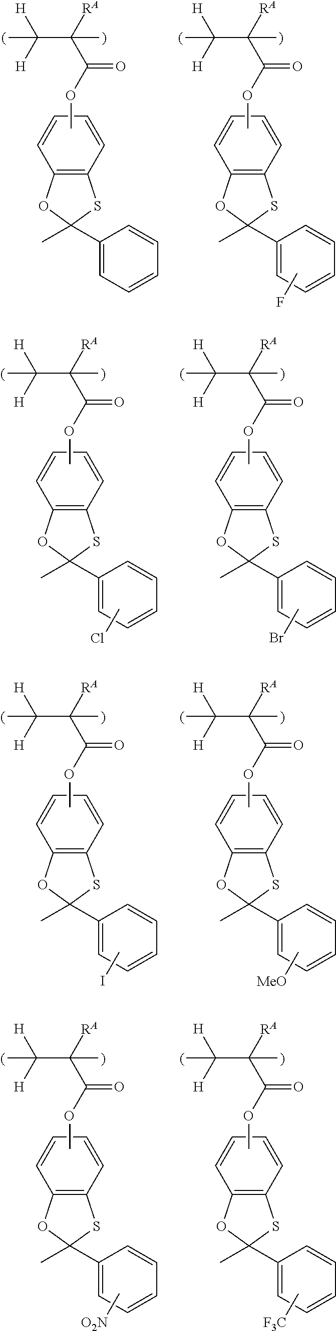

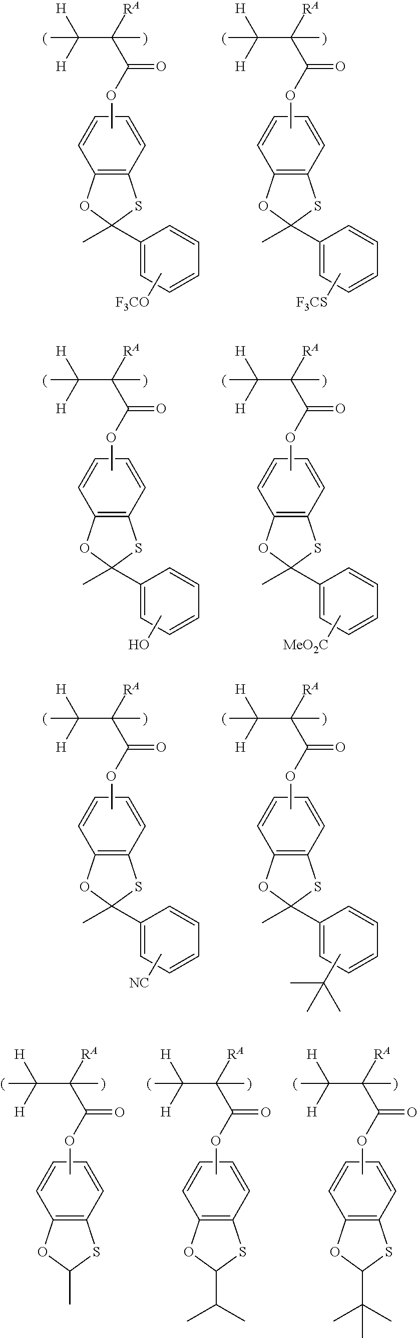

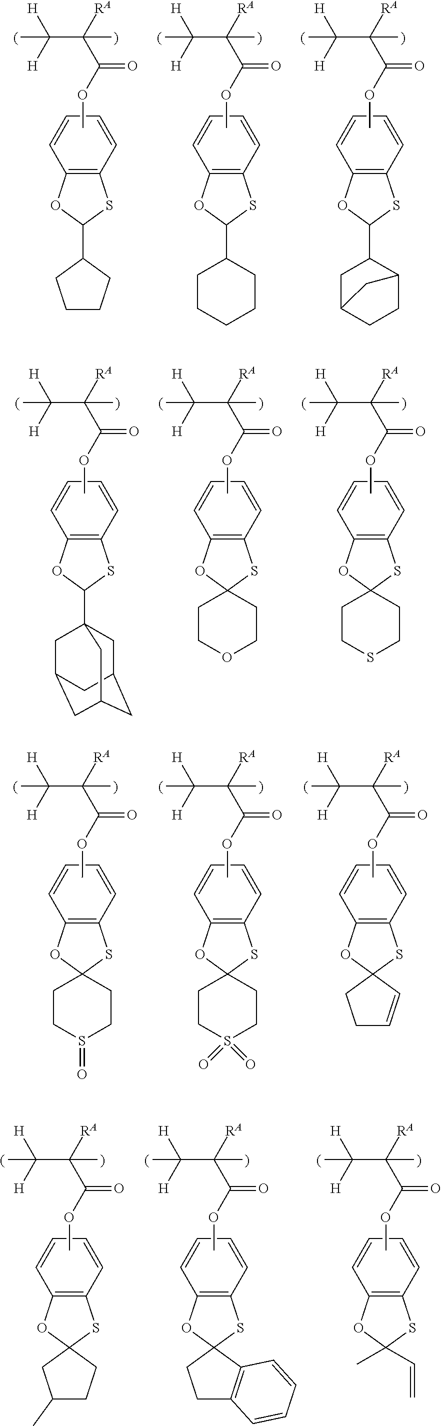

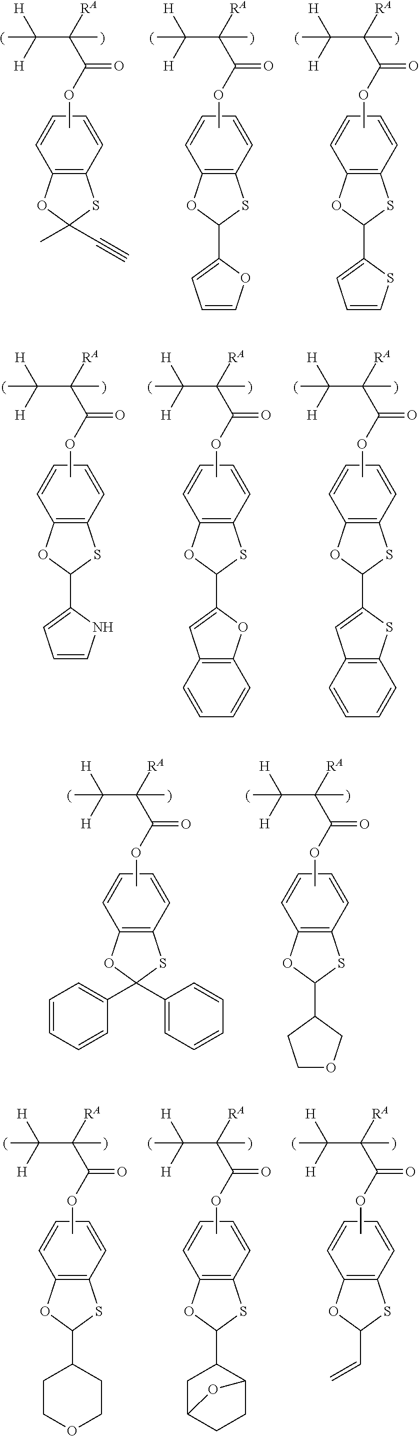

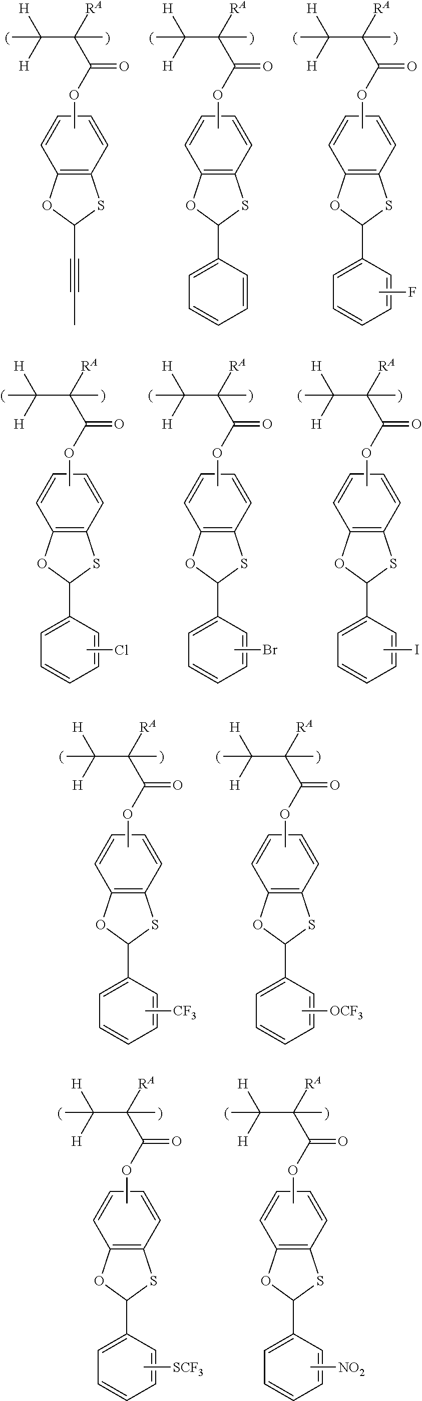

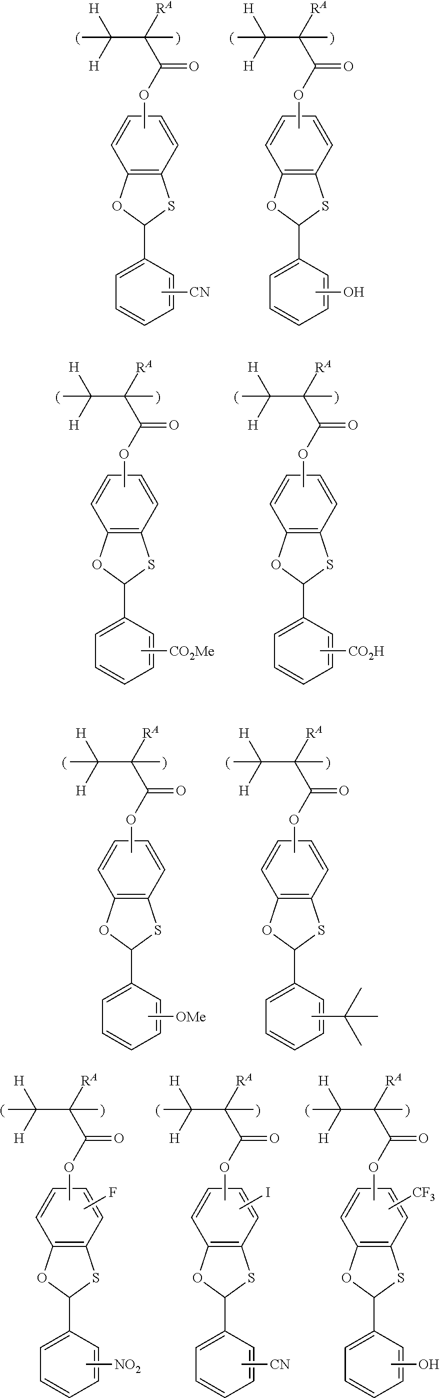

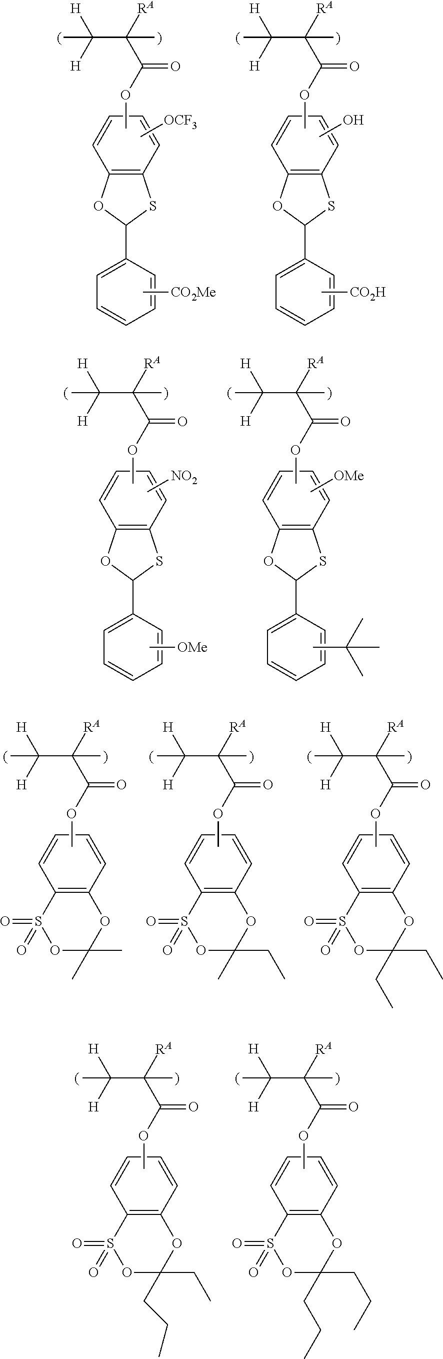

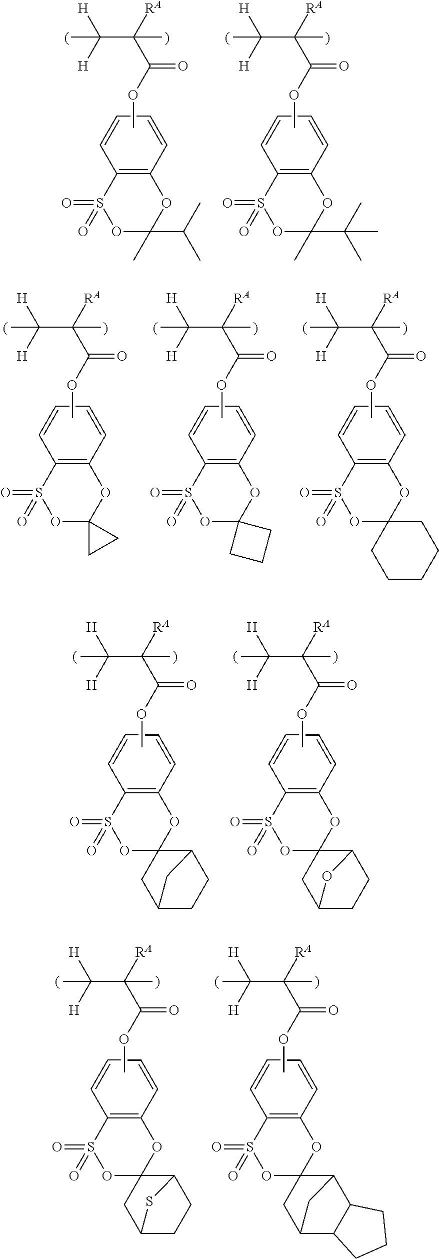

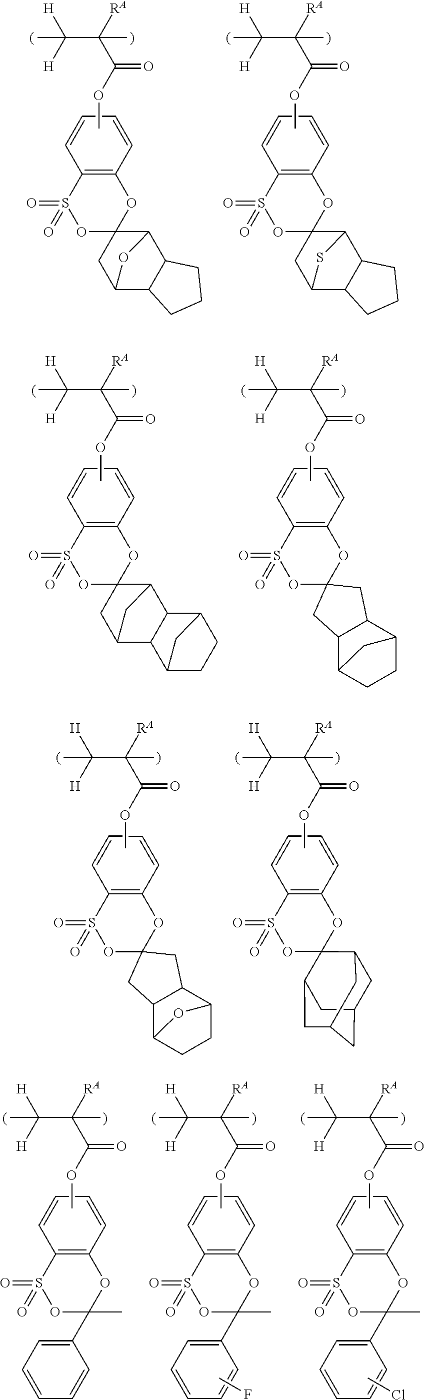

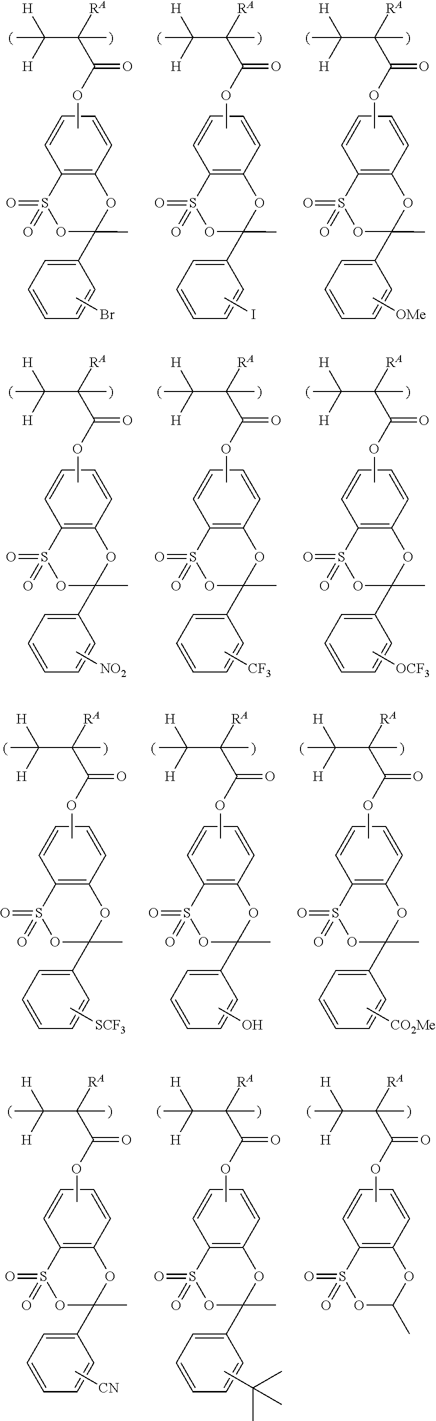

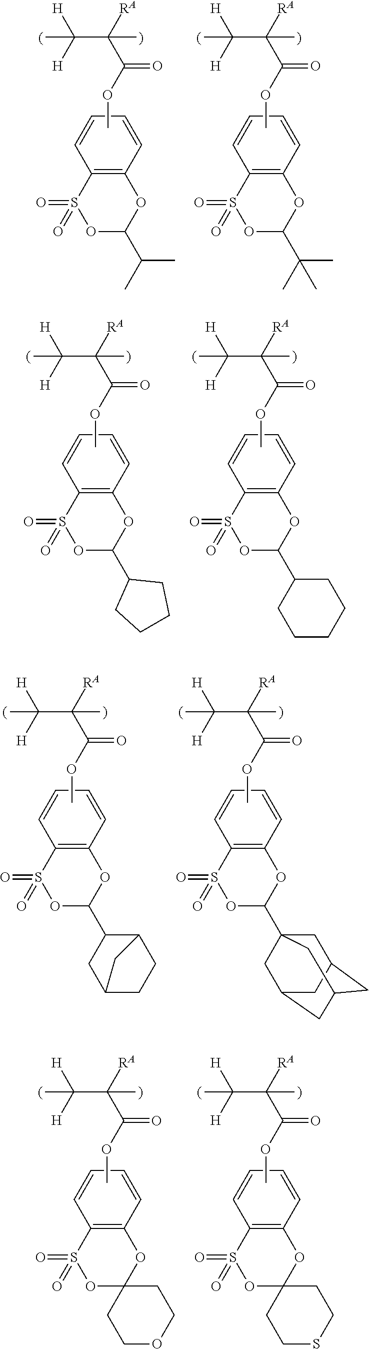

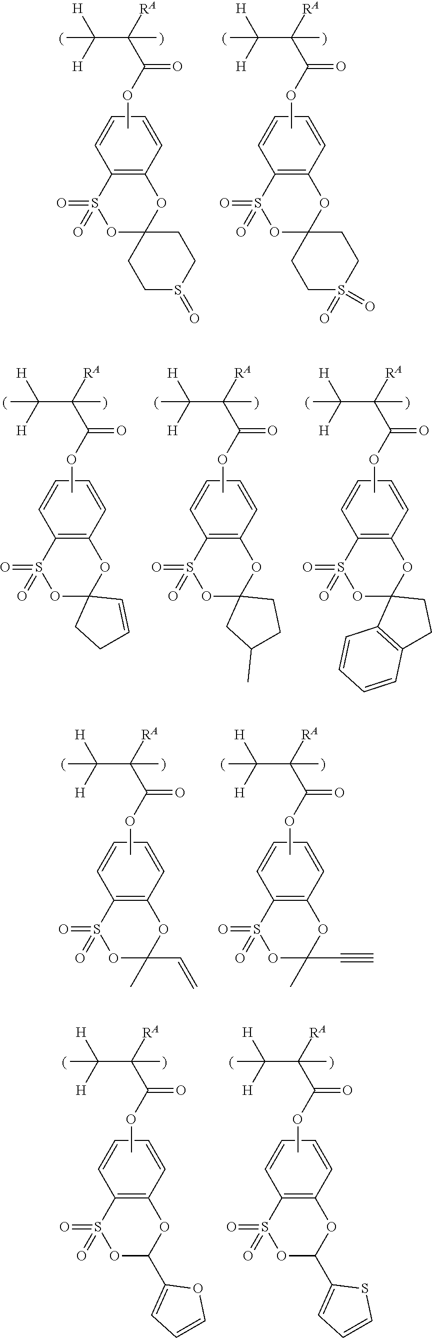

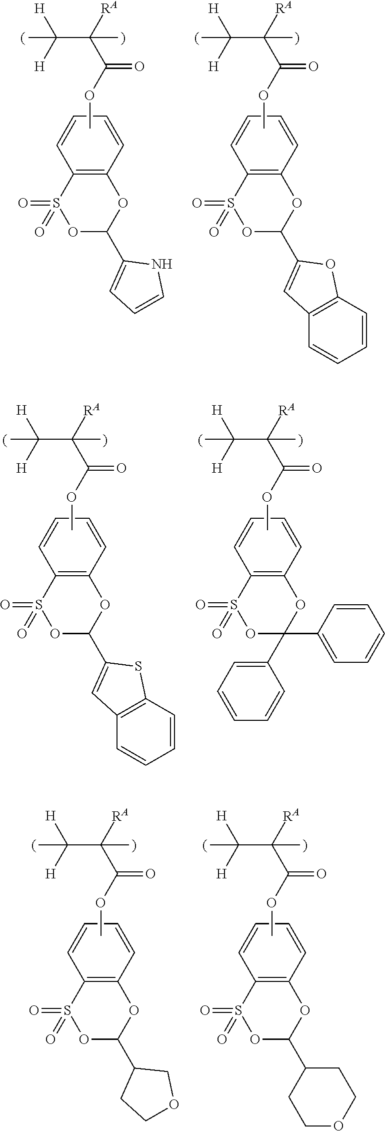

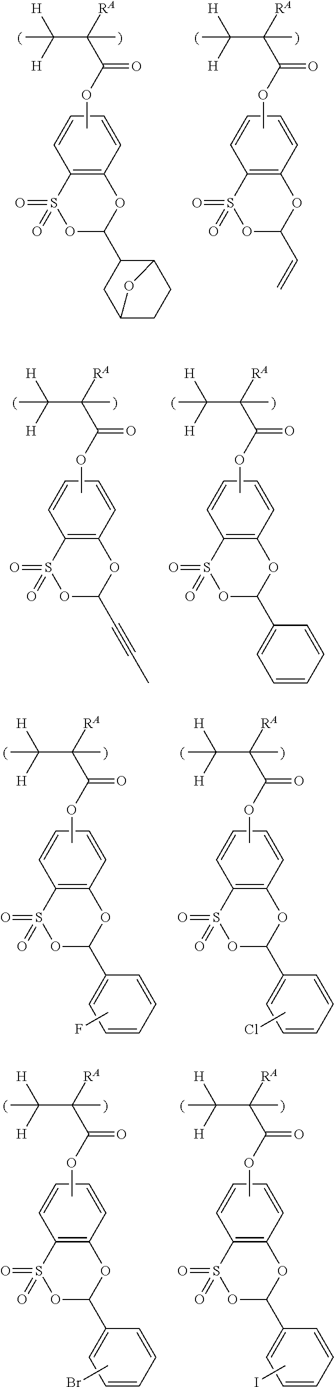

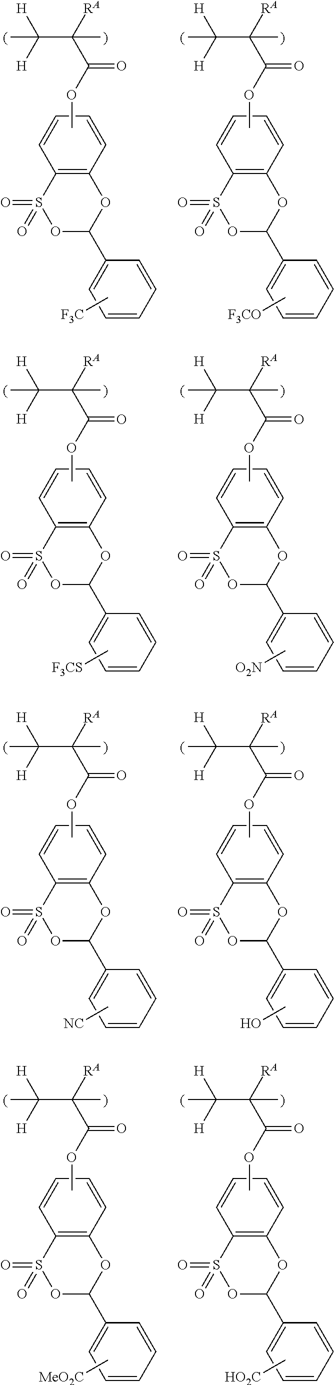

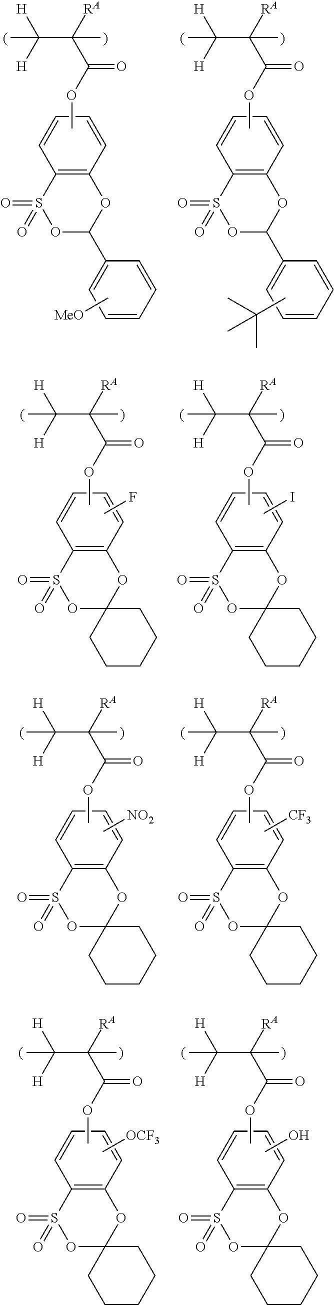

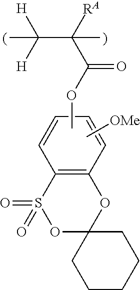

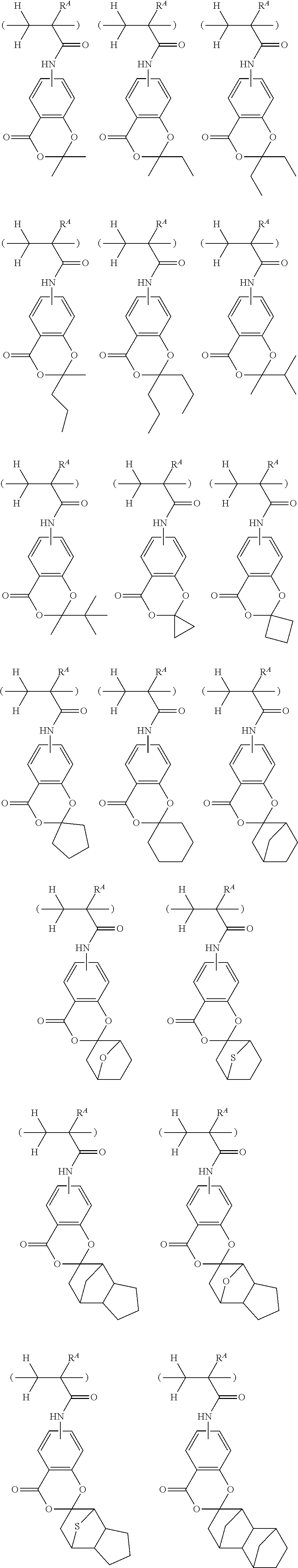

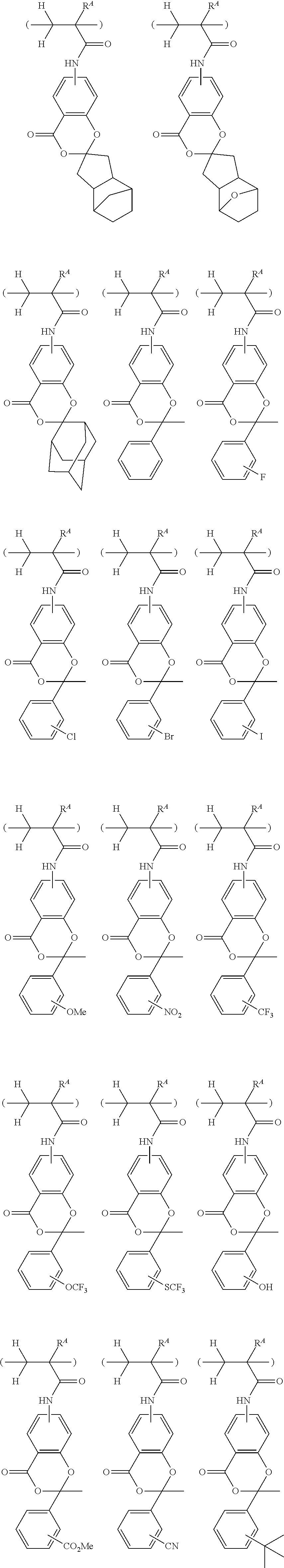

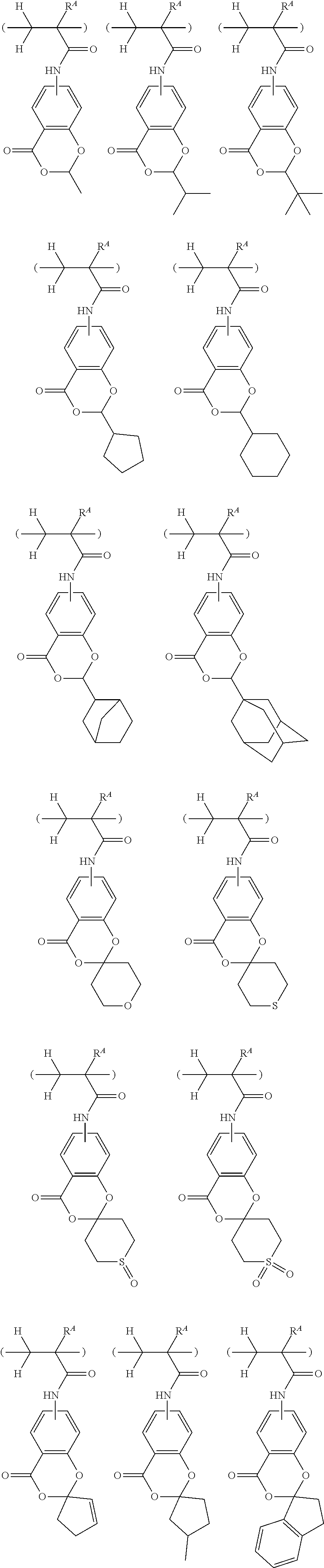

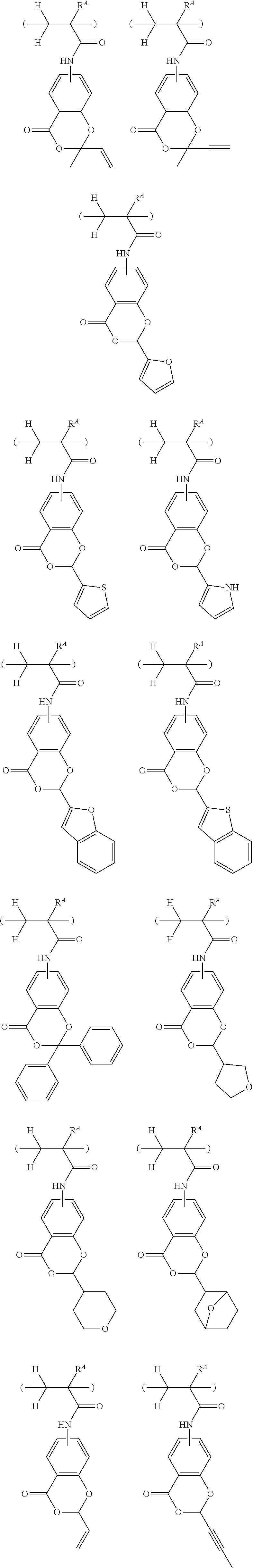

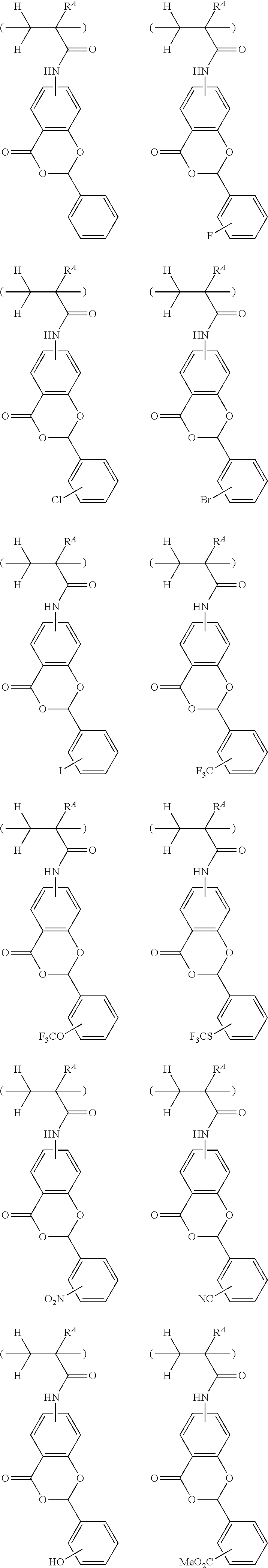

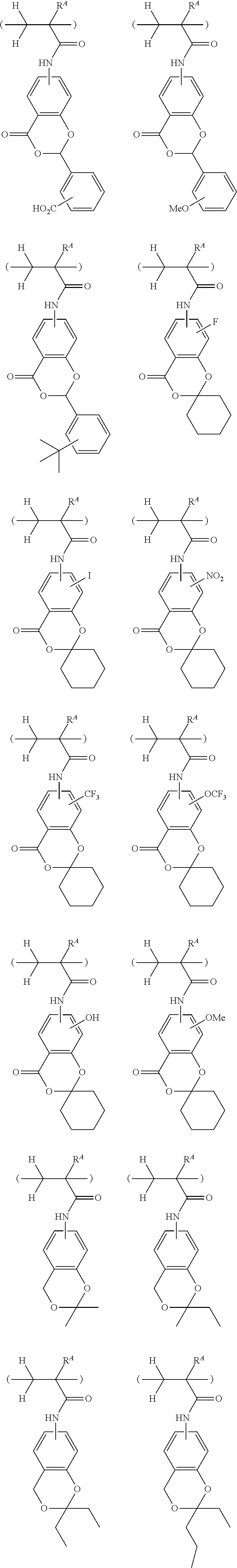

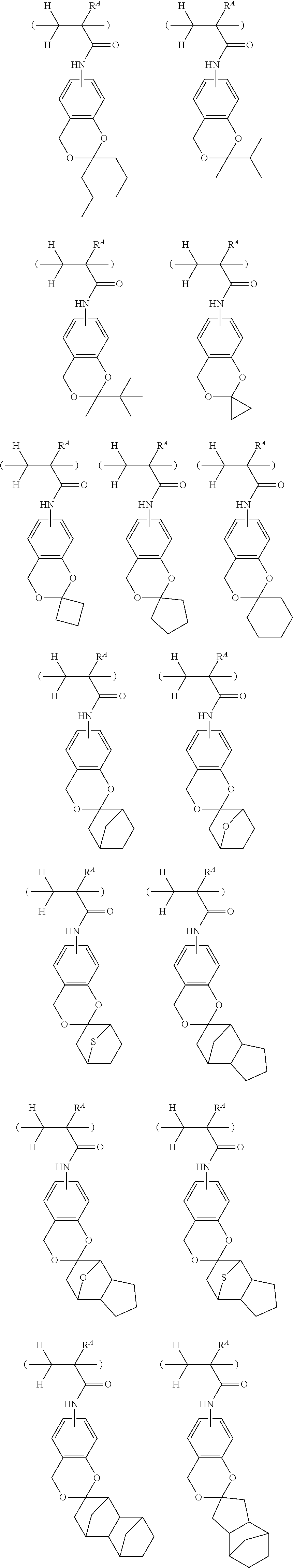

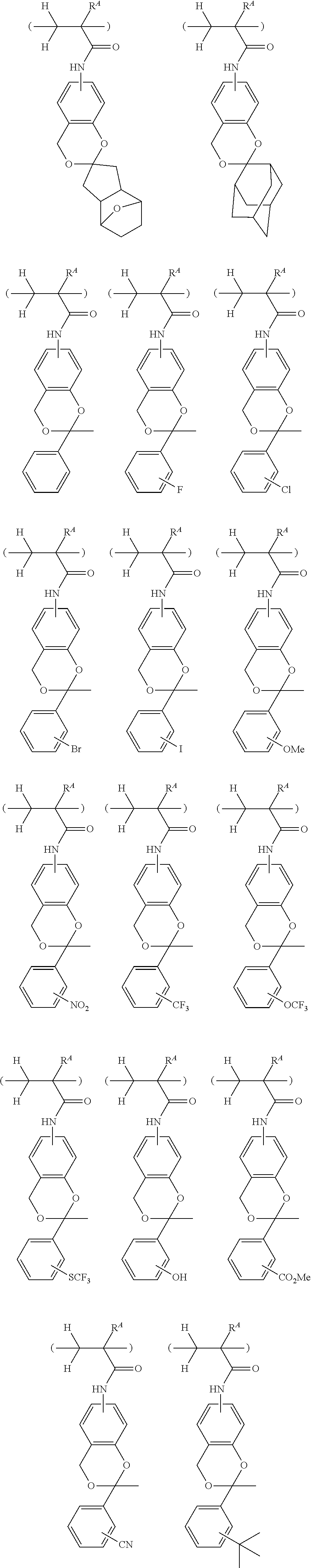

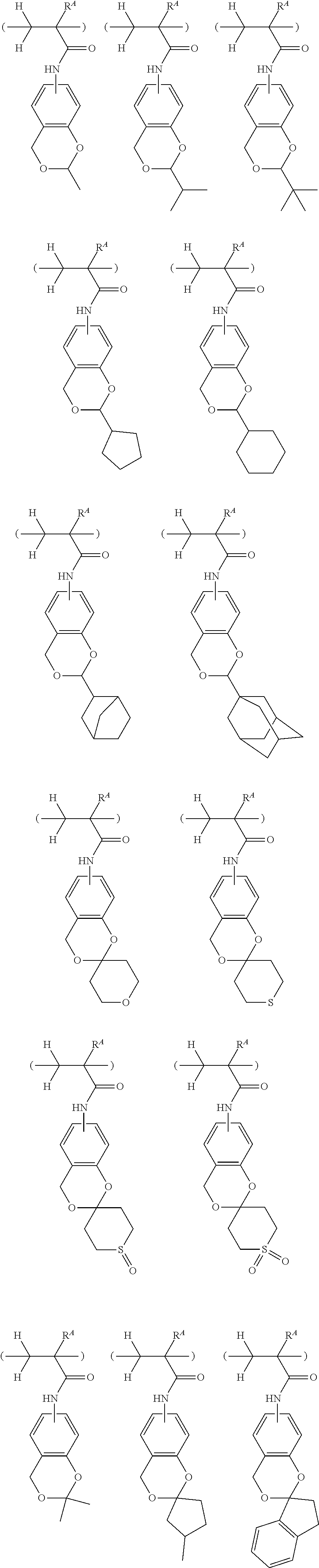

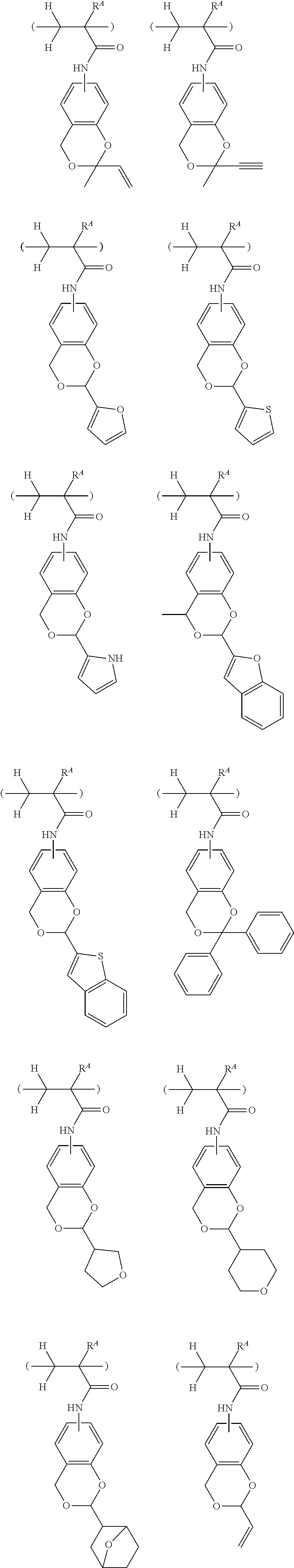

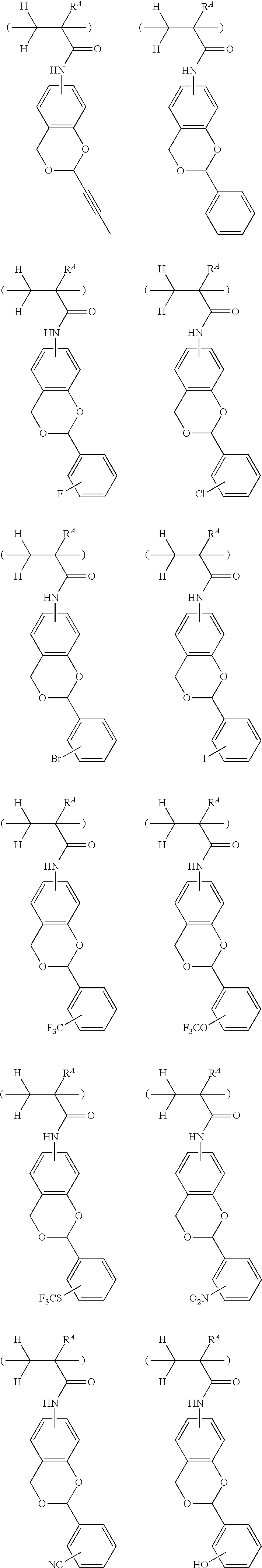

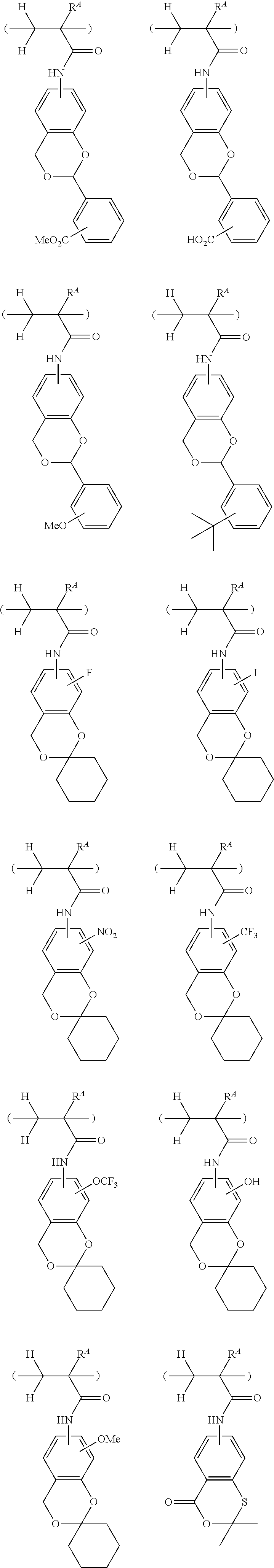

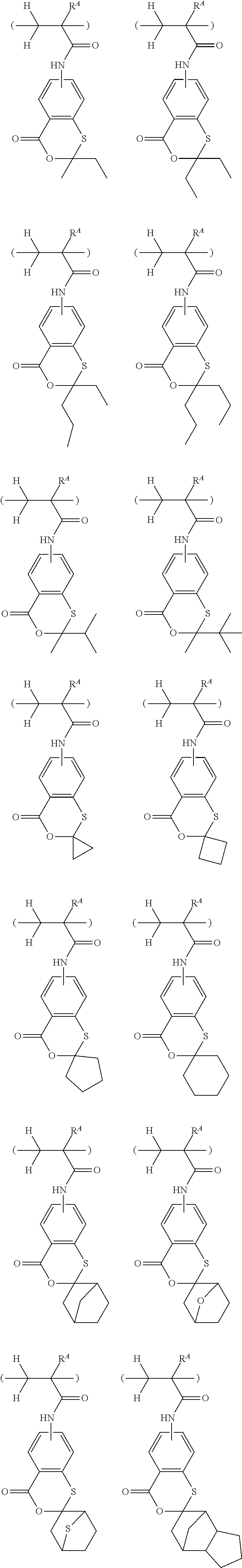

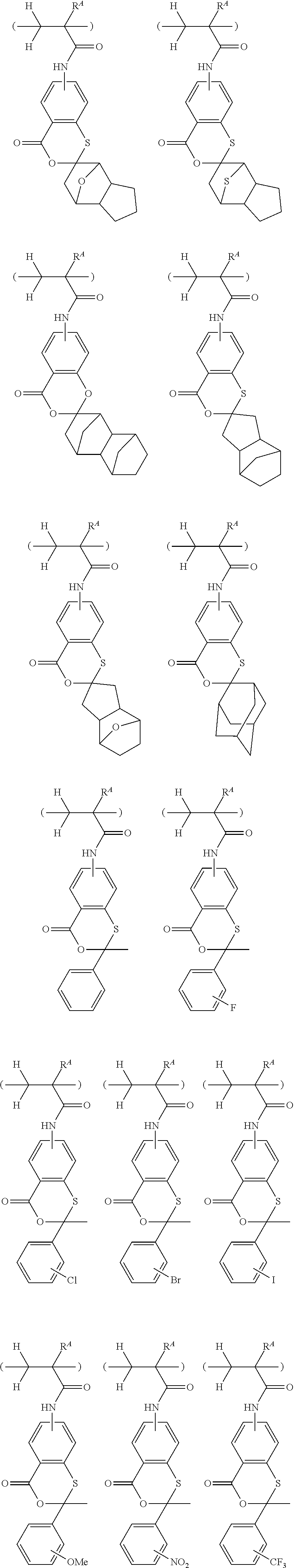

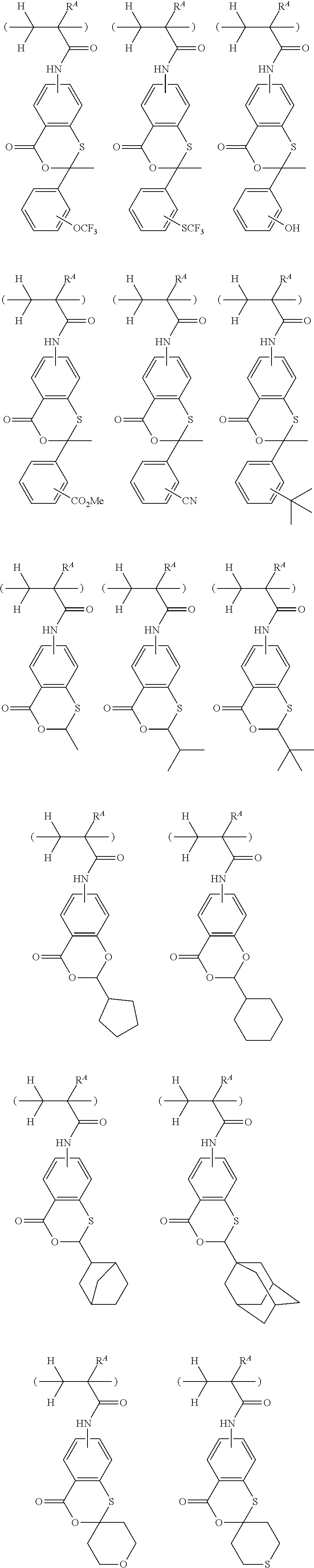

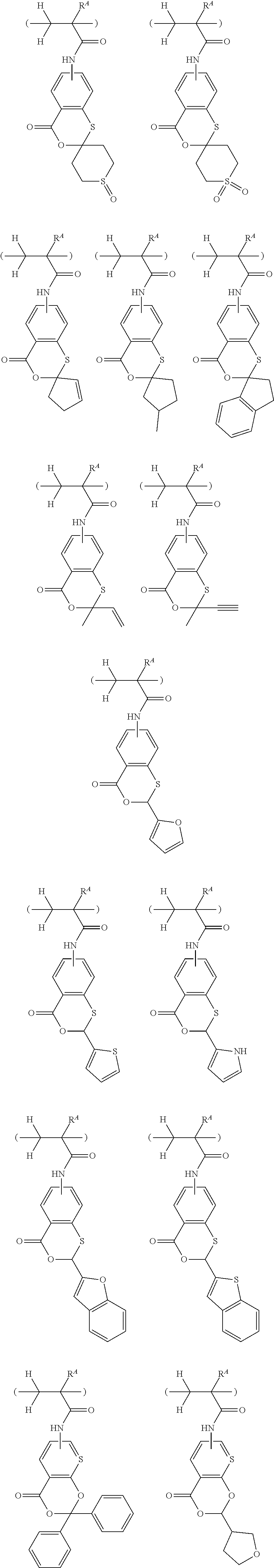

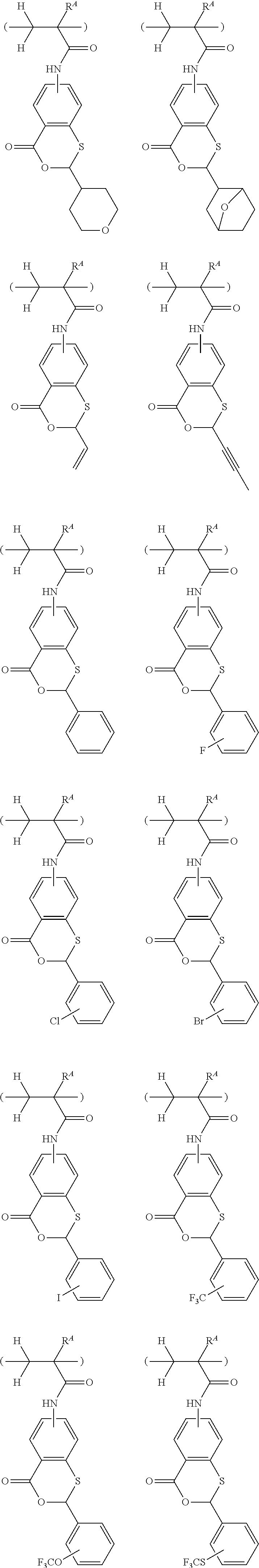

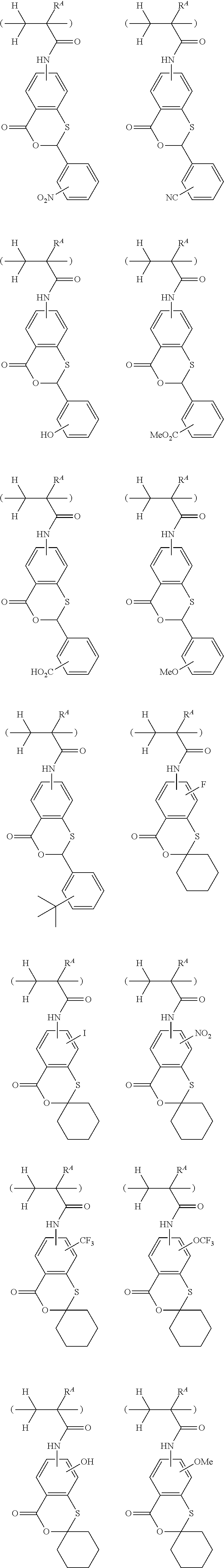

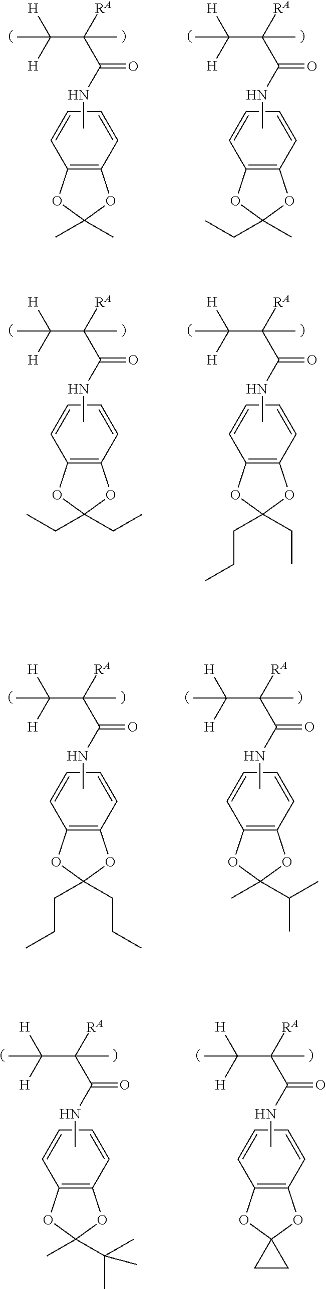

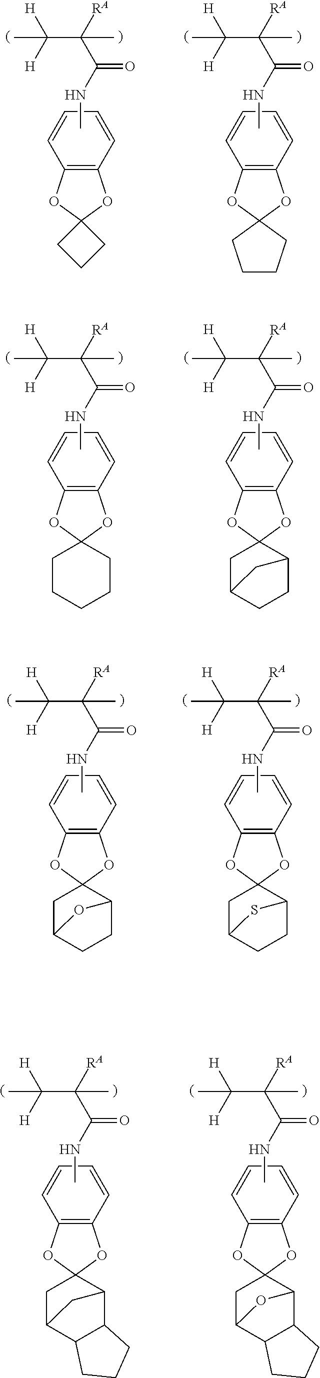

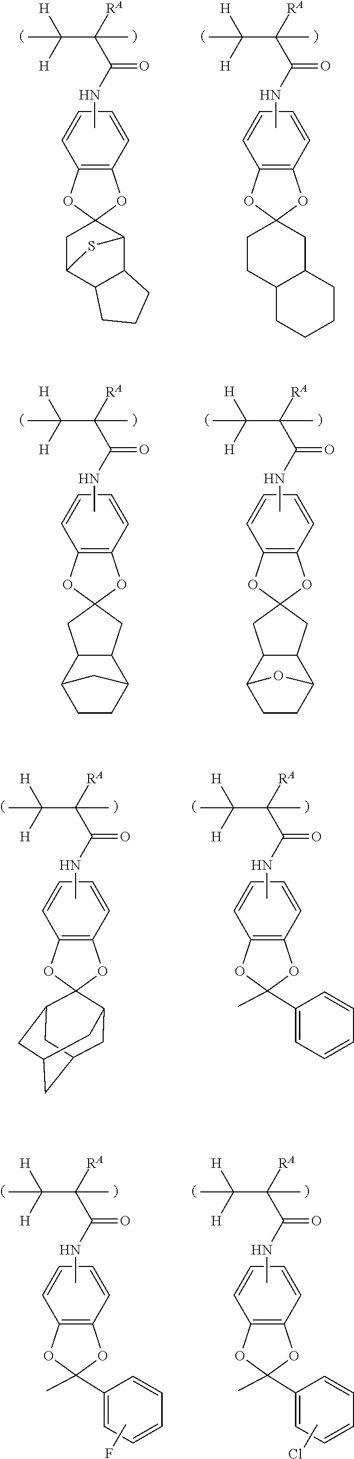

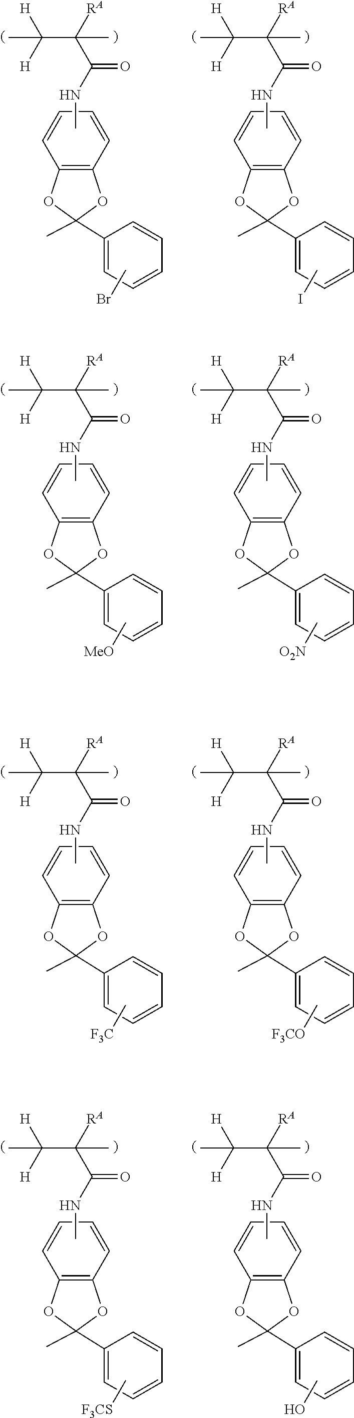

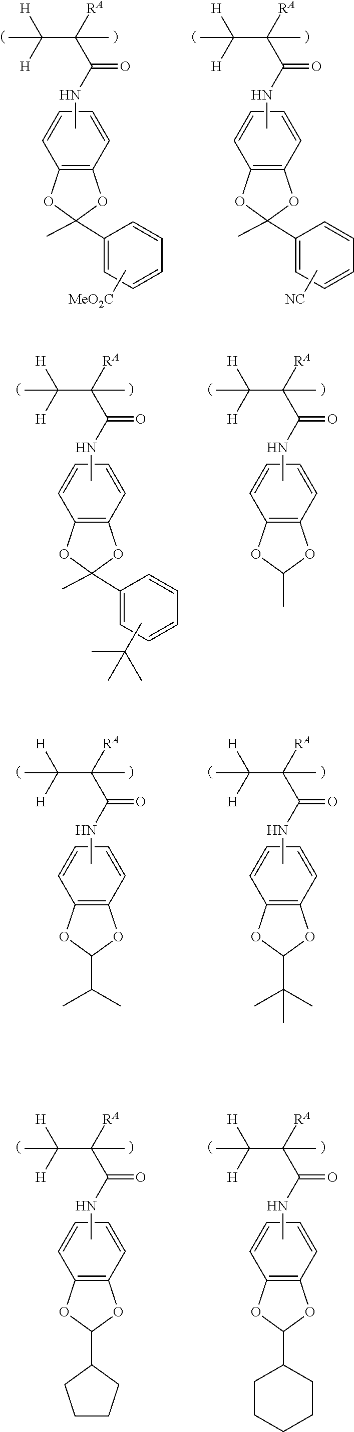

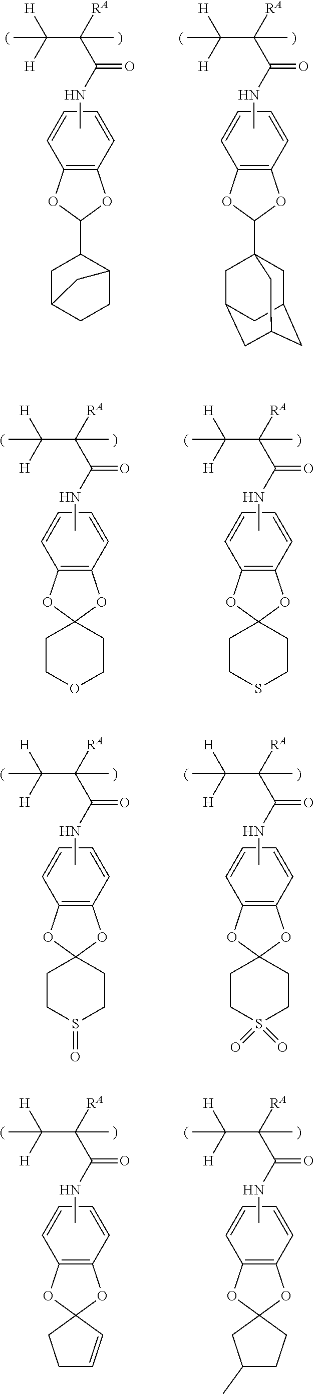

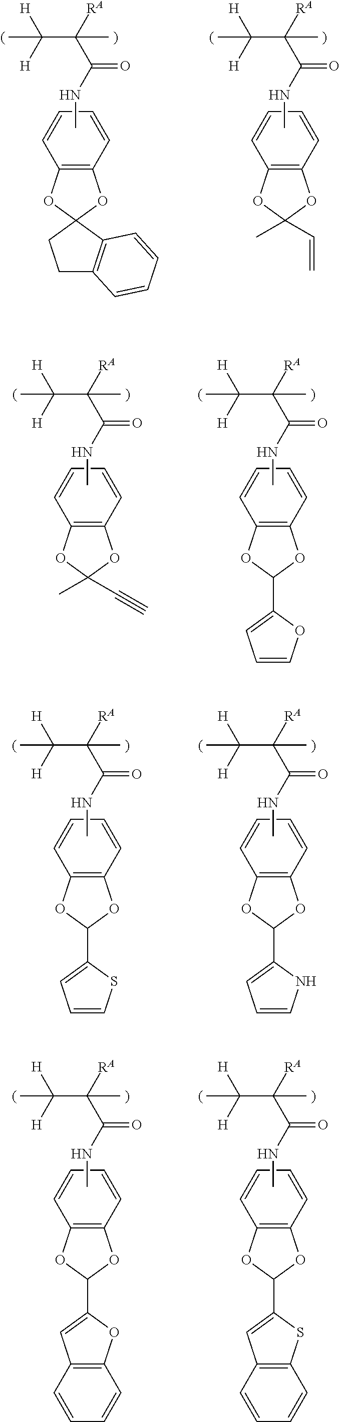

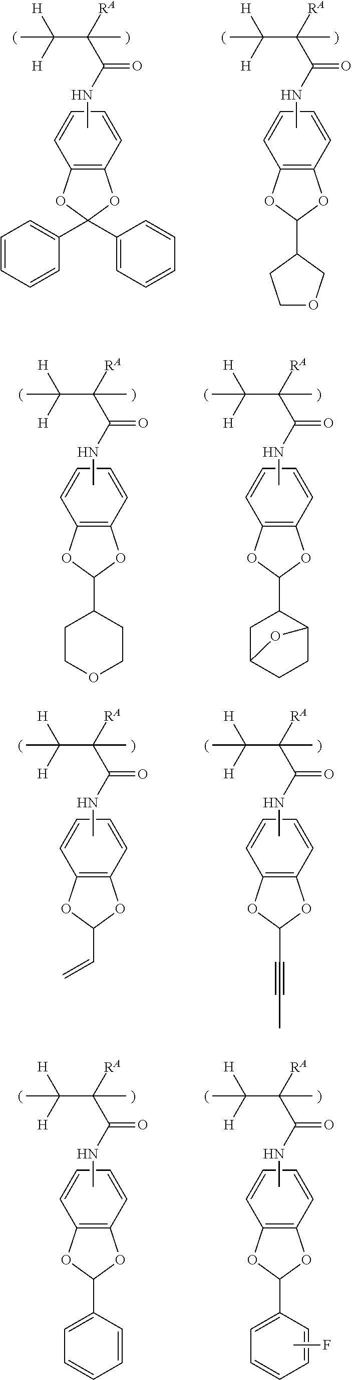

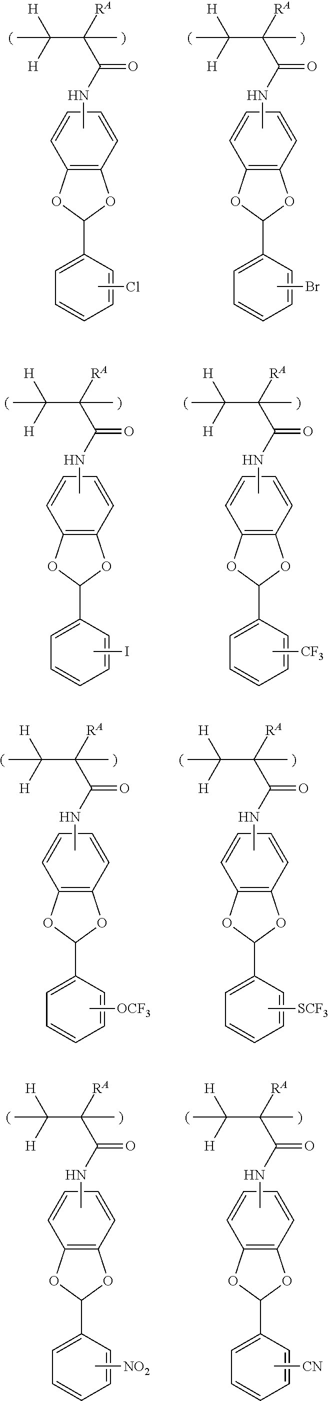

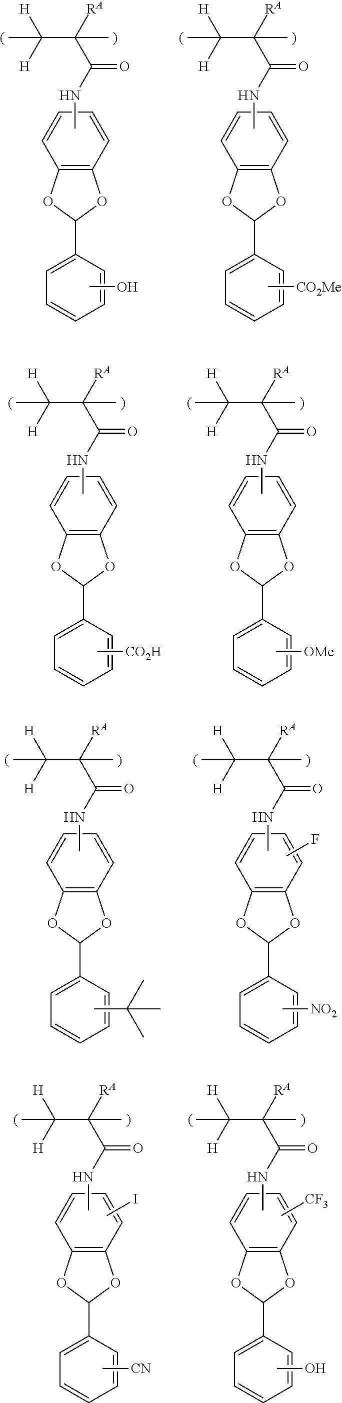

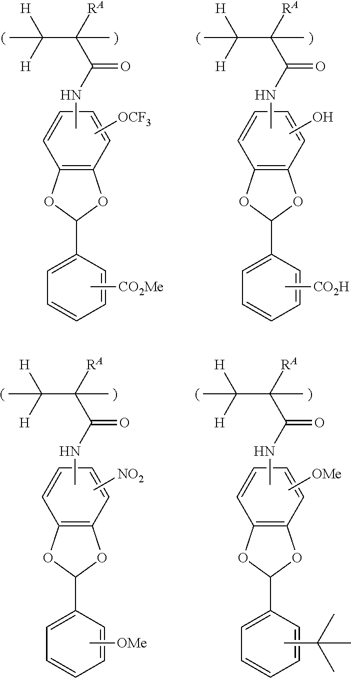

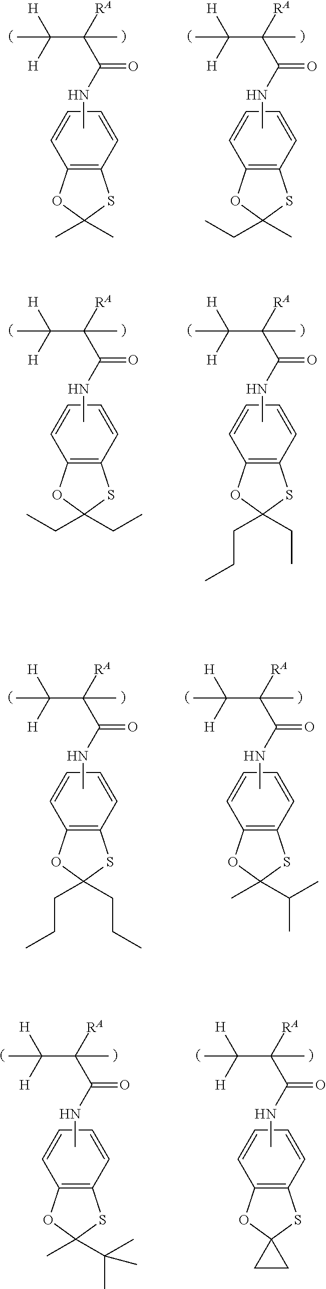

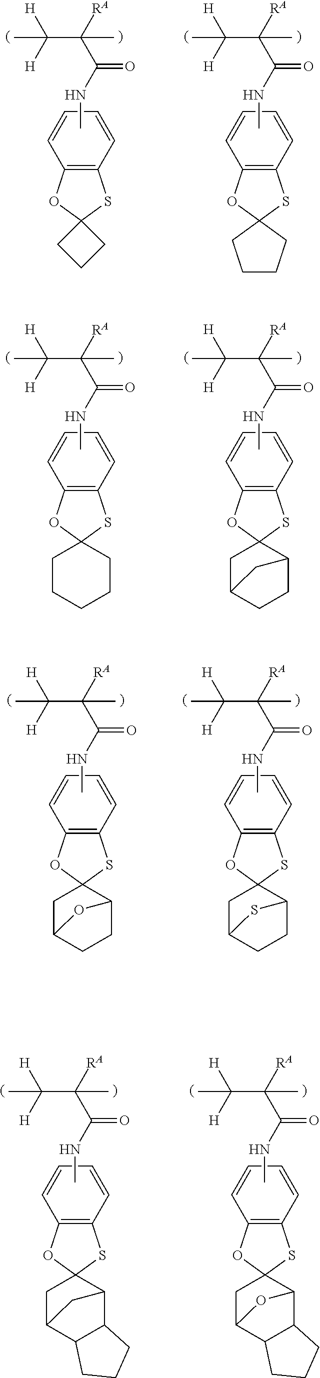

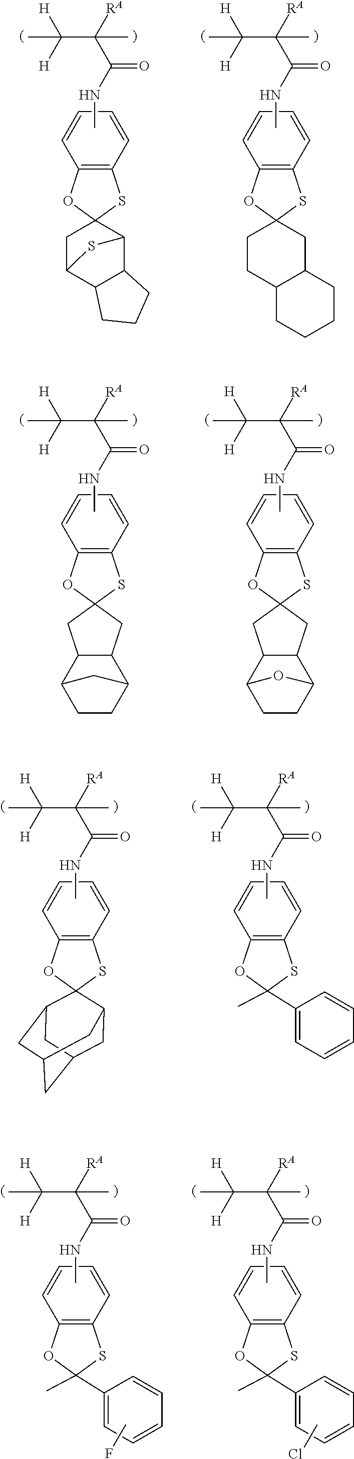

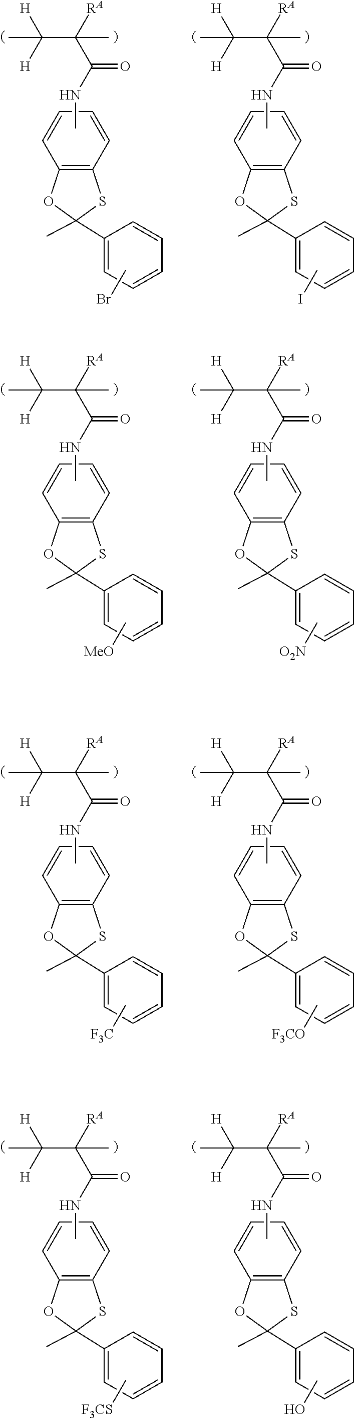

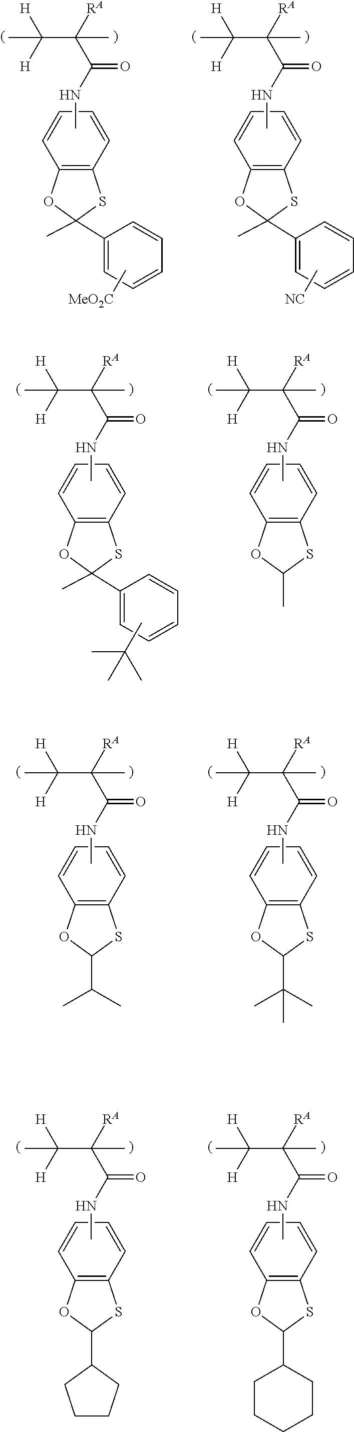

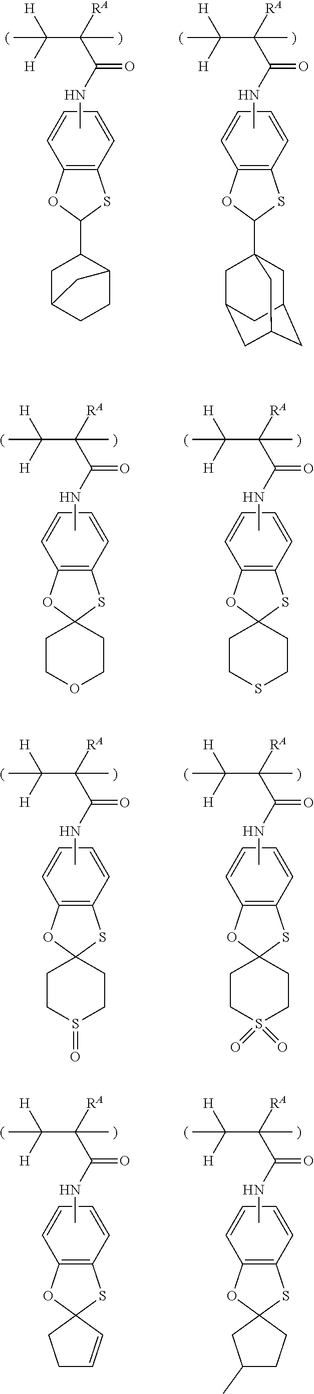

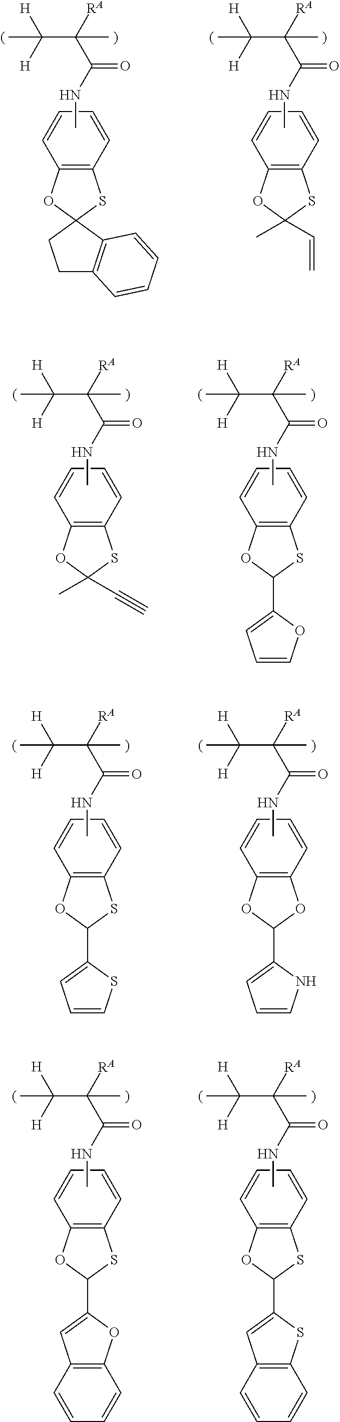

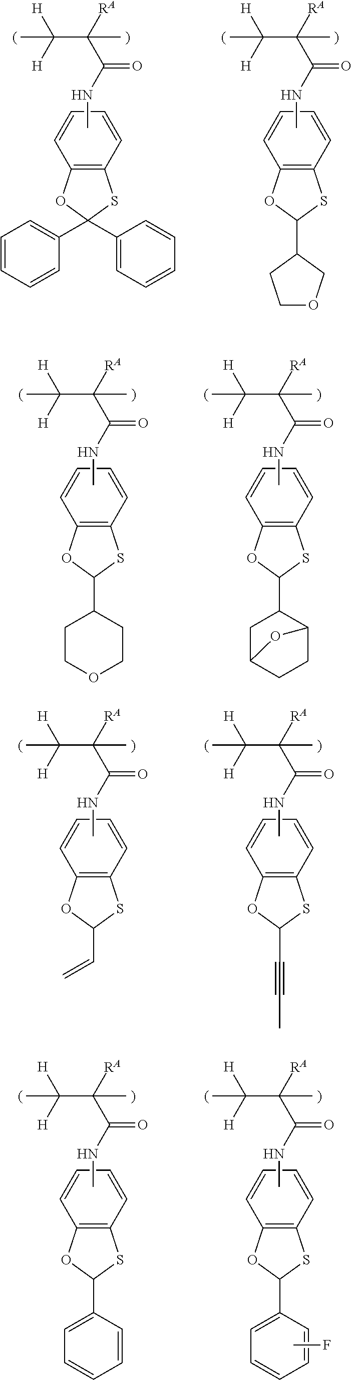

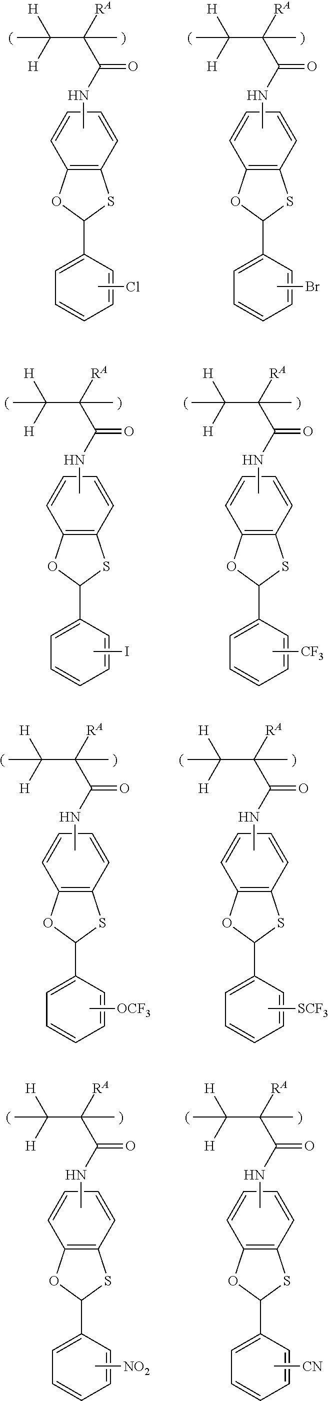

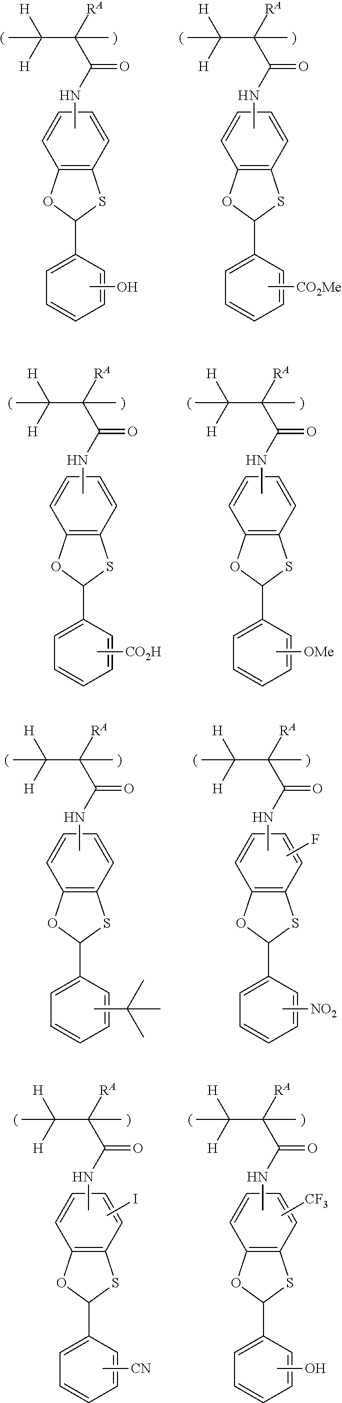

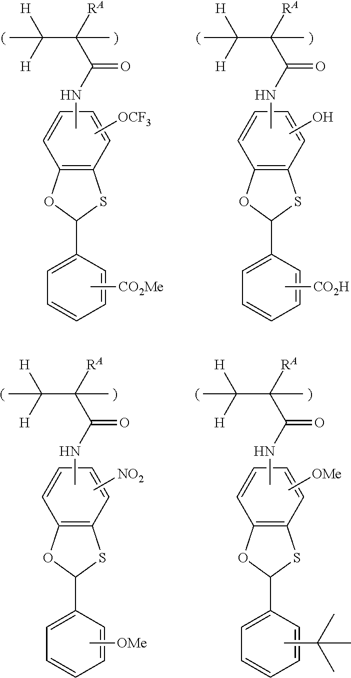

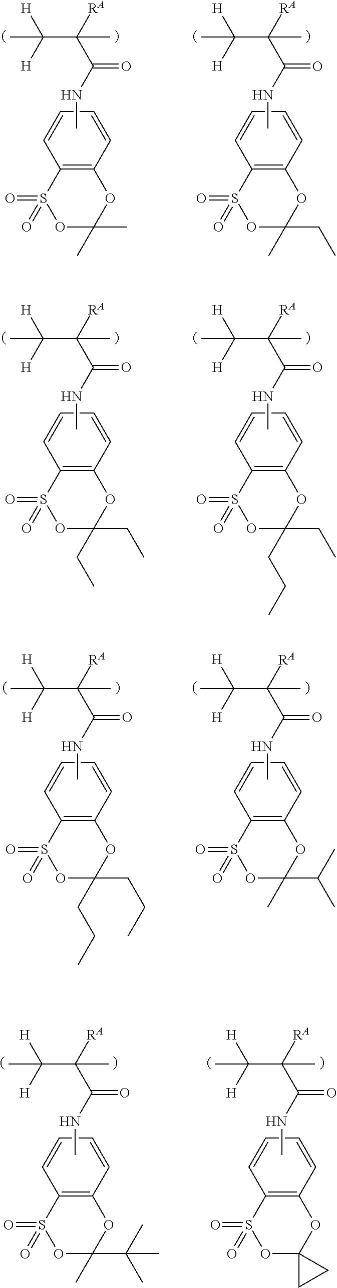

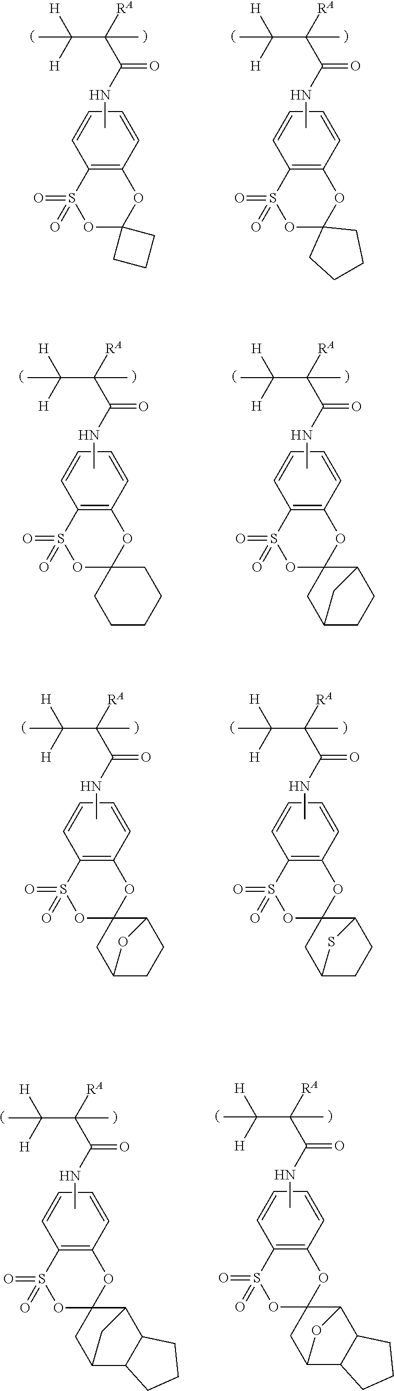

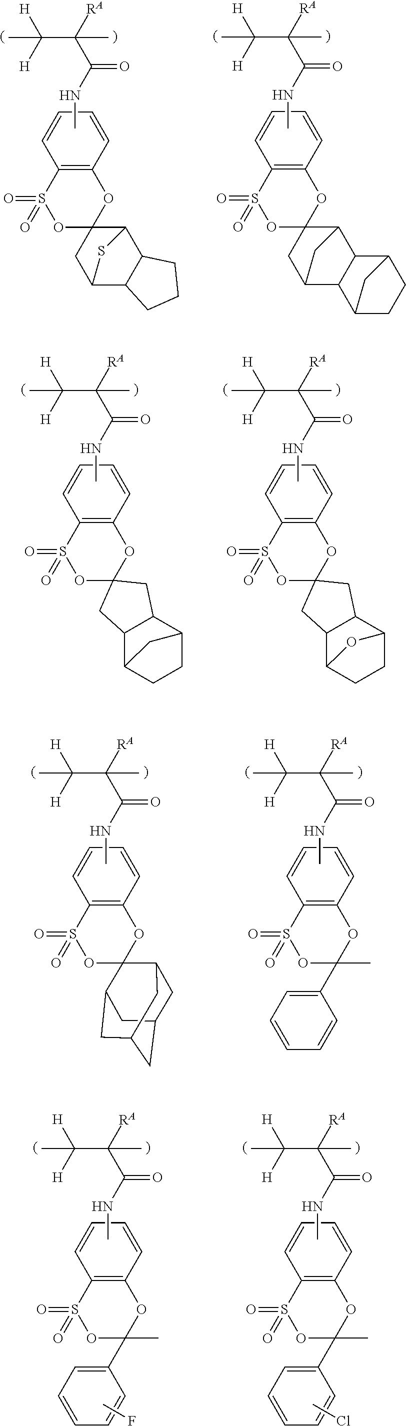

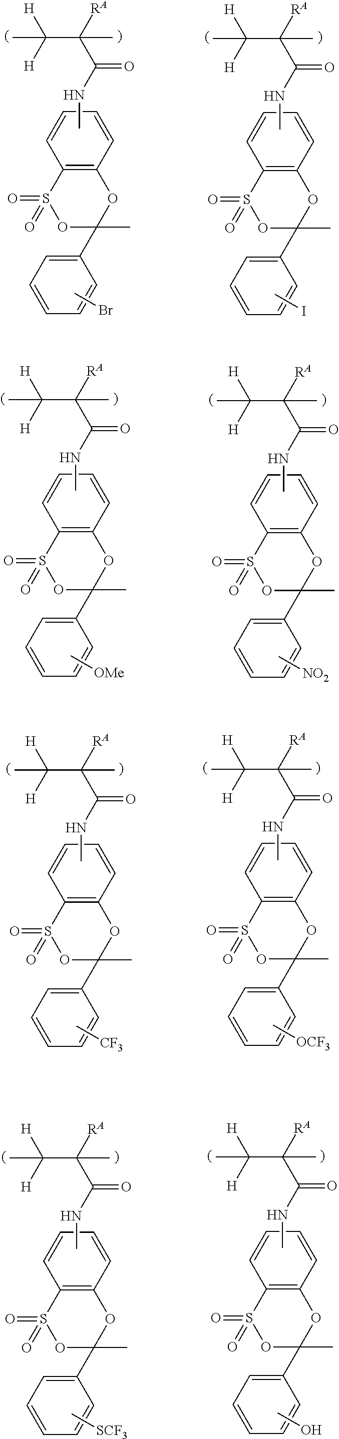

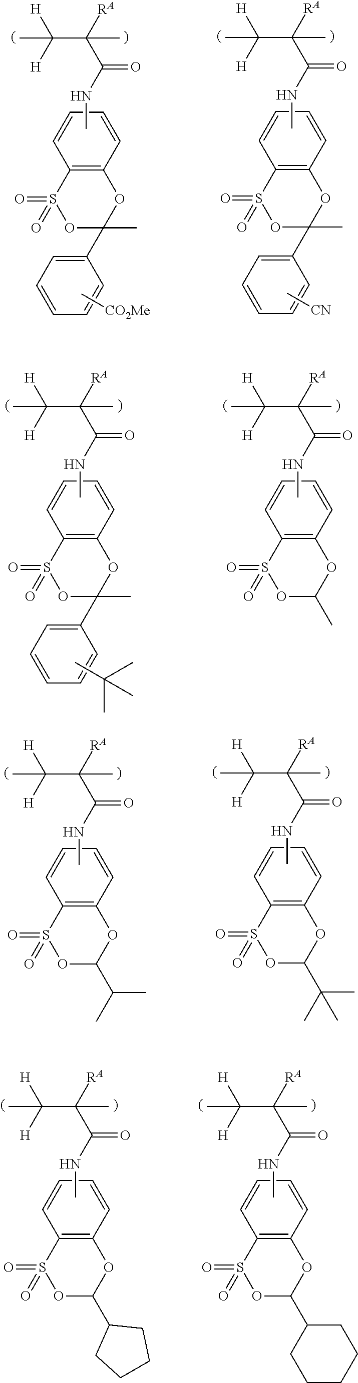

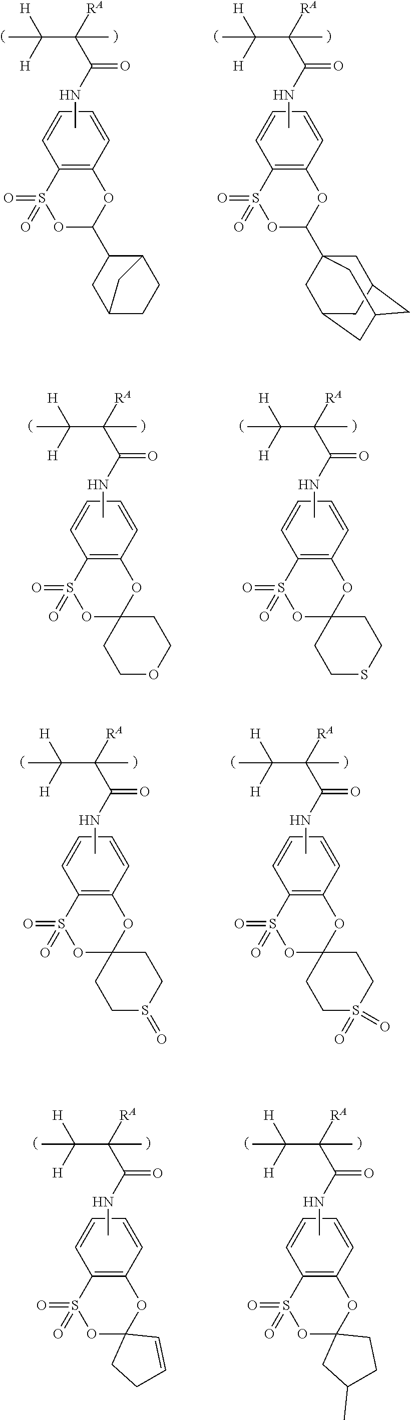

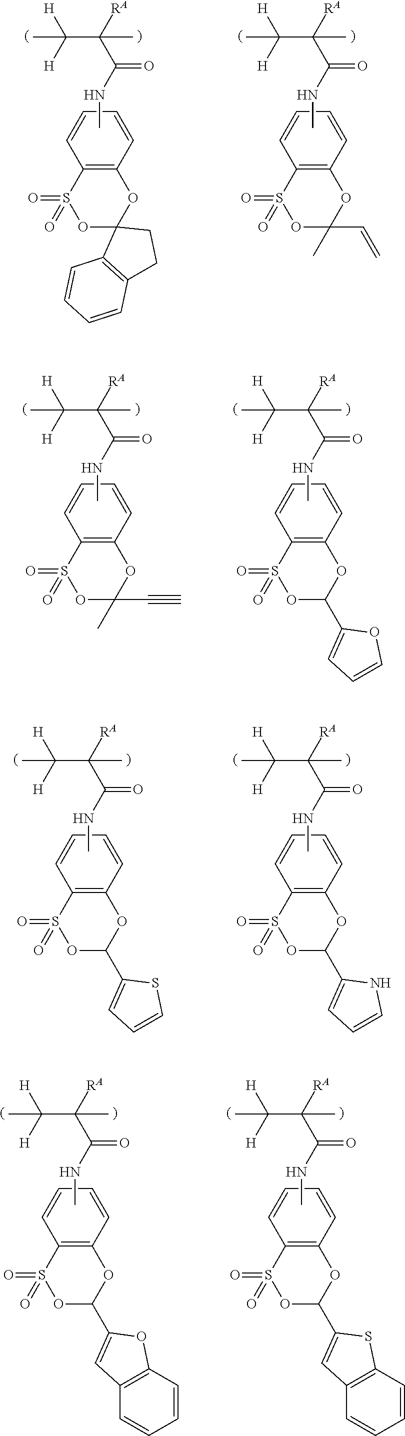

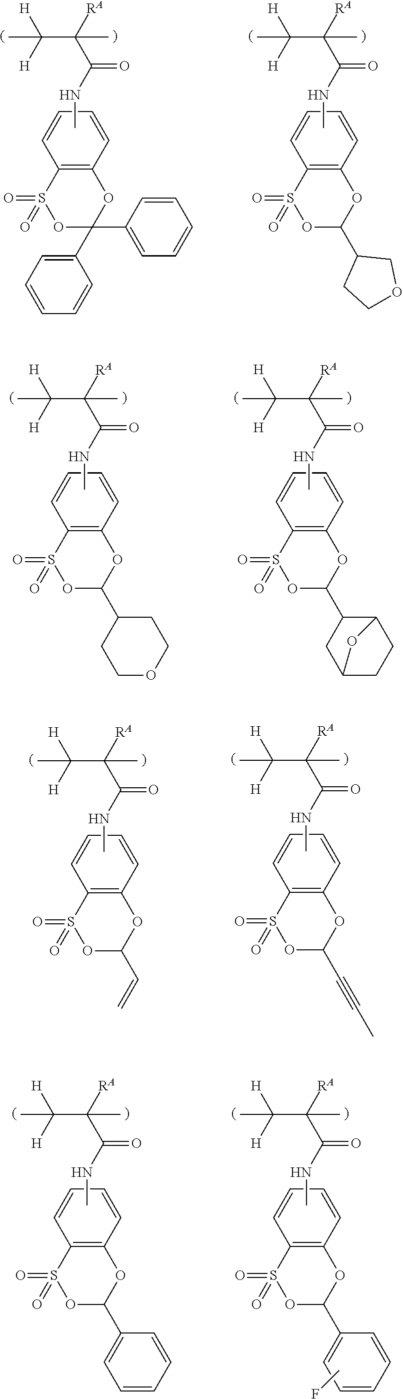

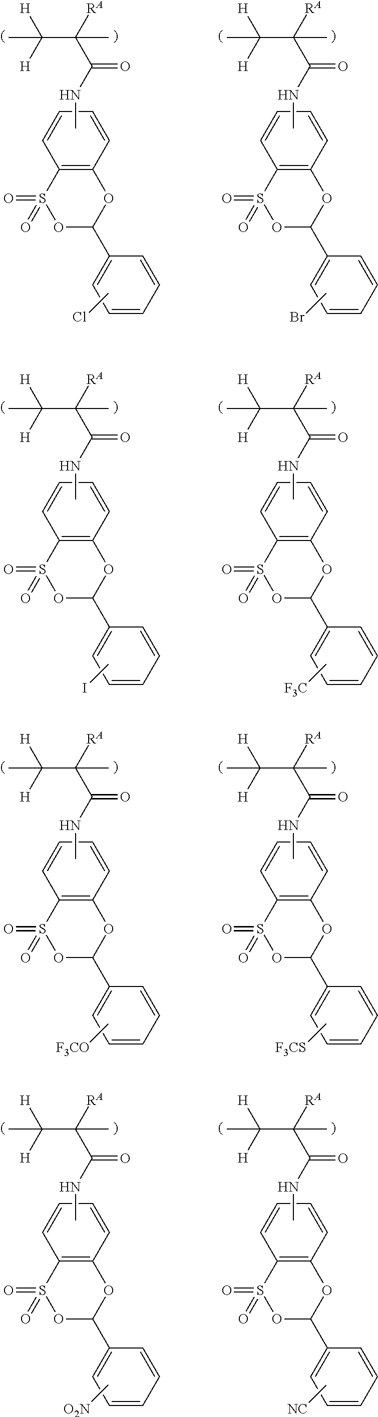

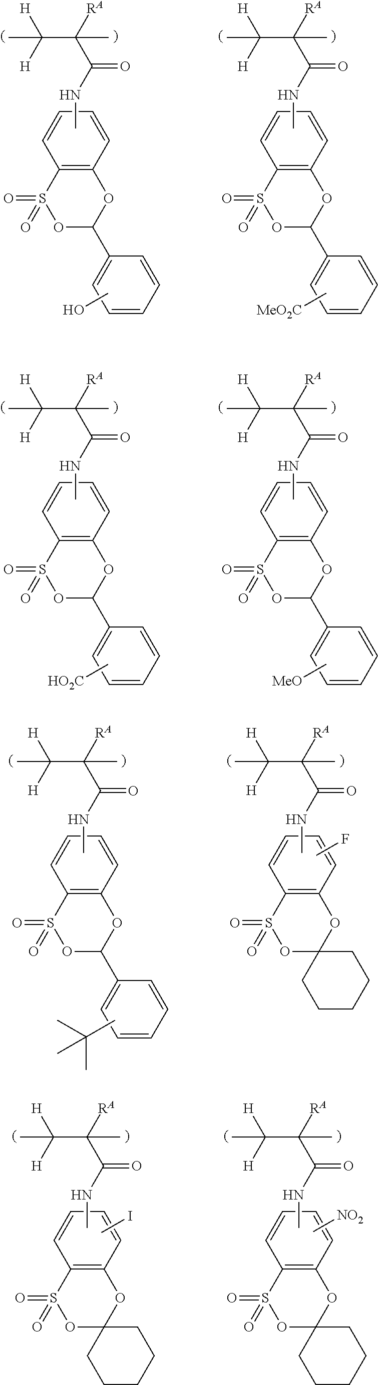

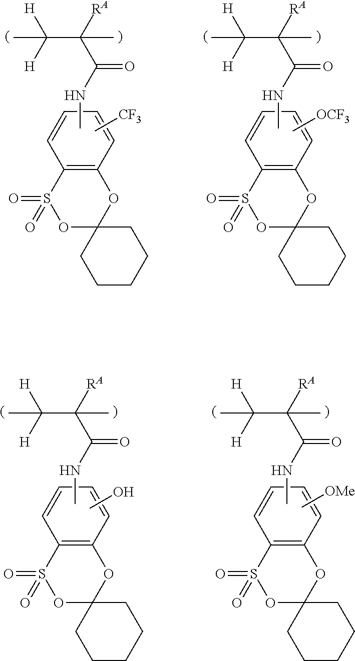

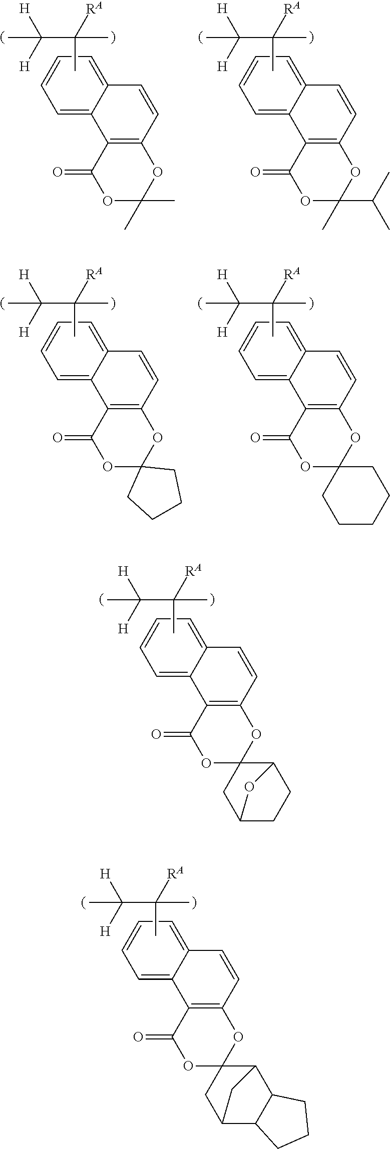

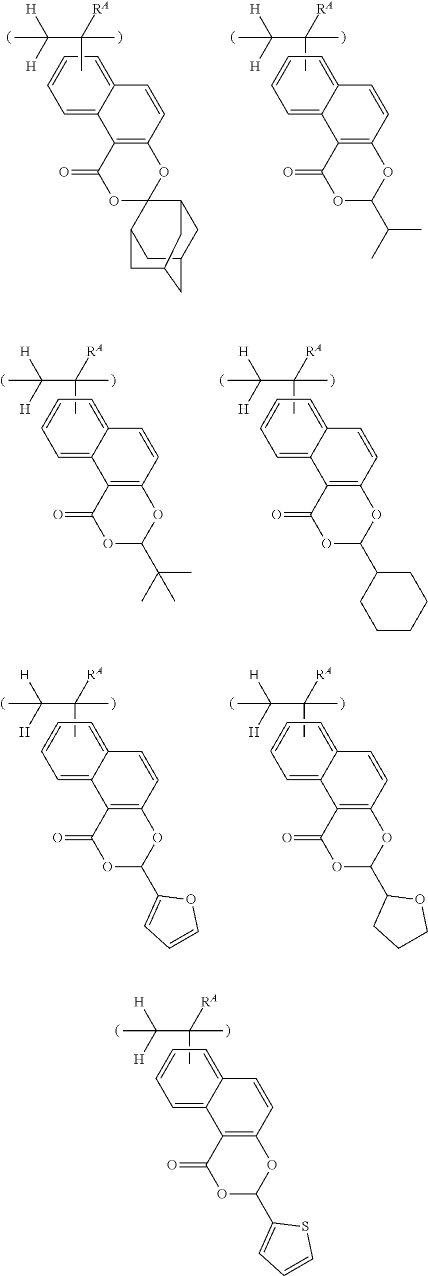

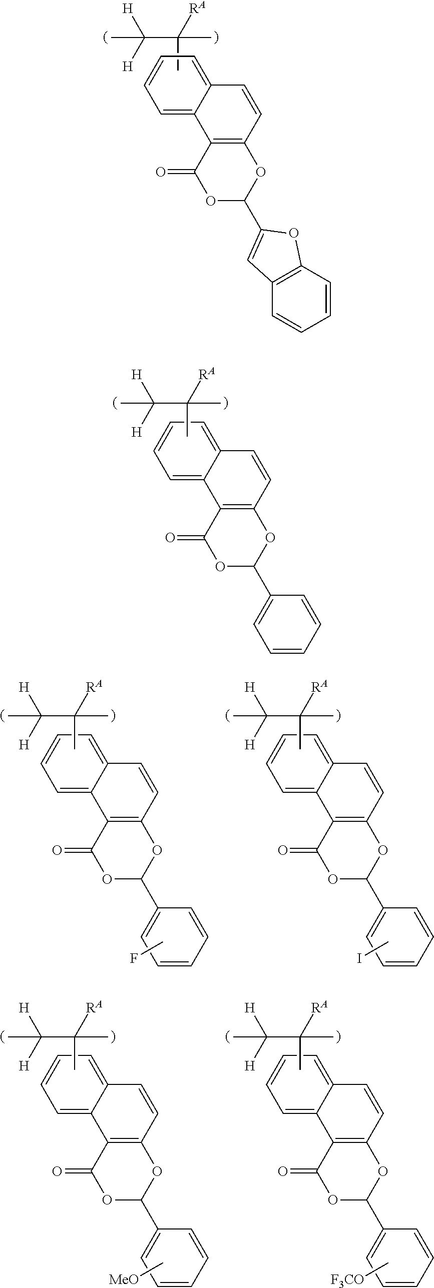

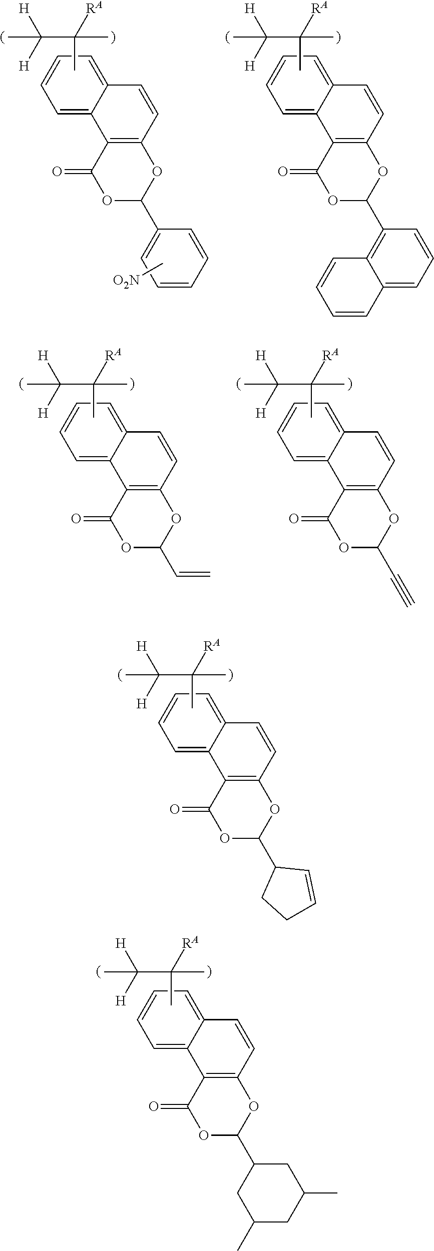

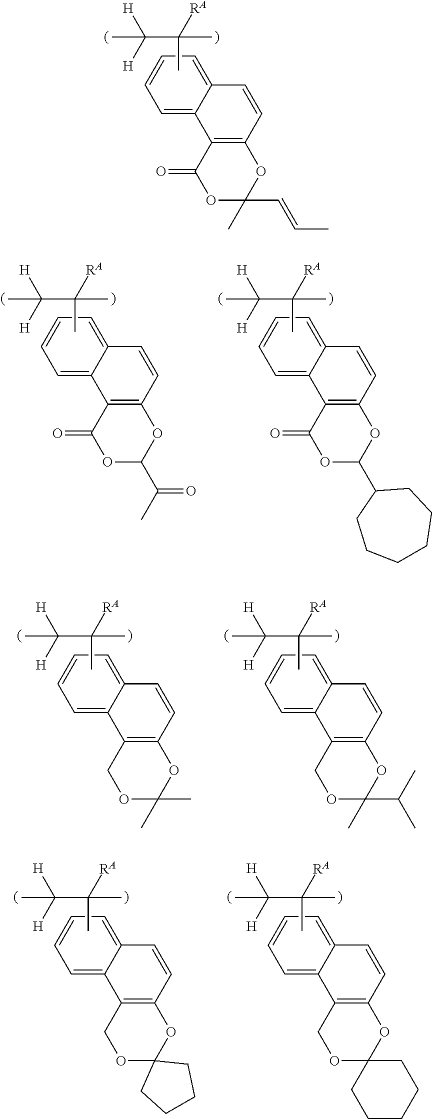

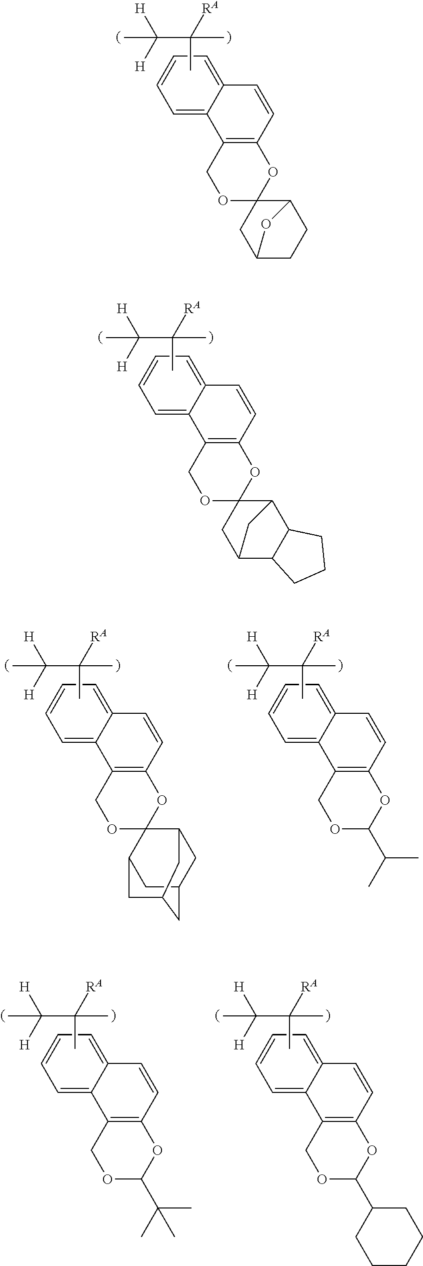

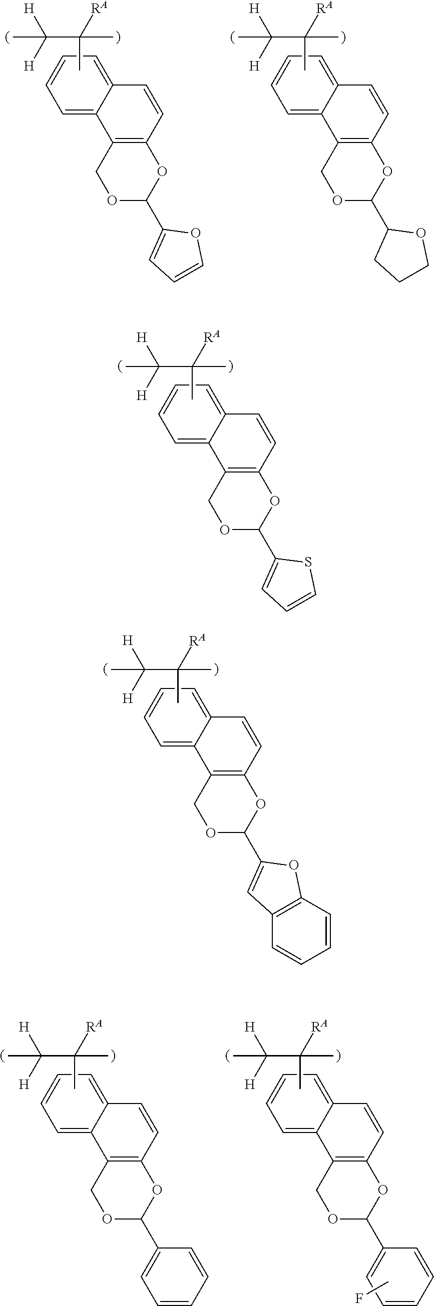

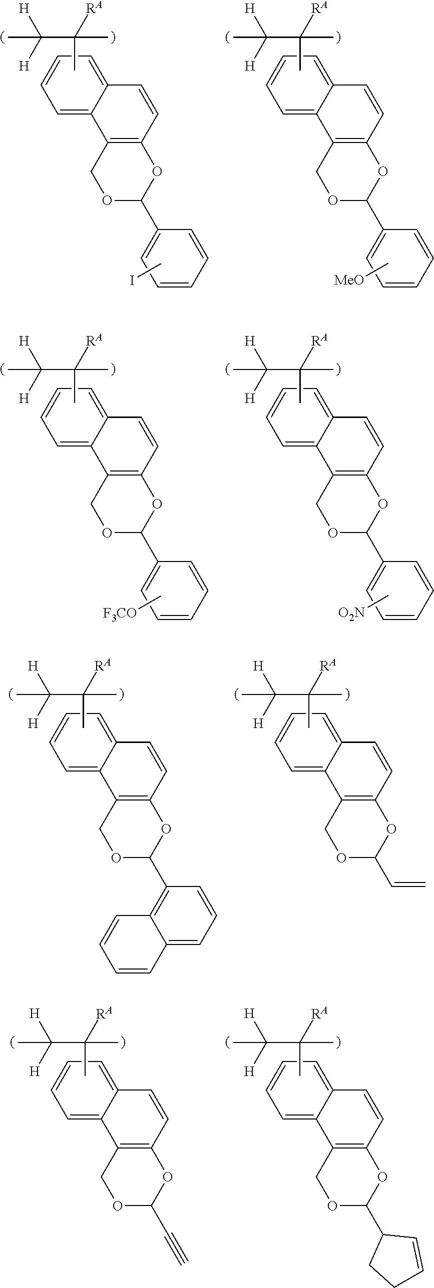

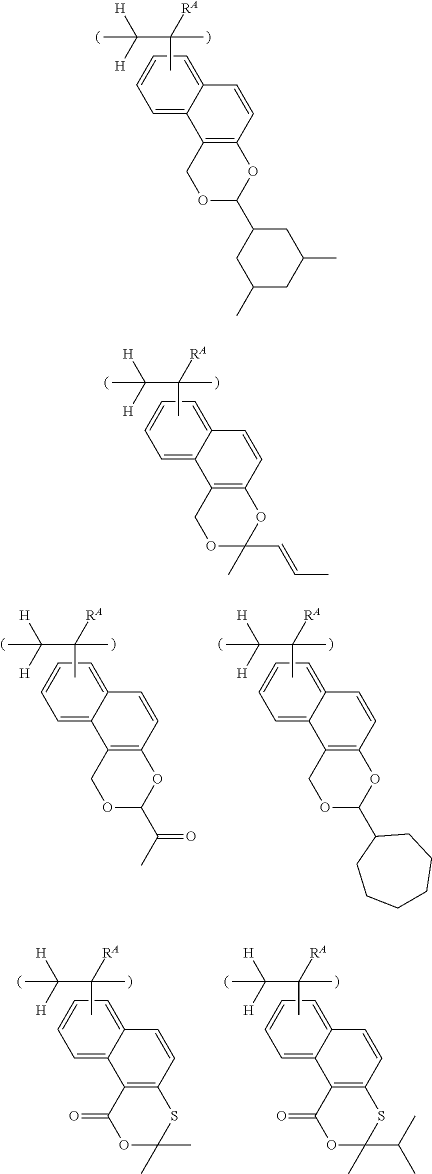

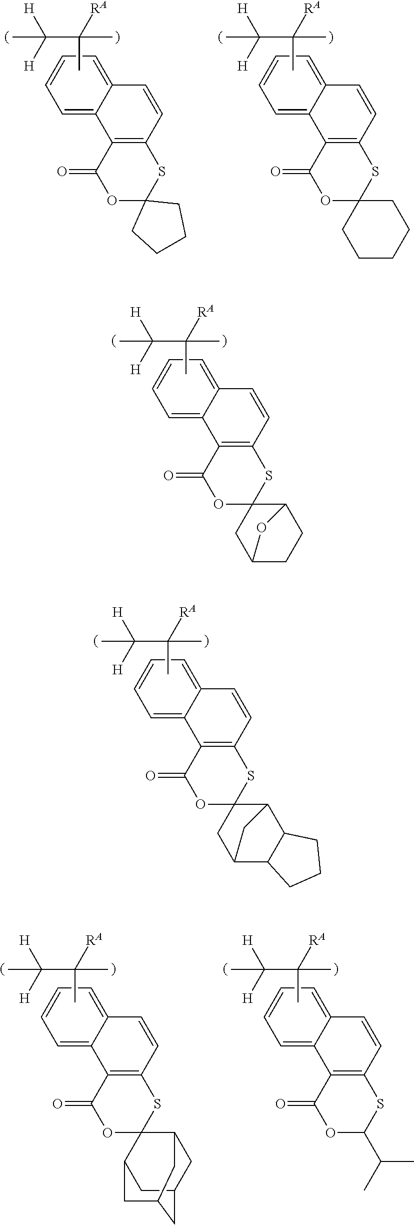

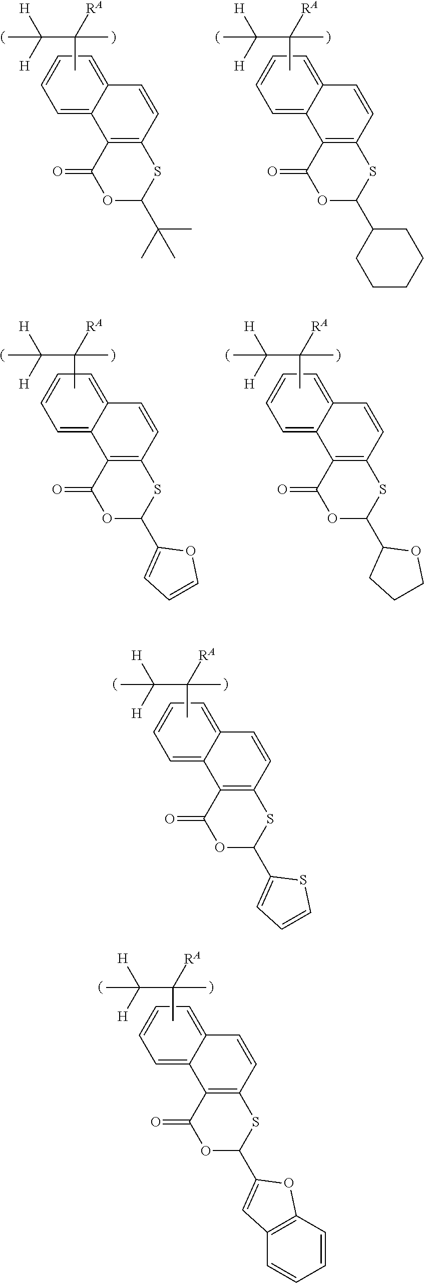

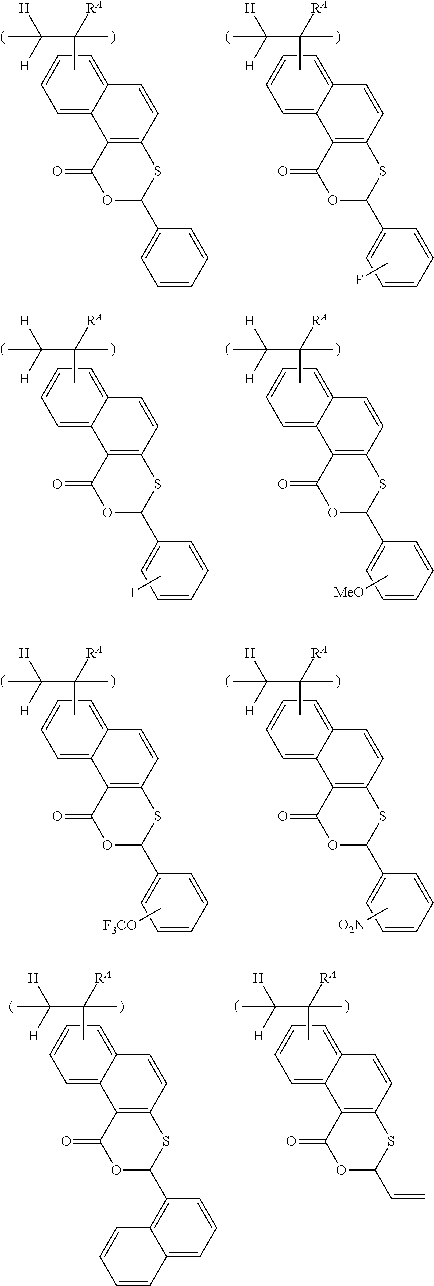

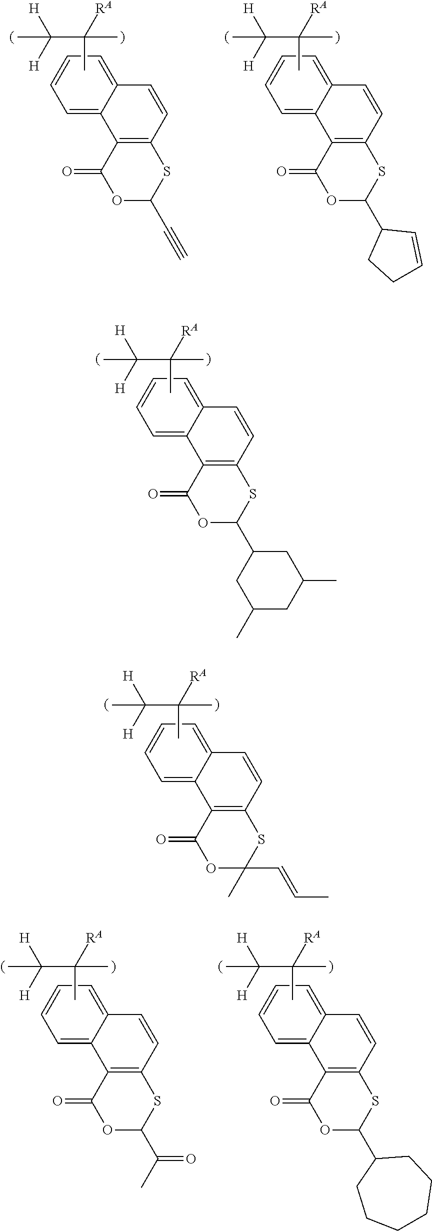

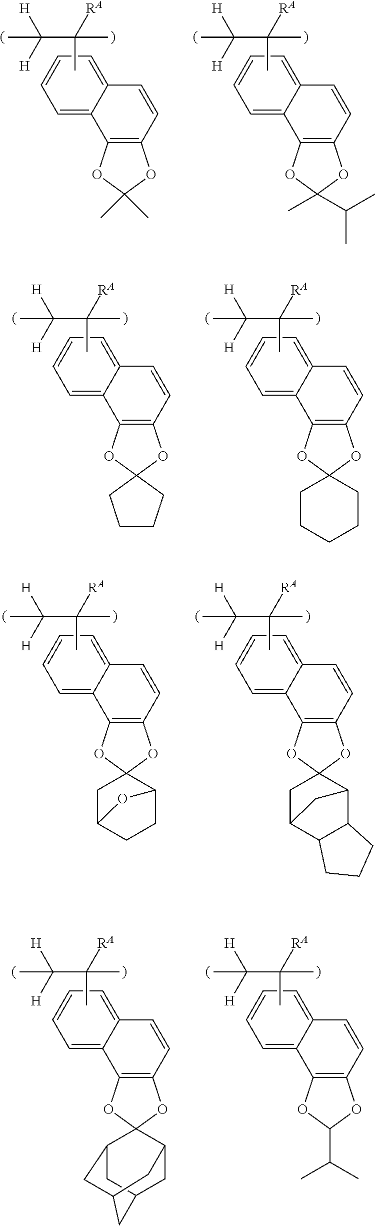

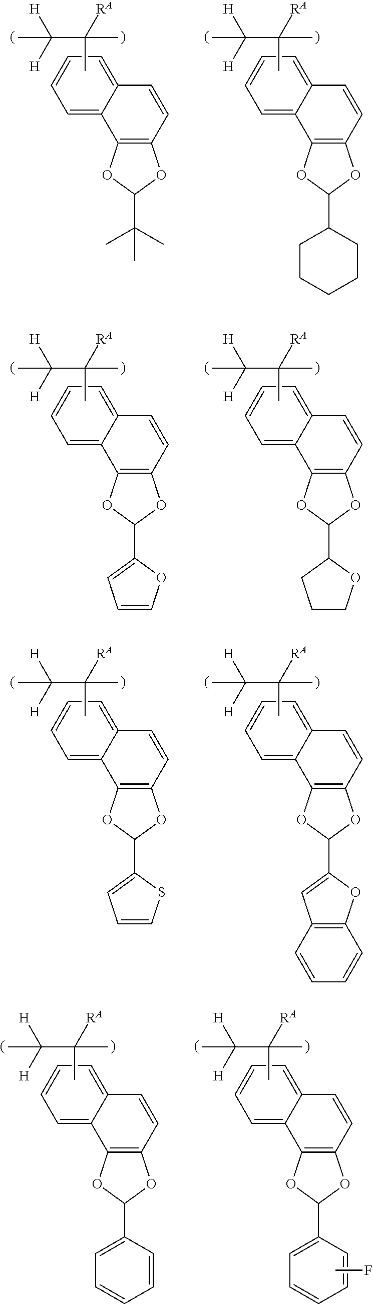

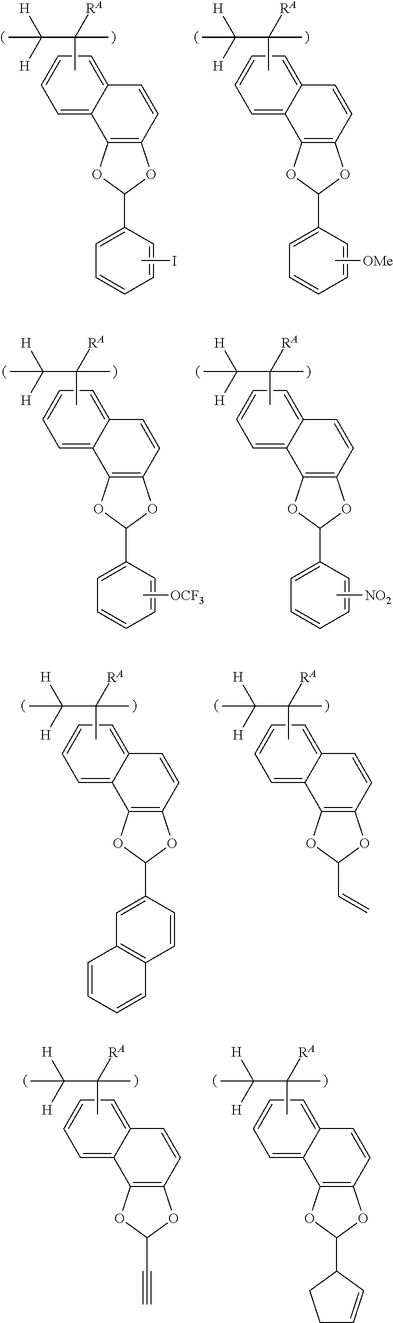

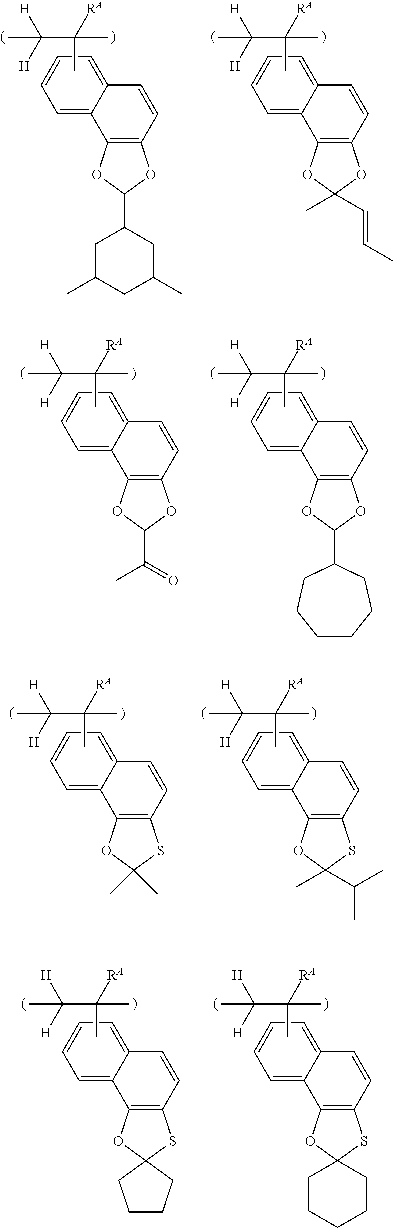

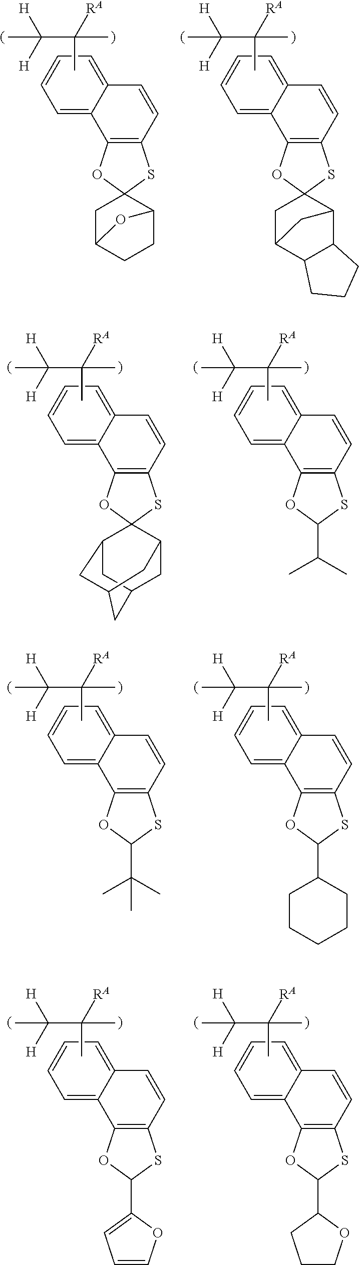

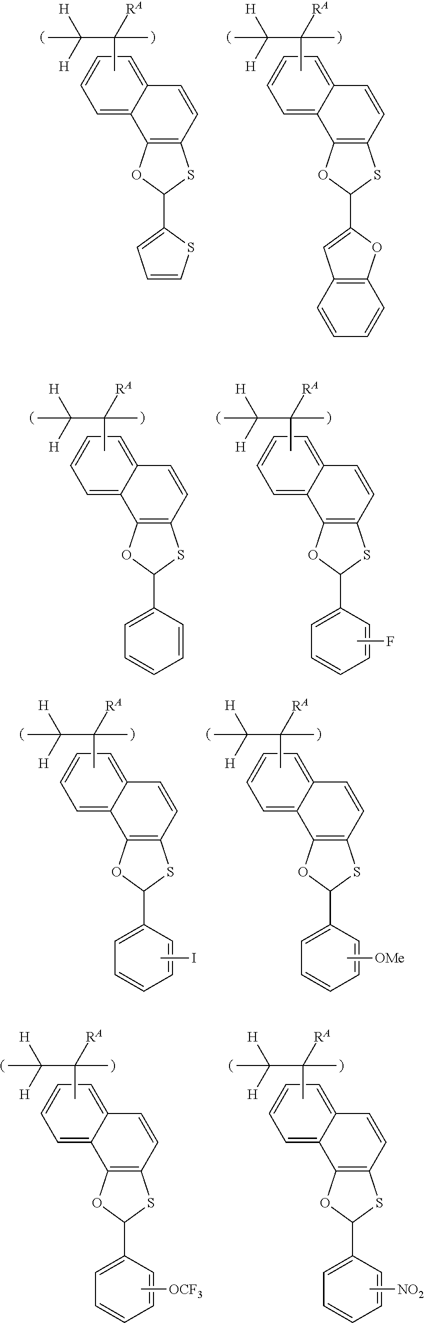

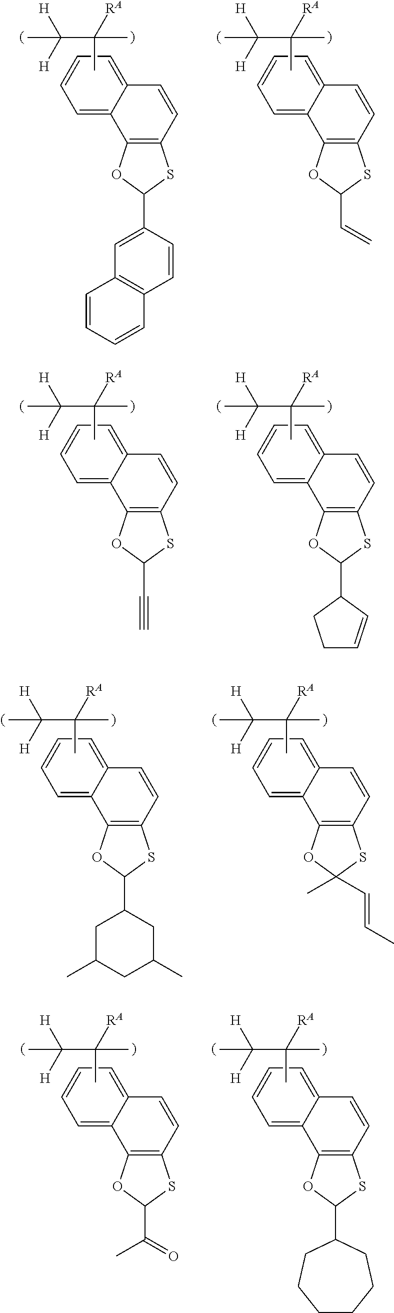

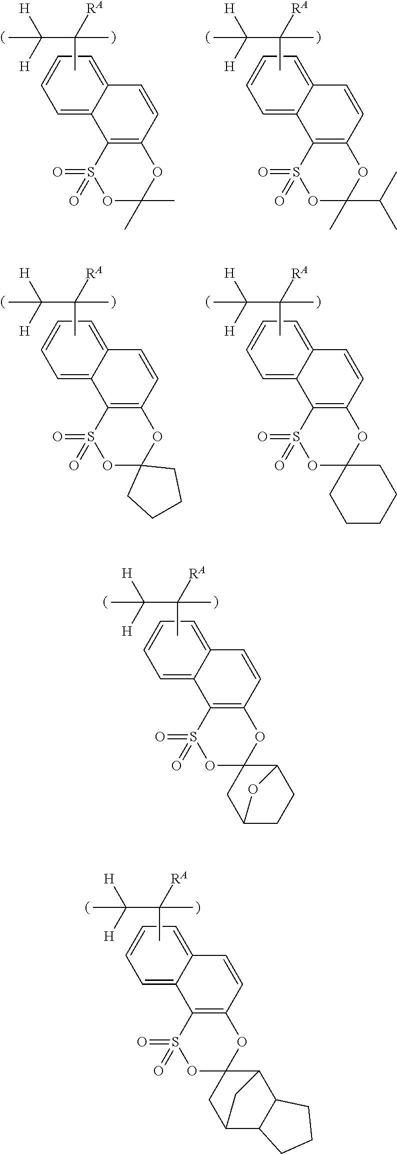

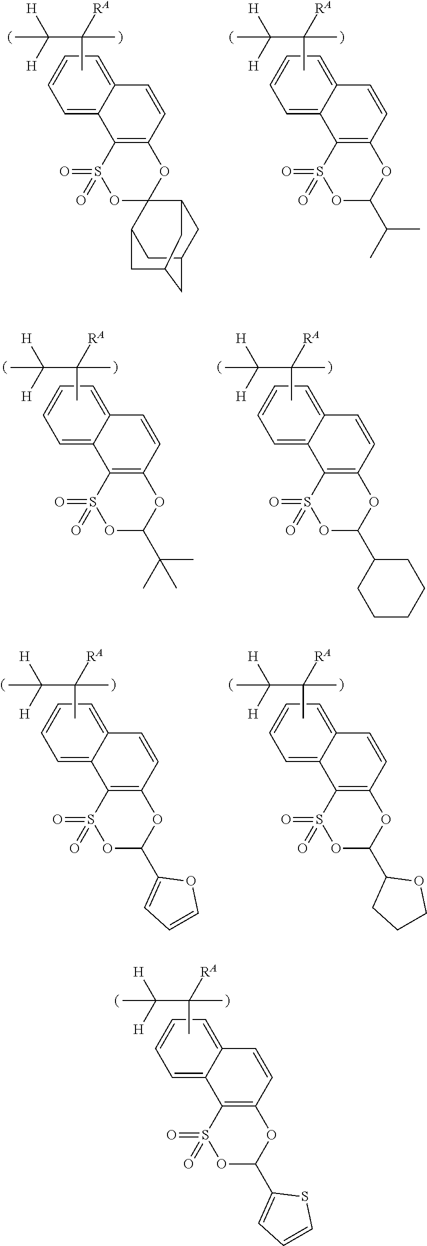

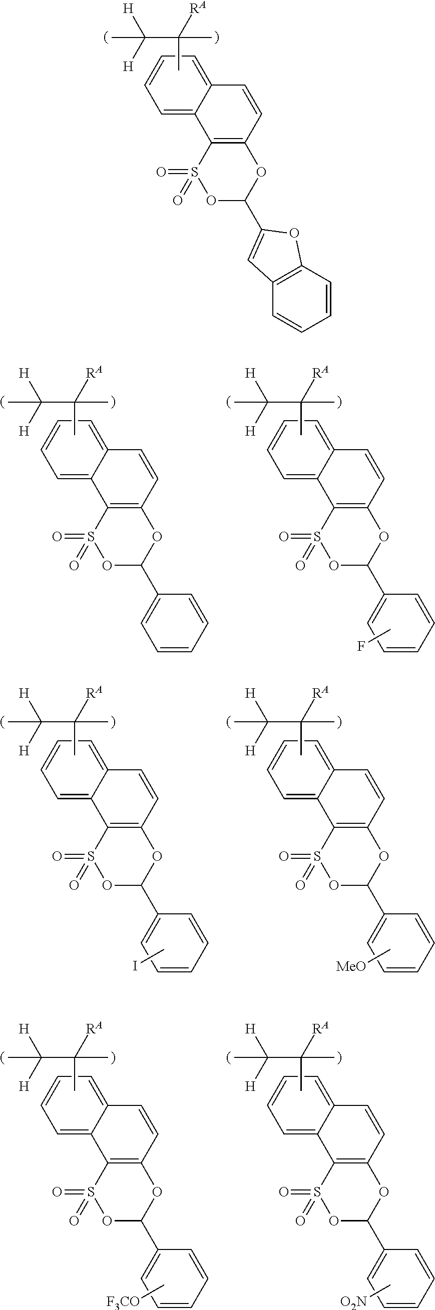

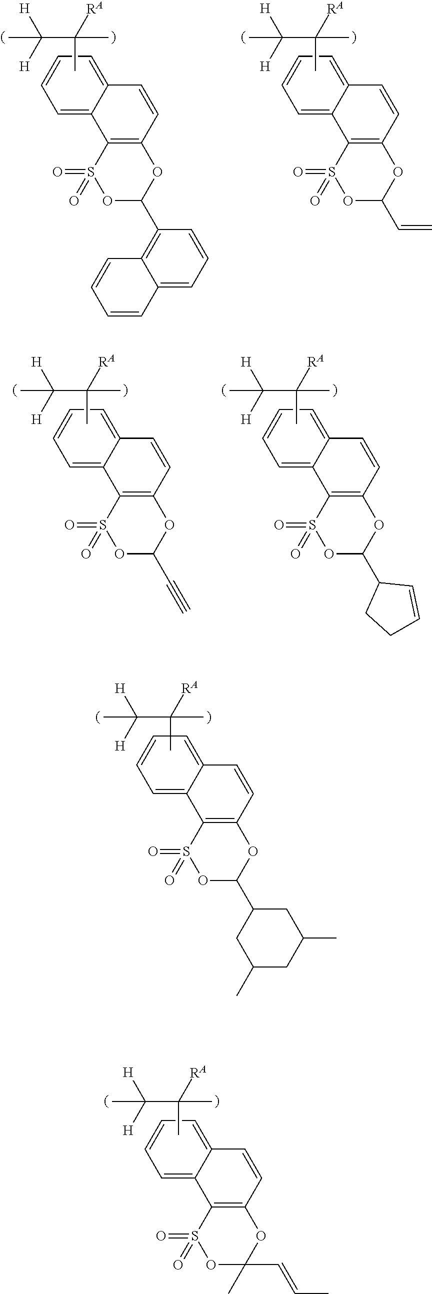

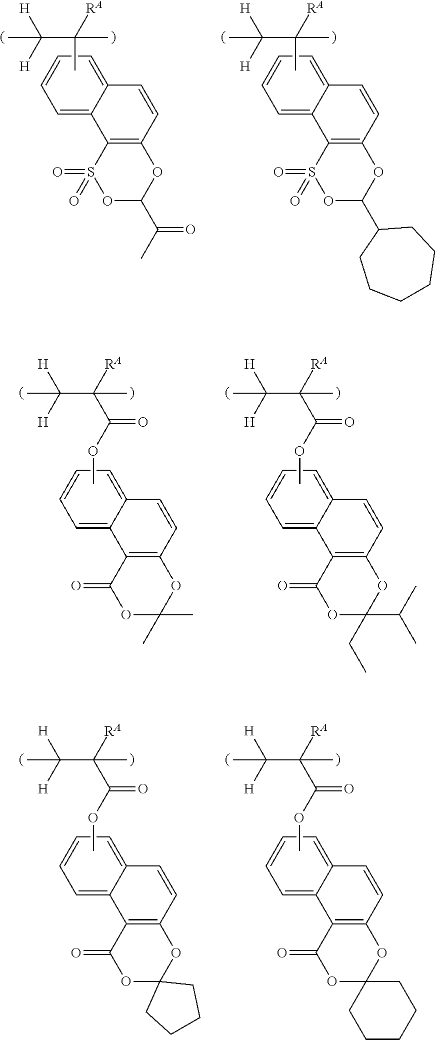

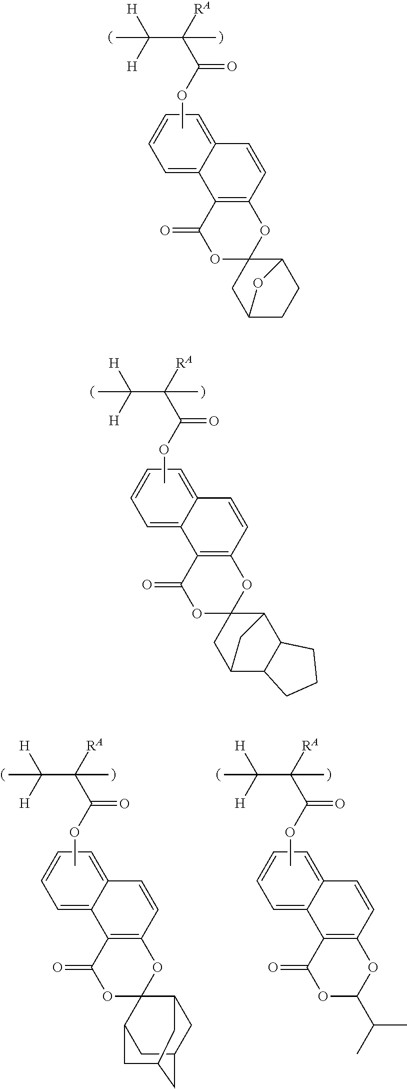

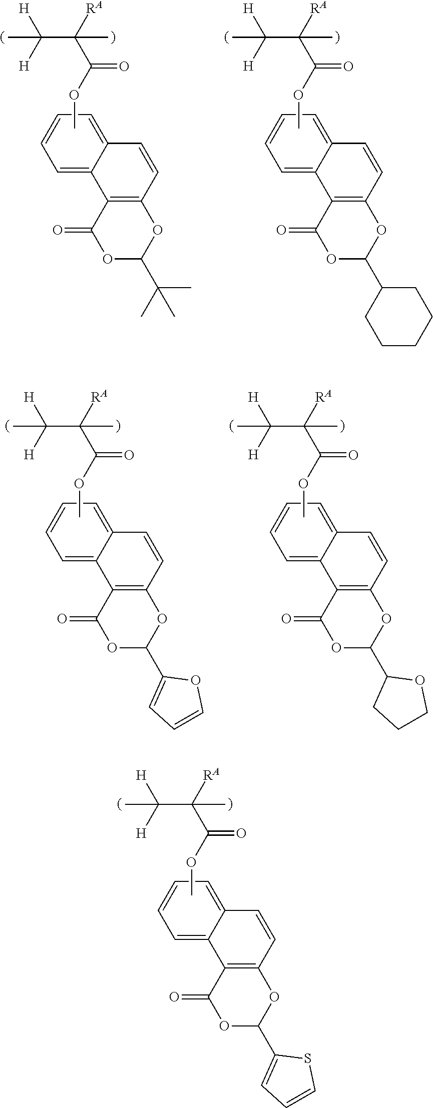

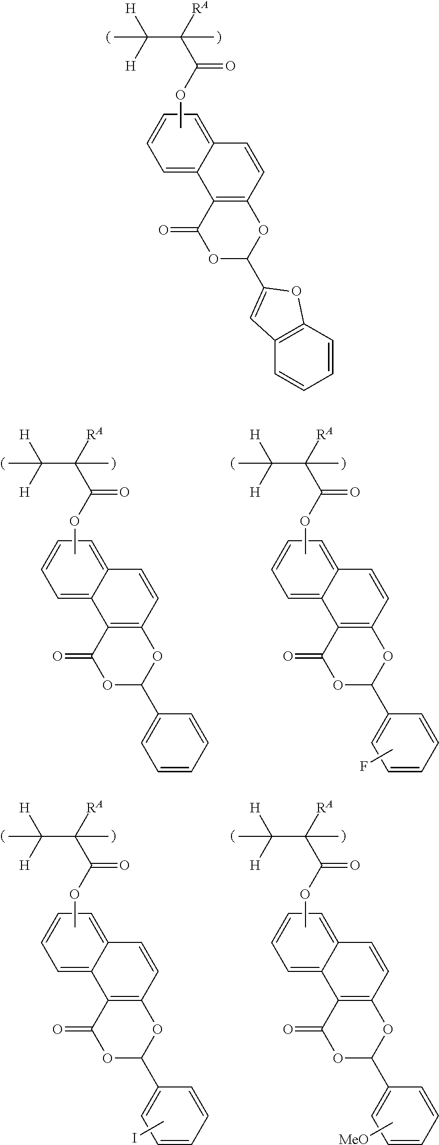

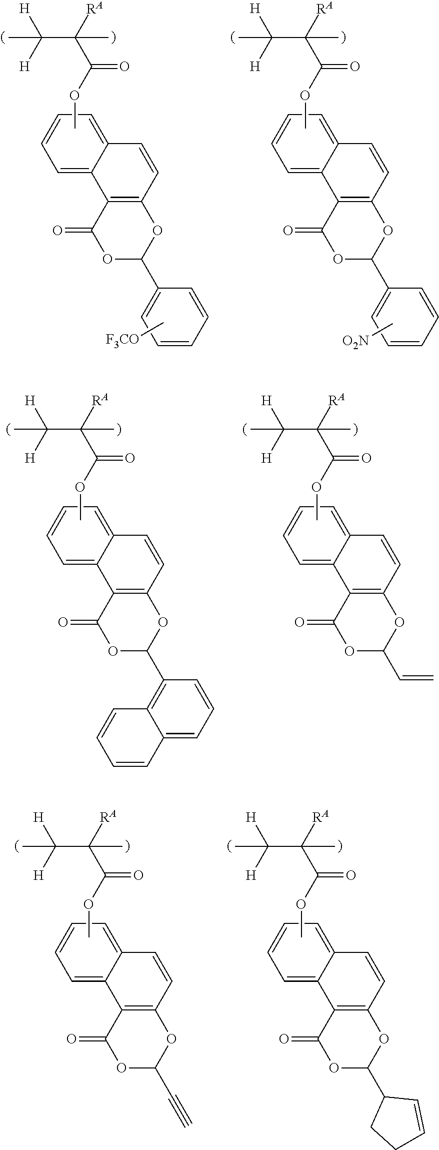

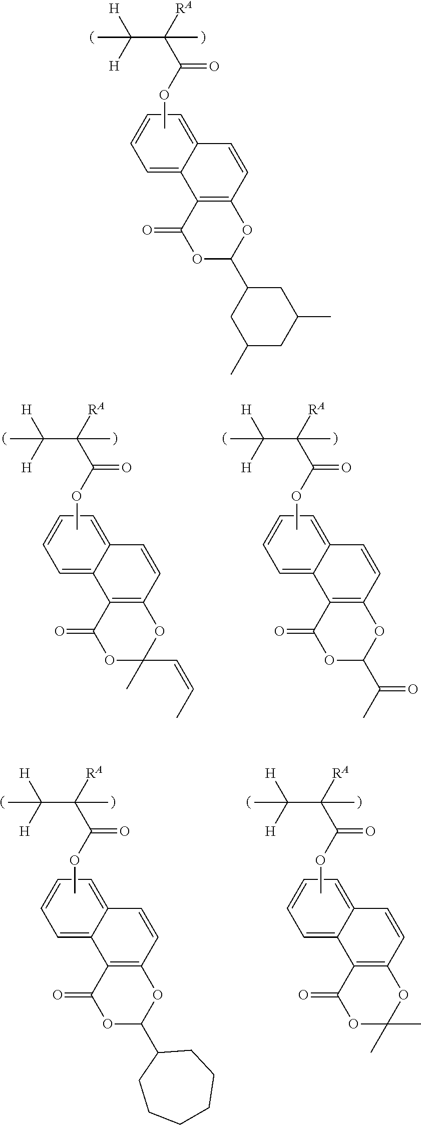

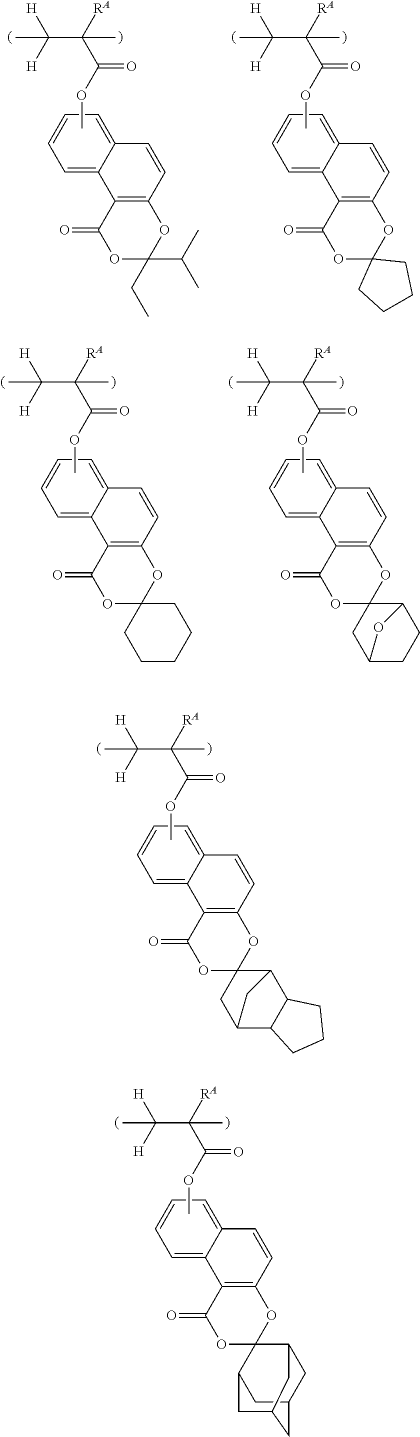

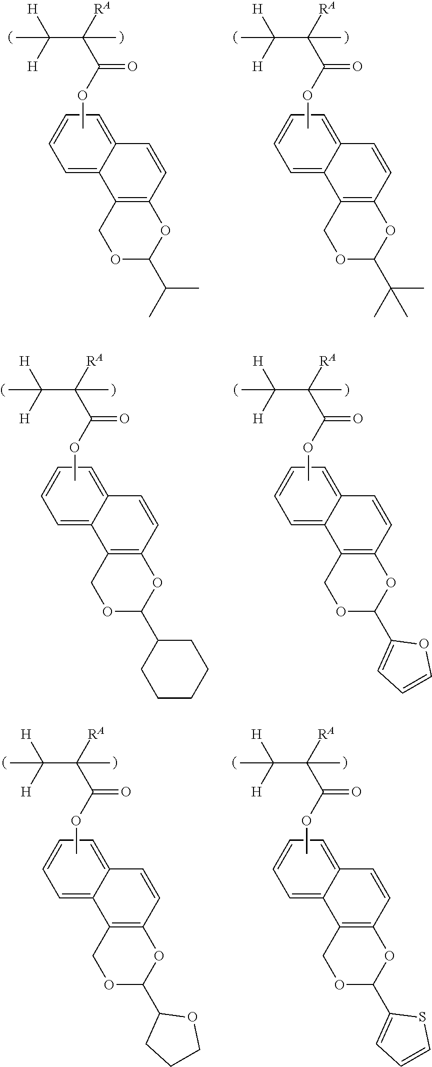

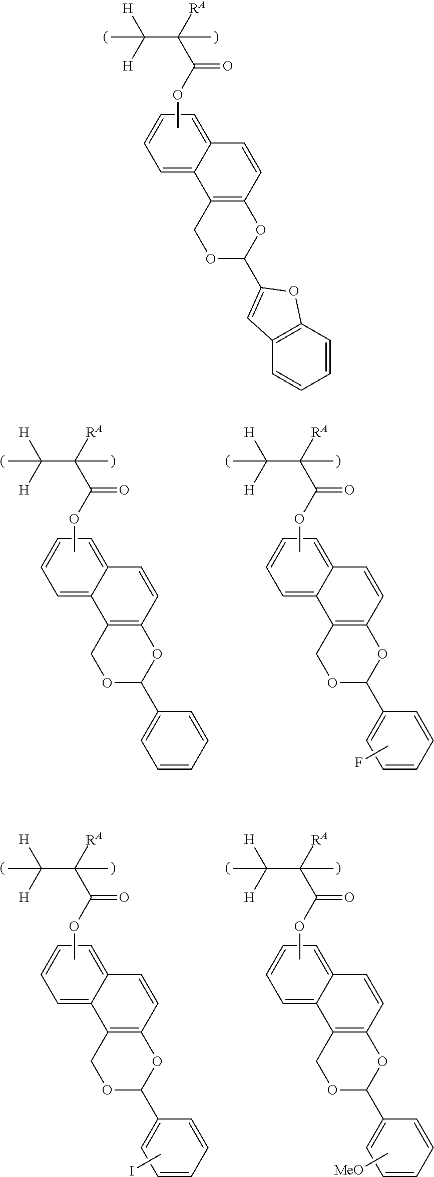

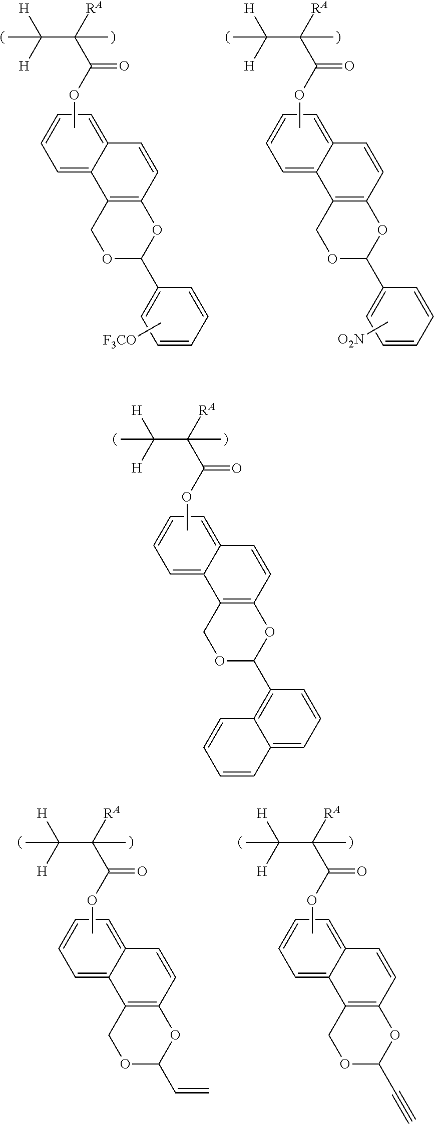

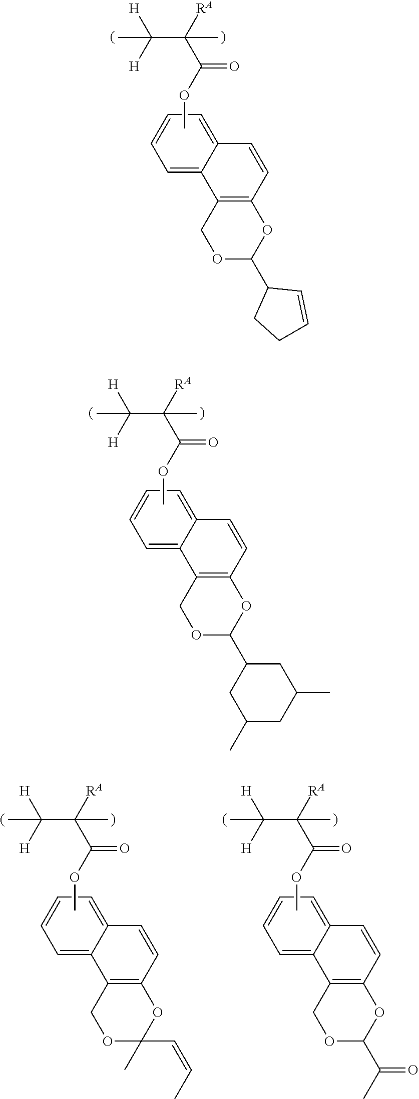

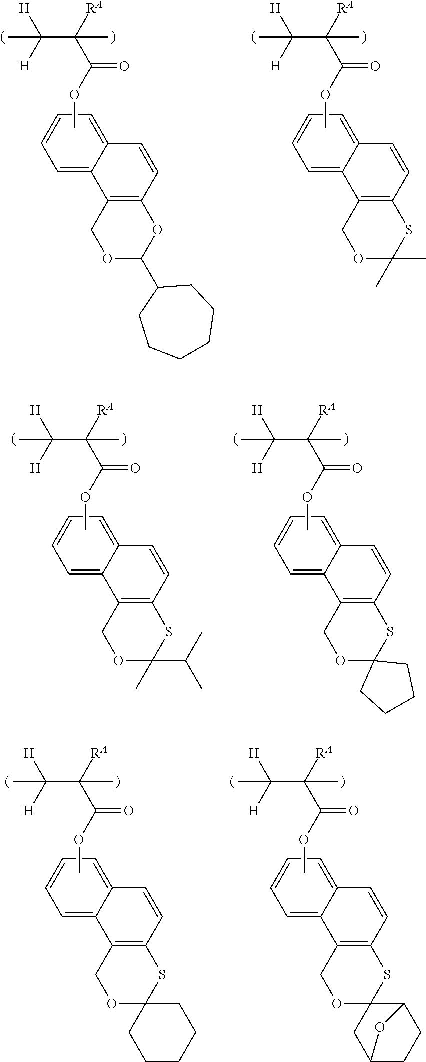

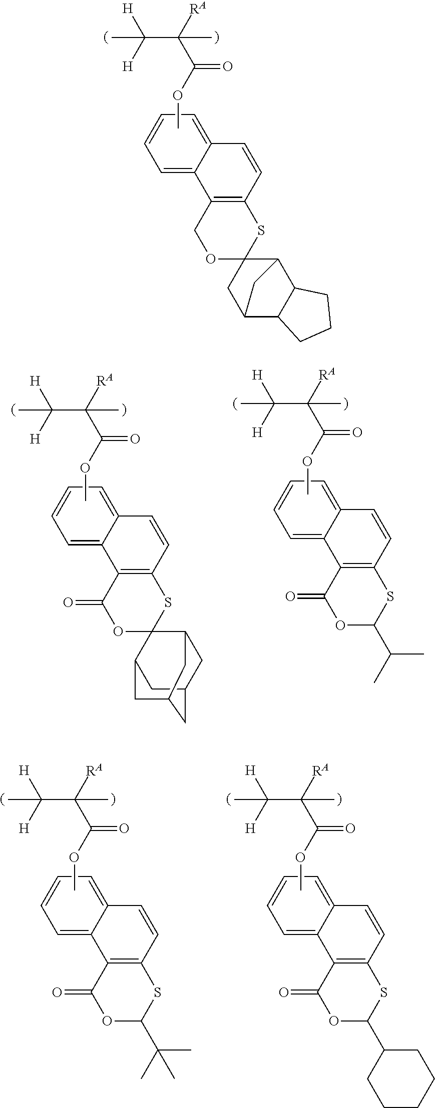

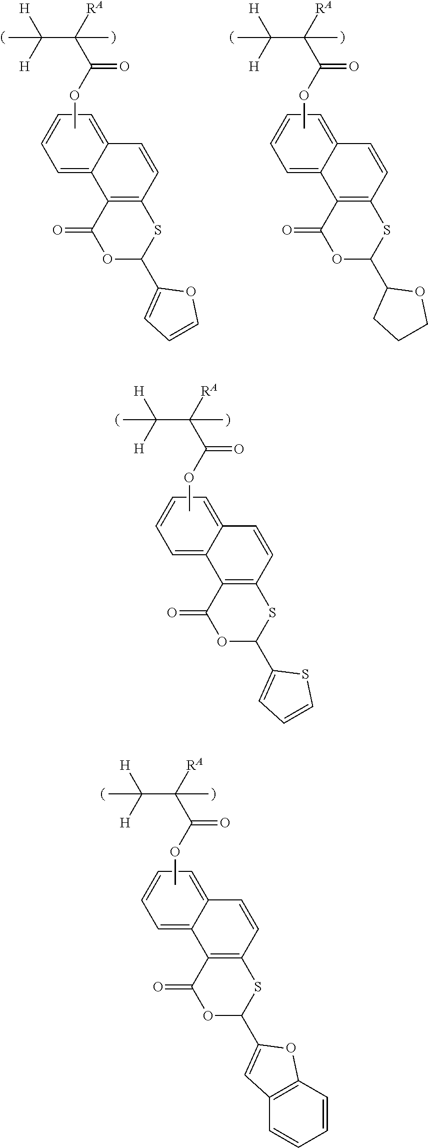

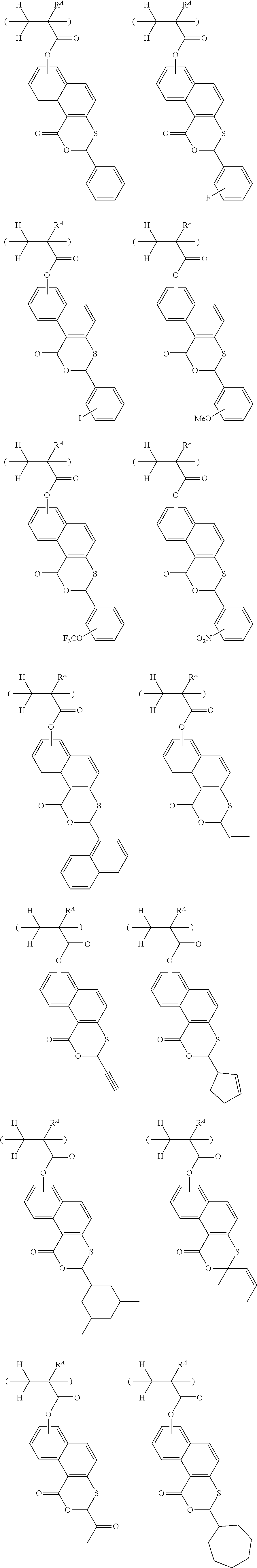

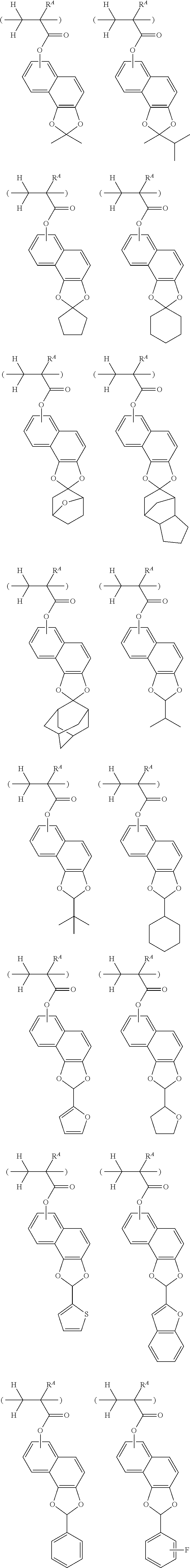

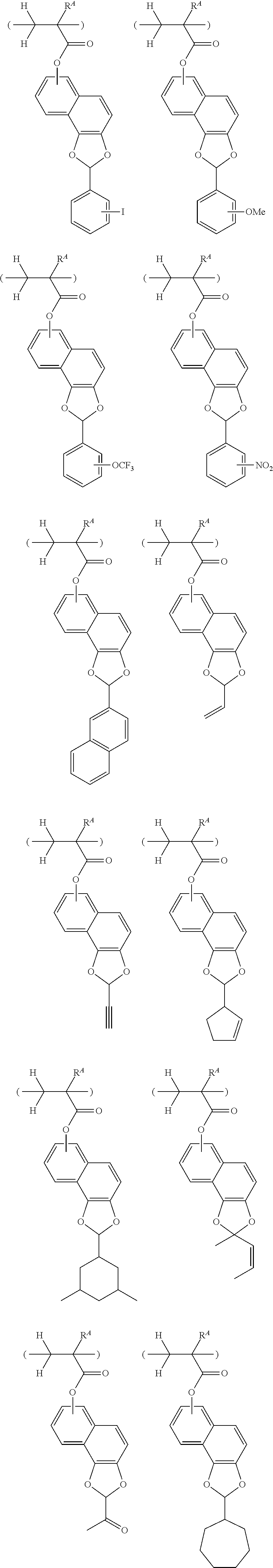

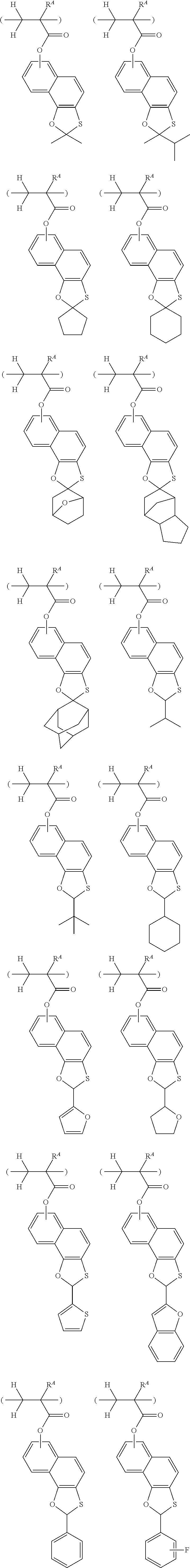

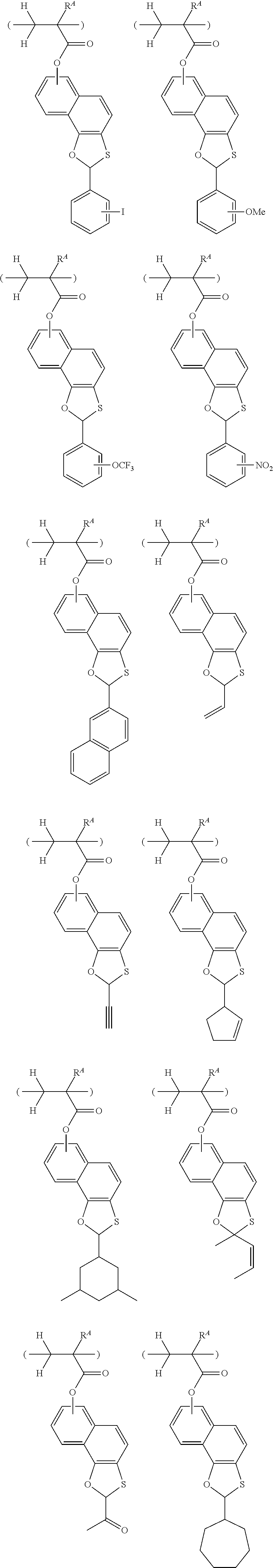

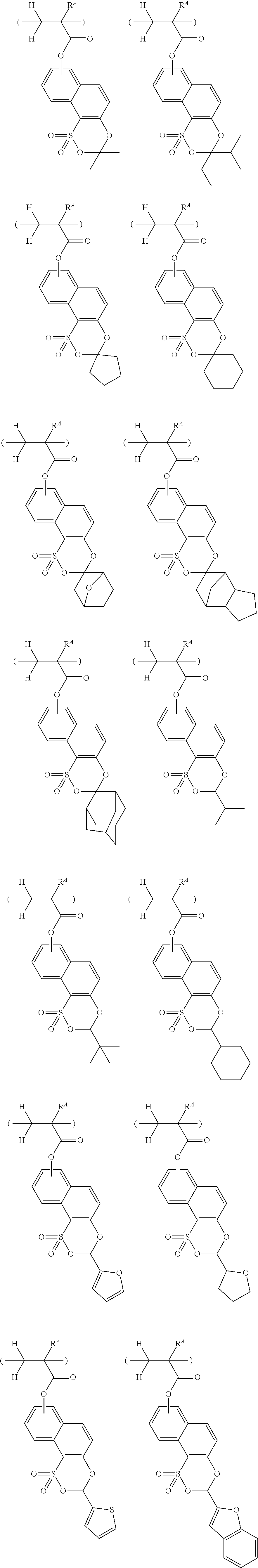

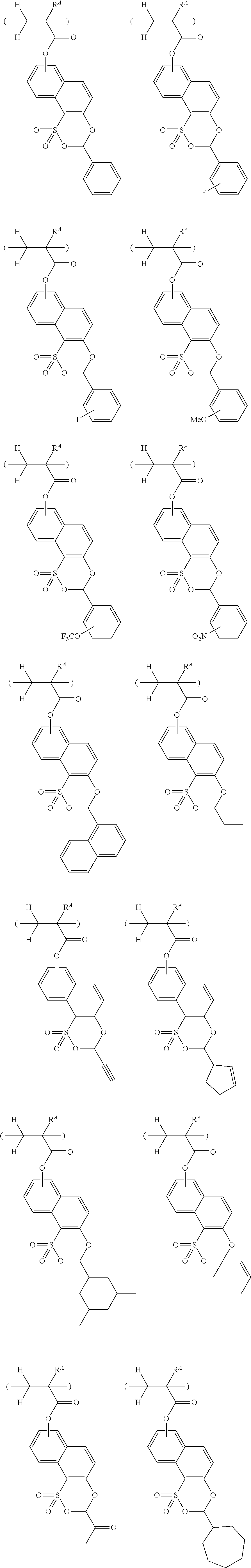

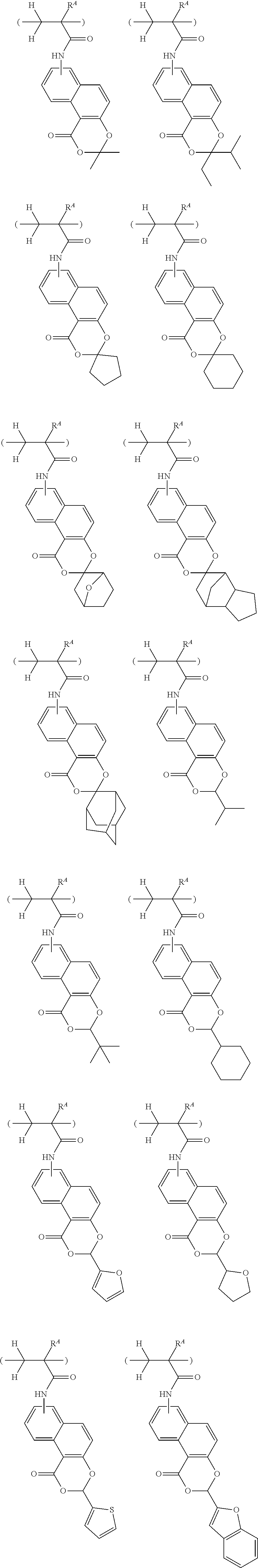

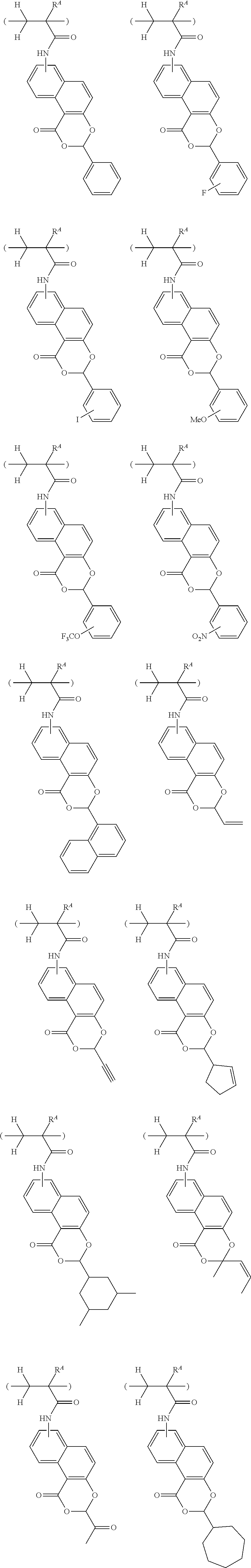

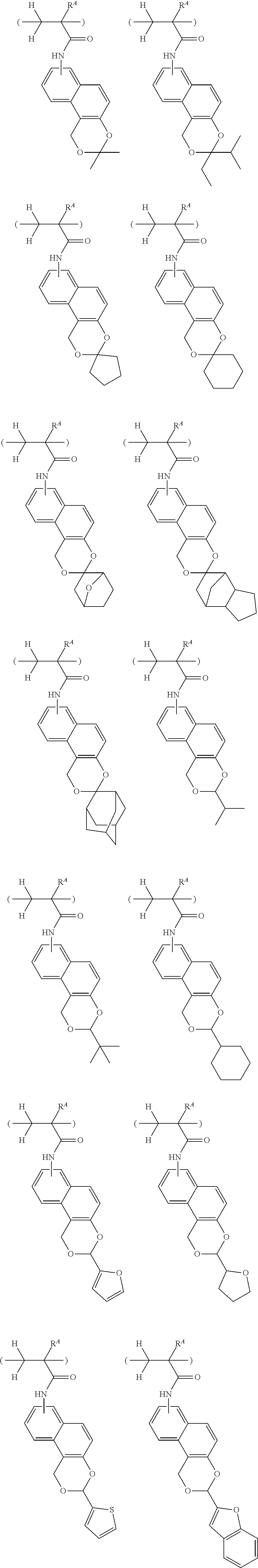

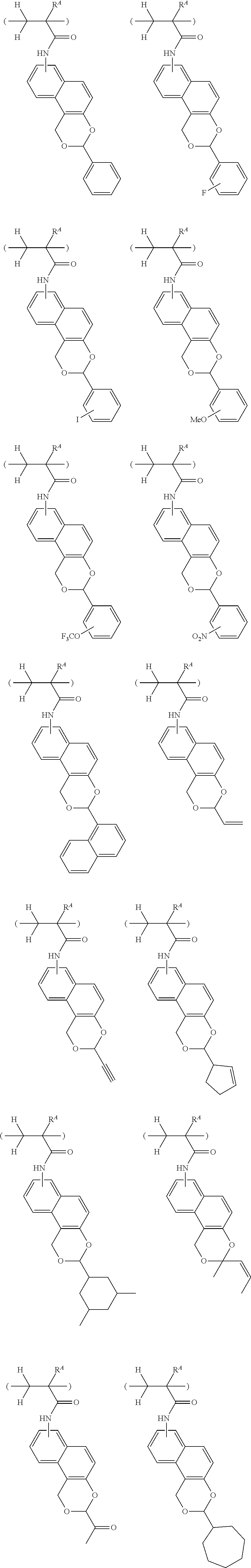

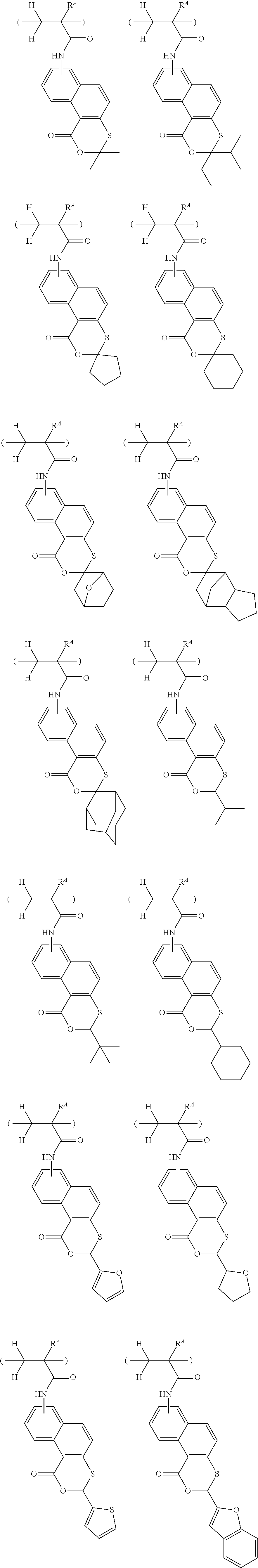

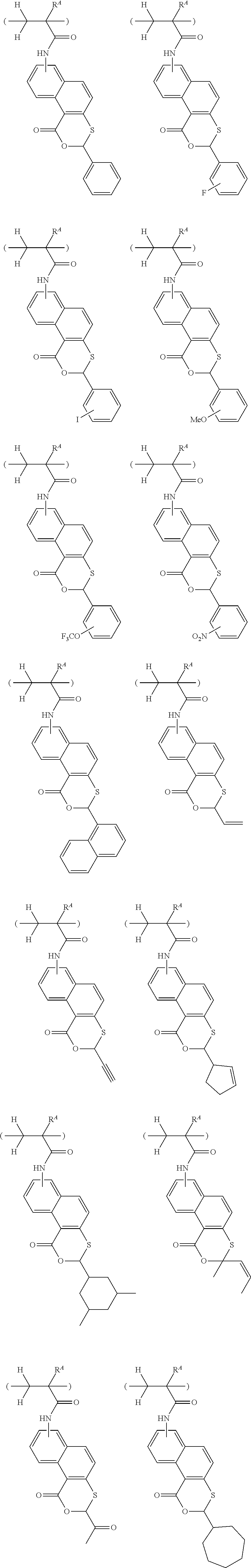

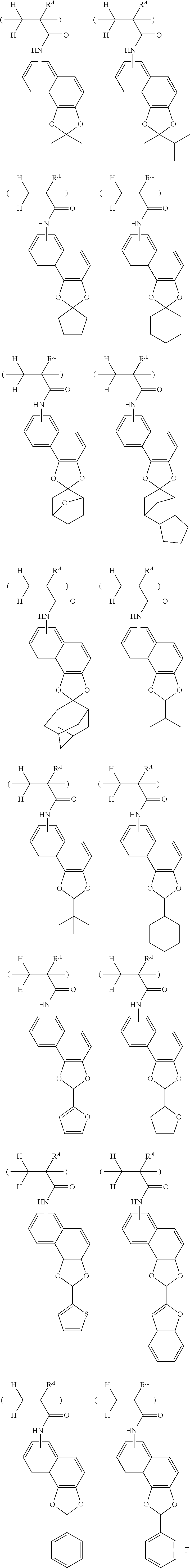

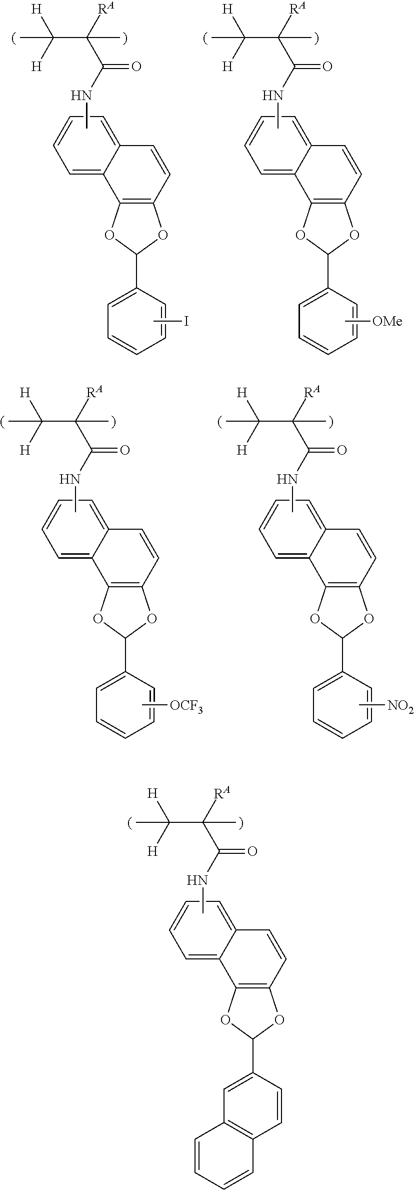

[chemical structure]

[chemical structure]

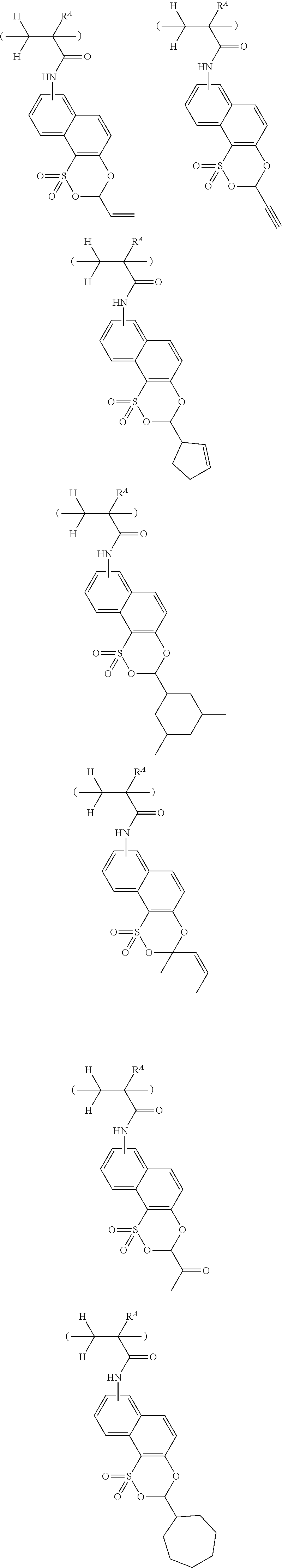

In the chemically amplified resist composition, the polymer (A) is structurally characterized by comprising repeat units (a1) having a cyclic acetal structure fused to an aromatic ring. The cyclic acetal structure fused to an aromatic ring has satisfactory solvent solubility and acts as an acid labile group which undergoes deprotection reaction under the action of acid to produce two polar groups. This improves the contrast between exposed and unexposed regions. Since the two polar groups thus produced are bonded to adjacent carbon atoms, hydroxy or carboxy groups form a hydrogen bond. Upon alkaline development, this restrains swelling of the resist film in the alkaline developer and prevents the resist pattern in the unexposed region from collapsing. The cyclic acetal structure fused to an aromatic ring remaining in the unexposed region now assumes a bicyclic structure which exerts high resistance in the etching step. Prior to exposure, the cyclic acetal structure in repeat unit (a1) of the polymer has a high solvent solubility so that precipitation in the solvent is inhibited. During development in alkaline developer after exposure, the polar groups produced after deprotection of the acetal structure have high affinity to the alkaline developer, allowing the resist film in the exposed region to be effectively removed. The risk of development defects is minimized.

On the other hand, the onium salt containing a fluoroalkanesulfonic acid anion containing an iodine-substituted aromatic ring structure has a large excluded volume and thus serves as a bulky substituent to effectively inhibit the generated acid from diffusing. Since iodine is highly absorptive to EUV, more secondary electrons are generated upon light exposure. This promotes decomposition of the cation and contributes to a higher sensitivity. Also, iodine having a large atomic weight is effective for fully suppressing diffusion of the generated acid. In addition, iodine is resistant to the alkaline developer, reducing any film thickness loss of the pattern or unexposed region. Fluorine in the fluoroalkanesulfonic acid anion has a high EUV-absorbing effect, though not so high as iodine. Then, as the number of fluorine atoms increases, the number of generated secondary electrons increases. This promotes decomposition of the cation and contributes to a higher sensitivity. By virtue of the synergy of these effects, the resist composition can form patterns with improved LWR (of line patterns) or improved CDU (of hole patterns), minimized development defects, and collapse resistance. These advantages become outstanding particularly when the resist composition is of positive tone.

The polymer may further comprise repeat units of at least one type selected from repeat units having the formula (a2) and repeat units having the formula (a3). These units are also referred to as repeat units (a2) and (a3).

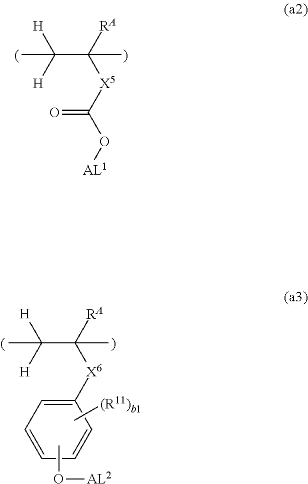

In formulae (a2) and (a3), R^{A} is each independently hydrogen, fluorine, methyl or trifluoromethyl.

In formula (a2), X⁵ is a single bond, phenylene group, naphthylene group, or *—C(═O)—O—X— wherein * designates a point of attachment to the carbon atom in the backbone. The phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen. X⁵¹ is a C₁-C₁₀ saturated hydrocarbylene group, phenylene group or naphthylene group, and the saturated hydrocarbylene group may contain hydroxy, ether bond, ester bond or lactone ring.

In formula (a3), X⁶ is a single bond, *—C(═O)—O— or *—C(═O)—N(H)—, wherein * designates a point of attachment to the carbon atom in the backbone. R¹¹ is halogen, cyano, hydroxy, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom, and b1 is 0, 1, 2, 3 or 4, preferably 0 or 1. When b1 is 2, 3 or 4, a plurality of R¹¹ may be identical or different.

In formulae (a2) and (a3), AL¹ and AL² are each independently an acid labile group. The acid labile group may be selected from a variety of such groups, for example, those groups described in JP-A 2013-080033 (U.S. Pat. No. 8,574,817) and JP-A 2013-083821 (U.S. Pat. No. 8,846,303).

Typical of the acid labile group are groups of the following formulae (AL-1) to (AL-3).

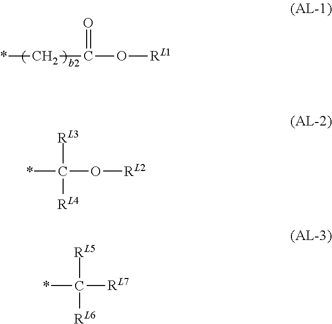

In formulae (AL-1) and (AL-2), R^{L1} and R^{L2} are each independently a C₁-C₄₀ hydrocarbyl group which may contain a heteroatom such as oxygen, sulfur, nitrogen or fluorine. The hydrocarbyl group may be saturated or unsaturated and straight, branched or cyclic. Inter alia, C₁-C₂₀ hydrocarbyl groups are preferred.

In formula (AL-1), b2 is an integer of 0 to 10, preferably 1, 2, 3, 4 or 5.

In formula (AL-2), R^{L3} and R^{L4} are each independently hydrogen or a C₁-C₂₀ hydrocarbyl group which may contain a heteroatom such as oxygen, sulfur, nitrogen or fluorine. The hydrocarbyl group may be saturated or unsaturated and straight, branched or cyclic. Any two of R^{L2}, R^{L3} and R^{L4} may bond together to form a C₃-C₂₀ ring with the carbon atom or carbon and oxygen atoms to which they are attached. The ring preferably contains 4 to 16 carbon atoms and is typically alicyclic.

In formula (AL-3), R^{L5}, R^{L6} and R^{L7} are each independently a C₁-C₂₀ hydrocarbyl group which may contain a heteroatom such as oxygen, sulfur, nitrogen or fluorine. The hydrocarbyl group may be saturated or unsaturated and straight, branched or cyclic. Any two of R^{L5}, R^{L6} and R^{L7} may bond together to form a C₃-C₂₀ ring with the carbon atom to which they are attached. The ring preferably contains 4 to 16 carbon atoms and is typically alicyclic.

Examples of the acid labile group include those described in JP-A 2023-123222, paragraphs [0064]-[0068] and JP 7492842, paragraphs [0013]-[0014]. After acid elimination reaction, these groups form conjugated olefins or acrylate derivatives which serve to drive the reaction forward.

Examples of the repeat unit (a2) are shown below, but not limited thereto. Herein R^{A} and AL¹ are as defined above.

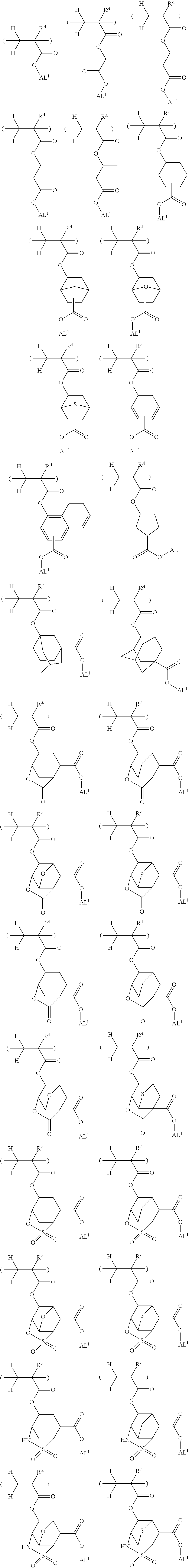

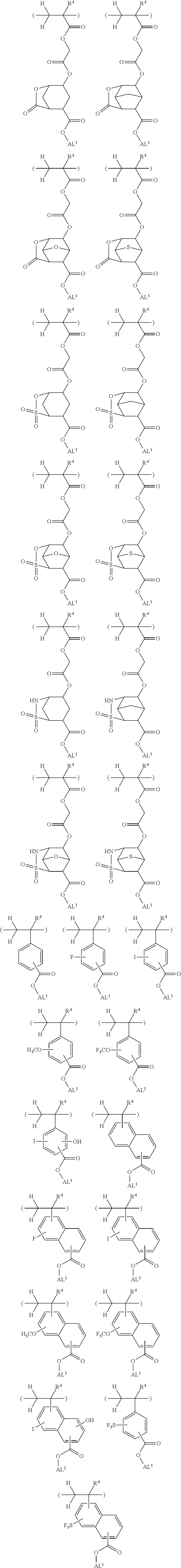

Examples of the repeat unit (0) are shown below, but not limited thereto. Herein R^{A} and AL² are as defined above.

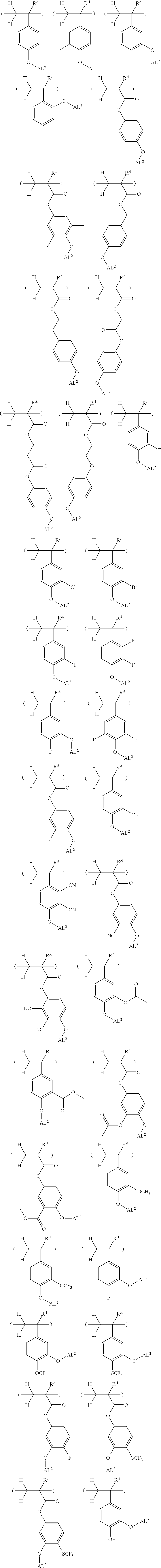

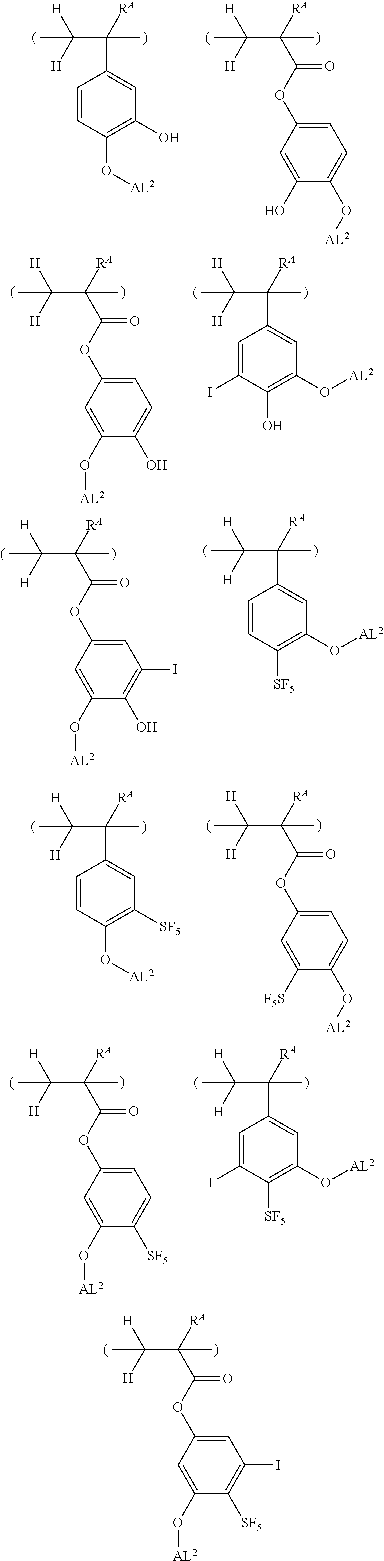

The polymer may further comprise repeat units having the formula (b), which are also referred to as repeat units (b).

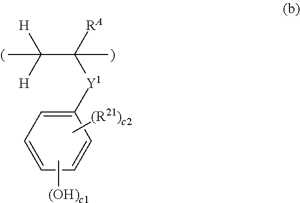

In formula (b), R^{A} is hydrogen, fluorine, methyl or trifluoromethyl. Y¹ is a single bond, *—C(═O)—O— or *—C(═O)—N(H)—, wherein * designates a point of attachment to the carbon atom in the backbone. R²¹ is halogen, carboxy, nitro, cyano, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when c2 is 2, 3 or 4, a plurality of R²¹ may be identical or different, c1 is 1, 2, 3 or 4, c2 is 0, 1, 2, 3 or 4, and 1≤c1+c2≤5.

Examples of the repeat unit (b) are shown below, but not limited thereto. Herein R^{A} is as defined above.

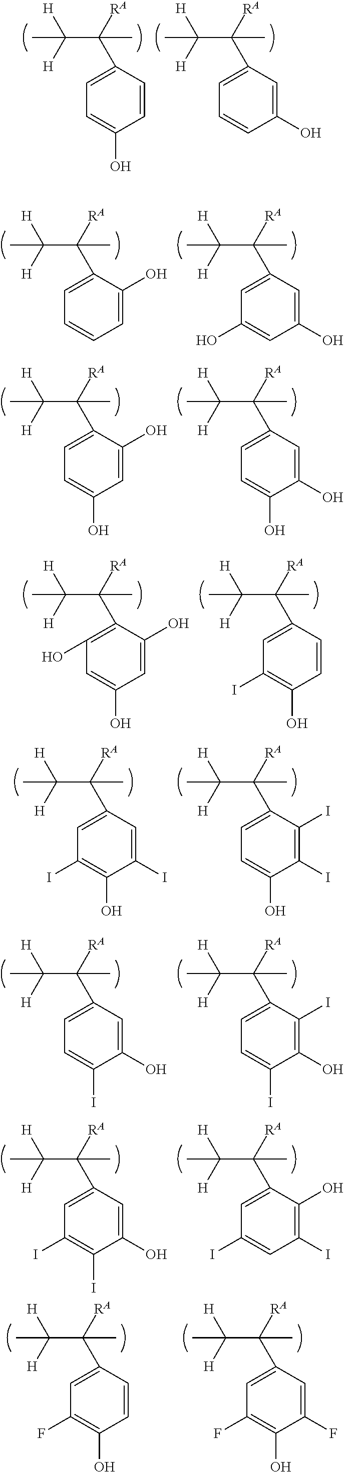

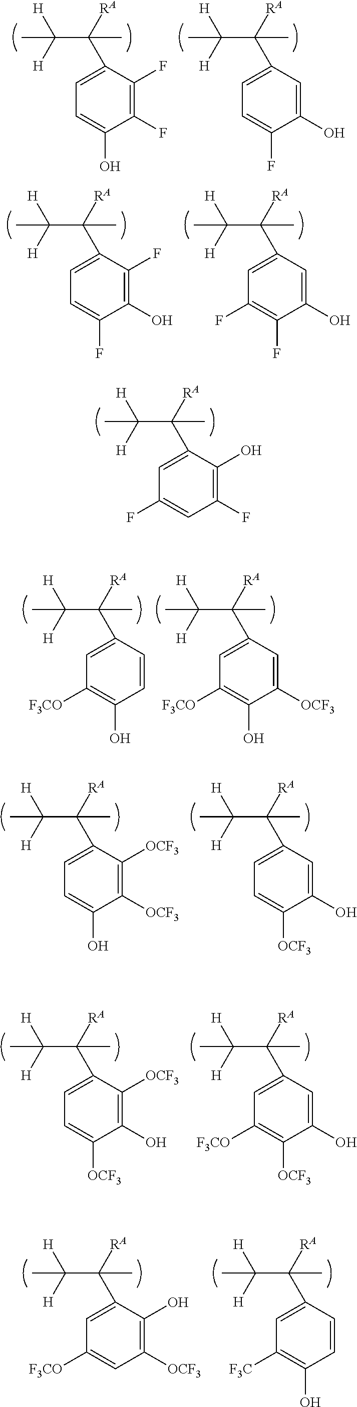

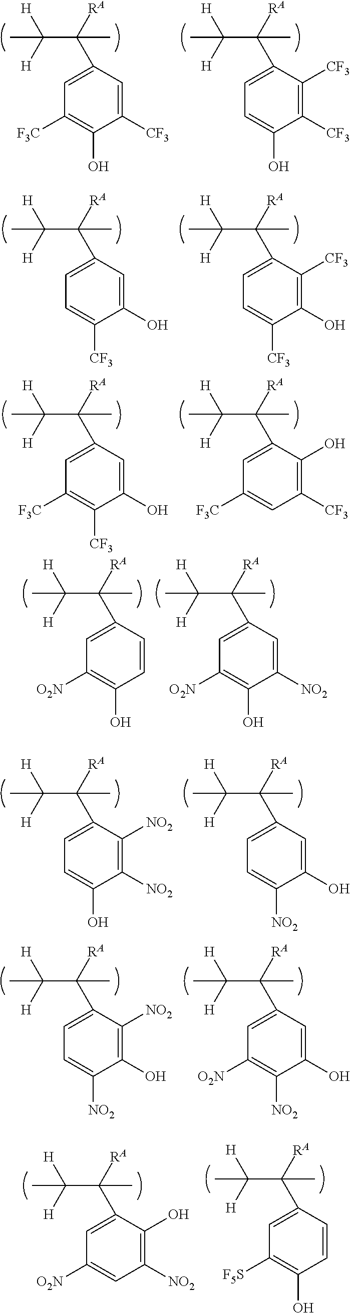

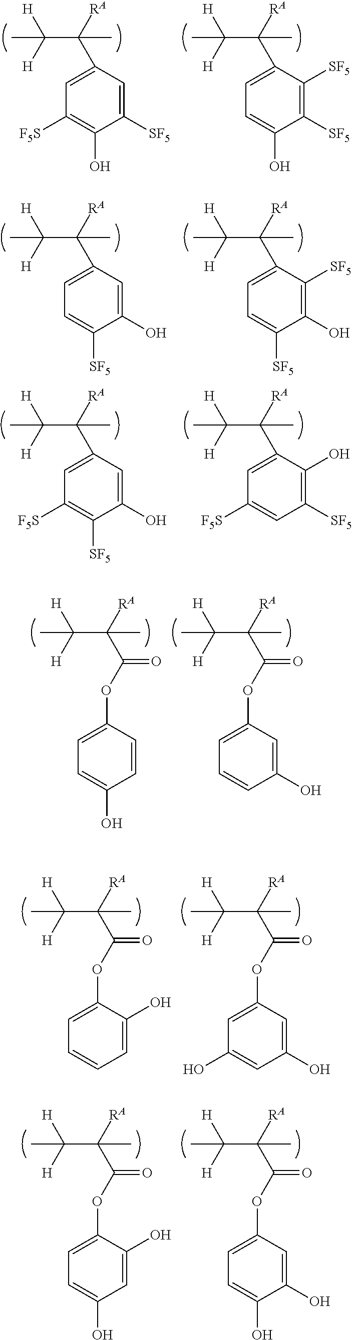

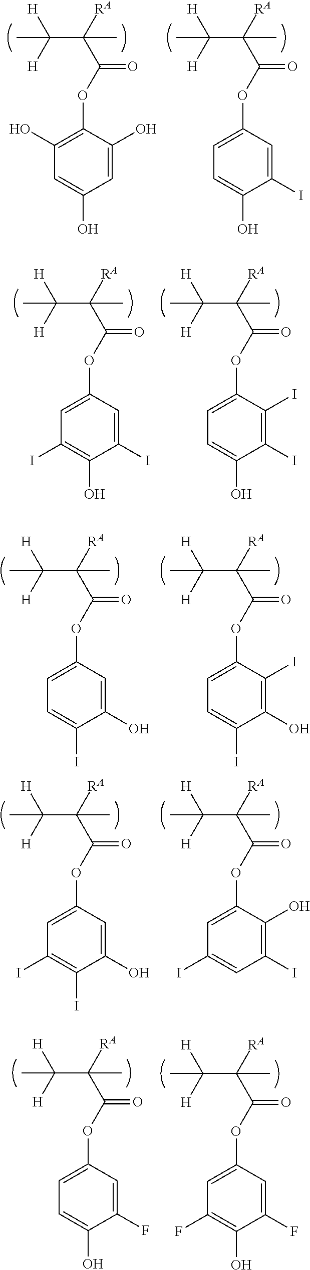

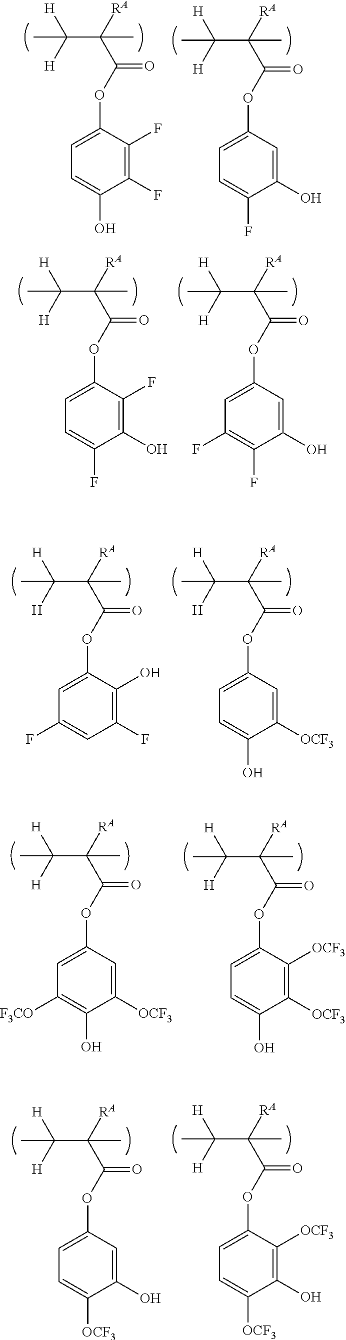

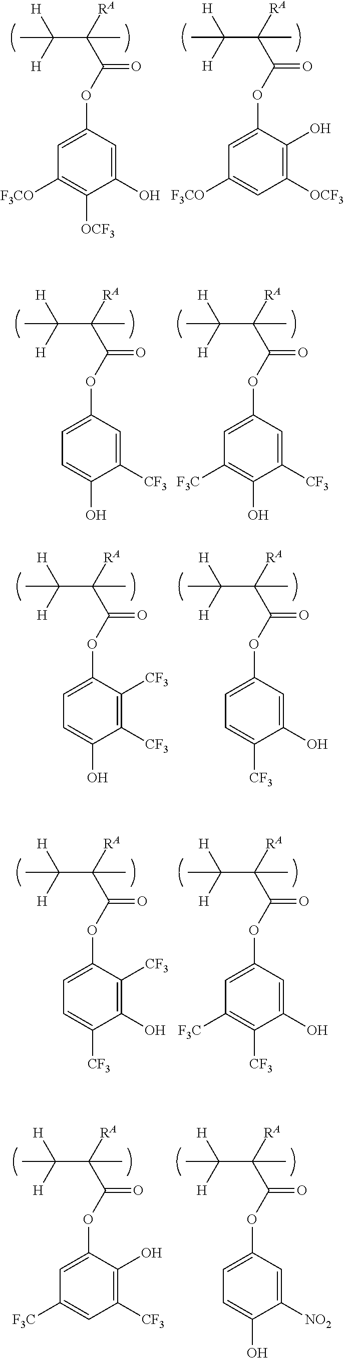

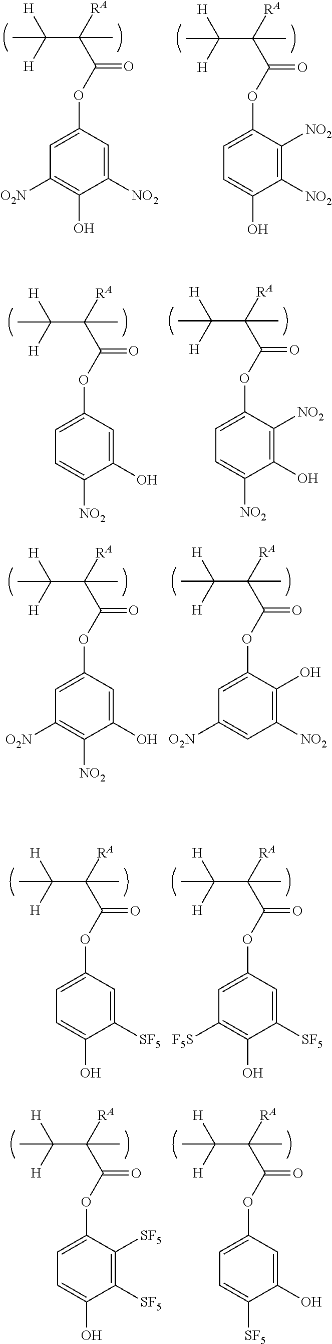

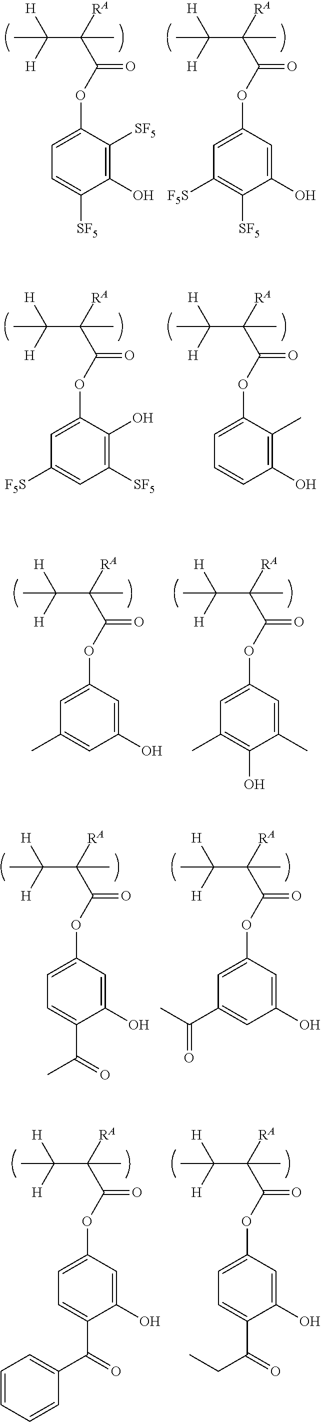

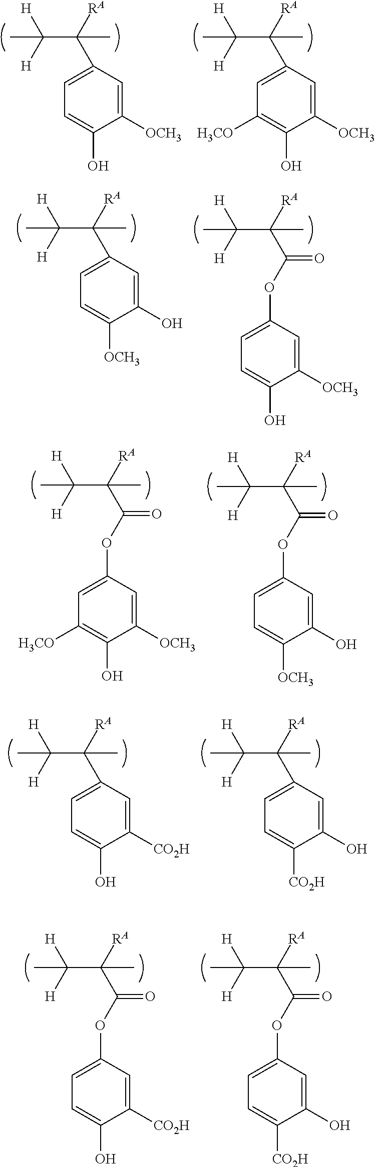

In a preferred embodiment, the polymer further comprises repeat units having the formula (c), referred to as repeat units (c), hereinafter.

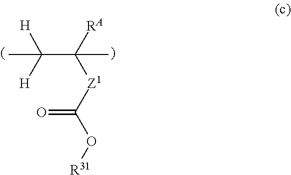

In formula (c), R^{A} is hydrogen, fluorine, methyl or trifluoromethyl. Z¹ is a single bond, phenylene group, naphthylene group, *—C(═O)—O—Z¹¹— or *—C(═O)—N(H)—Z¹¹— wherein * designates a point of attachment to the carbon atom in the backbone. The phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen. Z¹¹ is a C₁-C₁₀ saturated hydrocarbylene group, phenylene group or naphthylene group, the saturated hydrocarbylene group may contain hydroxy, ether bond, ester bond or lactone ring. R³¹ is hydrogen or a C₁-C₂₀ group containing at least one structure selected from hydroxy other than phenolic hydroxy, cyano, carbonyl, carboxy, ether bond, ester bond, sulfonate ester bond, carbonate bond, lactone ring, sultone ring and carboxylic anhydride (—C(═O)—O—C(═O)—).

Examples of the repeat unit (c) are shown below, but not limited thereto. Herein R^{A} is as defined above.

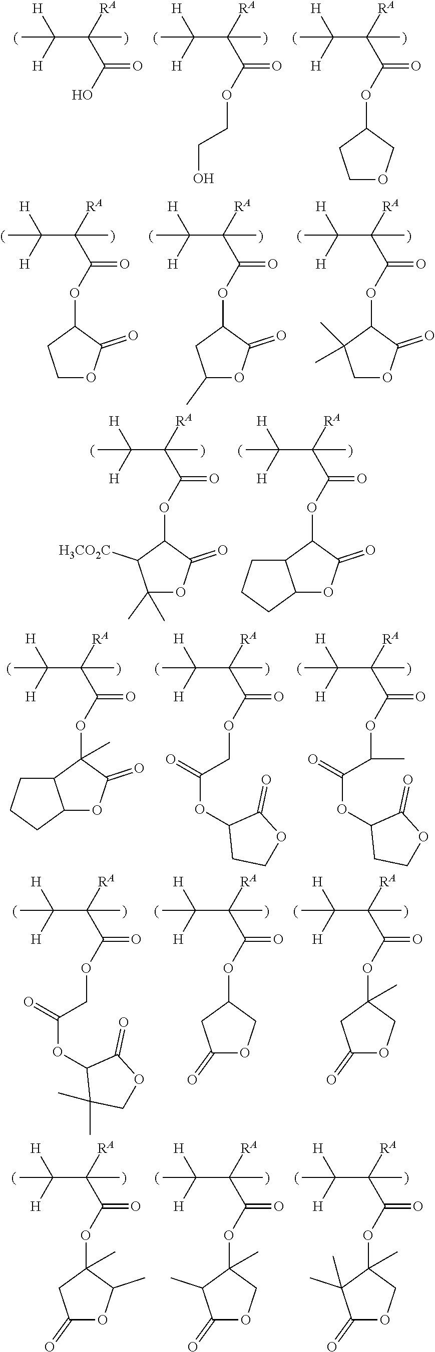

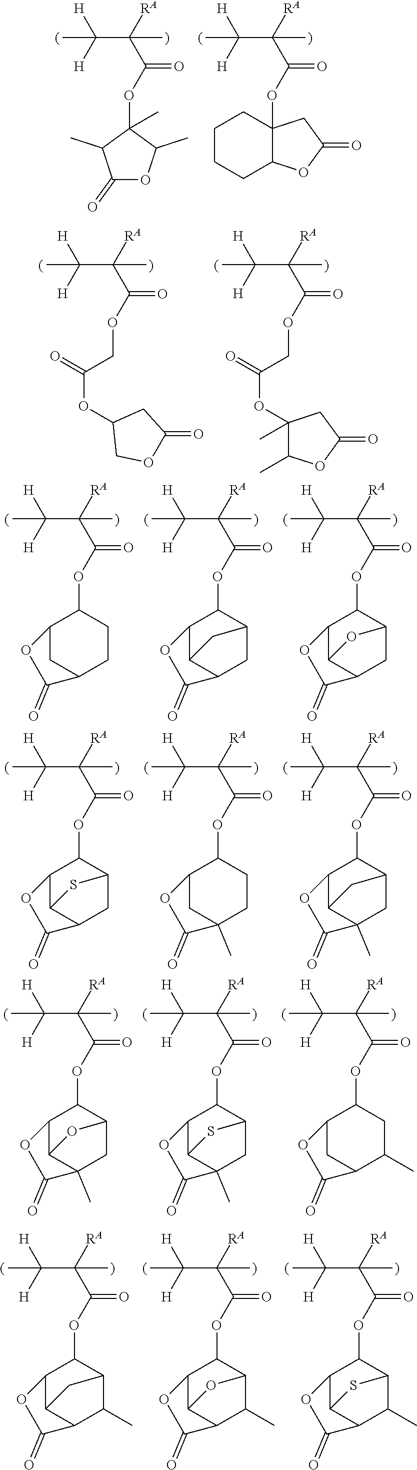

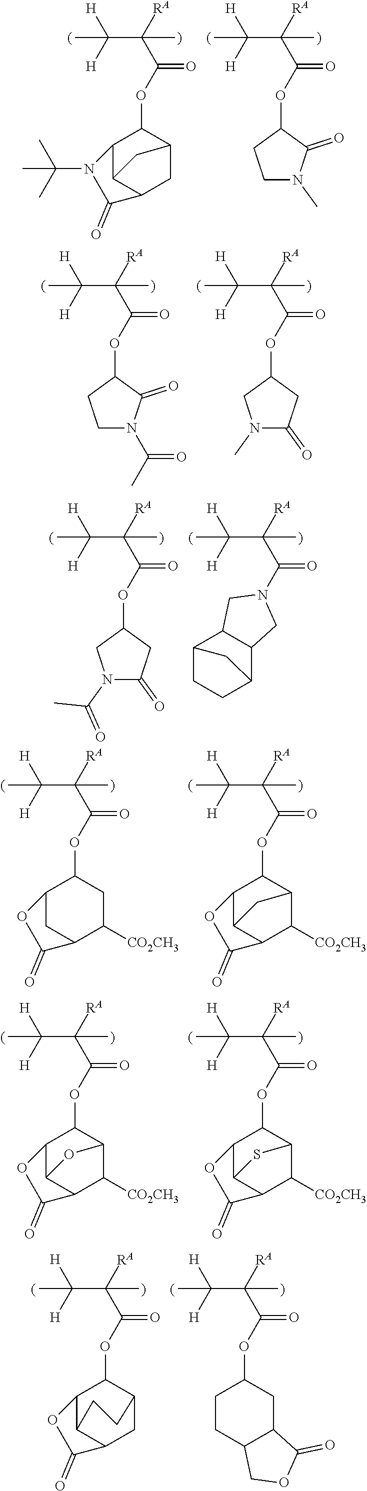

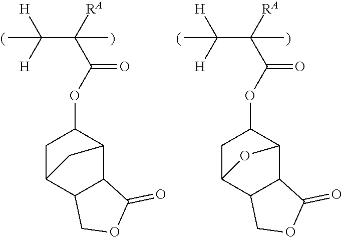

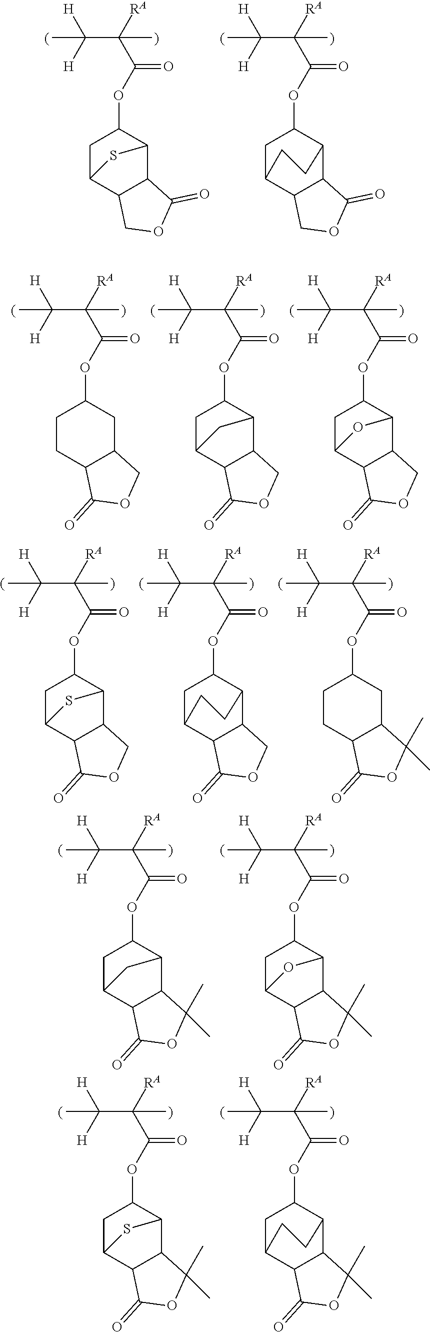

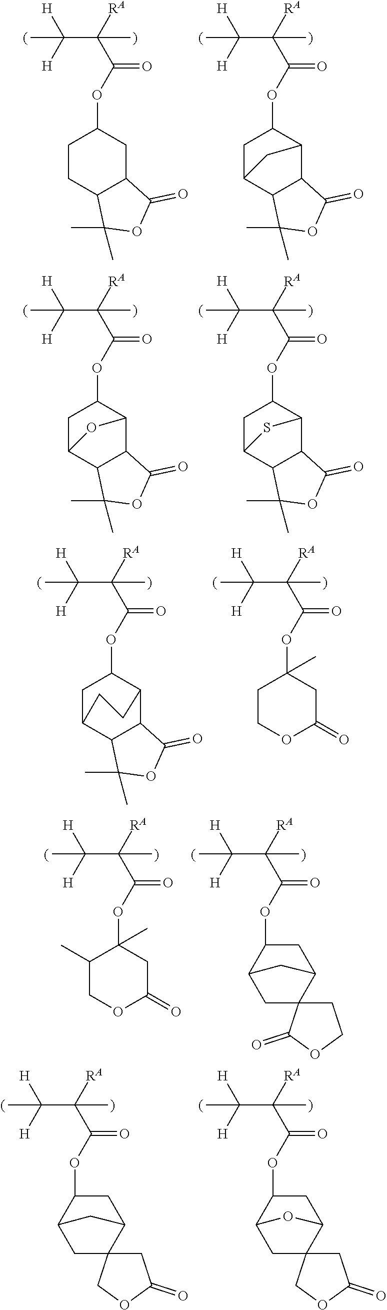

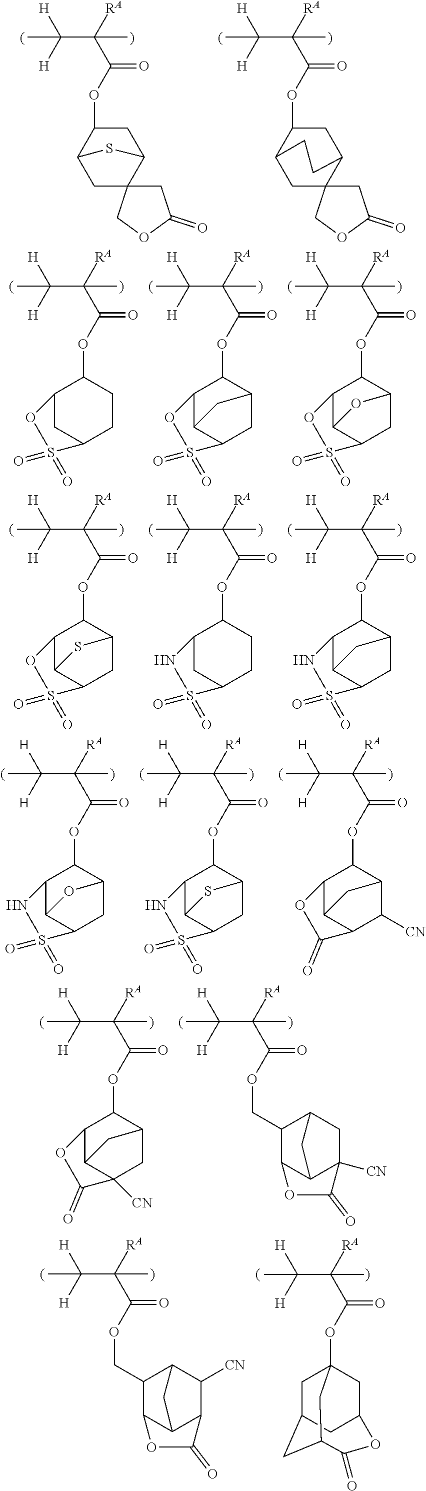

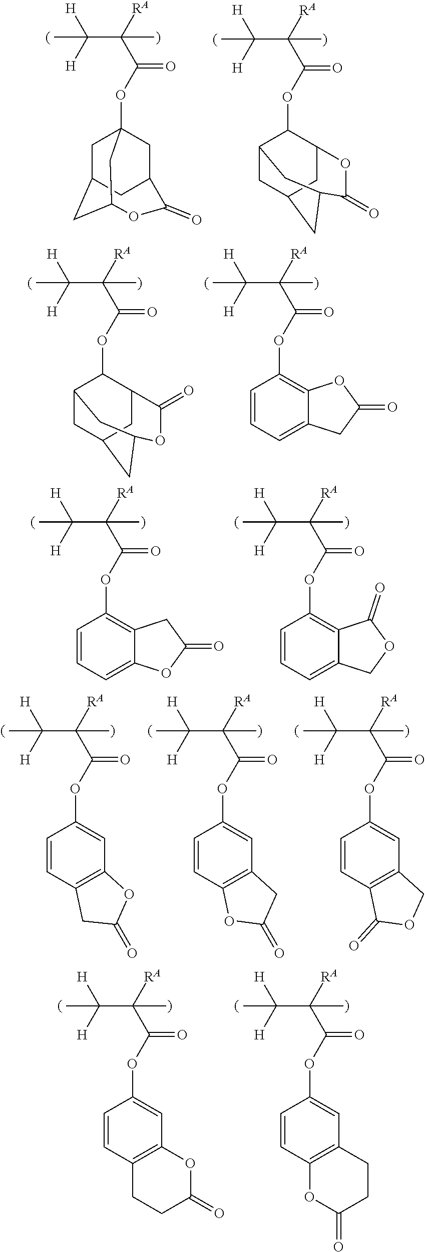

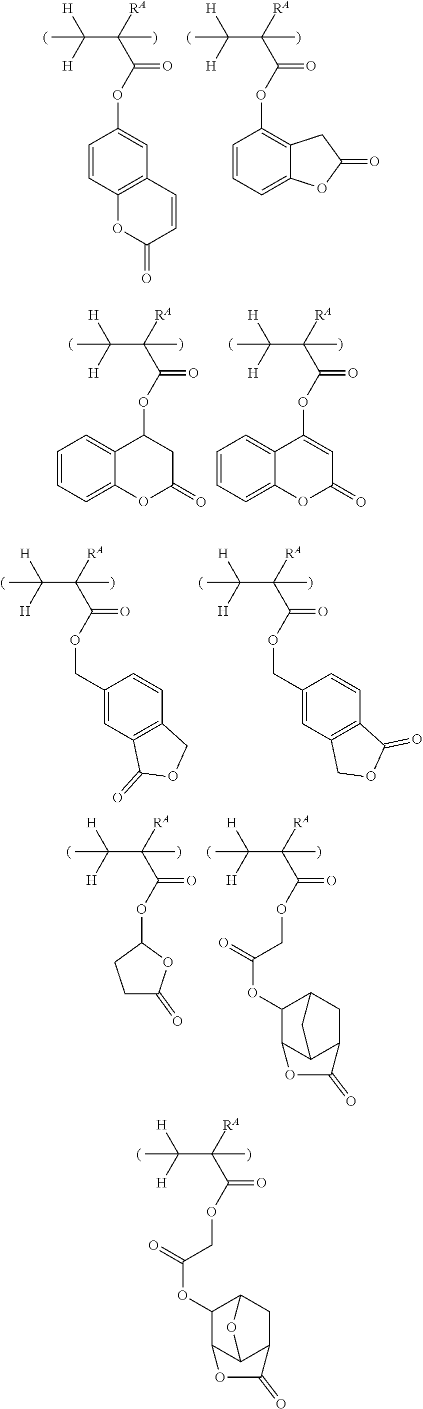

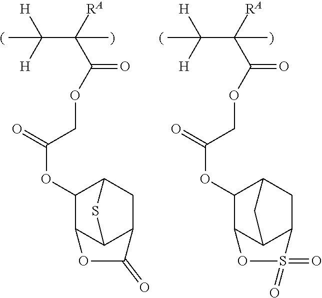

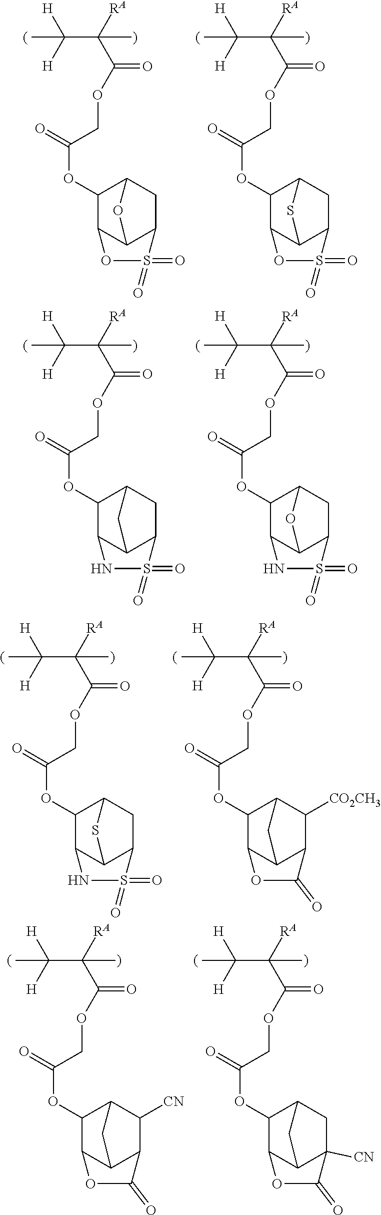

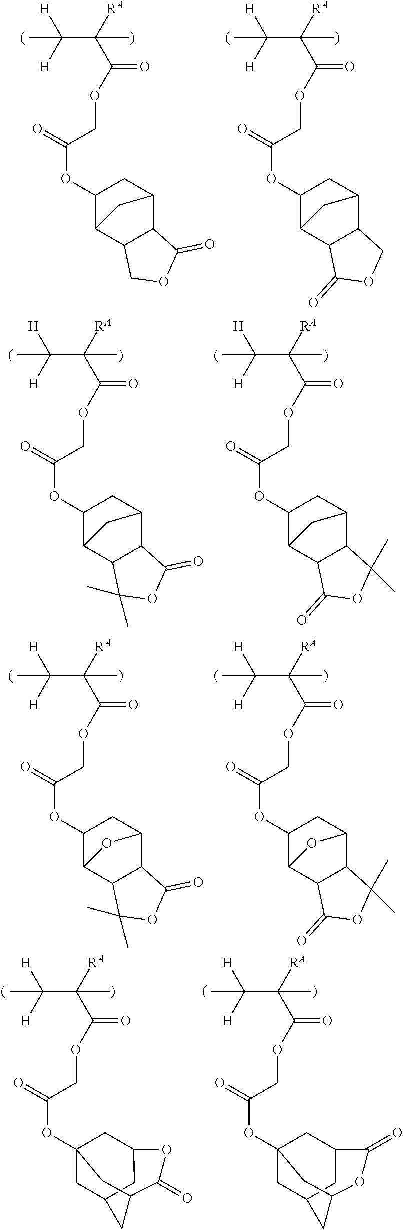

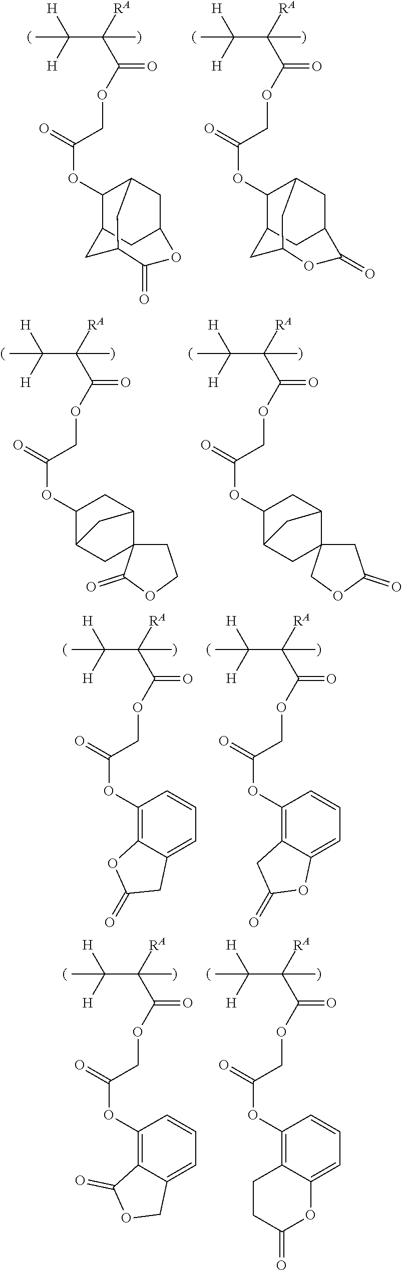

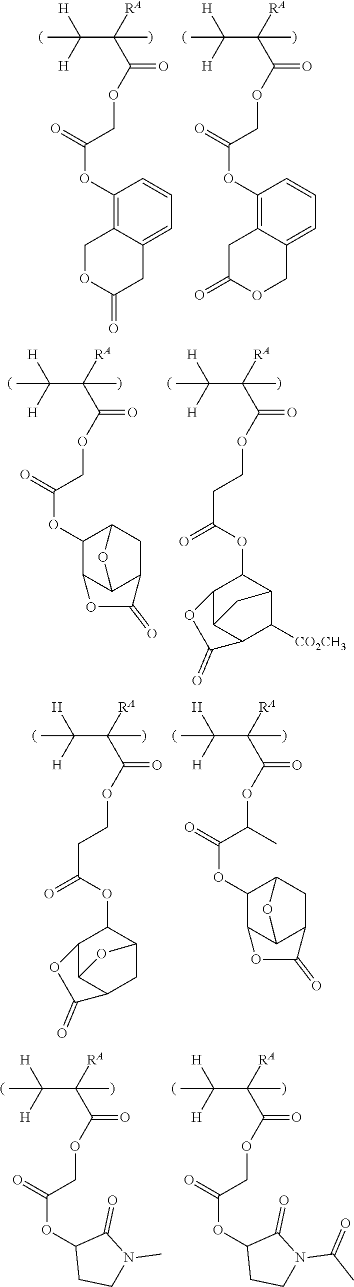

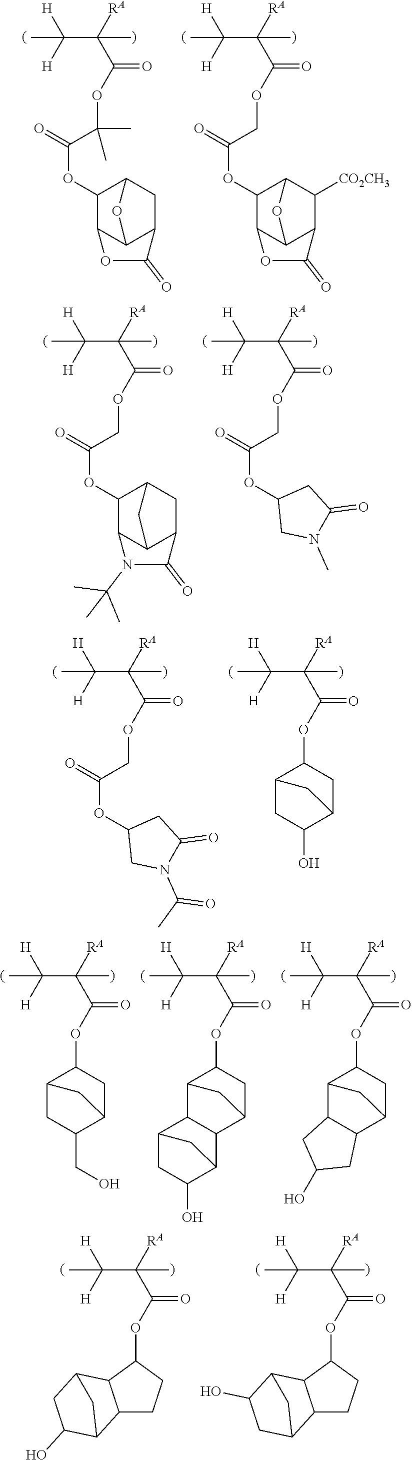

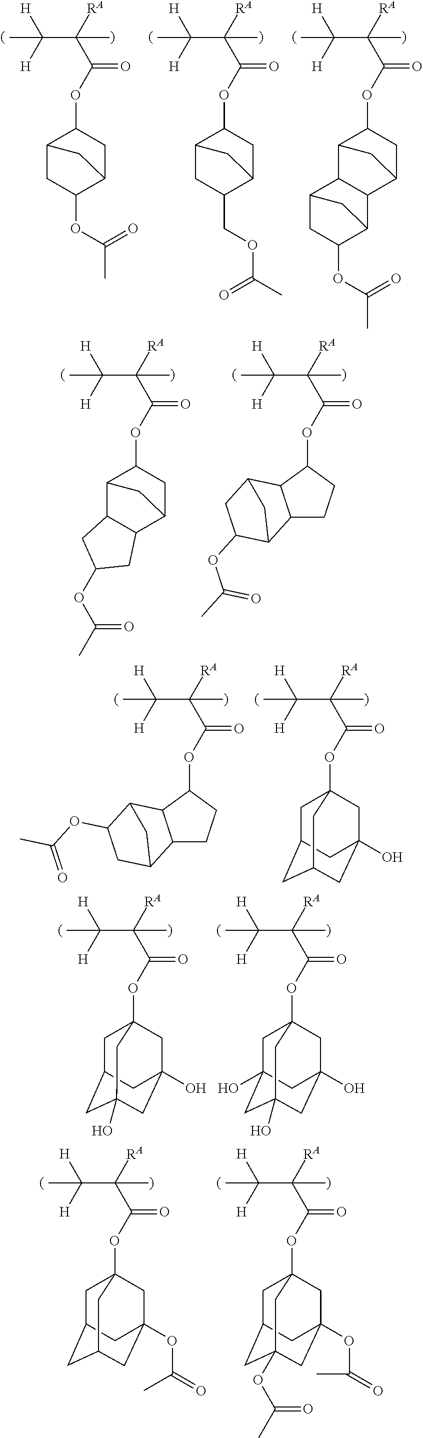

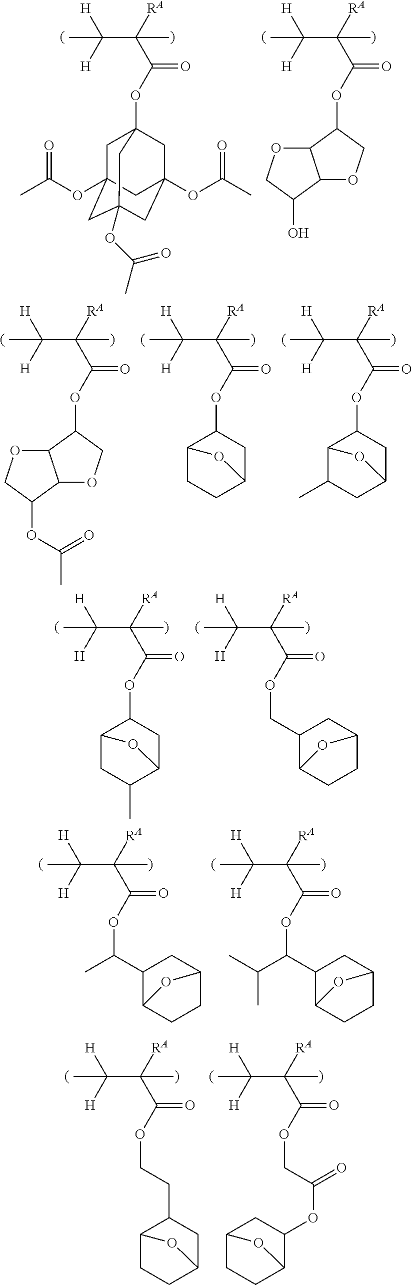

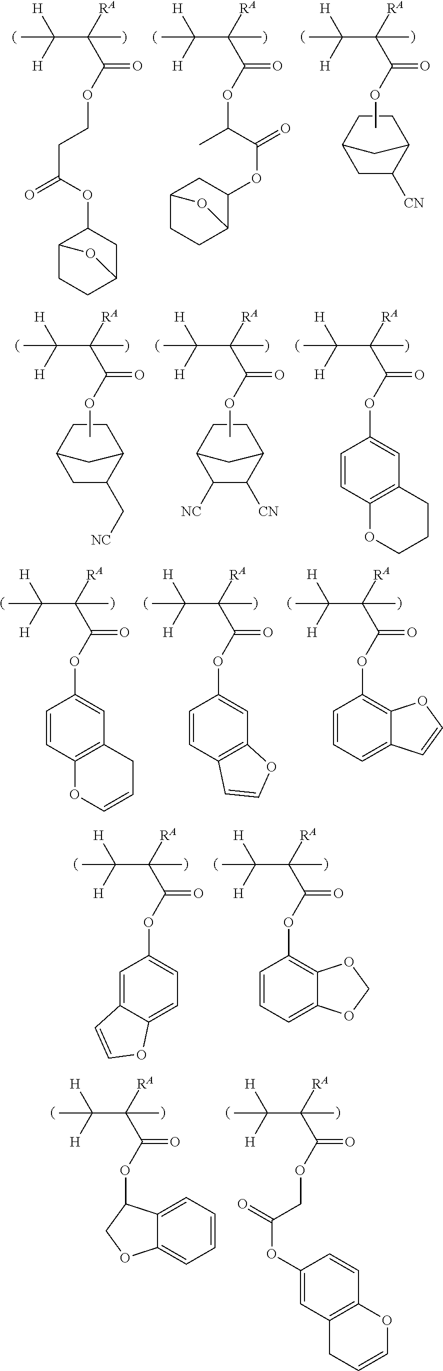

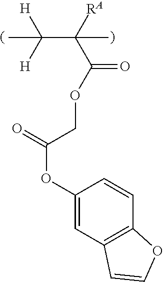

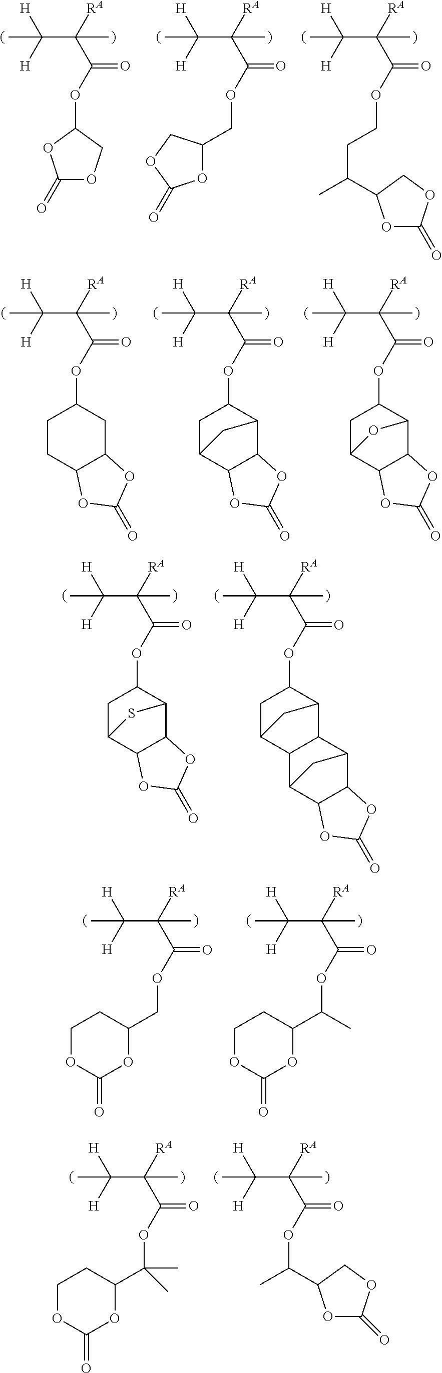

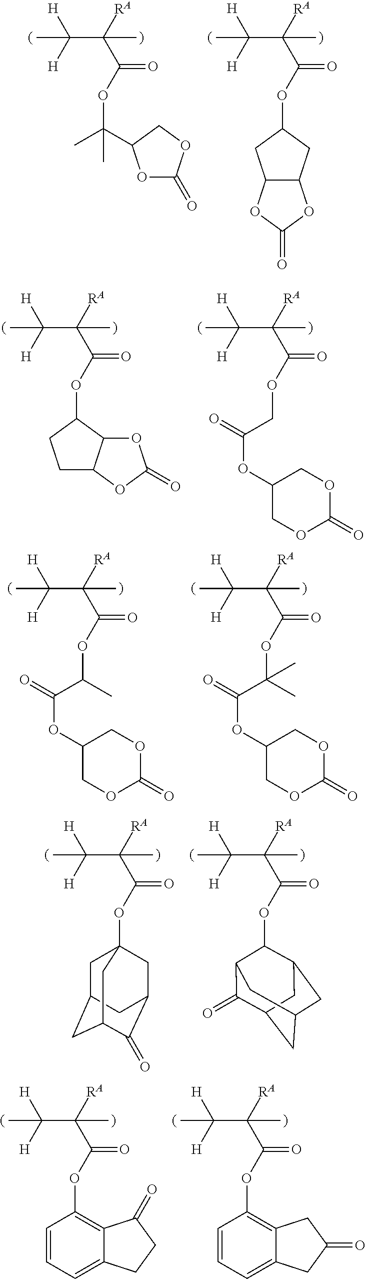

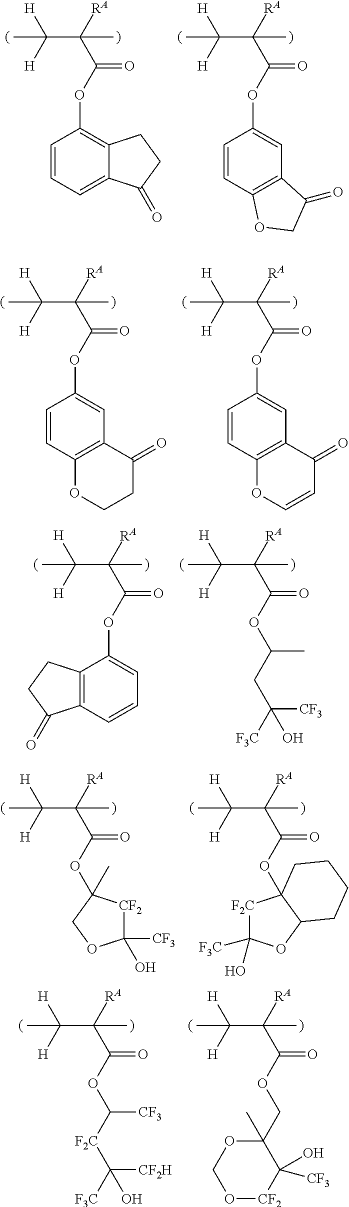

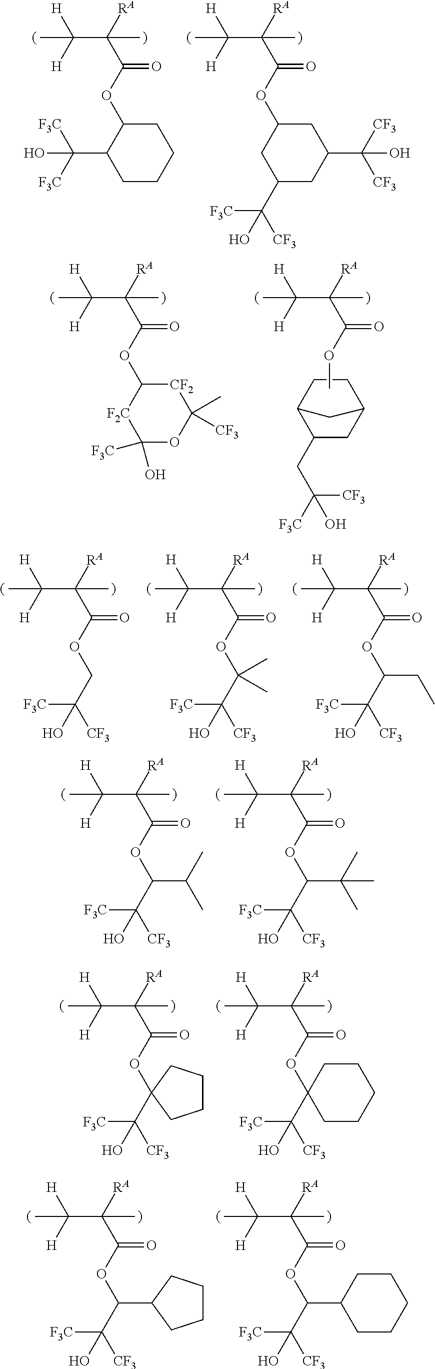

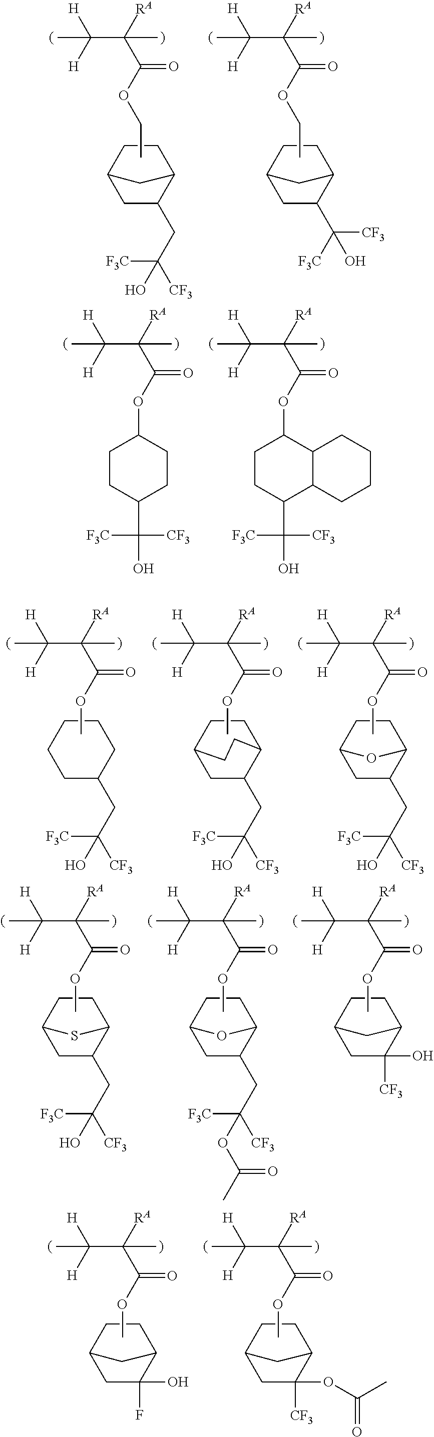

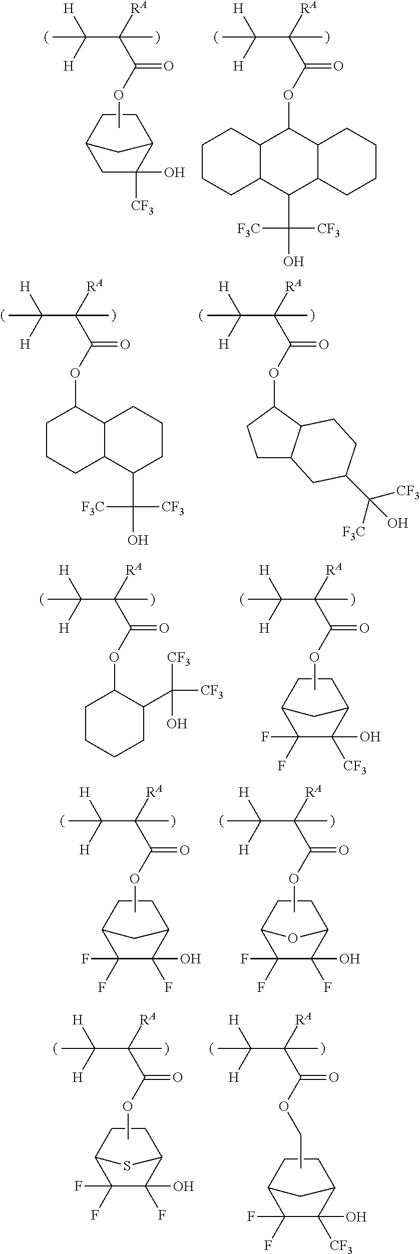

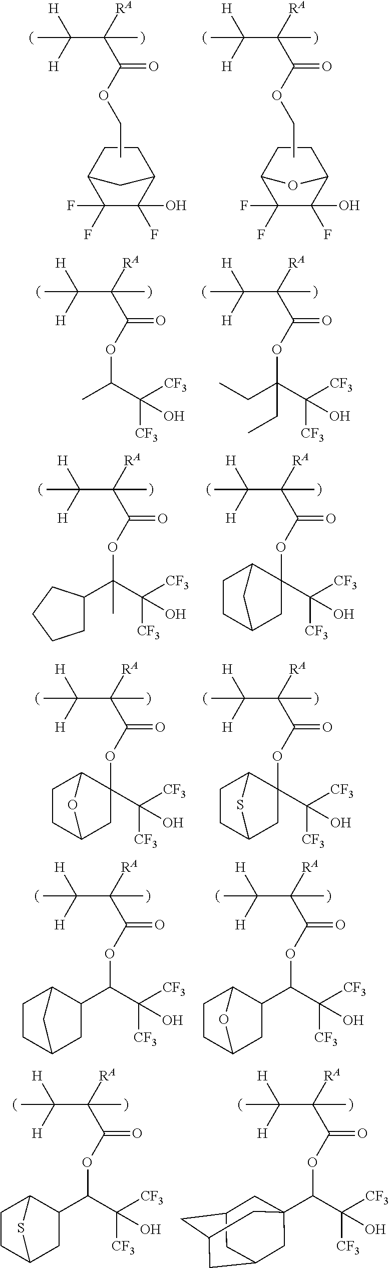

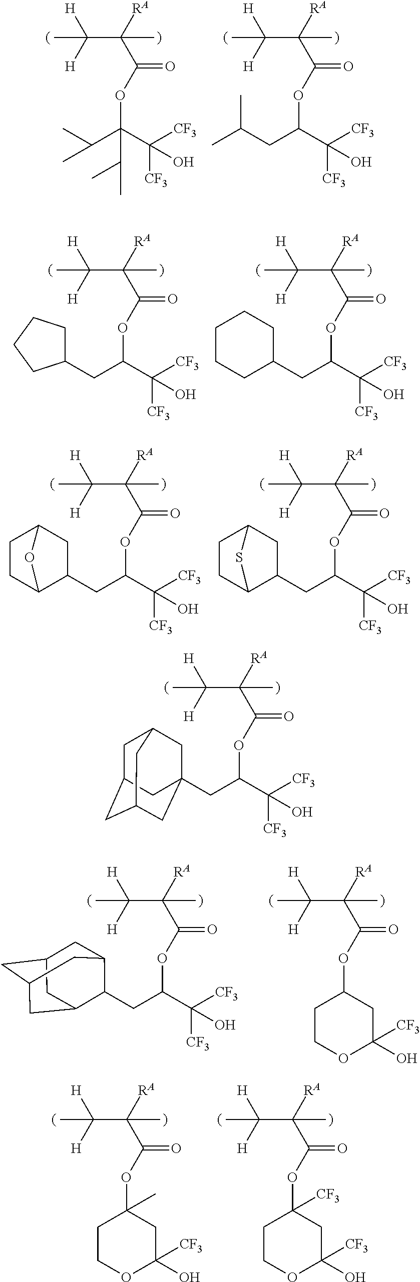

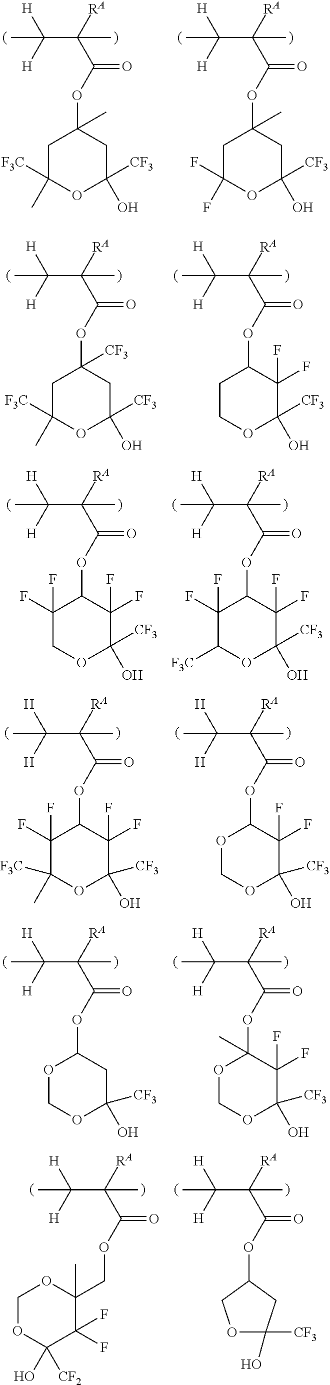

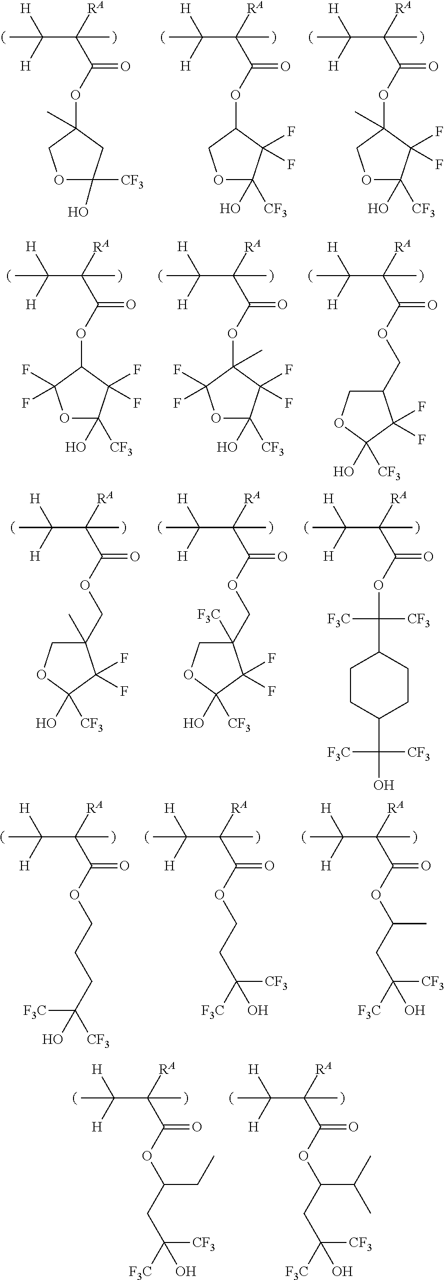

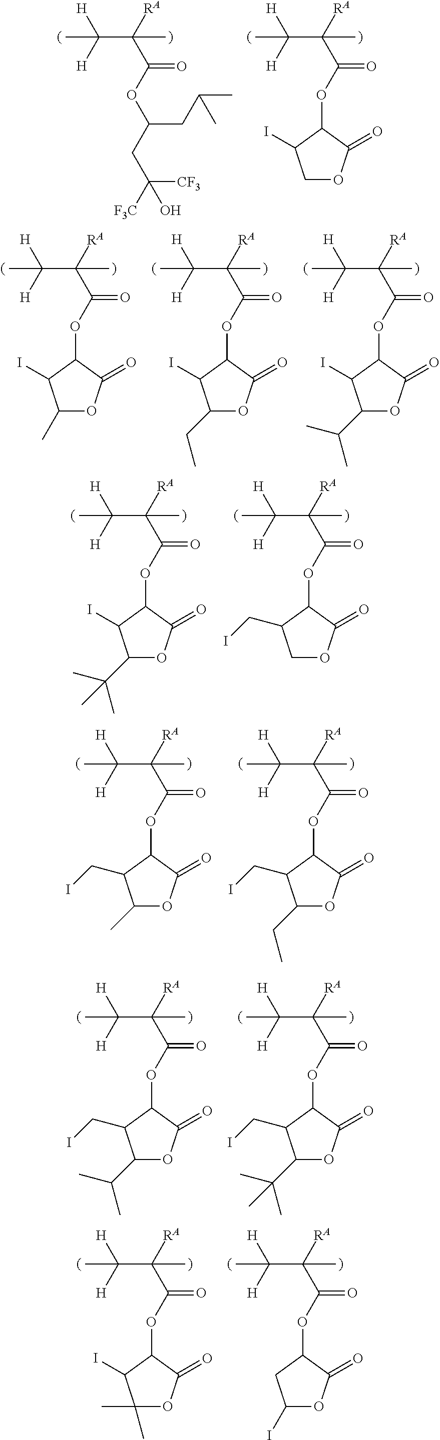

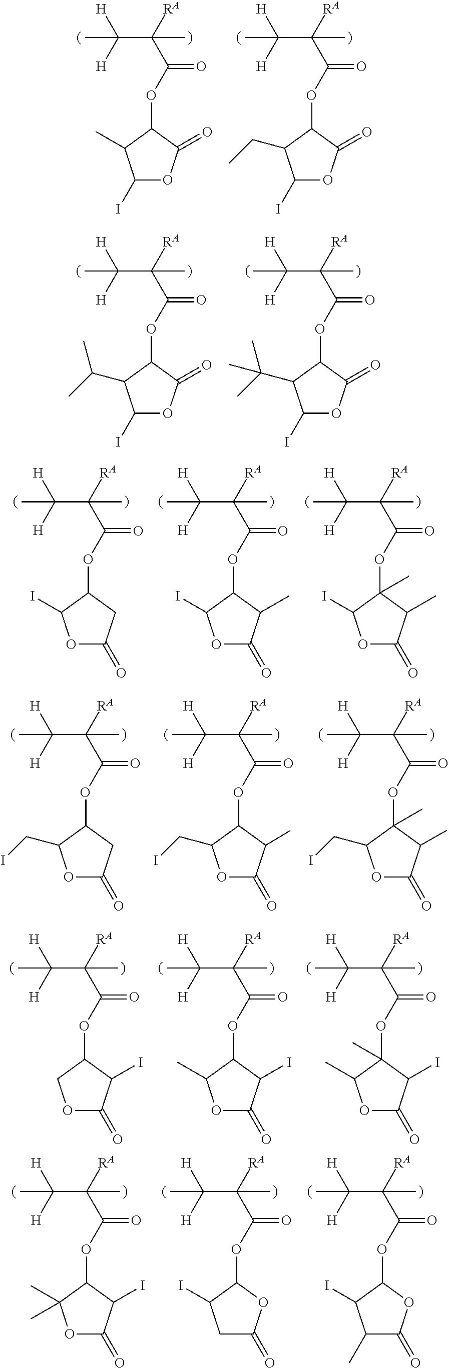

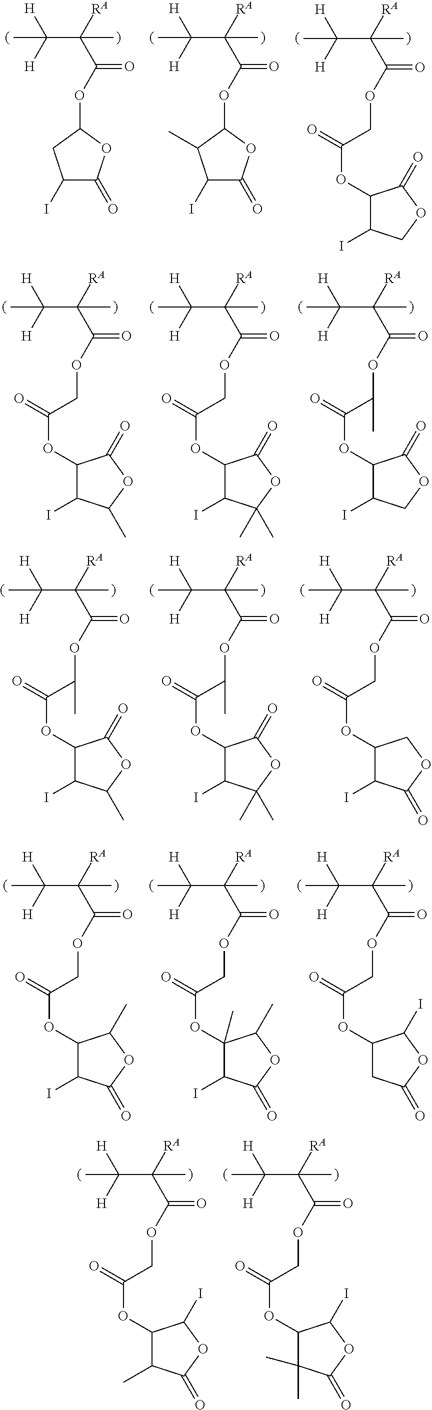

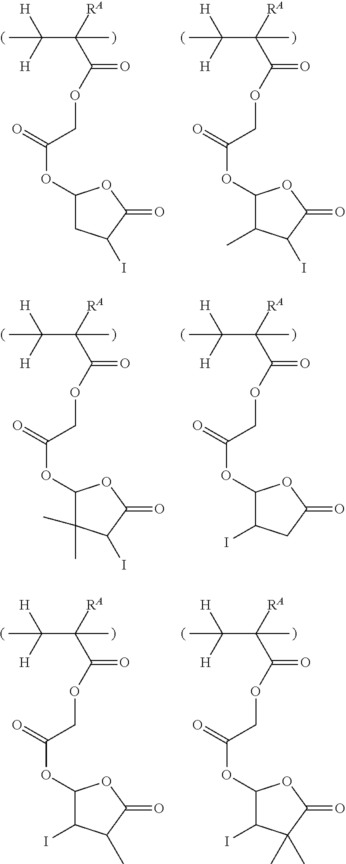

The repeat units (c) having a lactone ring as the polar group are preferred in the case of ArF lithography, and the repeat units (b) having a phenol site are preferred in the case of KrF, EB and EUV lithography processes.

The polymer may further comprise repeat units (d) of a structure having a hydroxy group protected with an acid labile group. The repeat unit (d) is not particularly limited as long as the unit includes one or more structures having a hydroxy group protected with a protective group such that the protective group is decomposed to generate a hydroxy group under the action of acid. Repeat units having the formula (d1) are preferred.

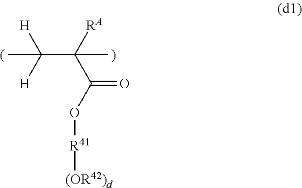

In formula (d1), R^{A} is hydrogen, fluorine, methyl or trifluoromethyl. R⁴¹ is a C₁-C₃₀ (d+1)-valent hydrocarbon group which may contain a heteroatom. R⁴² is an acid labile group, and d is 1, 2, 3 or 4.

In formula (d1), the acid labile group R⁴² is deprotected under the action of acid so that a hydroxy group is generated. Although the structure of R⁴² is not particularly limited, preferred are an acetal structure, ketal structure, hydrocarbyloxycarbonyl group, and hydrocarbyloxymethyl group having the following formula (d2):

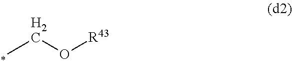

wherein R⁴³ is a C₁-C₁₅ hydrocarbyl group. The hydrocarbyloxymethyl group having formula (d2) is more preferred.

Illustrative examples of the acid labile group R⁴², the hydrocarbyloxymethyl group having formula (d2), and the repeat units (d) are as exemplified for the repeat units (d) in JP-A 2020-111564 (U.S. Pat. No. 11,560,355).

In addition to the foregoing units, the polymer may further comprise repeat units (e) derived from indene, benzofuran, benzothiophene, acenaphthylene, chromone, coumarin, and norbornadiene, or derivatives thereof. Examples of the monomer from which repeat units (e) are derived are shown below, but not limited thereto.

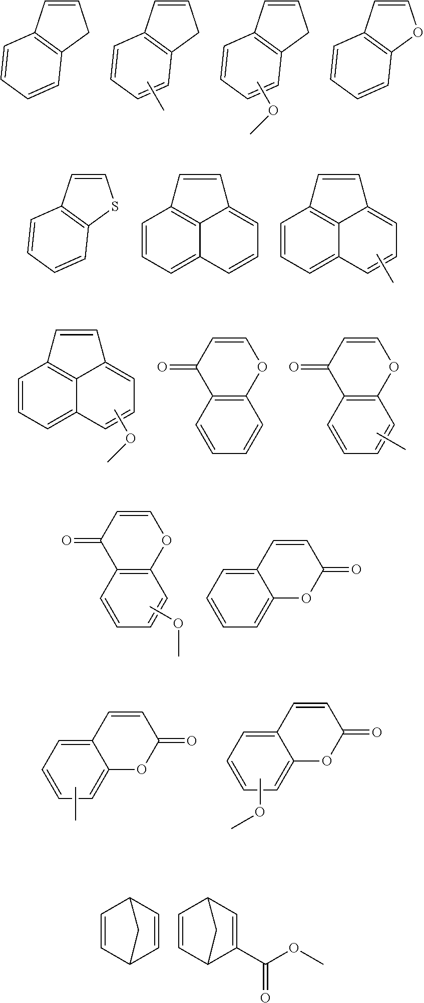

Furthermore, the polymer may comprise repeat units (f) derived from styrene, indane, vinylpyridine, vinylcarbazole, or derivatives thereof.

In the polymer, a fraction of units (a1), (a2), (a3), (b), (c), (d), (e), and (f) is: preferably 0<a1≤0.6, 0≤a2≤0.6, 0≤a3≤0.6, 0≤b≤0.6, 0≤c≤0.5, 0≤d≤0.6, 0≤e≤0.3, and 0≤f≤0.3; more preferably 0<a1≤0.5, 0≤a2≤0.5, 0≤a3≤05 0≤b≤0.5, 0≤c≤0.4, 0≤d≤0.5, 0≤e≤0.2, and 0≤f≤0.2, with the proviso: a1+a2+a3+b+c+d+e+f<1.

The polymer should preferably have a weight average molecular weight (Mw) in the range of 1,000 to 500,000, and more preferably 3,000 to 100,000. A Mw in the range ensures satisfactory etch resistance and eliminates the risk of resolution being lowered due to a failure to acquire a difference in dissolution rate before and after exposure. It is noted that Mw is as measured by GPC versus polystyrene standards using tetrahydrofuran (THF) or N,N-dimethylformamide (DMF) solvent.

Since the influence of dispersity (Mw/Mn) becomes stronger as the pattern rule becomes finer, the polymer should preferably have a narrow dispersity (Mw/Mn) of 1.0 to 2.0 in order to provide a resist composition suitable for micropatterning to a small feature size. A Mw/Mn in the range indicates smaller amounts of lower and higher molecular weight fractions and eliminates the risk of leaving foreign particles on the pattern or degrading the pattern profile after exposure and development.

The polymer may be synthesized by any desired methods, for example, by dissolving one or more monomers selected from the monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, methyl ethyl ketone (MEK), PGMEA, and GBL. Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The amount of the initiator added is preferably 0.01 to 25 mol % based on the total of monomers. The reaction temperature is preferably 50 to 150° C., more preferably 60 to 100° C. The reaction time is preferably 2 to 24 hours, a time of 2 to 12 hours being more preferred in view of production efficiency.

The polymerization initiator may be added to the monomer solution, which is fed to the reactor. Alternatively, a solution of the polymerization initiator is prepared separately from the monomer solution, and the monomer and initiator solutions are independently fed to the reactor. Since there is a possibility that the initiator generates a radical in the standby time, by which polymerization reaction takes place to form a ultrahigh molecular weight compound, it is preferred from the standpoint of quality control that the monomer solution and the initiator solution be independently prepared and added dropwise. The acid labile group that has been incorporated in the monomer may be kept as such, or the polymerization may be followed by protection or partial protection. Any of well-known chain transfer agents such as dodecylmercaptan and 2-mercaptoethanol may be used for the purpose of adjusting molecular weight. An appropriate amount of the chain transfer agent is 0.01 to 20 mol % based on the total of monomers to be polymerized.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene. For alkaline hydrolysis, a base such as aqueous ammonia or triethylamine may be used. Preferably the reaction temperature is −20° C. to 100° C., more preferably 0° C. to 60° C., and the reaction time is 0.2 to 100 hours, more preferably 0.5 to 20 hours.

The amounts of monomers in the monomer solution may be determined appropriate so as to provide the preferred fractions of repeat units as mentioned above.

It is described how to use the polymer obtained by the above preparation method. The reaction solution resulting from polymerization reaction may be used as the final product. Alternatively, the polymer may be recovered in powder form through a purifying step such as re-precipitation step of adding the reaction solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product.

The solvents which can be used herein are described in JP-A 2008-111103, paragraphs [0144]-[0145](U.S. Pat. No. 7,537,880). Exemplary solvents include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol, and diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; lactones such as GBL; and high-boiling alcohols such as diethylene glycol, propylene glycol, glycerol, 1,4-butanediol, and 1,3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign particles and gel which can cause defects are removed.

Suitable materials of which the filter is made include fluorocarbon, cellulose, nylon, polyester, and hydrocarbon base materials. Preferred for the filtration of a resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 nm. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

The base polymer (A) may be a single polymer or a blend of polymers which are different in compositional ratio, Mw and/or Mw/Mn. The base polymer may also be a blend of the polymer defined above and a hydrogenated product of a ring-opening metathesis polymerization (ROMP) polymer as described in JP-A 2003-066612.

### (B) Photoacid Generator

The chemically amplified resist composition comprises (B) a photoacid generator containing a fluoroalkane sulfonic acid anion having an aromatic ring structure substituted with iodine or iodine and bromine. The photoacid generator preferably has the formula (1).

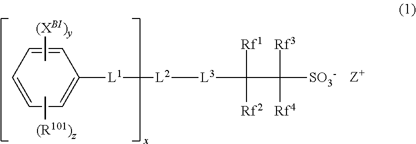

In formula (1), x is 1, 2 or 3, y is 1, 2, 3, 4 or 5, z is 0, 1, 2 or 3, and 1≤y+z≤5. Preferably, y is 1, 2 or 3, more preferably 2 or 3, and z is 0, 1 or 2.

In formula (1), X^{BI} is iodine when y is 1, and X^{BI} is iodine or bromine, at least one being iodine, when y is 2, 3, 4 or 5.

In formula (1), L¹ is a single bond, ether bond, ester bond, sulfonate ester bond, sulfonamide bond, amide bond, carbonate bond, carbamate bond, or a C₁-C₆ saturated hydrocarbylene group. Some —CH₂— in the hydrocarbylene group may be replaced by an ether bond, ester bond, sulfonate ester bond, sulfonamide bond, amide bond, carbonate bond, or carbamate bond. The saturated hydrocarbylene group may be straight, branched or cyclic.

In formula (1), L² is a single bond or a C₁-C₂₀ hydrocarbylene group which may contain a heteroatom when x is 1. L² is a C₁-C₂₀ (x+1)-valent hydrocarbon group which may contain a heteroatom when x is 2 or 3.

The C₁-C₂₀ hydrocarbylene group L² may be saturated or unsaturated and straight, branched or cyclic. Examples thereof include C₁-C₂₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl; C₃-C₂₀ cyclic saturated hydrocarbylene groups such as cyclopentanediyl, cyclohexanediyl, norbornanediyl and adamantanediyl and tricyclo[5.2.1.0^{2,6}]decanediyl; C₂-C₂₀ unsaturated aliphatic hydrocarbylene groups such as vinylene and propene-1,3-diyl; C₆-C₂₀ arylene groups such as phenylene, naphthylene, and anthracenediyl; C₇-C₂₀ aromatic ring-containing polycyclic hydrocarbylene groups such as 9,10-ethano-9,10-dihydroanthracenediyl and 6,13-ethano-6,13-dihydropentacene, and combinations thereof. The C₁-C₂₀ (x+1)-valent hydrocarbon group L² may be saturated or unsaturated and straight, branched or cyclic. Examples thereof include those exemplified above for the C₁-C₂₀ hydrocarbylene group from which one or two hydrogen atoms are removed.

In the hydrocarbylene and (x+1)-valent hydrocarbon groups, some or all of the hydrogen atoms may be substituted by a moiety containing a heteroatom such as oxygen, sulfur, nitrogen or halogen, or some —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety.

In formula (1), L³ is a single bond, ether bond, ester bond, sulfonate ester bond, carbonate bond or carbamate bond.

In formula (1), R¹⁰¹ is hydroxy, carboxy, fluorine, chlorine, pentafluorosulfanyl, a C₁-C₂₀ hydrocarbyl group, C₁-C₂₀ hydrocarbyloxy group, C₁-C₂₀ hydrocarbylthio group, C₂-C₂₀ hydrocarbylcarbonyl group, C₂-C₂₀ hydrocarbyloxycarbonyl group, C₂-C₂₀ hydrocarbylcarbonyloxy group, C₁-C₂₀ hydrocarbylsulfonyloxy group, —N(R^{101A})(R^{101B}), —N(R^{101C})—C(═O)—R^{101D} or —N(R^{101C})—C(═O)—O—R^{101D}. The hydrocarbyl, hydrocarbyloxy, hydrocarbylthio, hydrocarbylcarbonyl, hydrocarbyloxycarbonyl, hydrocarbylcarbonyloxy, and hydrocarbylsulfonyloxy groups may contain at least one moiety selected from fluorine, chlorine, bromine, iodine, hydroxy, amino, ester bond and ether bond. R^{101A} and R^{101B} are each independently hydrogen or a C₁-C₆ saturated hydrocarbyl group. R^{101C} is hydrogen or a C₁-C₆ saturated hydrocarbyl group which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety. R^{101D} is a C₁-C₁₆ aliphatic hydrocarbyl group, C₆-C₁₂ aryl group or C₇-C₁₅ aralkyl group, which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbylcarbonyl, hydrocarbyloxycarbonyl, hydrocarbylcarbonyloxy, and hydrocarbylsulfonyloxy groups may be straight, branched or cyclic. When x and/or z is 2 or more, a plurality of R¹⁰ may be identical or different.

Of these, R¹⁰¹ is preferably selected from hydroxy, —N(R^{101C})—C(═O)—R^{101D}, —N(R^{101C})—C(═O)—O—R^{101D}, fluorine, chlorine, bromine, methyl and methoxy.

In formula (1), Rf¹ to Rf⁴ are each independently hydrogen, fluorine or trifluoromethyl, at least one being fluorine or trifluoromethyl. Rf¹ and Rf² may bond together to form a carbonyl group. Most preferably, both Rf³ and Rf⁴ are fluorine.

Examples of the anion in the PAG having formula (1) are shown below, but not limited thereto. X^{BI} is as defined above.

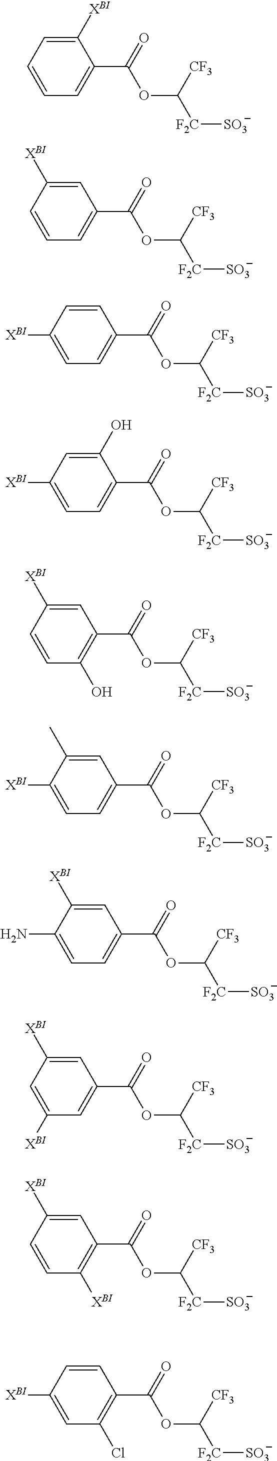

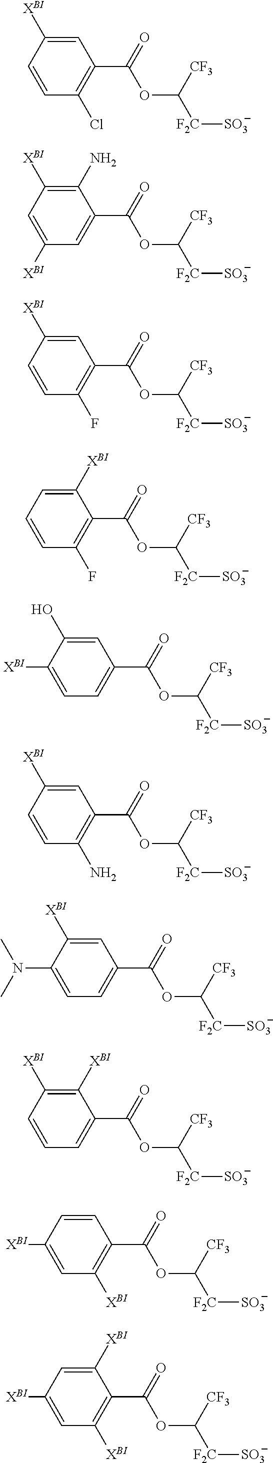

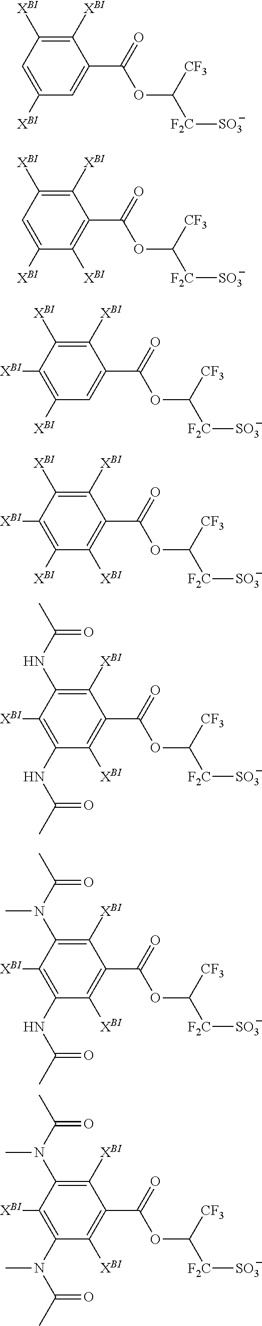

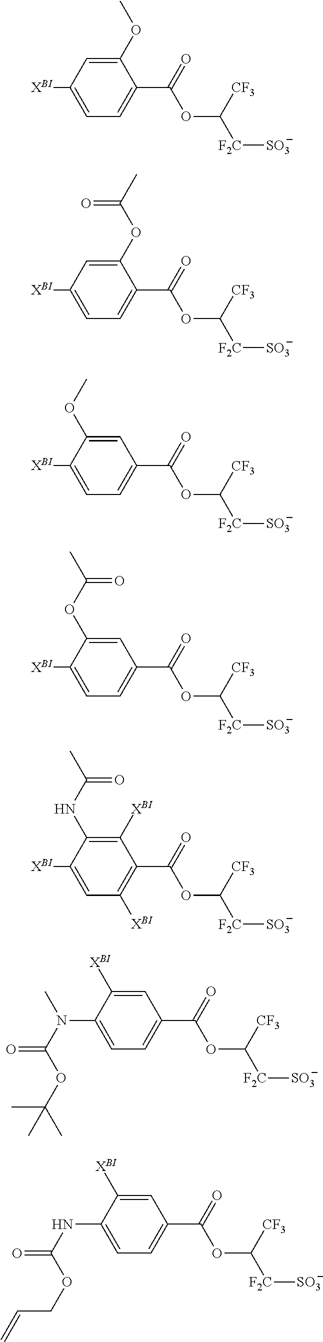

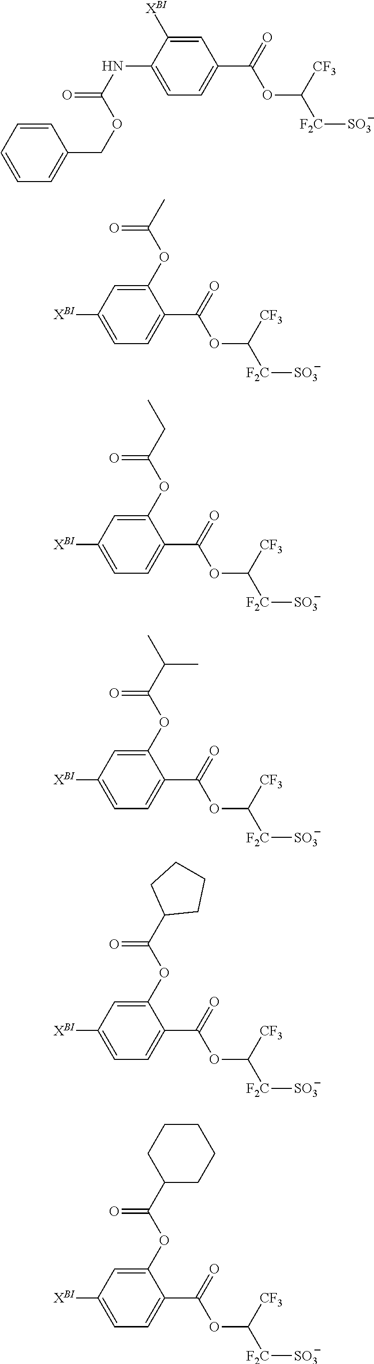

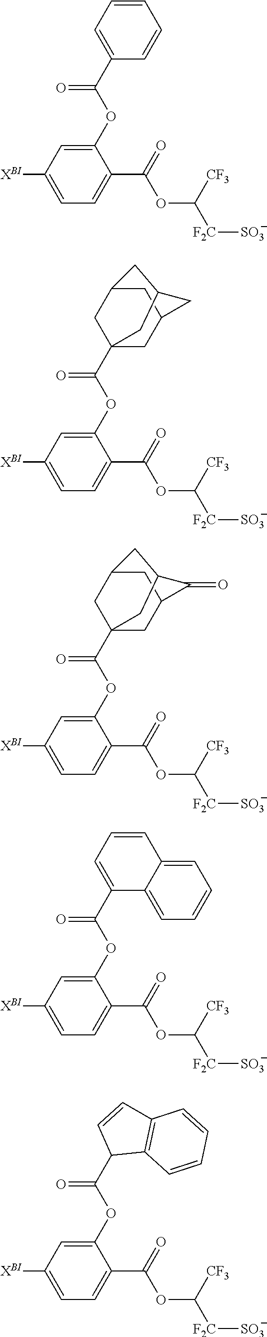

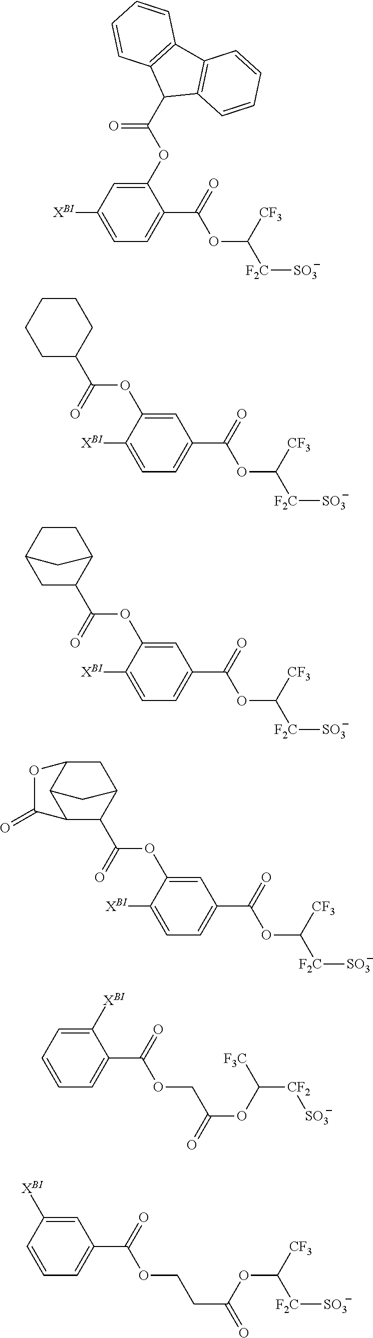

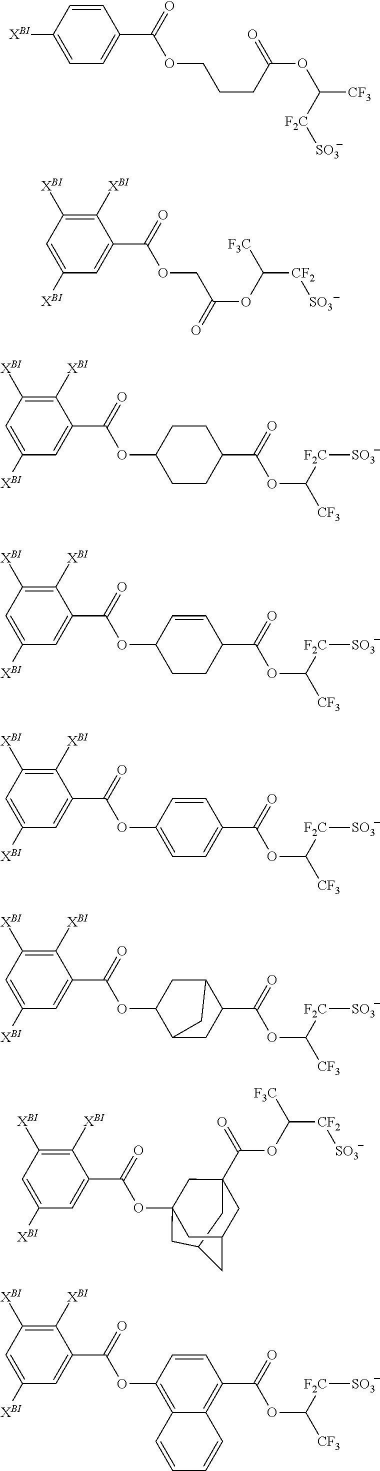

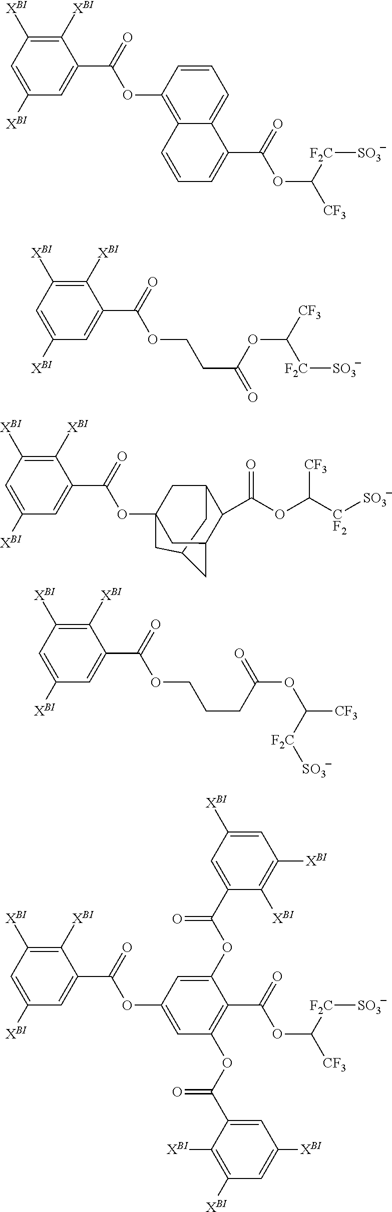

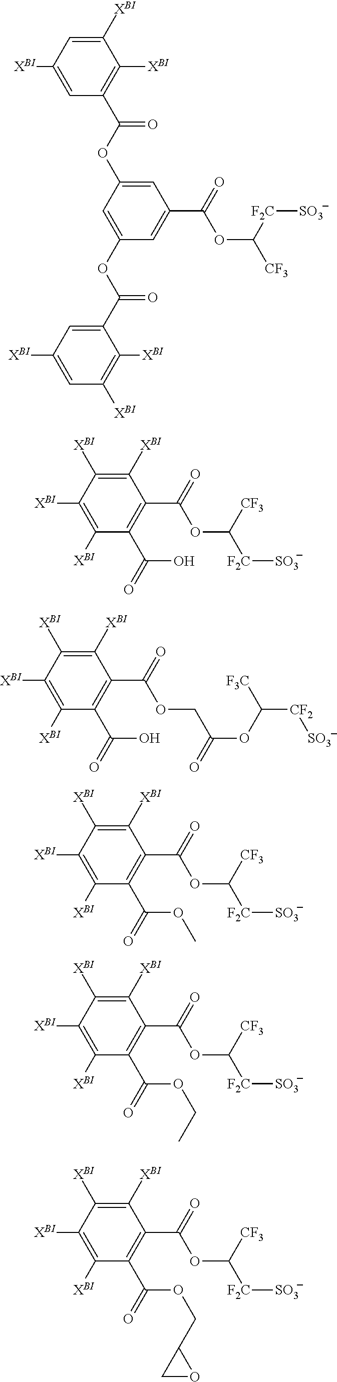

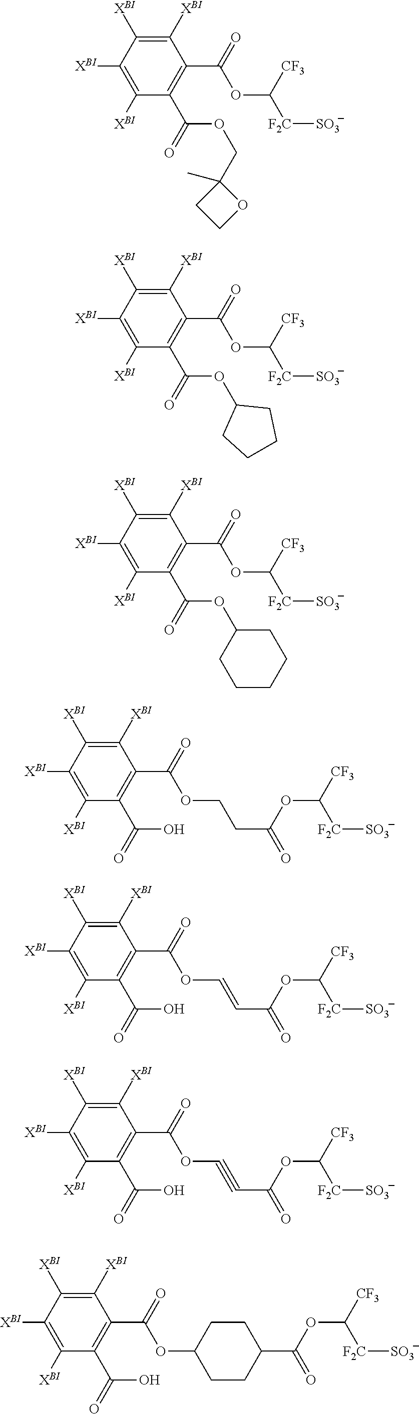

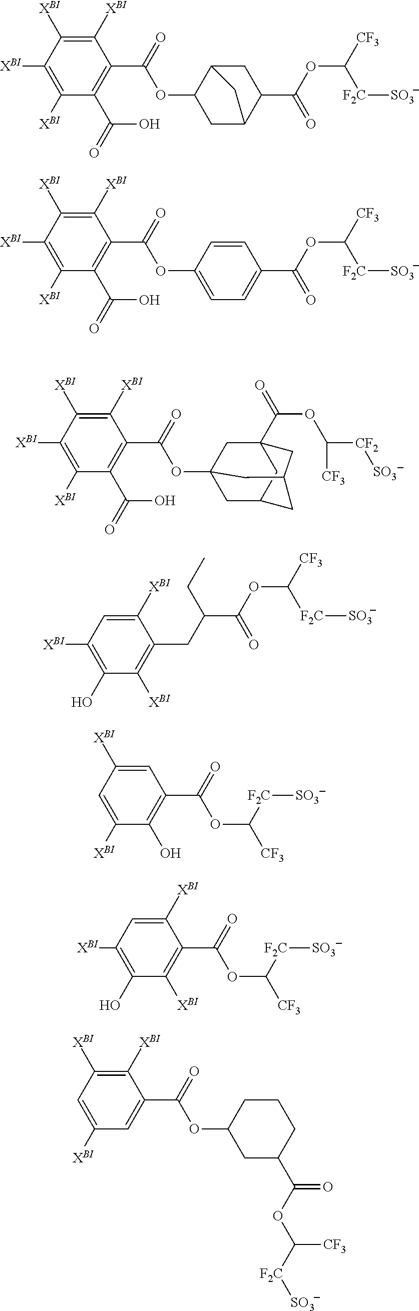

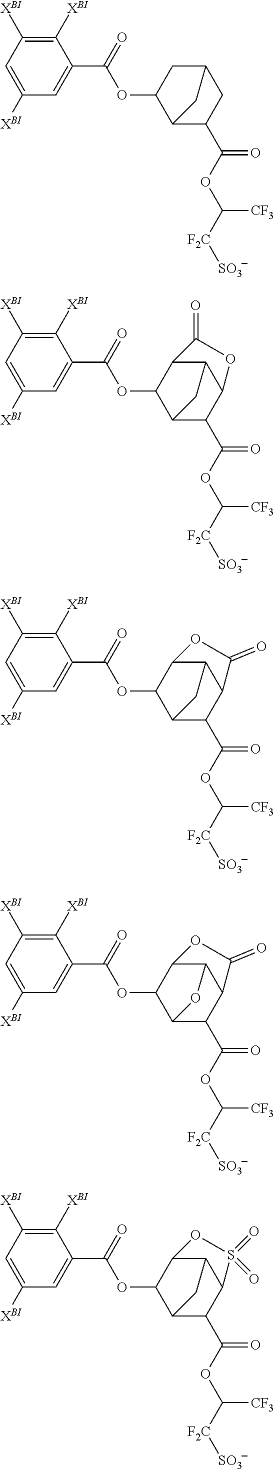

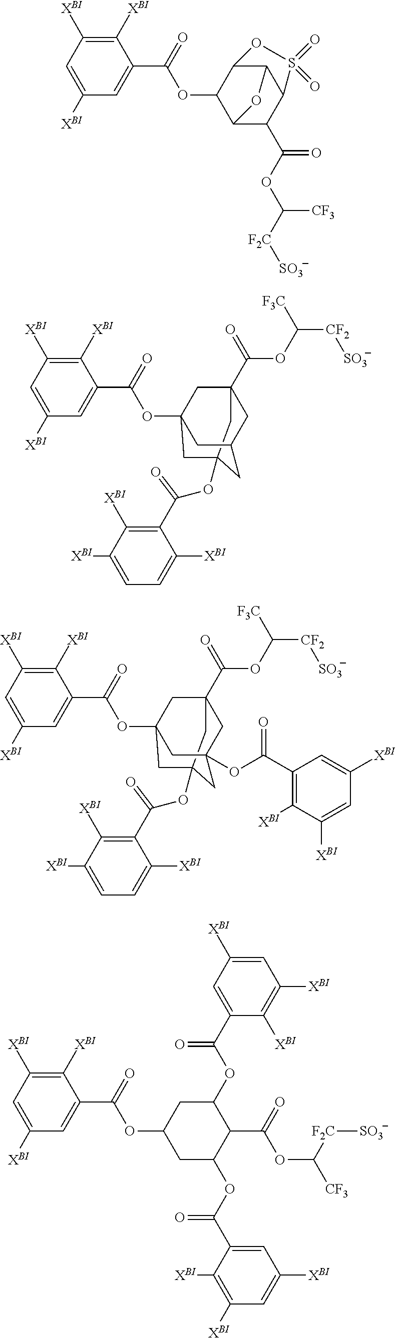

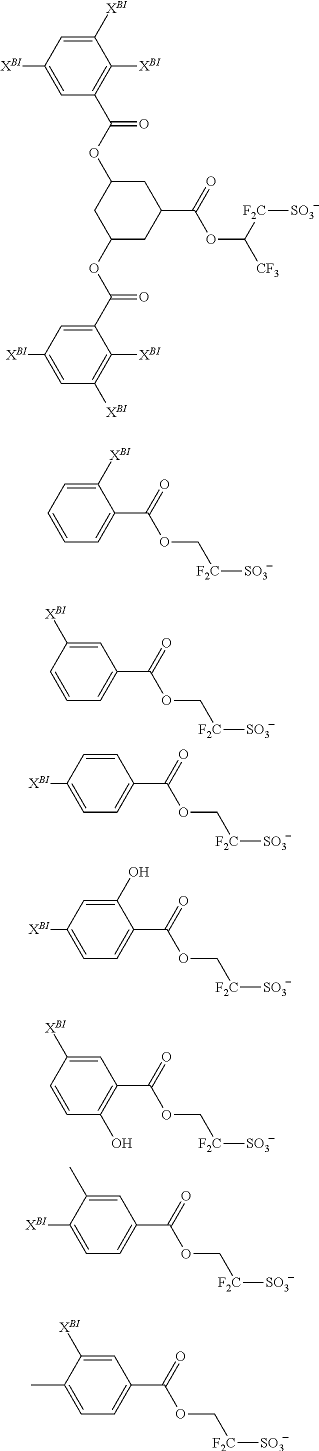

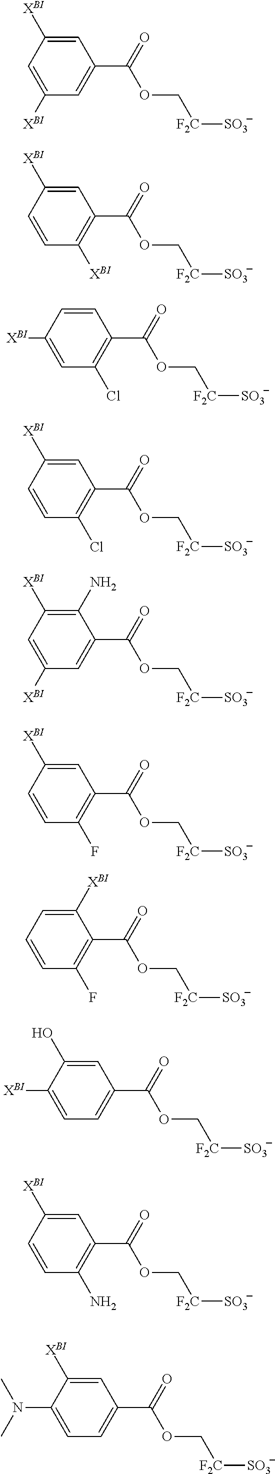

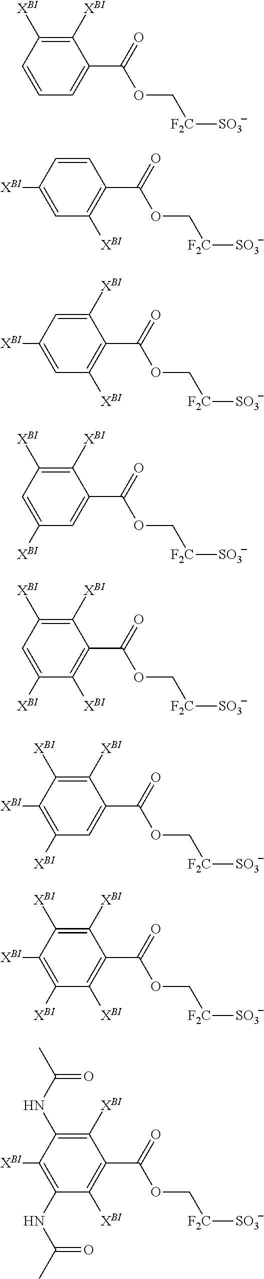

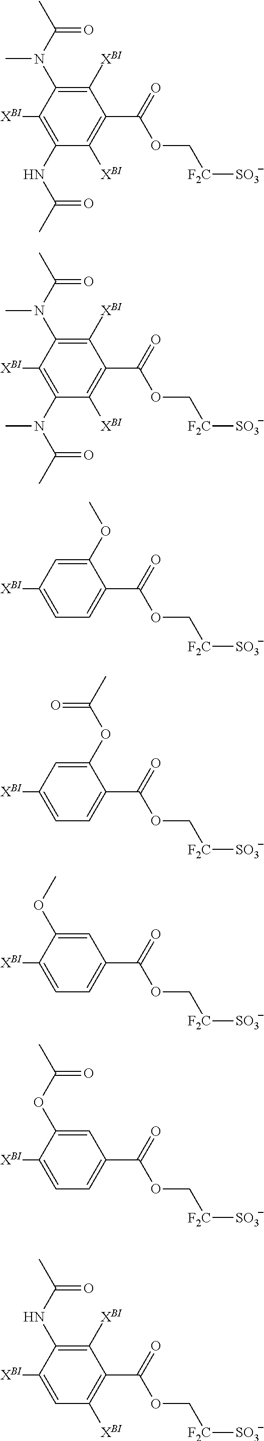

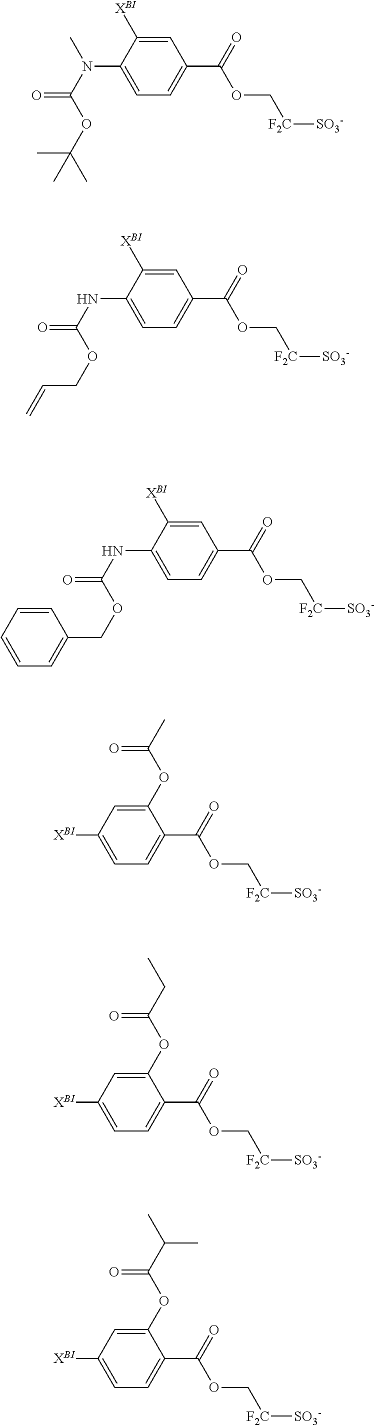

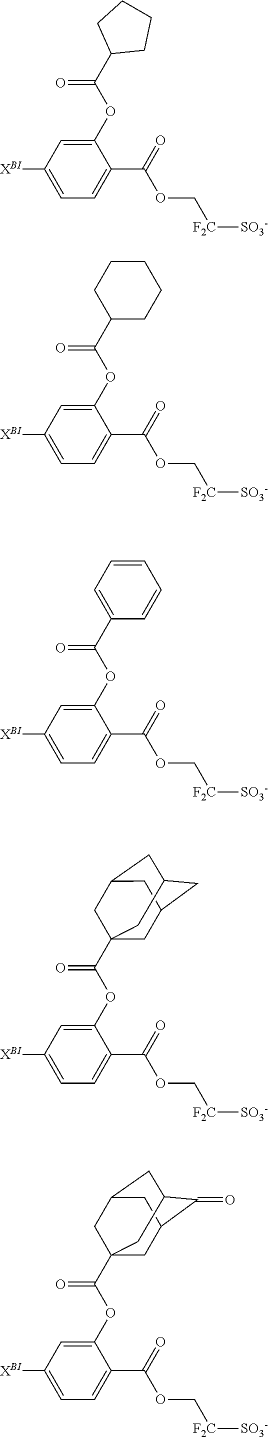

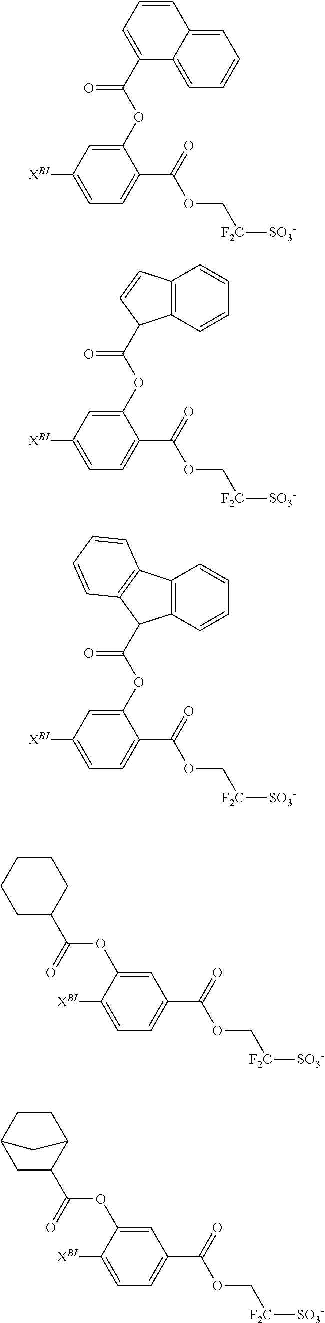

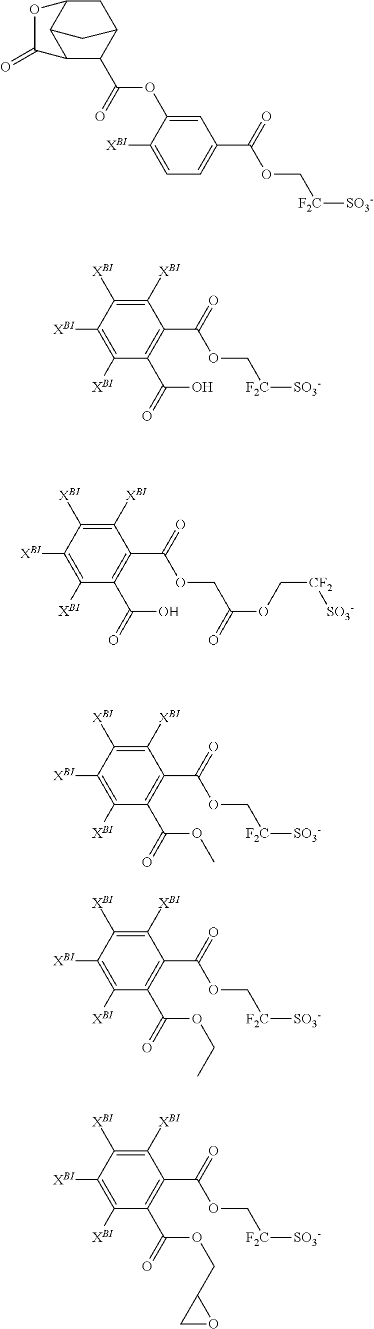

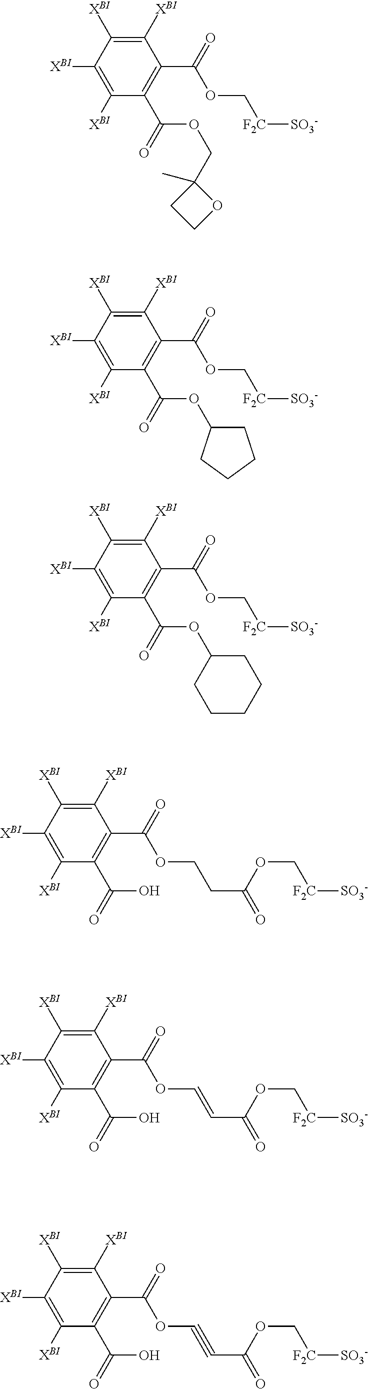

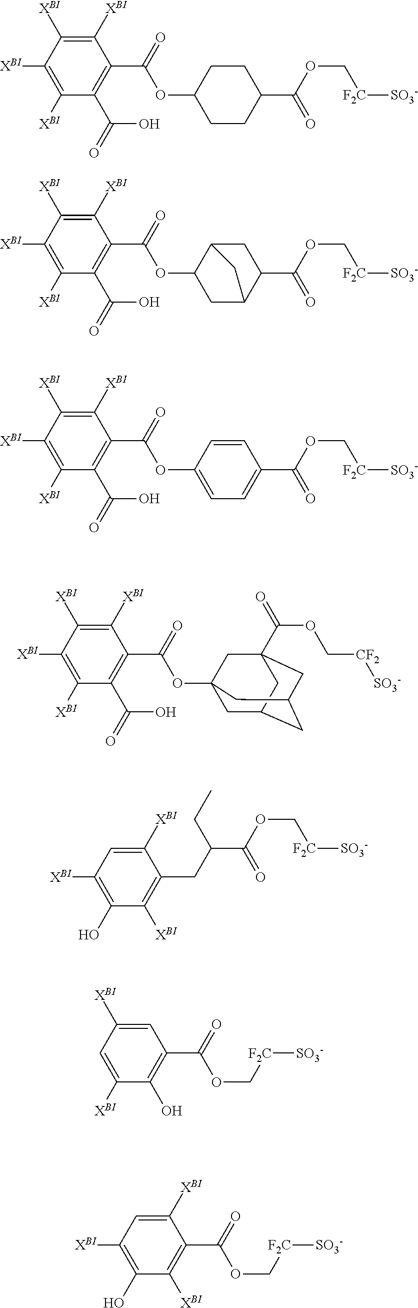

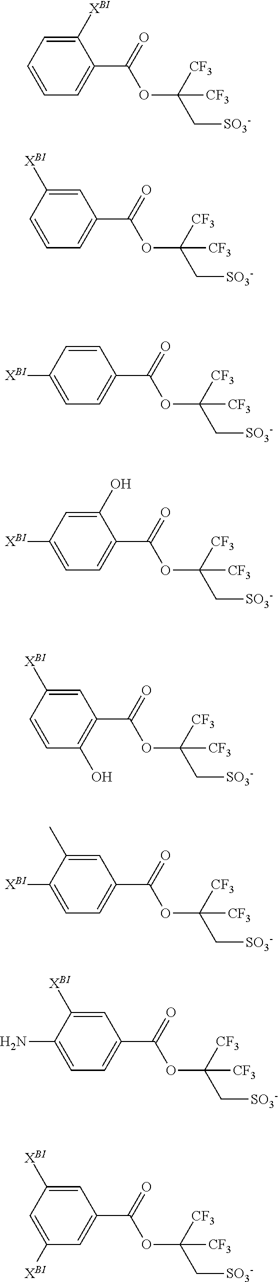

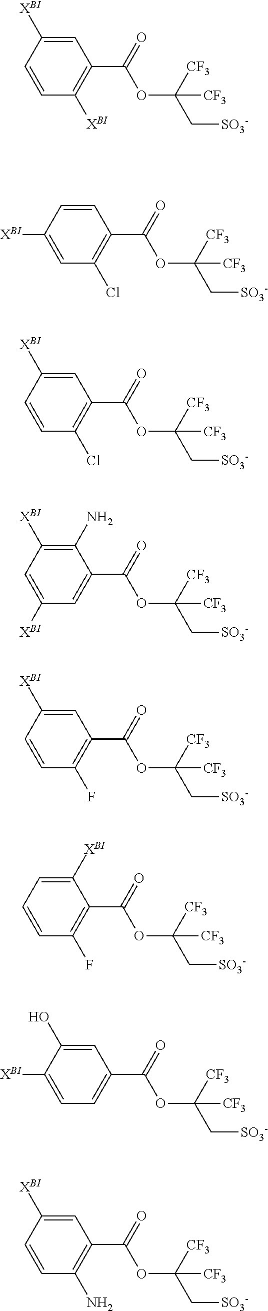

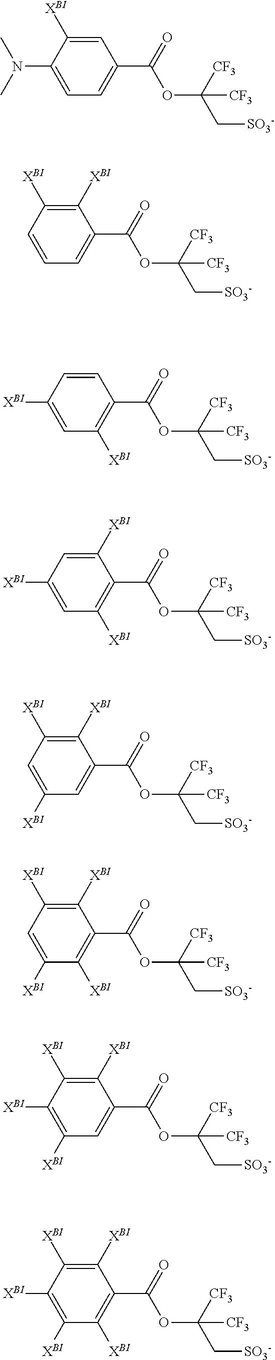

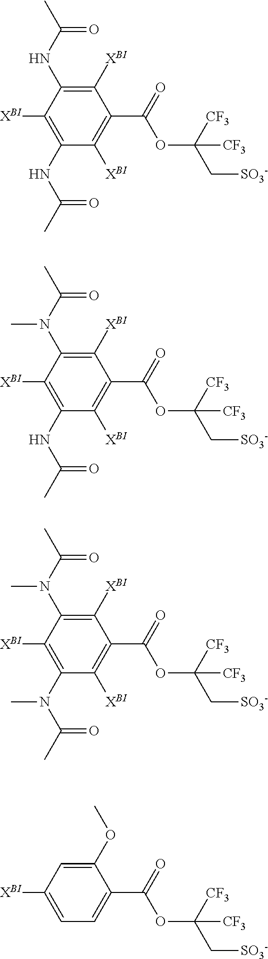

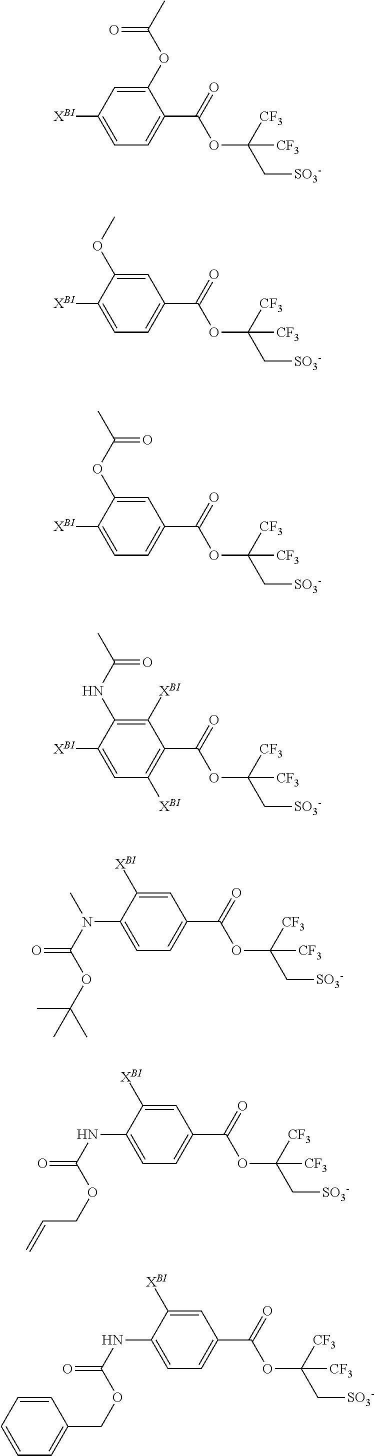

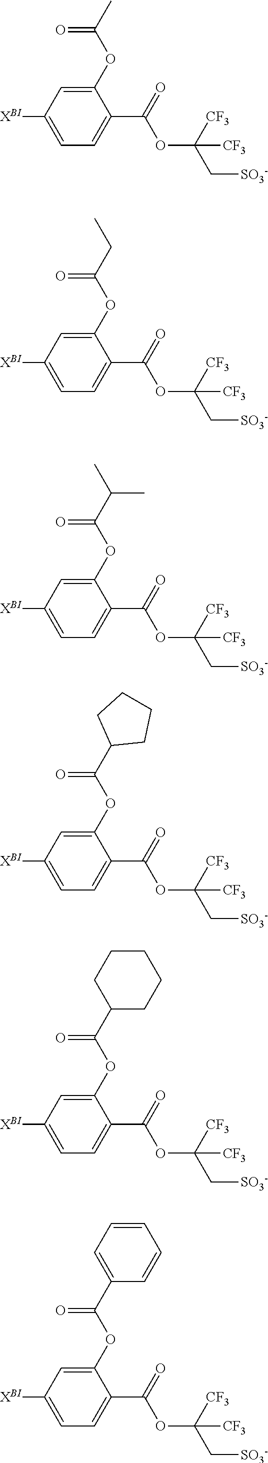

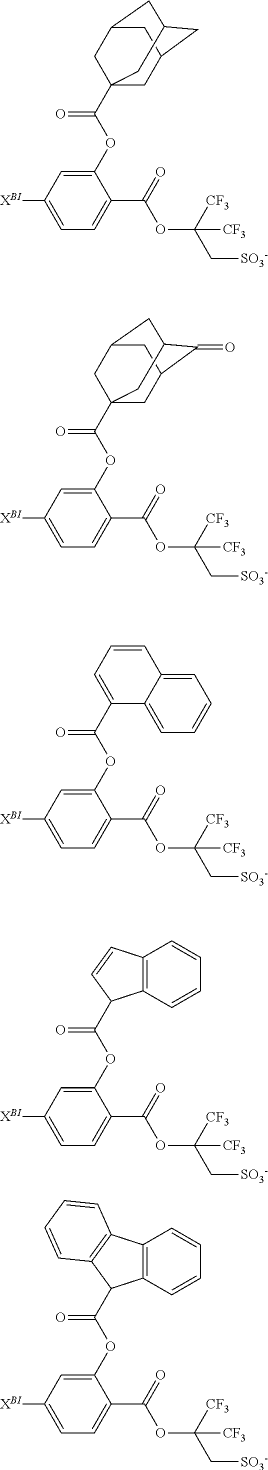

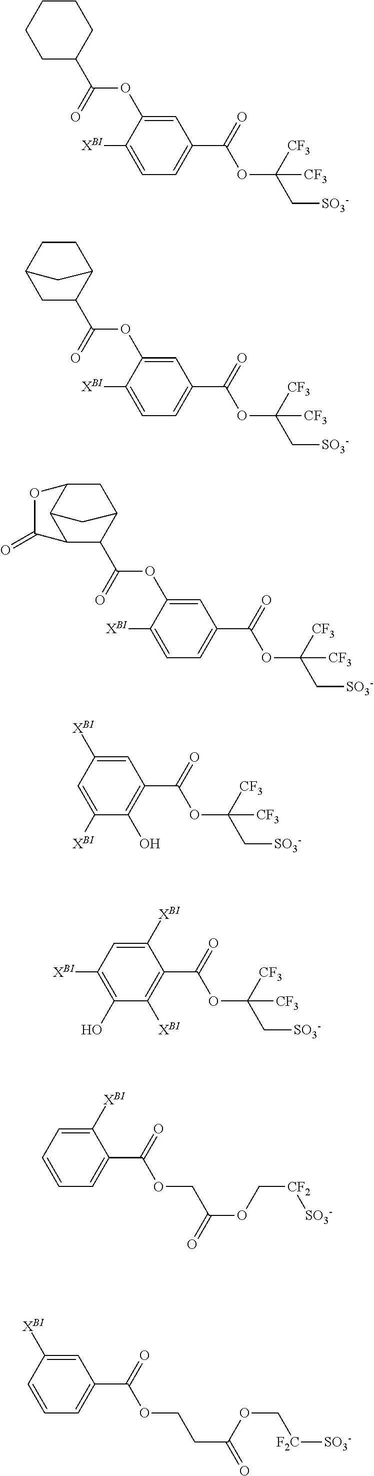

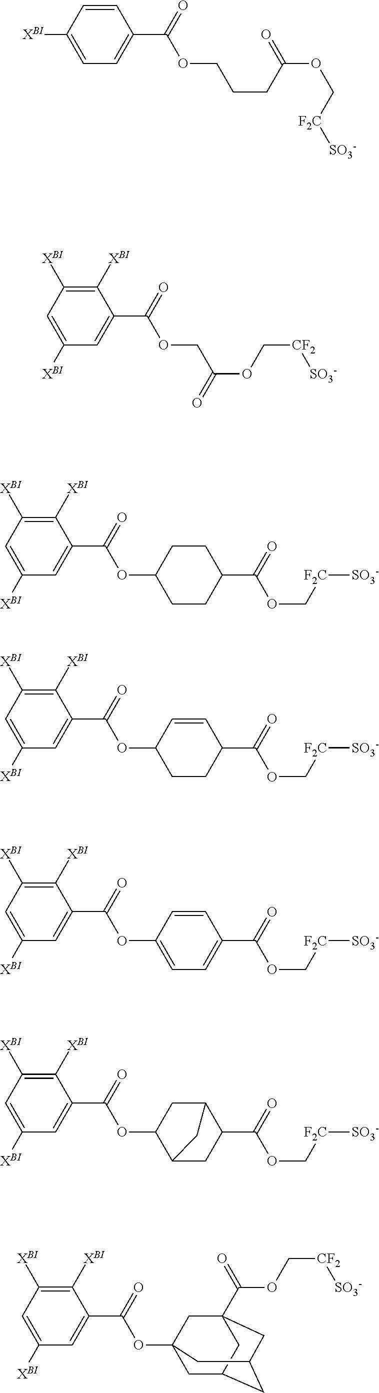

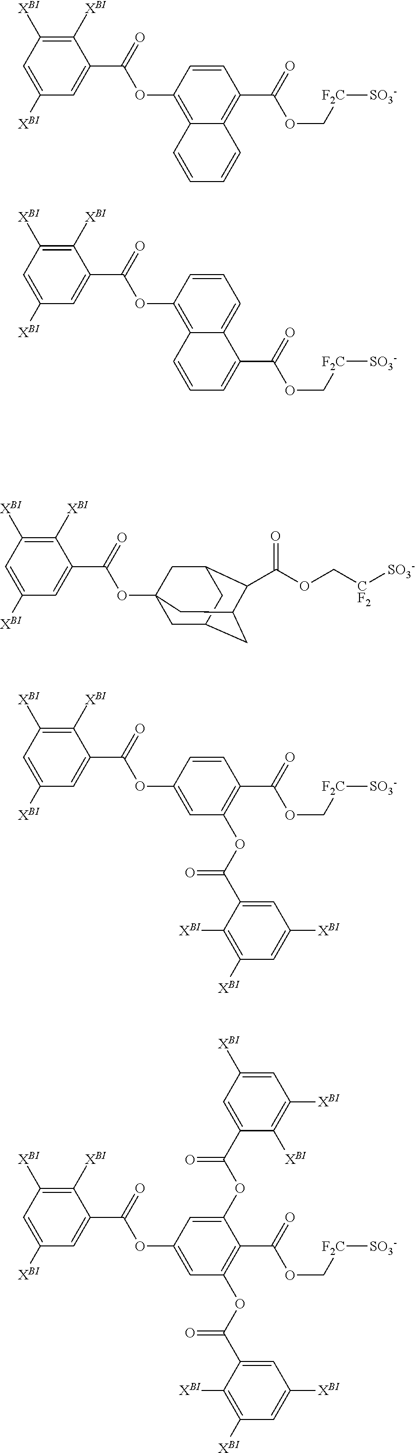

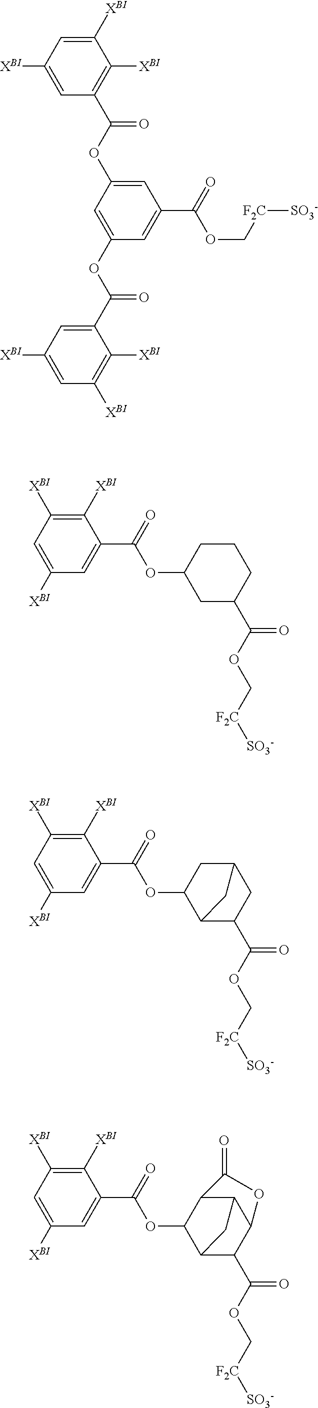

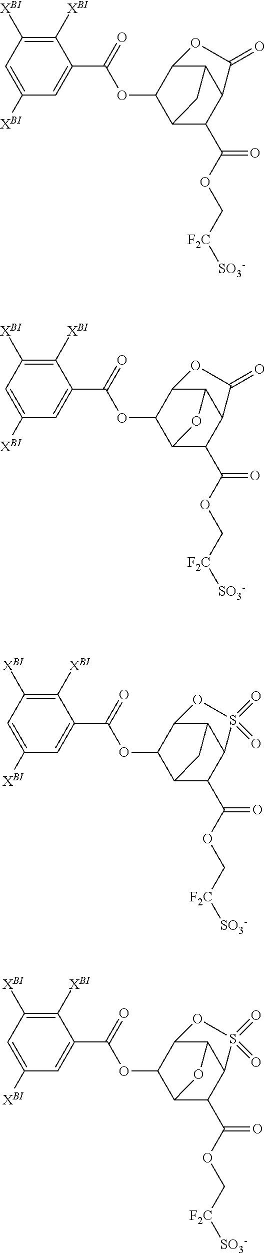

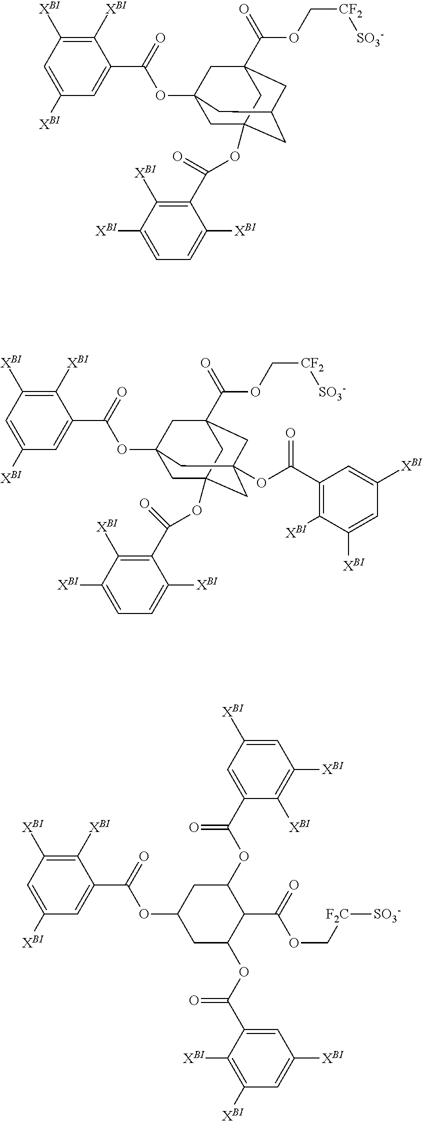

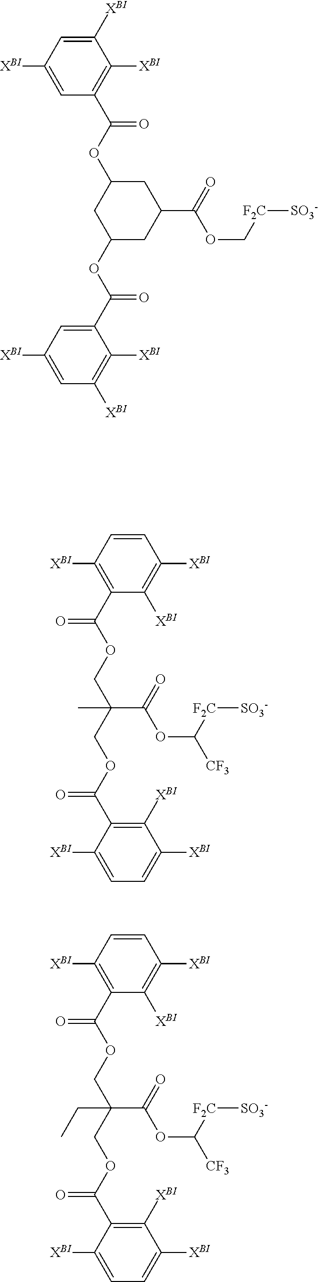

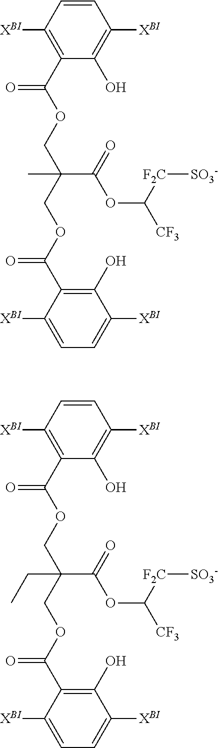

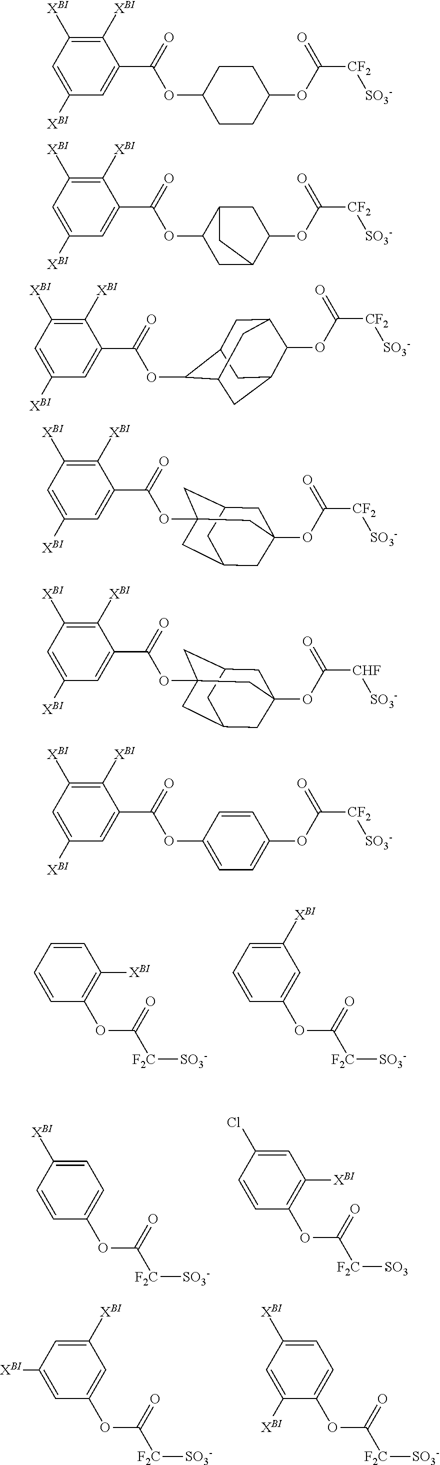

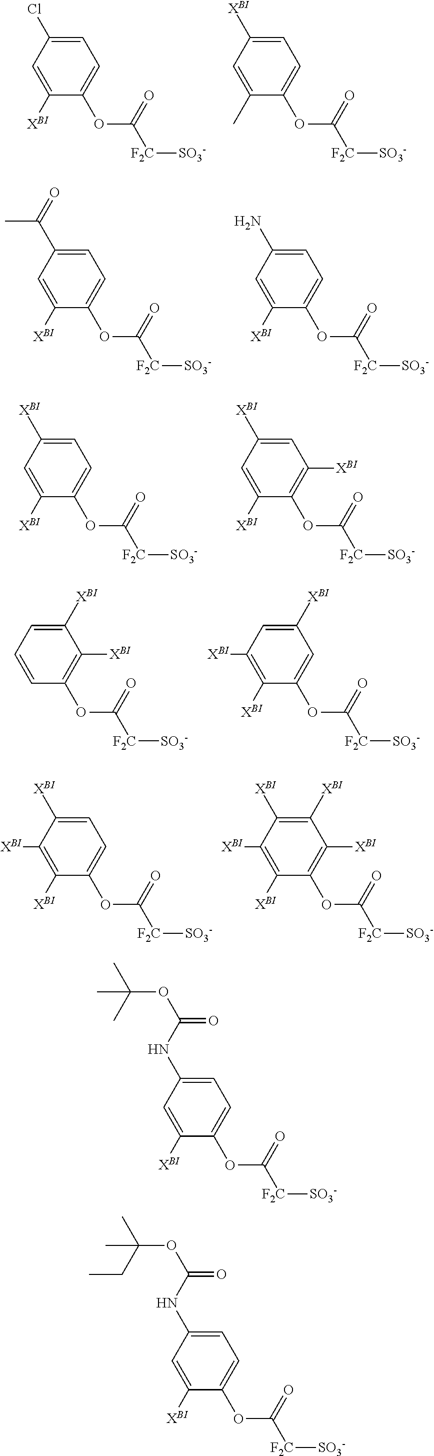

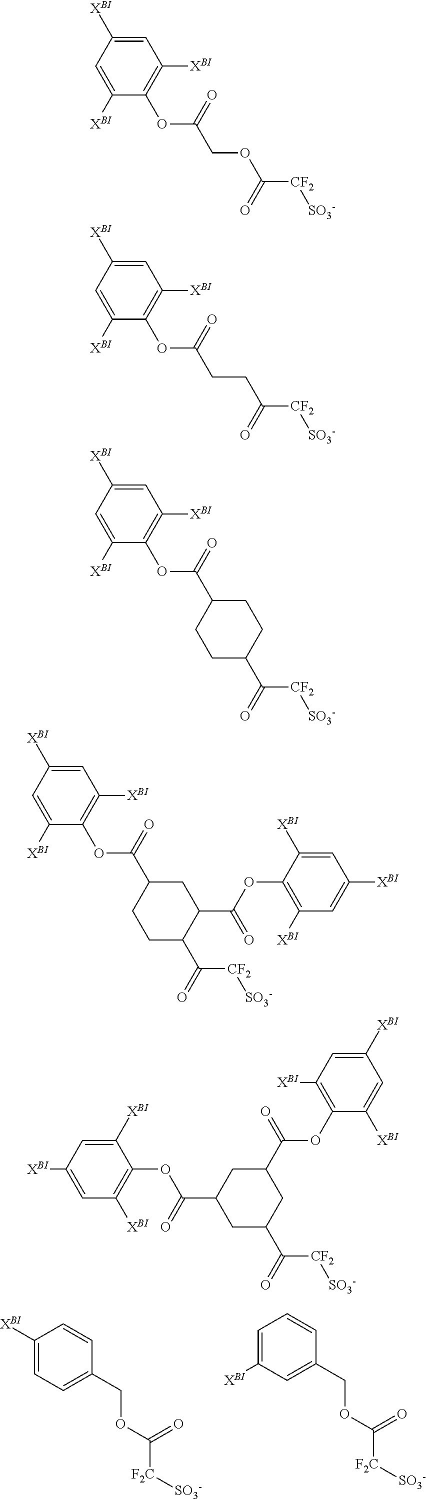

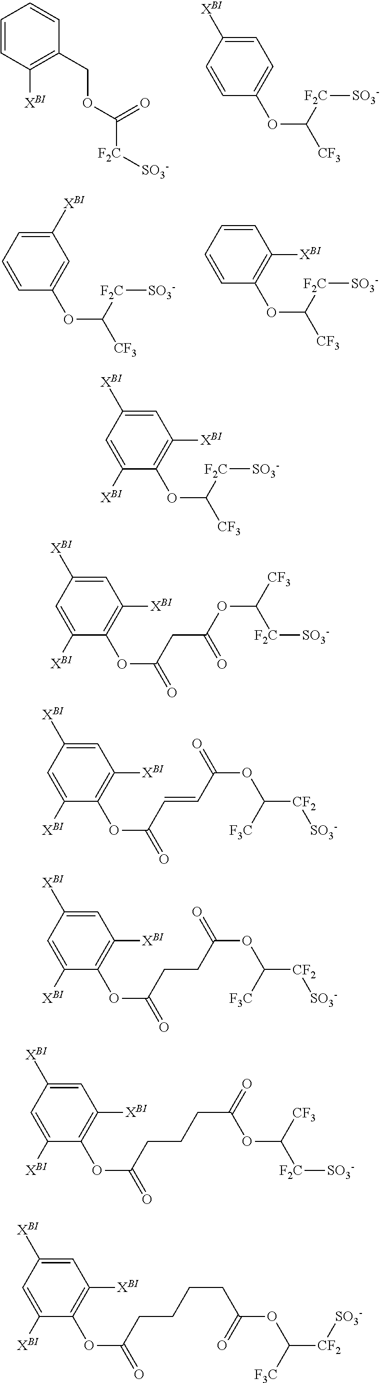

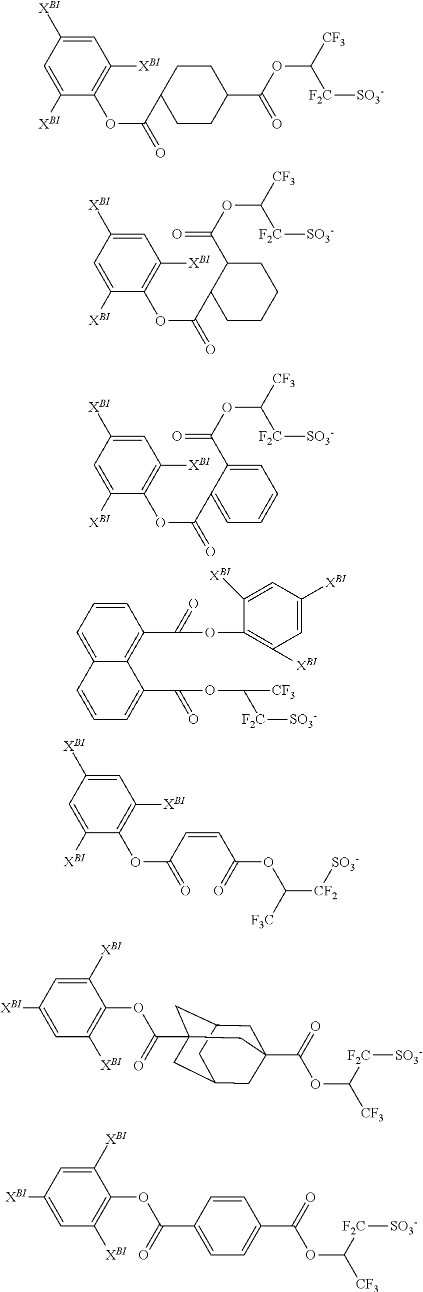

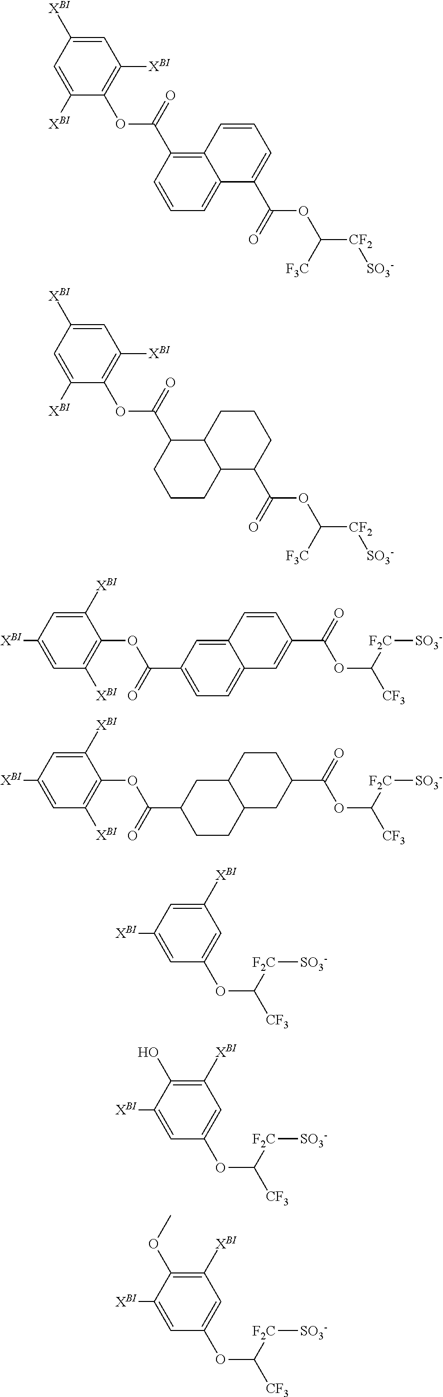

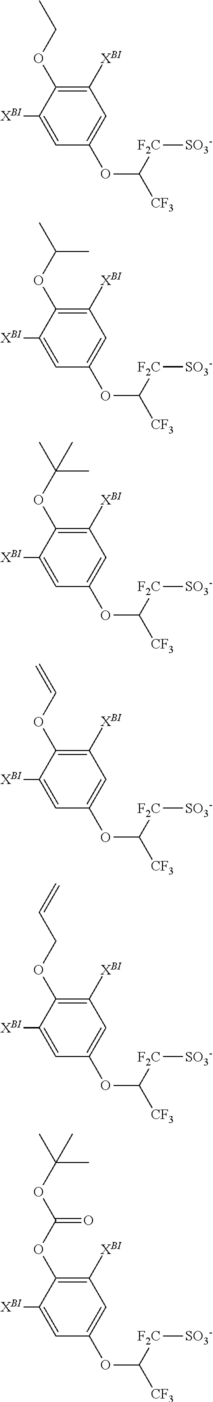

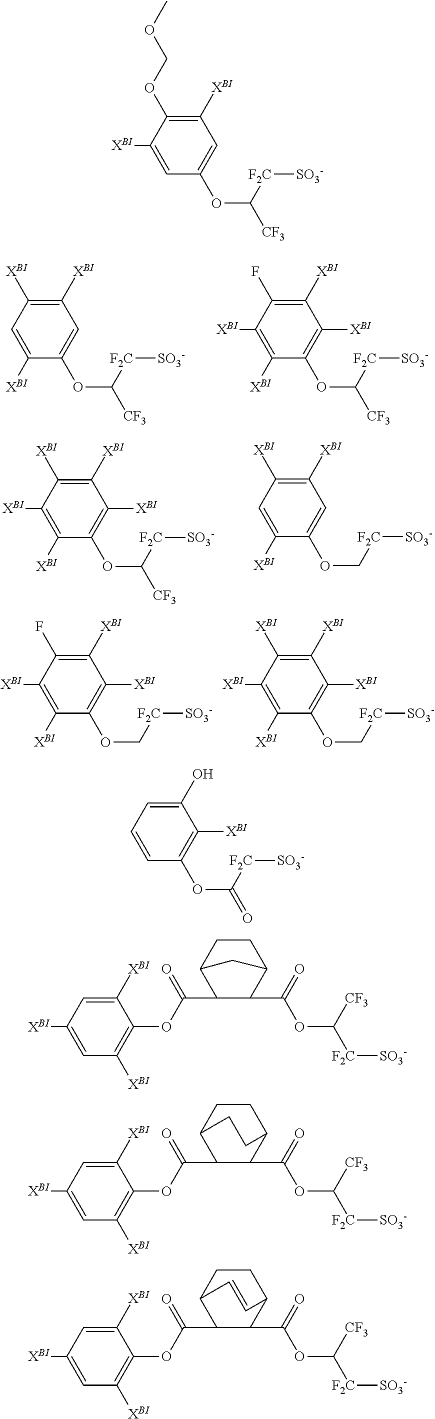

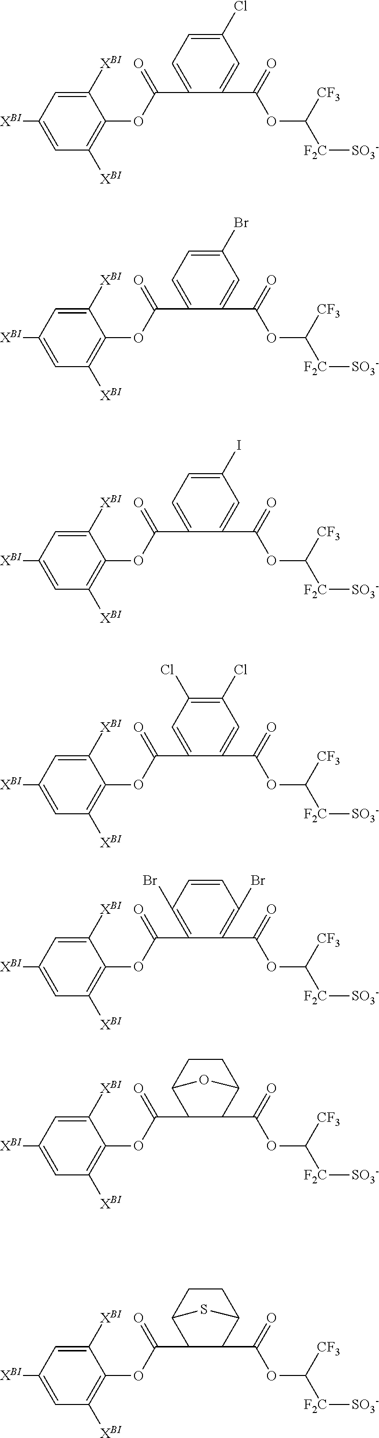

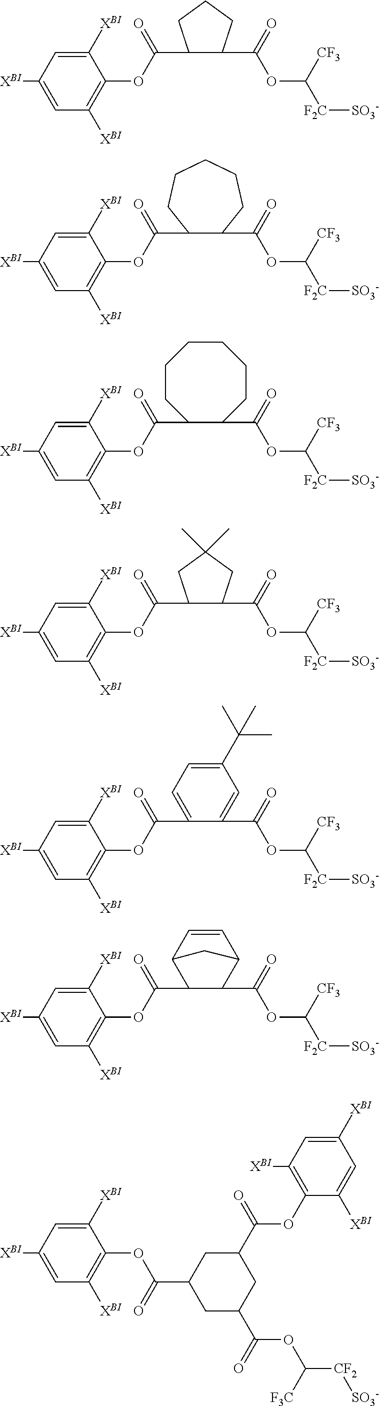

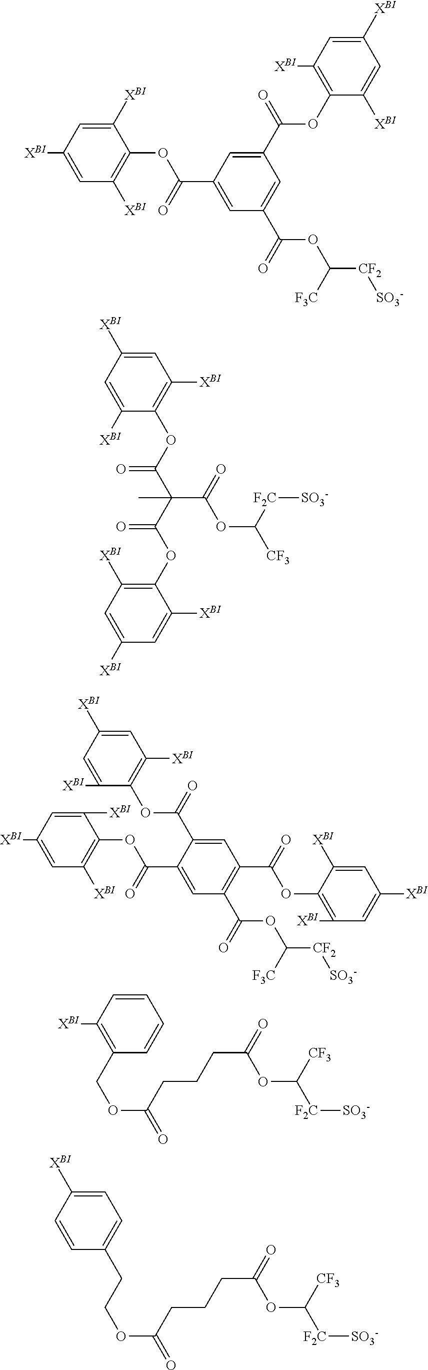

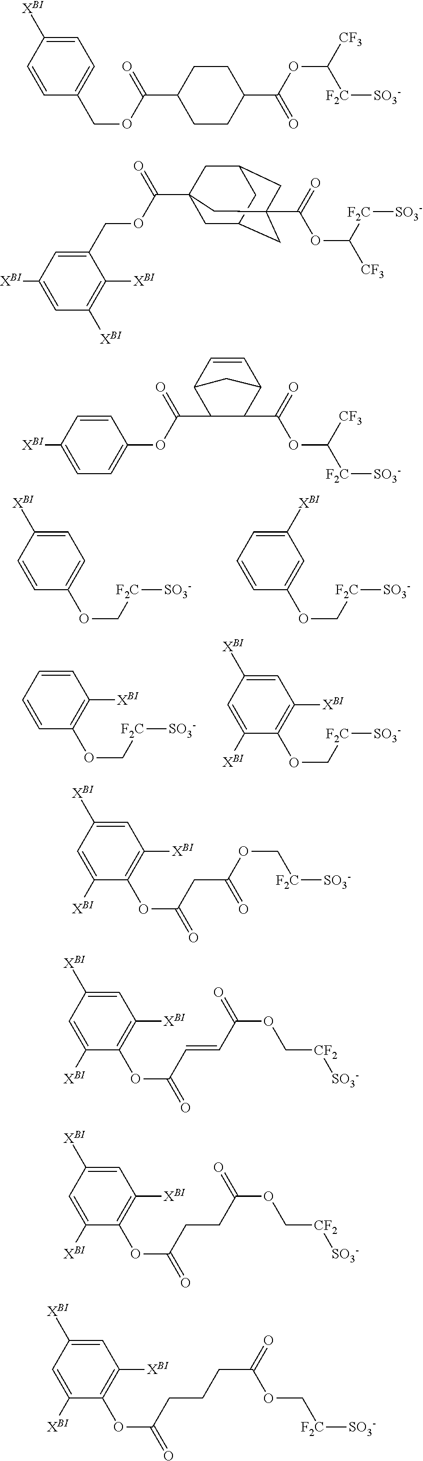

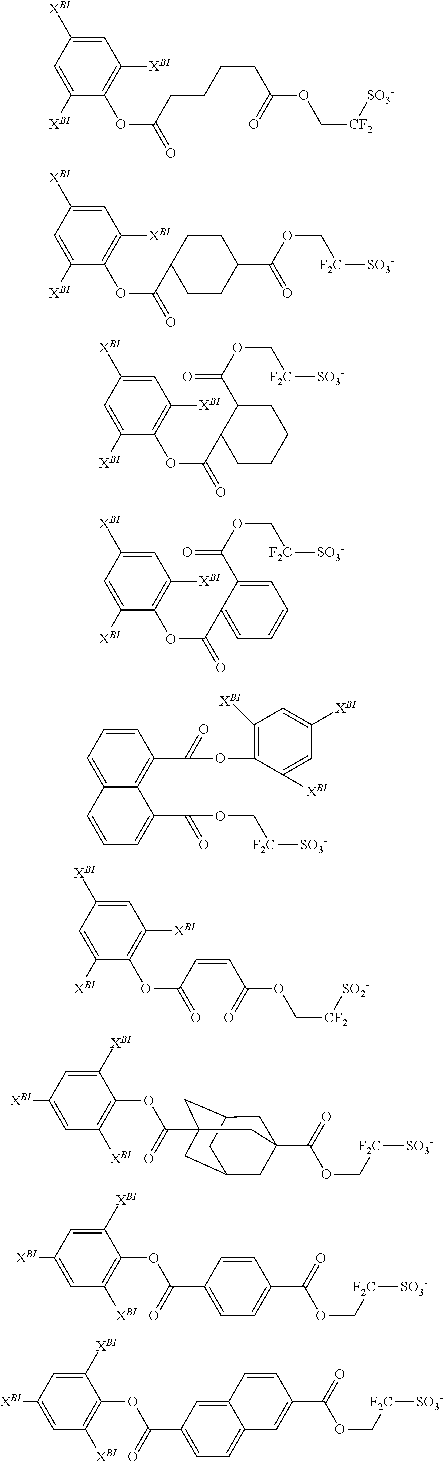

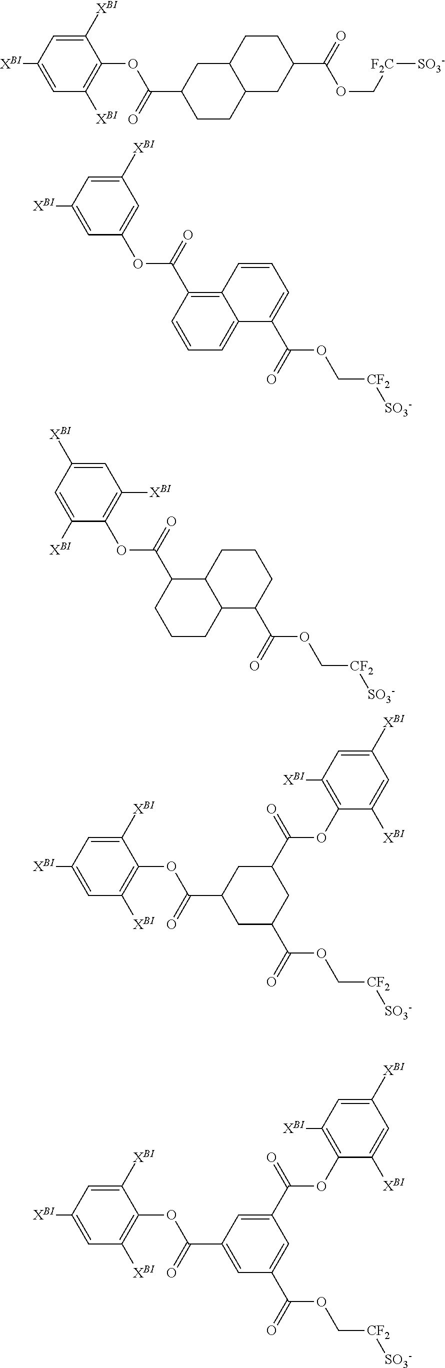

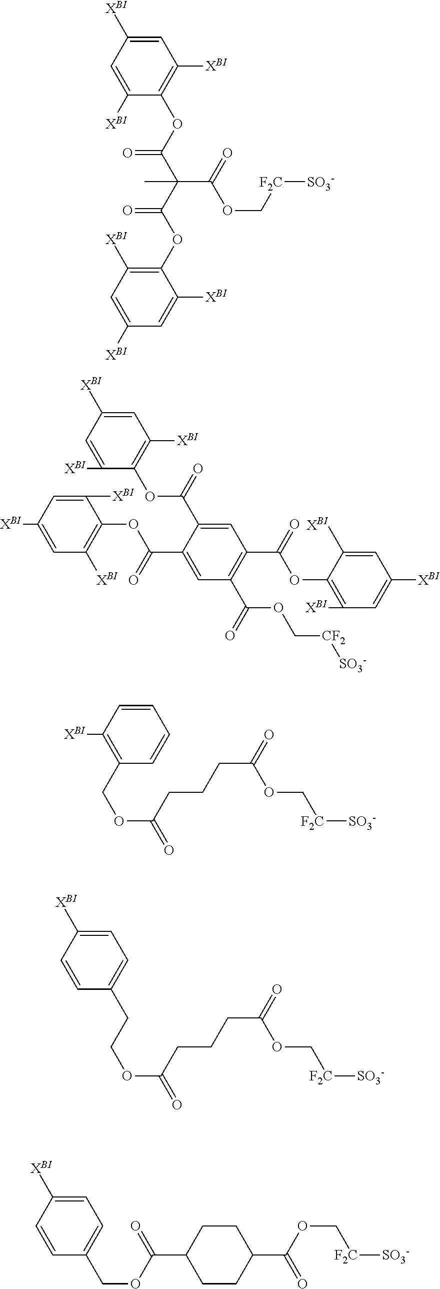

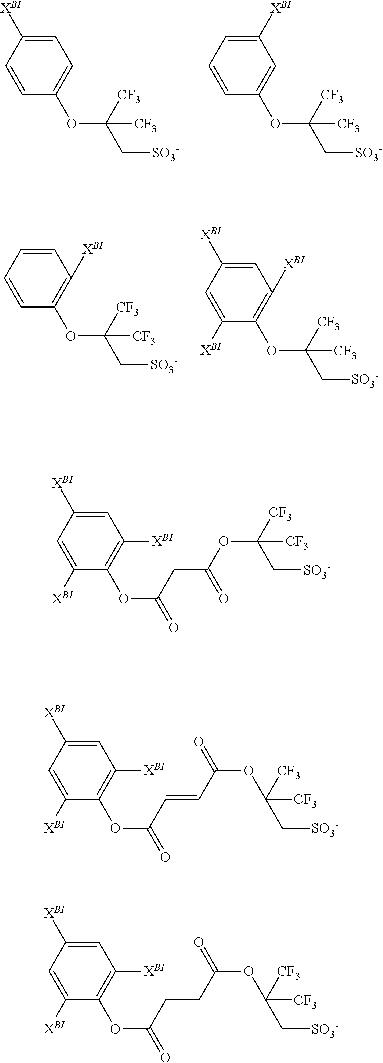

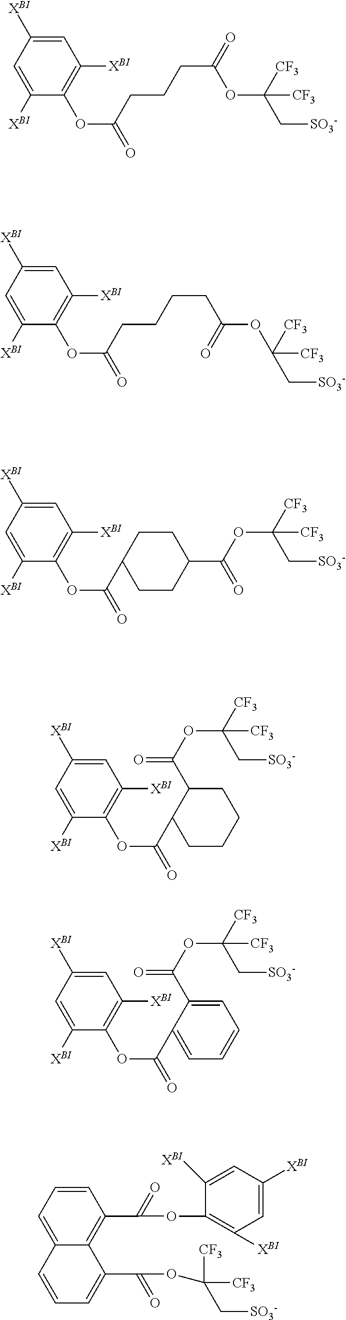

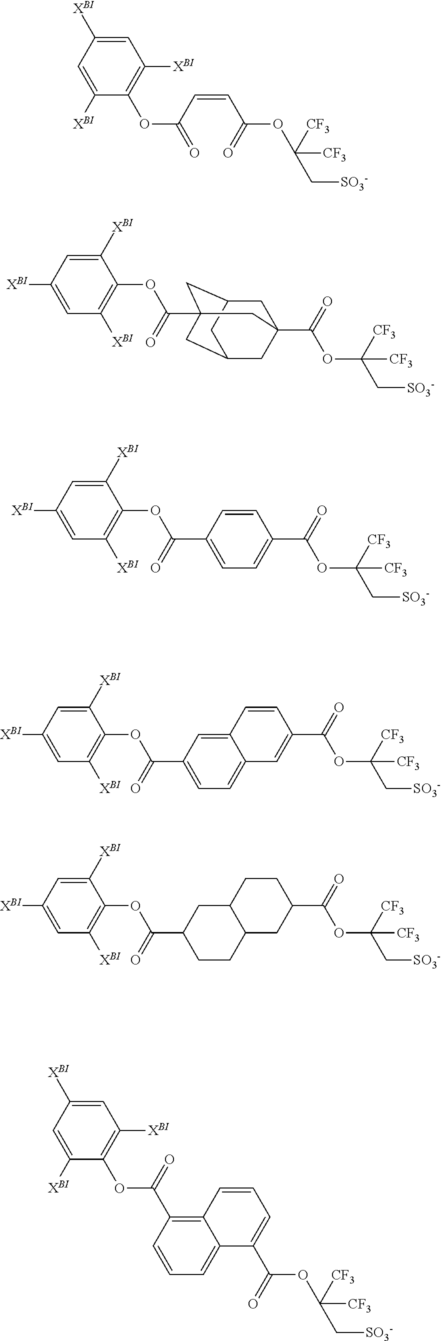

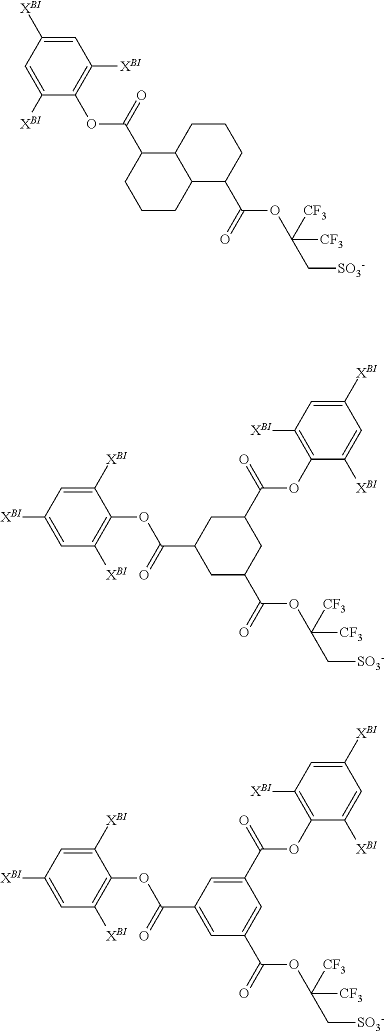

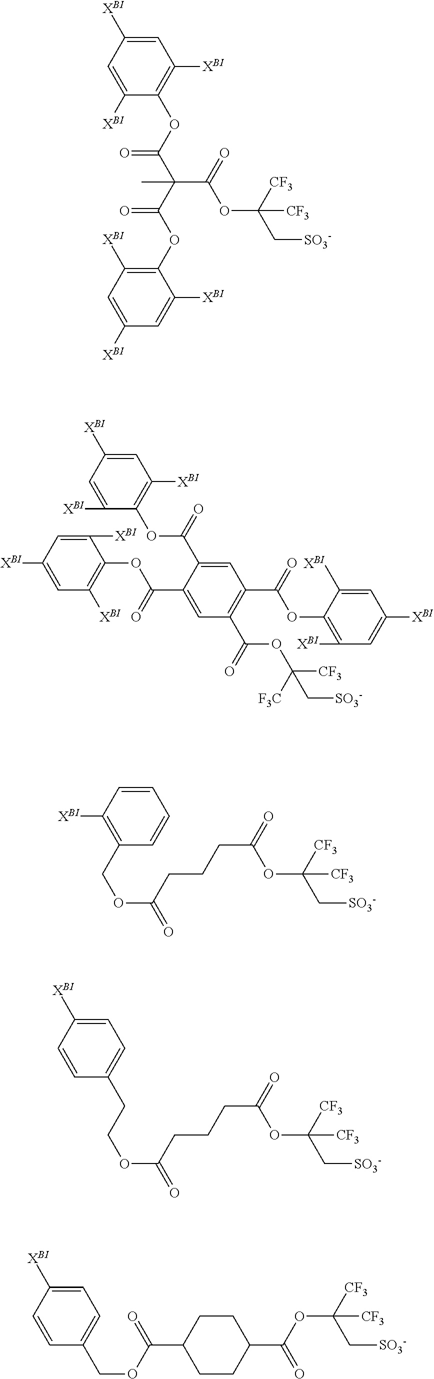

Other examples of the anion in the PAG having formula (1) include those described in the following patent documents.
WO 2023/157455, paragraphs [0076] and [0106]
WO 2024/24801, paragraph [0111]
WO 2024/43121, paragraphs [0253]-[0256]
WO 2024/57751, paragraphs [0044]-[0045]
WO 2024/122423, paragraphs [0205]-[0220]
JP-A 2023-123183, paragraphs [0170]-[0178]
JP-A 2024-062406, paragraphs [0026]-[0028]
JP-A 2024-062407, paragraphs [0022]-[0025]
JP-A 2024-062408, paragraphs [0026]-[0028]
JP-A 2024-068156, paragraphs [0028]-[0030]
JP-A 2024-068157, paragraphs [0026]-[0028]
JP-A 2024-068158, paragraphs [0028]-[0030]
JP-A 2024-068159, paragraphs [0028]-[0030]
JP-A 2024-072280, paragraphs [0031]-[0033]
JP-A 2024-072281, paragraphs [0023]-[0025]
JP-A 2024-077618, paragraphs [0026]-[0029]
JP-A 2024-077619, paragraphs [0020]-[0021]
JP-A 2024-080672, paragraphs [0140]-[0143]
JP-A 2024-083303, paragraphs [0023]-[0025]
JP-A 2024-083304, paragraphs [0028]-[0031]
JP-A 2024-099500, paragraphs [0030]-[0033]
JP-A 2024-099502, paragraphs [0028]-[0030]
JP-A 2024-101557, paragraphs [0030]-[0032]
JP-A 2024-102842, paragraphs [0025]-[0027]
JP-A 2024-102843, paragraphs [0033]-[0035]
JP-A 2024-127832, paragraphs [0021]-[0022]
JP-A 2024-144354, paragraphs [0169]-[0172]
JP-A 2024-144356, paragraphs [0178]-[0181]
JP-A 2024-160436, paragraphs [0040]-[0143]
JP 7247732, paragraphs [0157]-[0158]
JP 7446352, paragraphs [0227]-[0238]
JP 7466597, paragraphs [0253]-[0256]
JP 7466782, paragraphs [0309]-[0312]

In formula (1), Z⁺ is an onium cation, preferably a sulfonium cation having the formula (Z-1) or iodonium cation having the formula (Z-2).

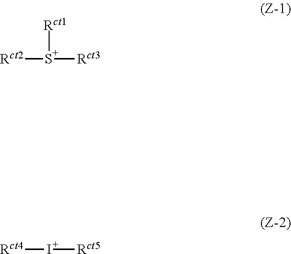

In formulae (Z-1) and (Z-2), R^{ct1} to R^{ct5} are each independently halogen or a C₁-C₃₀ hydrocarbyl group which may contain a heteroatom. Suitable halogen atoms include fluorine, chlorine, bromine and iodine. The hydrocarbyl group may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl; C₃-C₃₀ cyclic saturated hydrocarbyl groups such as cyclopropyl, cyclopentyl, cyclohexyl, cyclopropylmethyl, 4-methylcyclohexyl, cyclohexylmethyl, norbornyl, adamantyl; C₂-C₃₀ alkenyl groups such as vinyl, 1-propenyl, 2-propenyl, butenyl, hexenyl; C₃-C₃₀ cyclic unsaturated hydrocarbyl groups such as cyclohexenyl; C₆-C₃₀ aryl groups such as phenyl, naphthyl, thienyl; C₇-C₃₀ aralkyl groups such as benzyl, 1-phenylethyl, 2-phenylethyl, and combinations thereof. Inter alia, the aryl groups are preferred. In the hydrocarbyl groups, some or all hydrogen may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, pentafluorosulfanyl, carbonyl, ether bond, ester bond, sulfonate ester bond, carbonate bond, lactone ring, sultone ring, carboxylic anhydride (—C(═O)—O—C(═O)—) or haloalkyl moiety.

Also, R^{ct1} and R^{ct2} may bond together to form a ring with the sulfur atom to which they are attached. Exemplary structures of the ring are shown below.

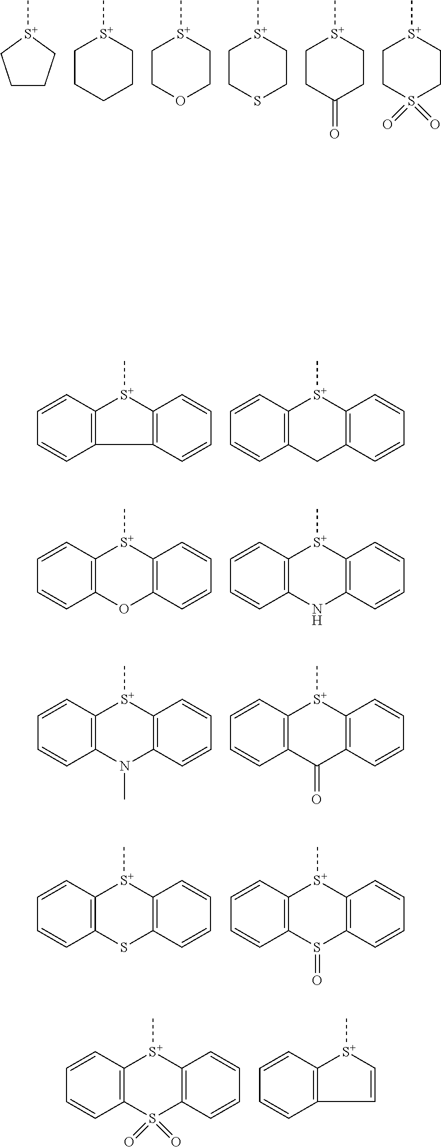

The broken line designates a point of attachment to R^{ct3}.

Non-limiting examples of the sulfonium cation having formula (Z-1) include those described in JP-A 2024-003744, paragraphs [0102]-[0125] and JP-A 2023-169812, paragraphs [0070]-[0085].

Non-limiting examples of the iodonium cation having formula (Z-2) include those described in JP-A 2024-000259, paragraph [0181].

A sulfonium cation having the formula (Z-3) is also preferred.

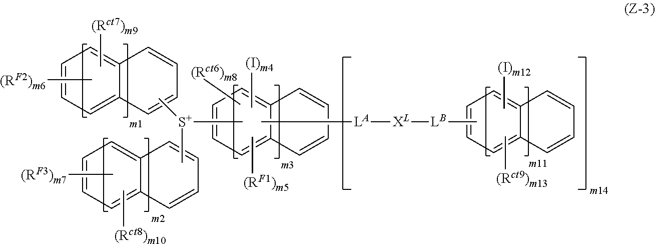

In formula (Z-3), m1 is 0 or 1. The relevant structure is a benzene ring when m1=0 and a naphthalene ring when m1=1. From the aspect of solvent solubility, the benzene ring corresponding to m1=0 is preferred. The subscript m2 is 0 or 1. The relevant structure is a benzene ring when m2=0 and a naphthalene ring when m2=1. From the aspect of solvent solubility, the benzene ring corresponding to m2=0 is preferred. The subscript m3 is 0 or 1. The relevant structure is a benzene ring when m3=0 and a naphthalene ring when m3=1. From the aspect of solvent solubility, the benzene ring corresponding to m3=0 is preferred.

In formula (Z-3), m4 is 0, 1, 2, 3 or 4. Since a cation structure containing more iodine atoms is more absorptive to EUV, but loses solvent solubility so that it may precipitate in a resist composition, it is preferred that m4 be 0, 1, 2 or 3, more preferably 0, 1 or 2.

In formula (Z-3), m5 is 0, 1, 2, 3 or 4. It is preferred from the aspect of reactant availability that m5 be 0, 1, 2 or 3, more preferably 0, 1 or 2. The subscript m6 is 0, 1, 2, 3, 4, 5 or 6. It is preferred from the aspect of reactant availability that m6 be 0, 1, 2 or 3, more preferably 0, 1 or 2. The subscript m7 is 0, 1, 2, 3, 4, 5 or 6. It is preferred from the aspect of reactant availability that m7 be 0, 1, 2 or 3, more preferably 0, 1 or 2.

In formula (Z-3), m8 is 0, 1 or 2. It is preferred from the aspect of reactant availability that m8 be 0 or 1. The subscript m9 is 0, 1 or 2. It is preferred from the aspect of reactant availability that m9 be 0 or 1. The subscript m10 is 0, 1 or 2. It is preferred from the aspect of reactant availability that m10 be 0 or 1.

In formula (Z-3), m11 is 0 or 1. The relevant structure is a benzene ring when m11=0 and a naphthalene ring when m11=1. From the aspect of solvent solubility, the benzene ring corresponding to m11=0 is preferred.

In formula (Z-3), m12 is 0, 1, 2, 3 or 4. Since a cation structure containing more iodine atoms is more absorptive to EUV, but loses solvent solubility so that it may precipitate in a resist composition, it is preferred that m12 be 0, 1, 2 or 3, more preferably 0, 1 or 2.

In formula (Z-3), m13 is 0, 1 or 2. It is preferred from the aspect of reactant availability that m13 be 0 or 1. The subscript m14 is 0, 1 or 2. It is preferred from the aspect of synthesis that m14 be 0 or 1.

The subscripts m1 to m13 are in the range: 0≤m6+m9≤4 when m1=0, and 0≤m6+m9≤6 when m1=1; 0≤m7+m10≤4 when m2=0, and 0≤m7+m10≤6 when m2=1; 1≤m4+m5+m8+m14≤4 when m3=0, and 1≤m4+m5+m8+m14≤6 when m3=1; 0≤m12+f13≤4 when m11=0, and 0≤m12+m13≤6 when m11=1; and m4+m12≥1.

In formula (Z-3), R^{F1} to R^{F3} are each independently fluorine, a C₁-C₆ fluorinated saturated hydrocarbyl group, C₁-C₆ fluorinated saturated hydrocarbyloxy group, or C₁-C₆ fluorinated saturated hydrocarbylthio group. Of these, trifluoromethyl, trifluoromethoxy, and trifluorothiomethoxy are preferred. A plurality of R^{F1} may be identical or different when m5 is 2, 3 or 4, a plurality of R^{F2} may be identical or different when m6 is 2, 3, 4, 5 or 6, and a plurality of R^{F3} may be identical or different when m7 is 2, 3, 4, 5 or 6.

In formula (Z-3), R^{ct6} to R^{ct9} are each independently halogen exclusive of iodine and fluorine, nitro, cyano, a C₁-C₂₀ hydrocarbyl group which may contain a heteroatom, C₁-C₂₀ hydrocarbyloxy group which may contain a heteroatom, or C₁-C₂₀ hydrocarbylthio group which may contain a heteroatom. The hydrocarbyl group and hydrocarbyl moiety in the hydrocarbyloxy and hydrocarbylthio groups may be saturated or unsaturated and straight, branched or cyclic. Examples thereof are as exemplified above for the hydrocarbyl group R¹ and R² in formula (a1). In the hydrocarbyl group and hydrocarbyl moiety in the hydrocarbyloxy and hydrocarbylthio groups, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy moiety, cyano moiety, fluorine, chlorine, bromine, iodine, carbonyl moiety, ether bond, ester bond, sulfonate ester bond, carbonate bond, lactone ring, sultone ring, carboxylic anhydride (—C(═O)—O—C(═O)—) or haloalkyl moiety.

When m8=2, two R^{ct6} may be identical or different and two R^{ct6} may bond together to form a ring with the carbon atoms to which they are attached. When m9=2, two R^{ct7} may be identical or different and two R^{ct7} may bond together to form a ring with the carbon atoms to which they are attached. When m10=2, two R^{ct8} may be identical or different and two R^{ct8} may bond together to form a ring with the carbon atoms to which they are attached. When m13=2, two R^{ct9} may be identical or different and two R^{ct9} may bond together to form a ring with the carbon atoms to which they are attached. Examples of the ring thus formed include cyclopropane, cyclobutane, cyclopentane, cyclohexane, norbornane, and adamantane rings. In the ring, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the ring may contain a hydroxy moiety, fluorine, chlorine, bromine, iodine, cyano moiety, carbonyl moiety, ether bond, ester bond, sulfonate ester bond, carbonate bond, lactone ring, sultone ring, carboxylic anhydride (—C(═O)—O—C(═O)—) or haloalkyl moiety.

The aromatic rings directly bonded to S⁺ in the sulfonium cation having formula (Z-3) may bond together to form a ring with S⁺. Exemplary structures of the ring are shown below.

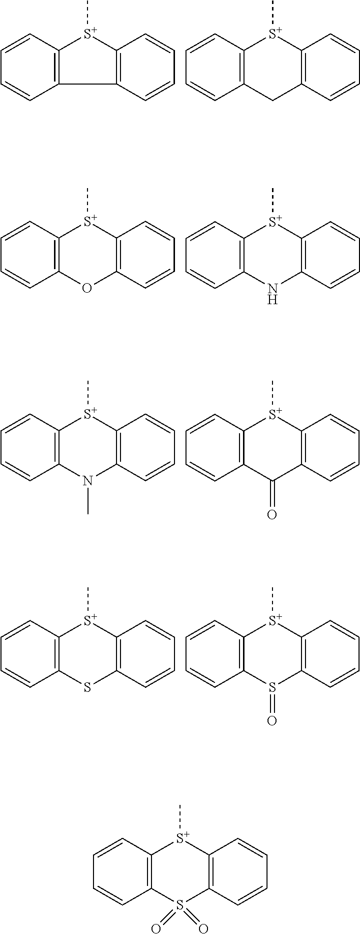

In formula (Z-3), L^{A} and L^{B} are each independently a single bond, ether bond, ester bond, sulfonate ester bond, amide bond, sulfonamide bond, carbonate bond or carbamate bond. L^{A} is preferably a single bond, ether bond, ester bond or sulfonate ester bond, more preferably an ester bond or sulfonate ester bond. L^{B} is preferably a single bond, ether bond or ester bond, more preferably a single bond.

In formula (Z-3), X^{L} is a single bond or a C₁-C₄₀ hydrocarbylene group which may contain a heteroatom. The hydrocarbylene group may be straight, branched or cyclic. Examples thereof include alkanediyl, cyclic saturated hydrocarbylene, and arylene groups. Suitable heteroatoms include oxygen, nitrogen and sulfur.

Examples of the C₁-C₄₀ hydrocarbylene group which may contain a heteroatom, represented by X^{L}, are shown below, but not limited thereto. Herein, * designates a point of attachment to L^{A} or L^{B}.

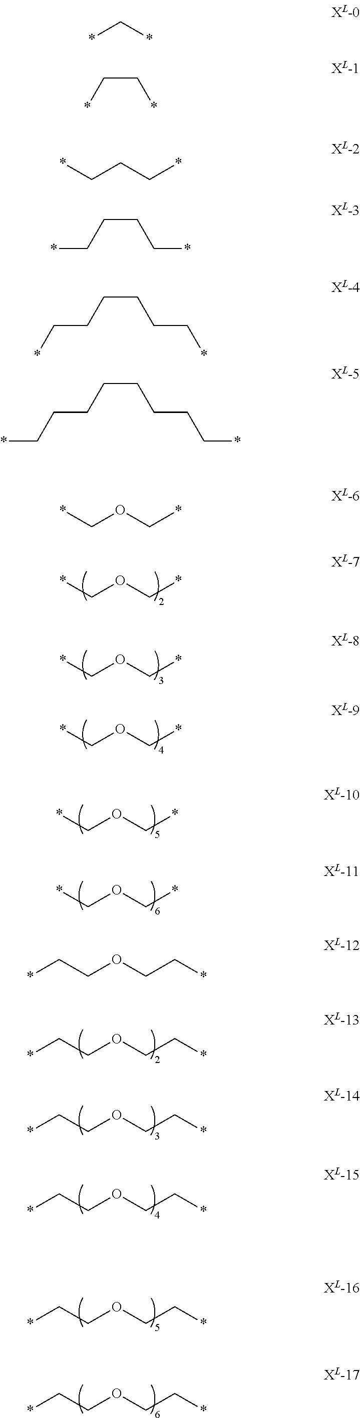

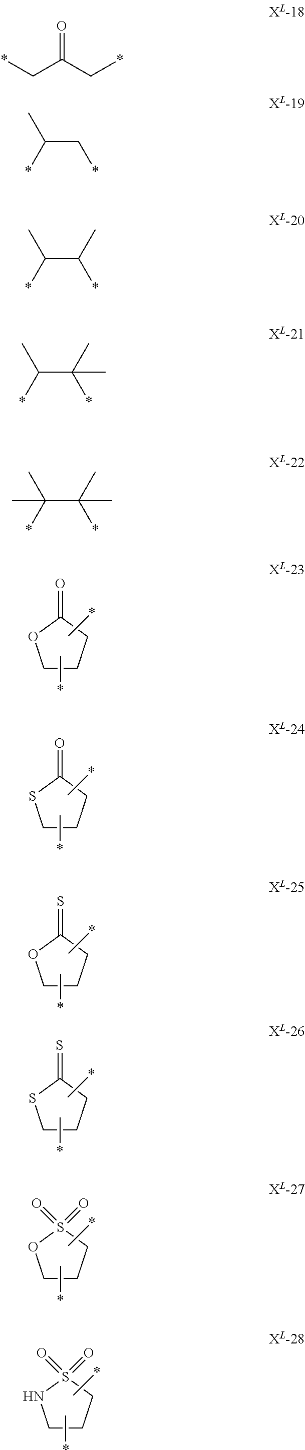

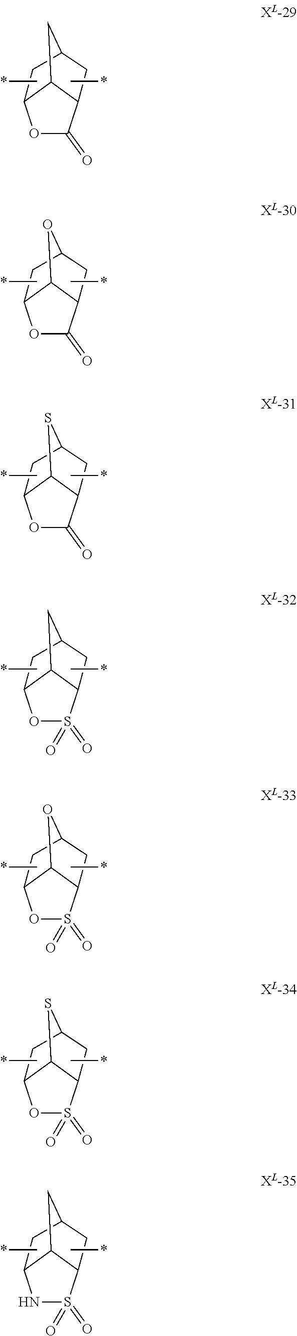

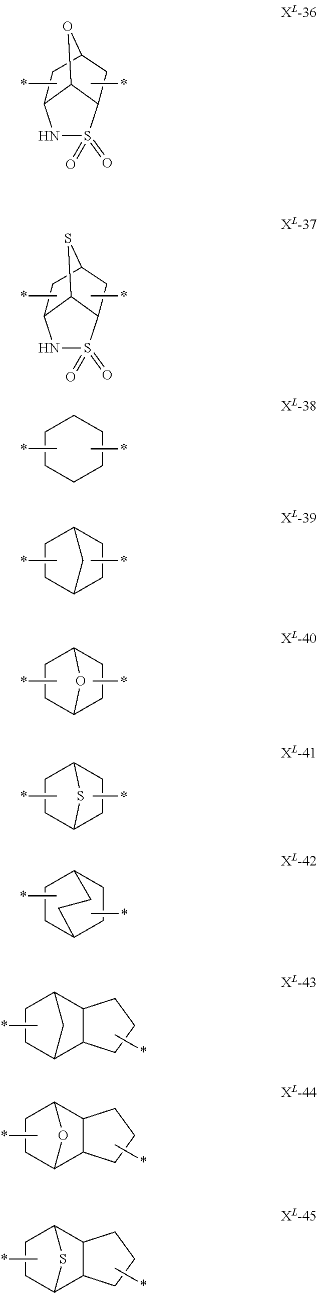

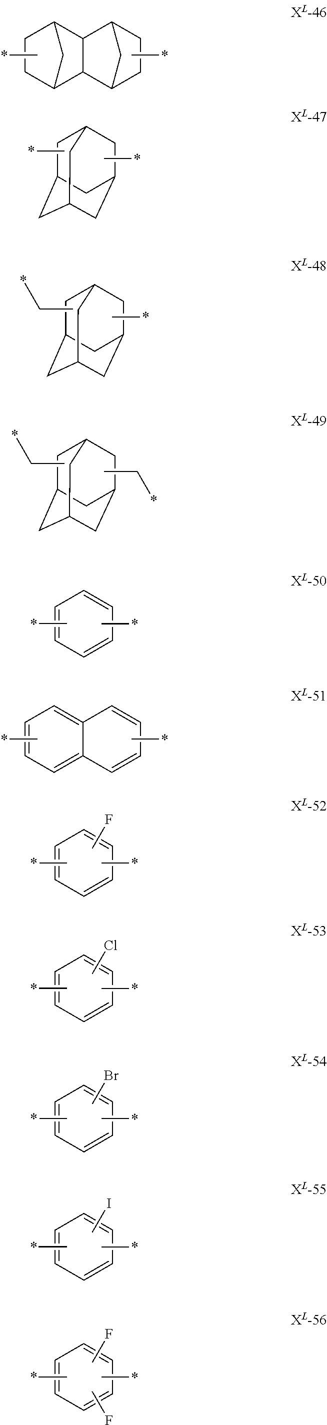

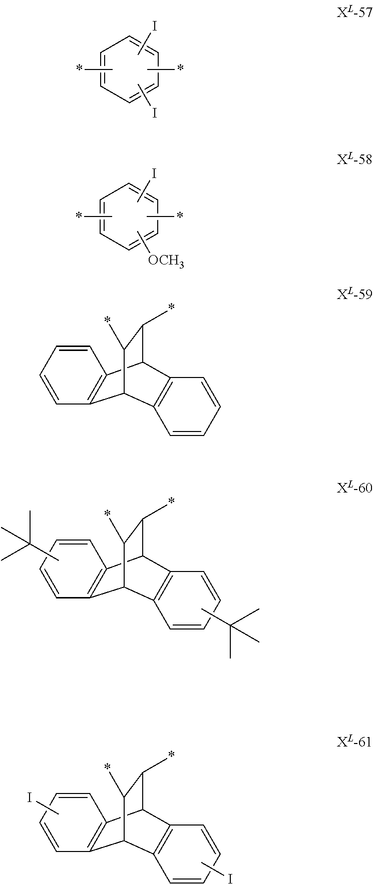

Of these, X^{L}-0 to X^{L}-22 and X^{L}-47 to X^{L}-61 are preferred.

Of the sulfonium cations having formula (Z-3), those having the formula (Z-3-1) are preferred:

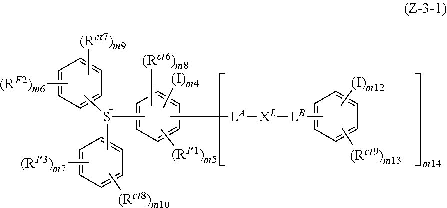

wherein m4 to m10, m12 to m14, R^{F1} to R^{F3}, R^{ct6} to R^{ct9}, L^{A}, L^{B}, and X^{L} are as defined above.

Of the sulfonium cations having formula (Z-3-1), those having the formula (Z-3-2) are more preferred:

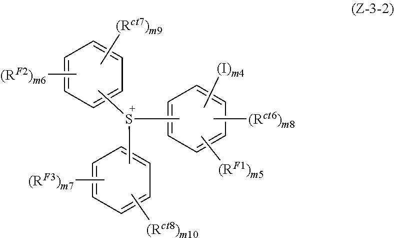

wherein m4 to m10, R^{F1} to R^{F3}, and R^{ct6} to R^{ct8} are as defined above.

Examples of the sulfonium cation having formula (Z-3) are shown below, but not limited thereto.

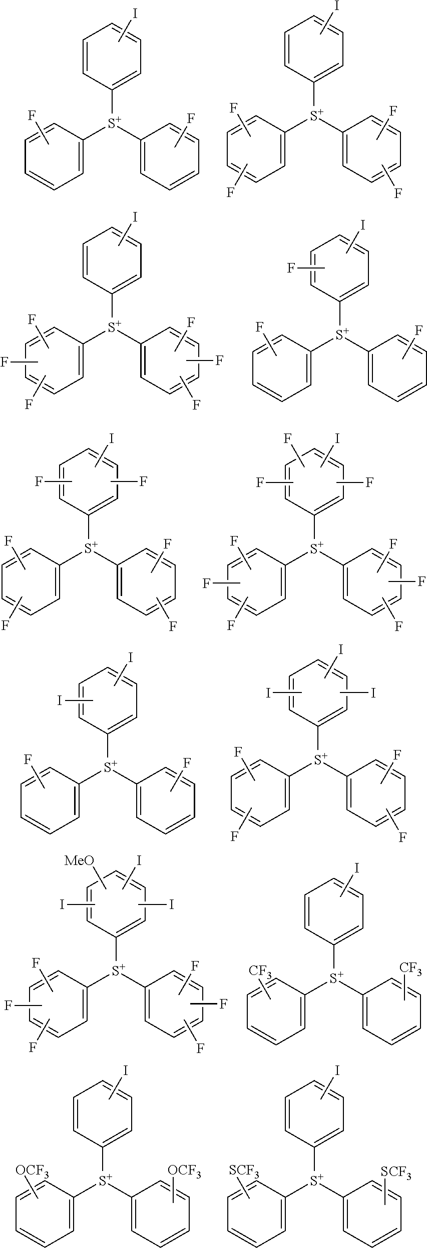

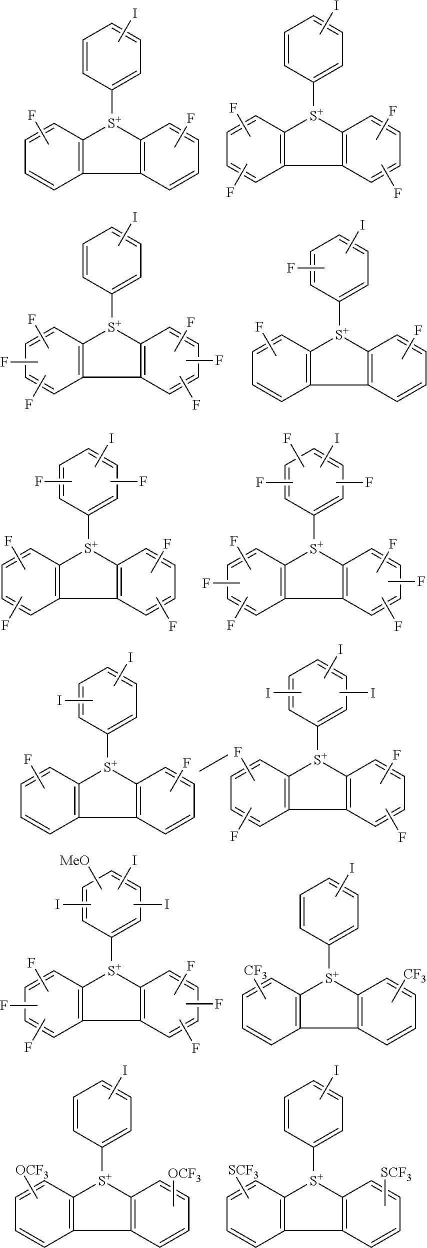

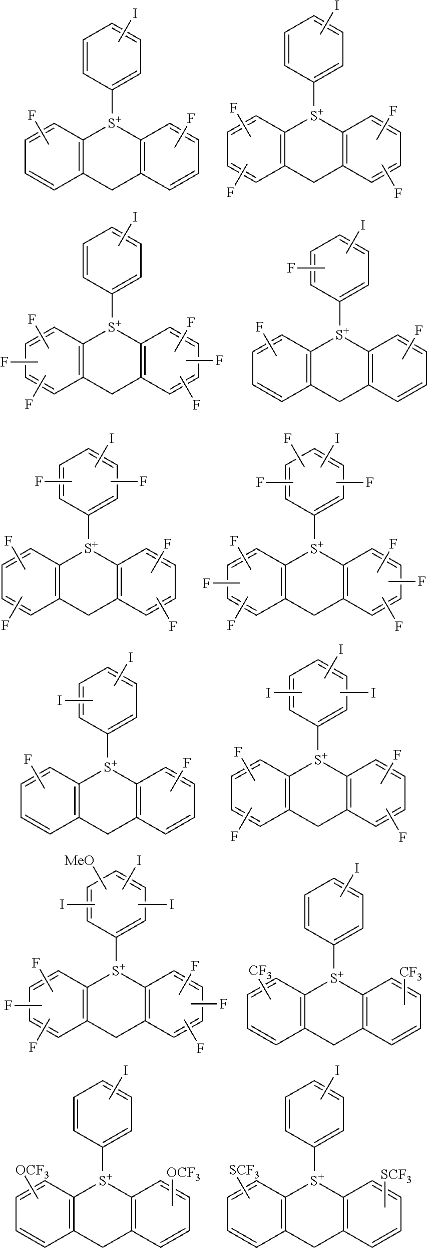

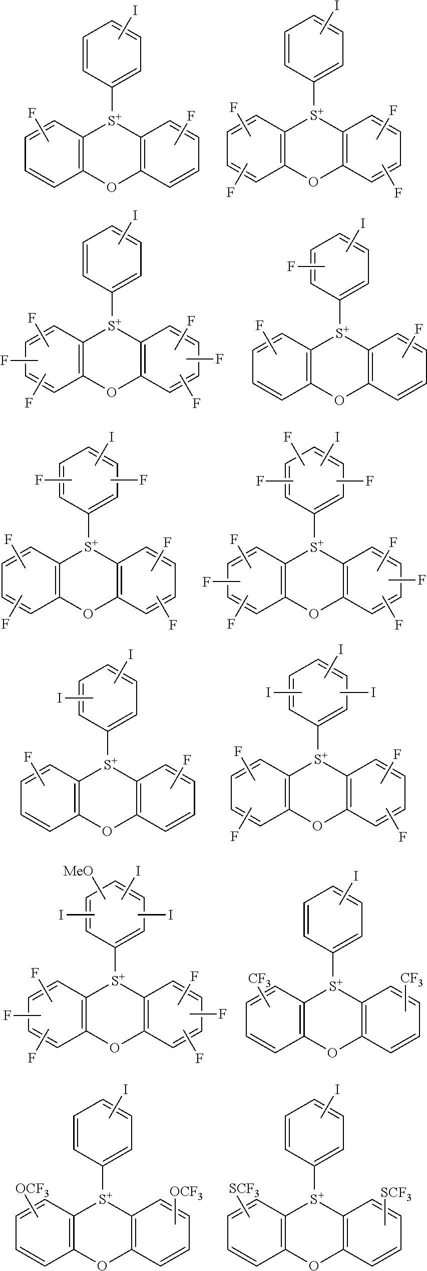

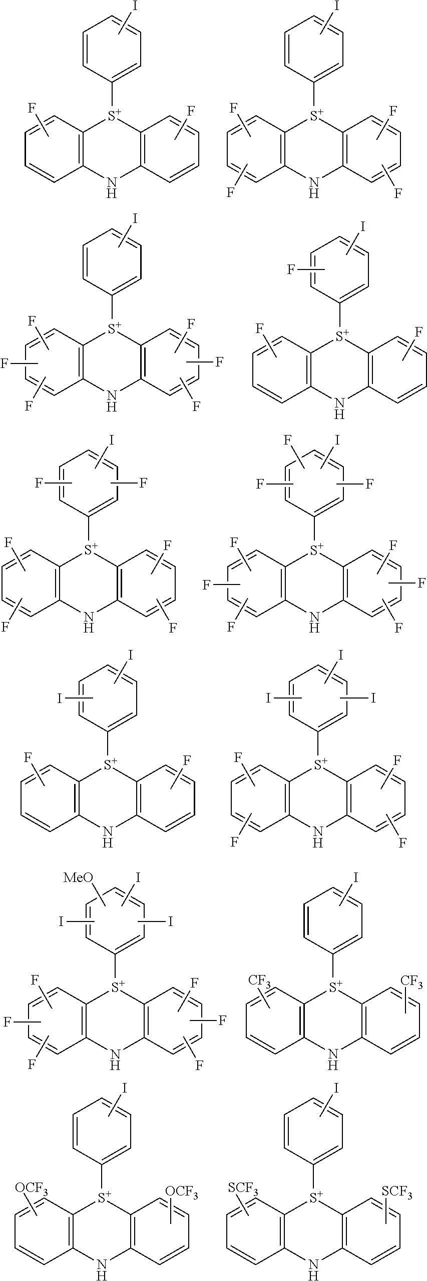

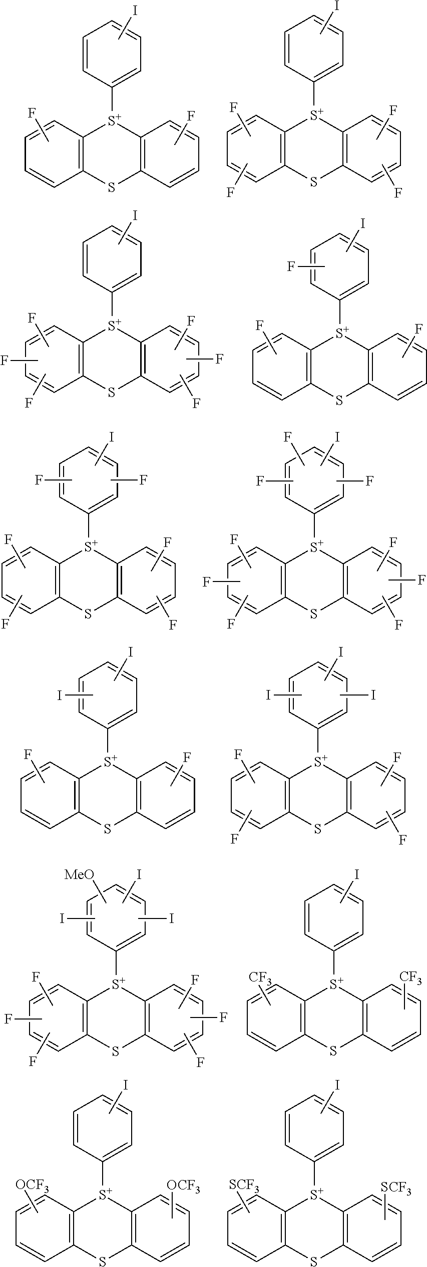

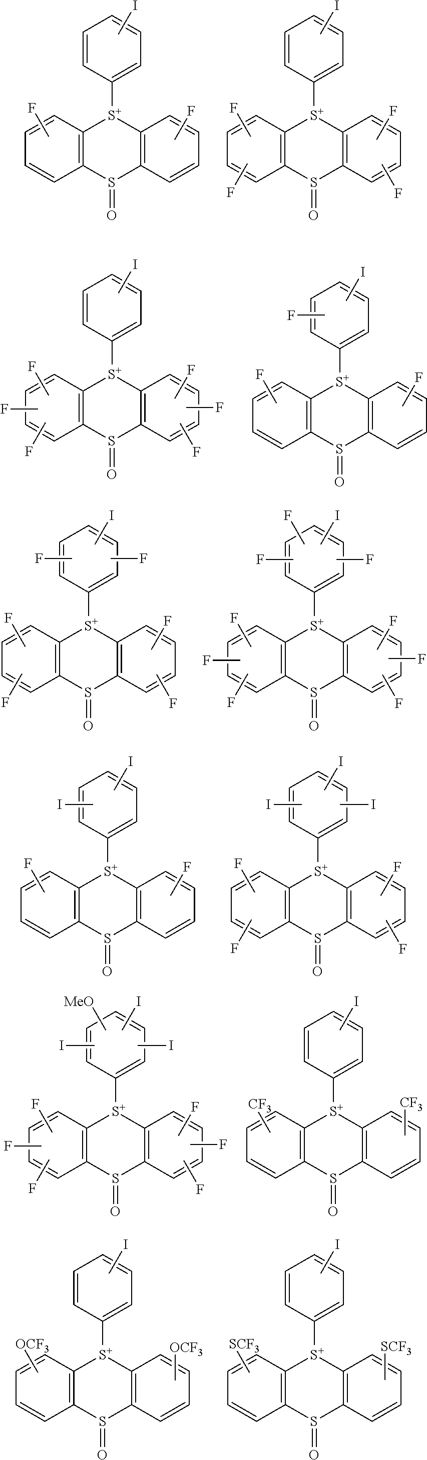

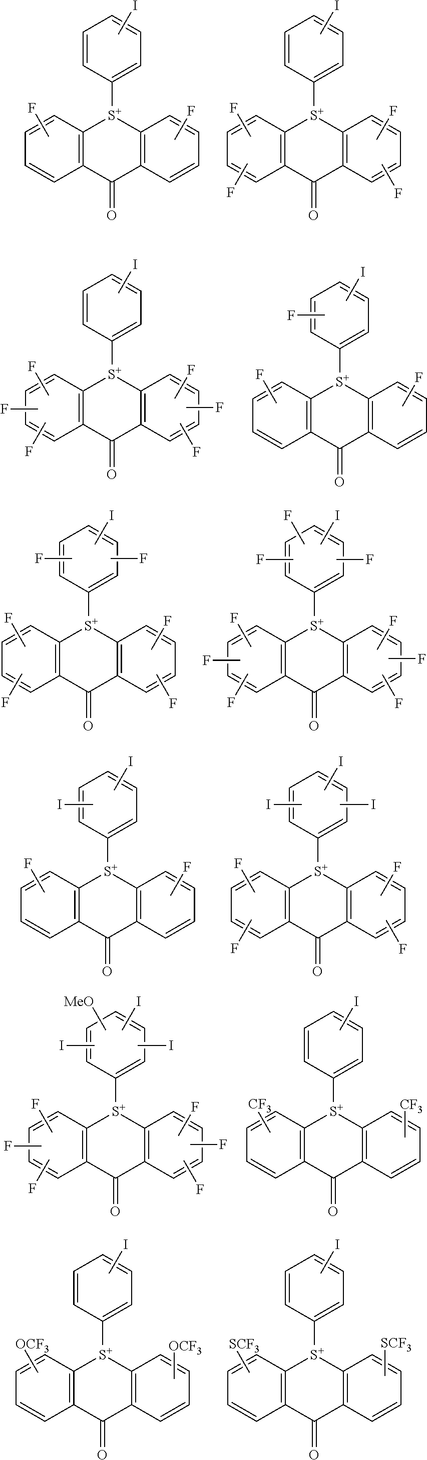

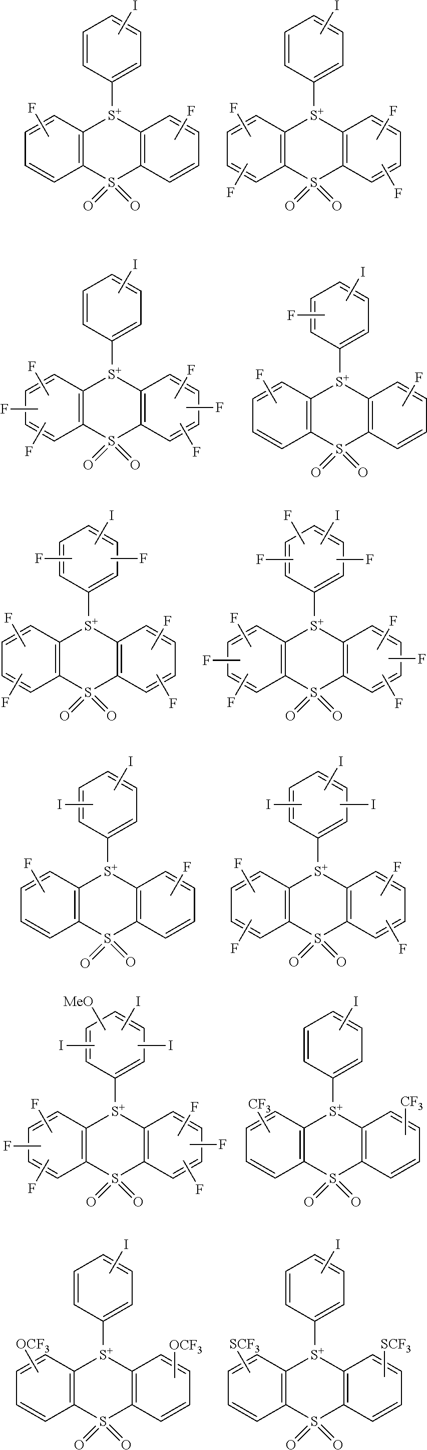

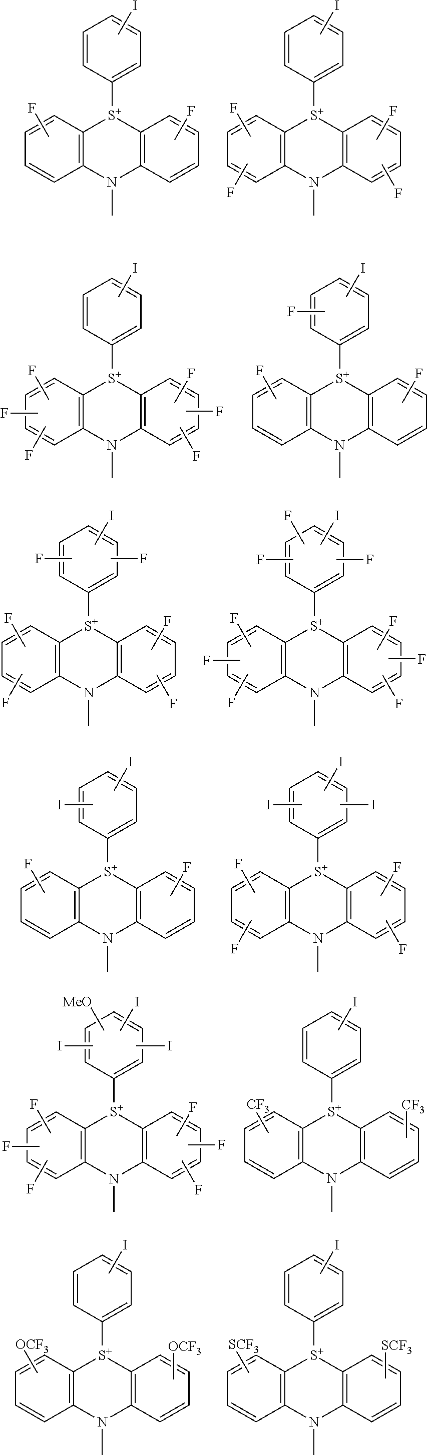

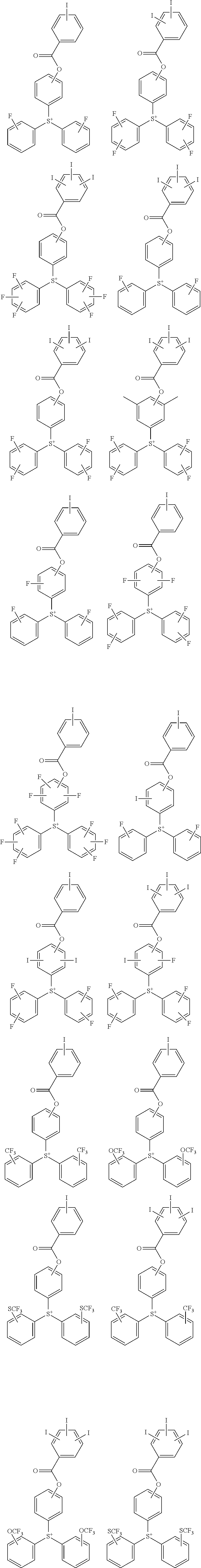

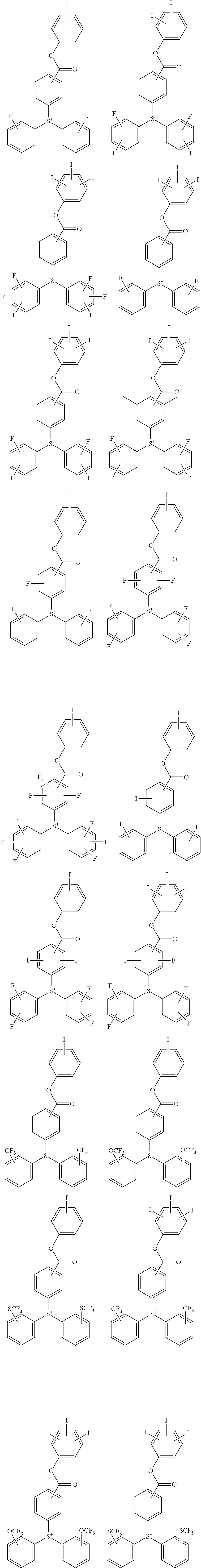

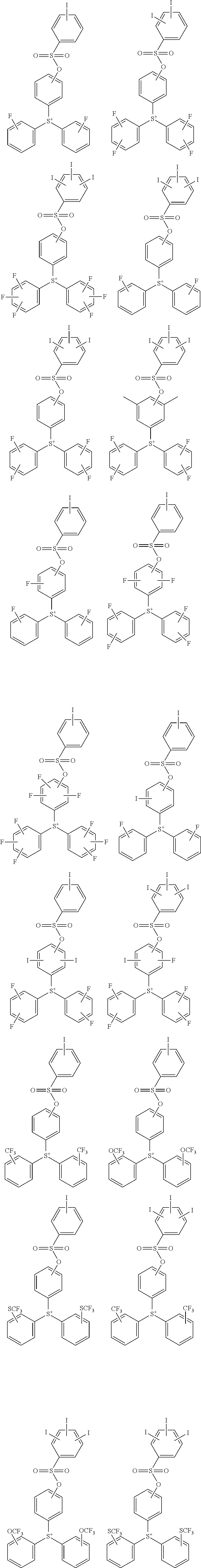

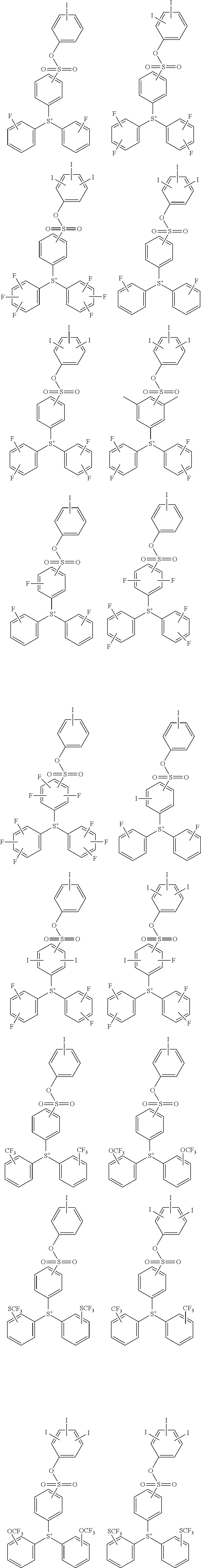

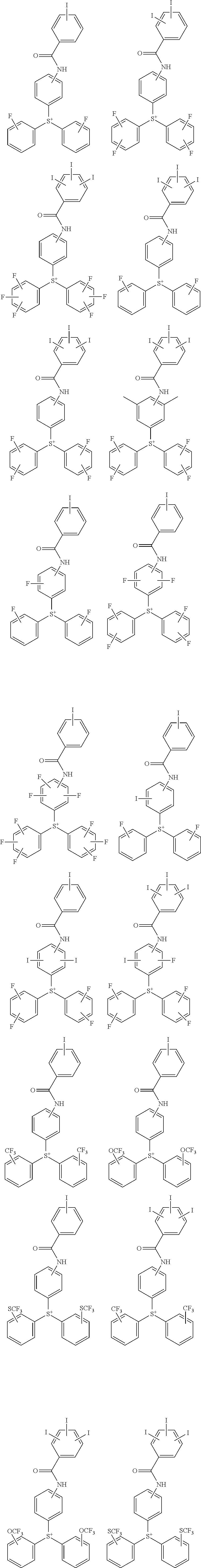

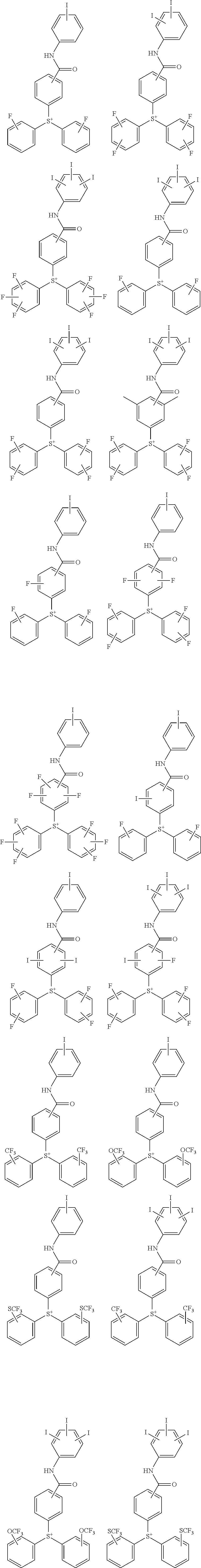

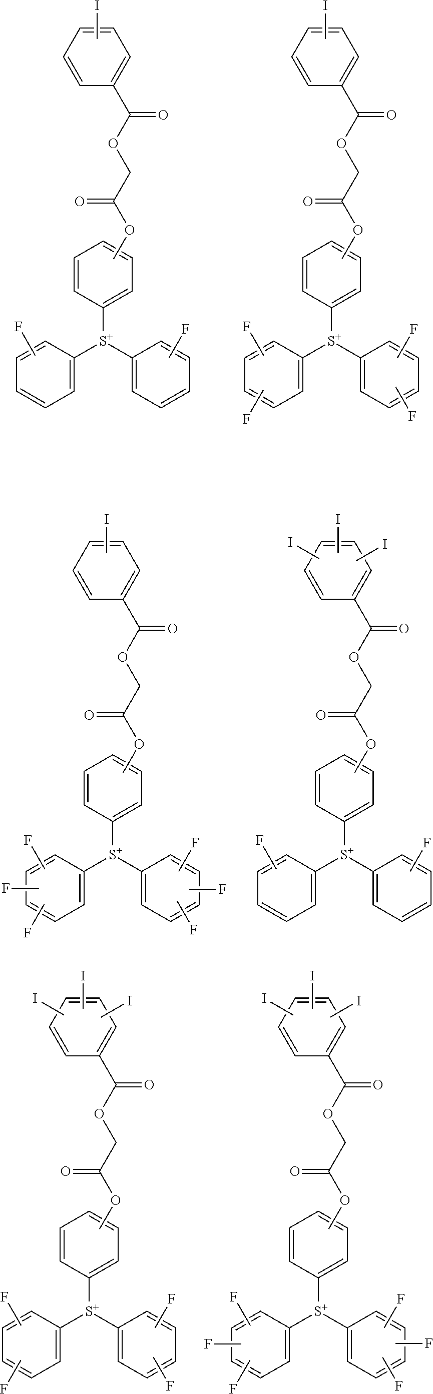

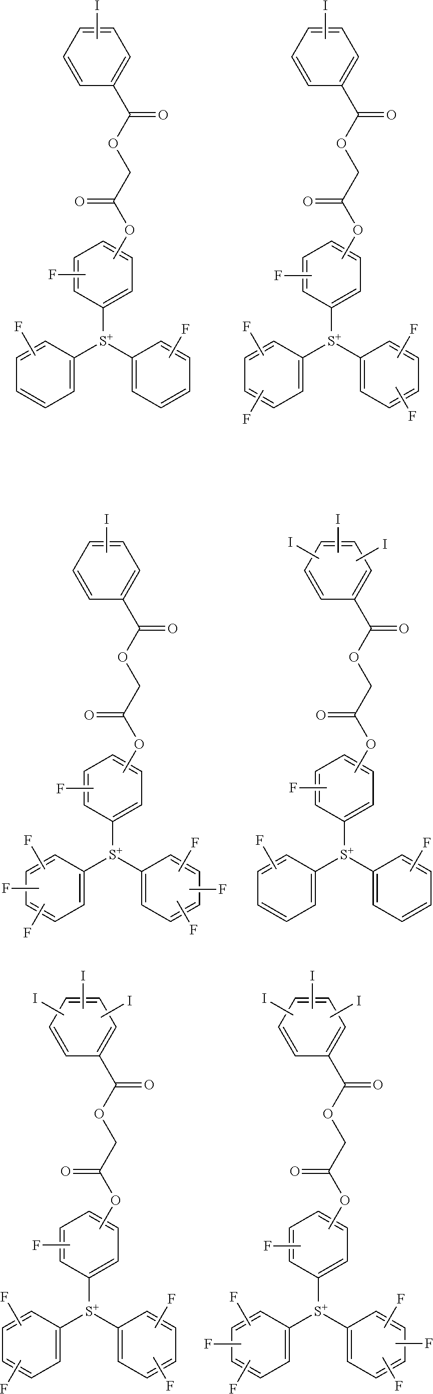

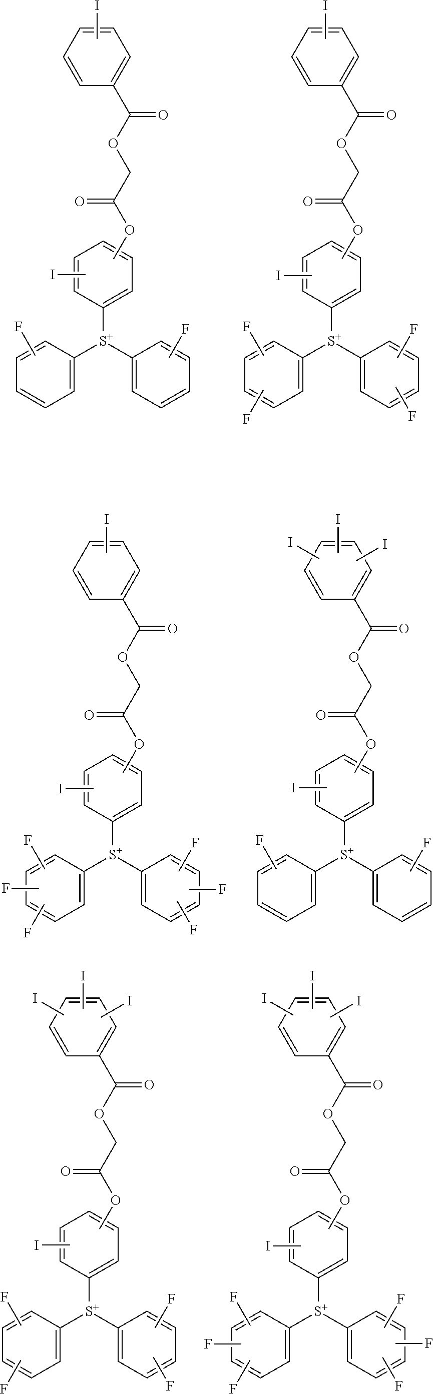

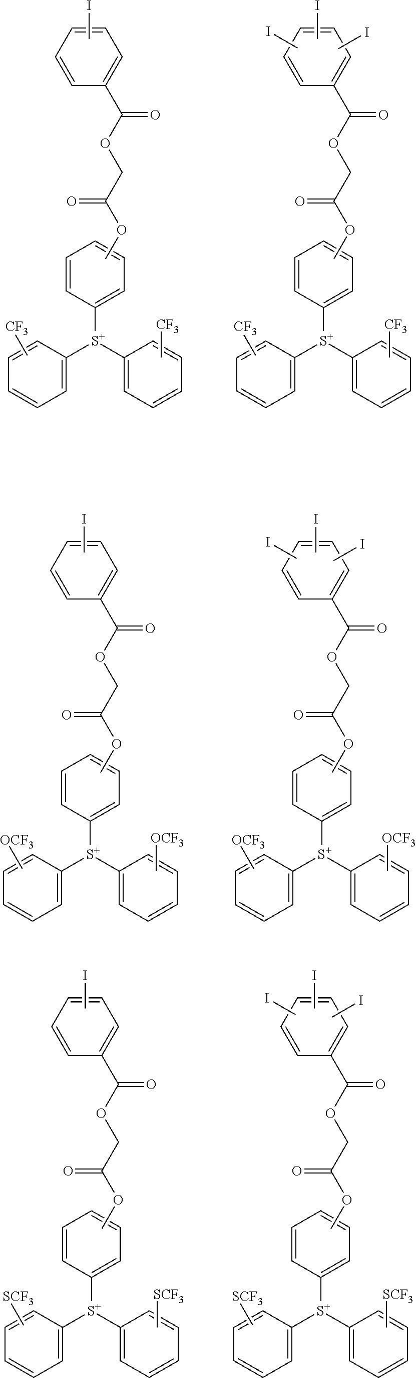

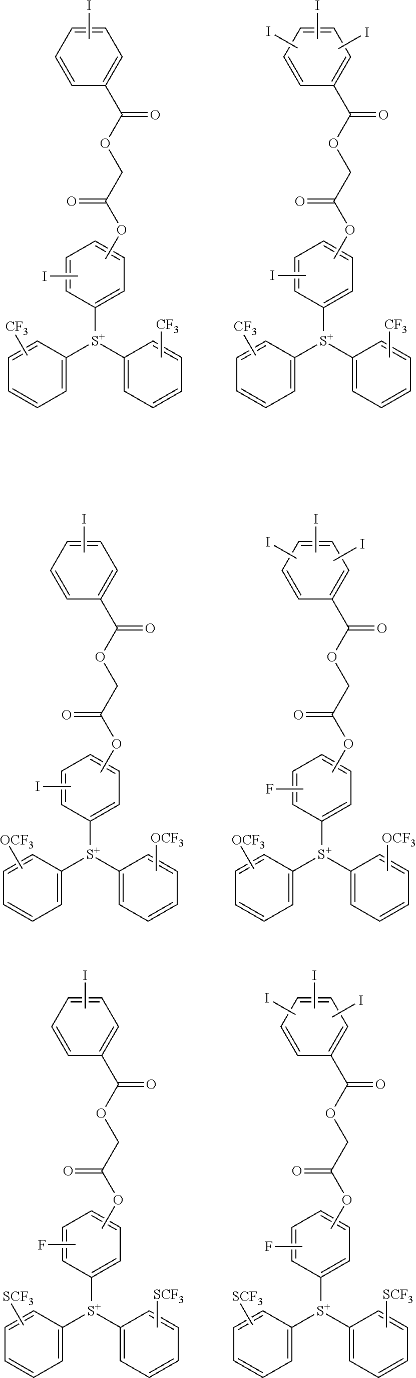

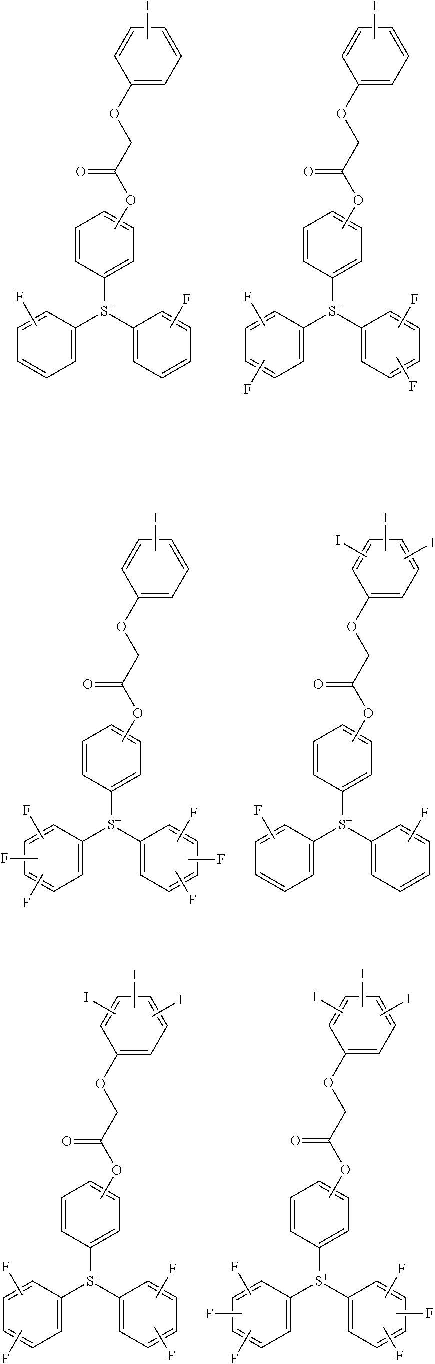

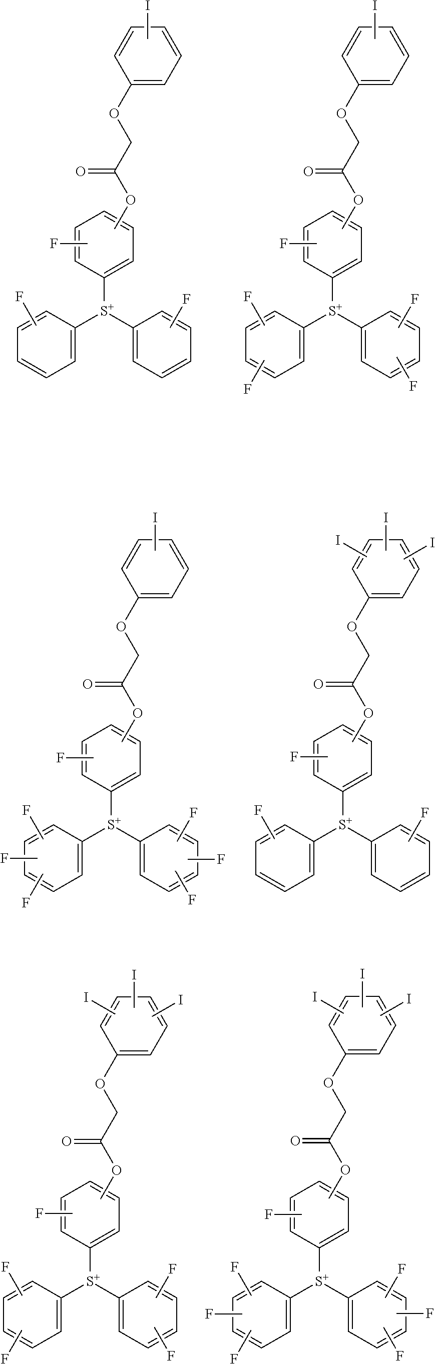

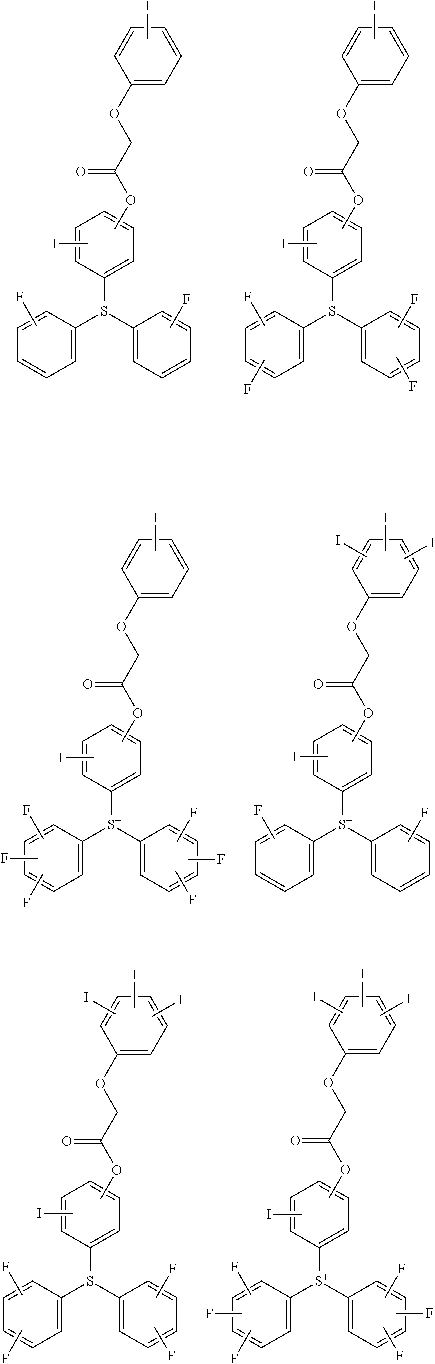

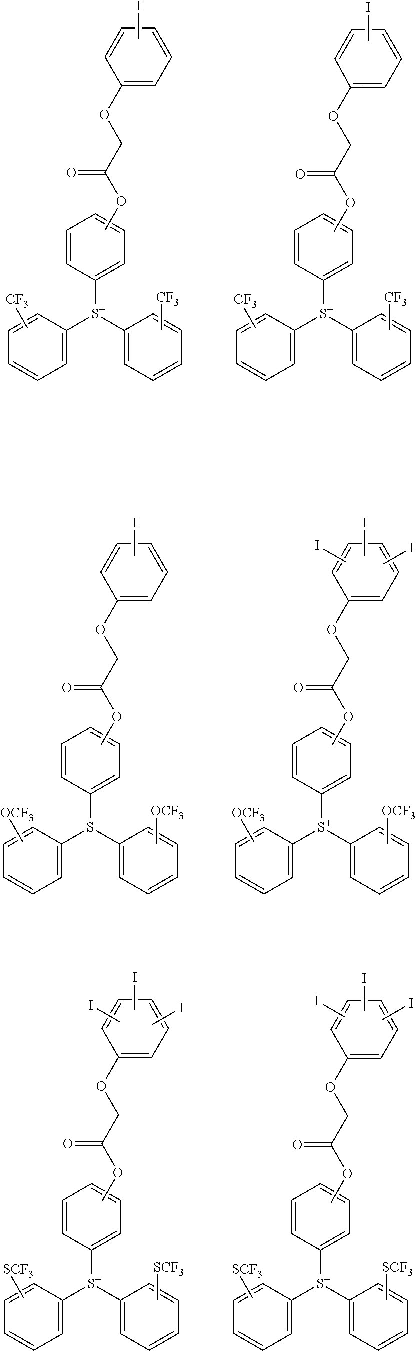

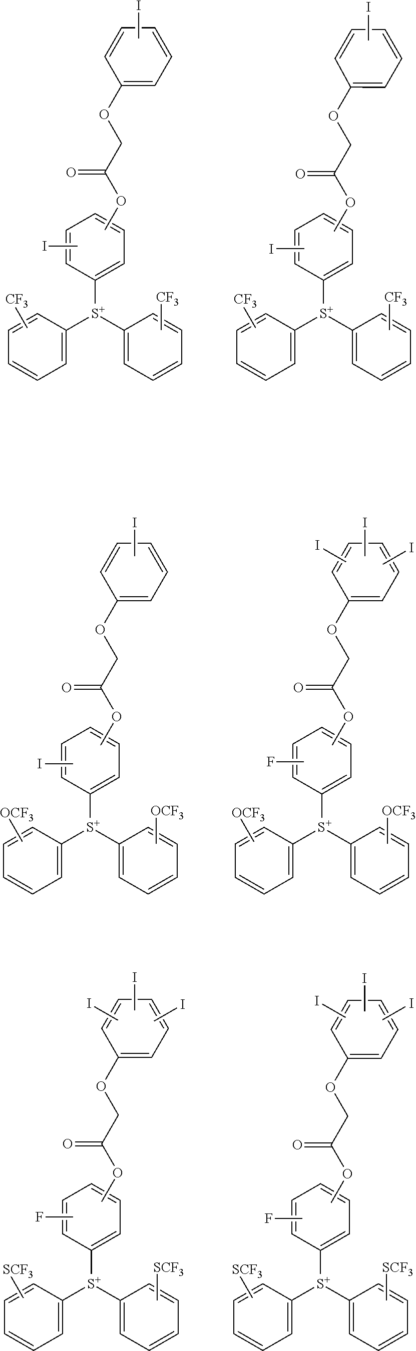

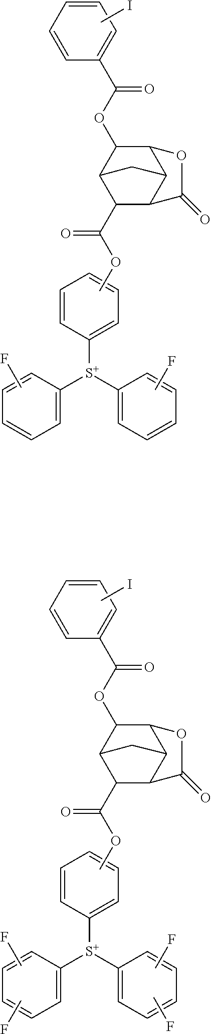

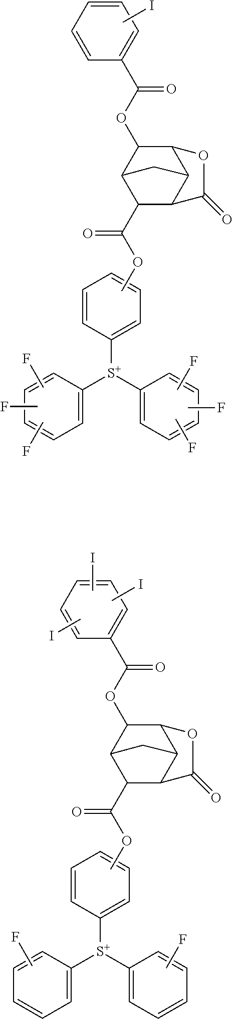

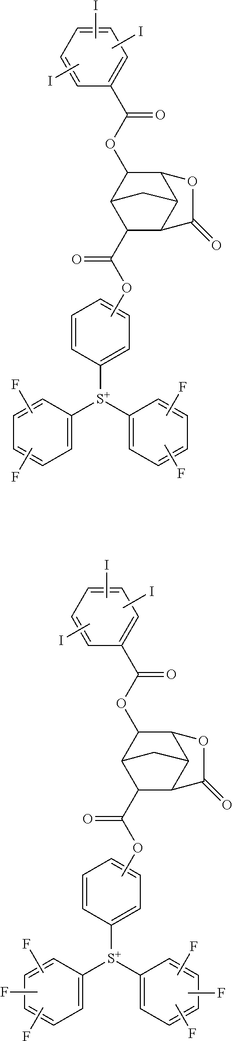

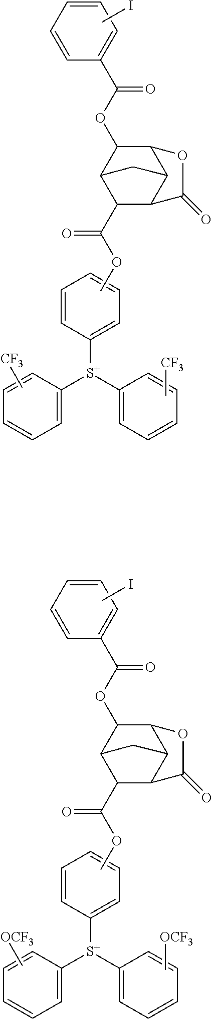

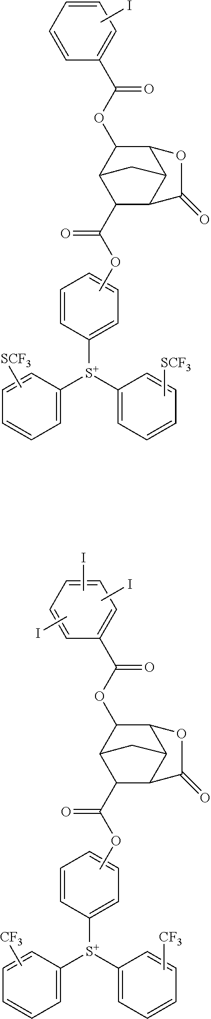

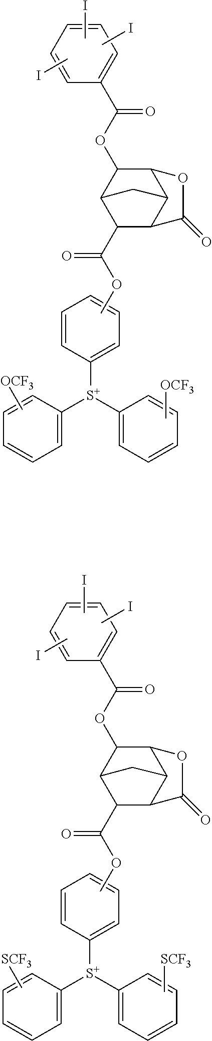

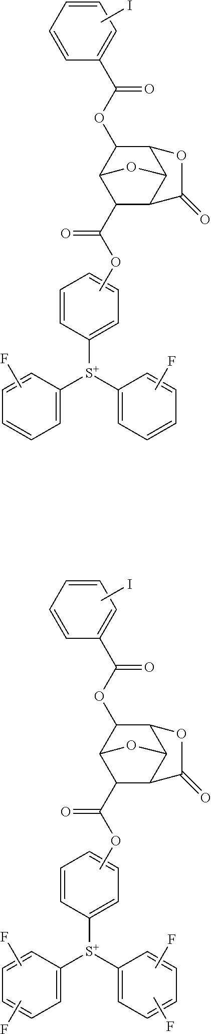

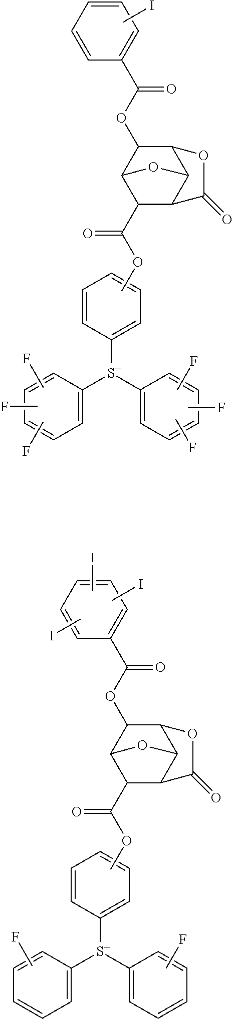

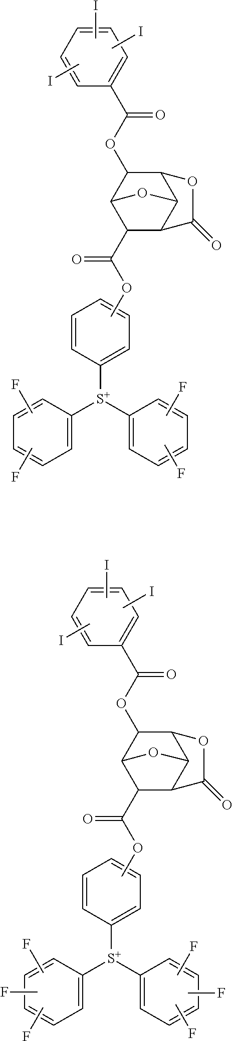

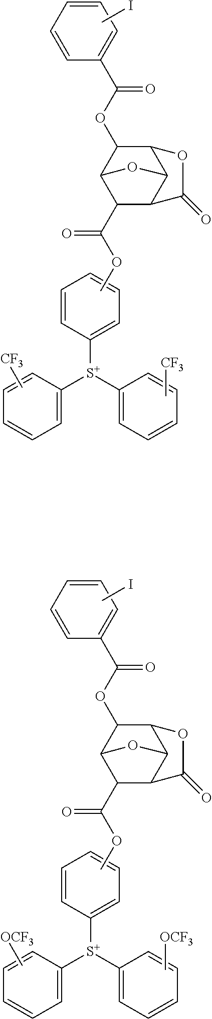

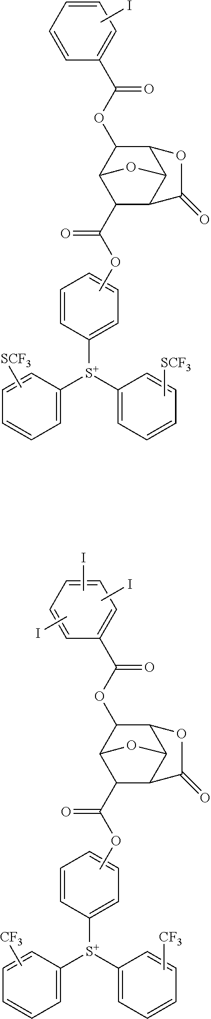

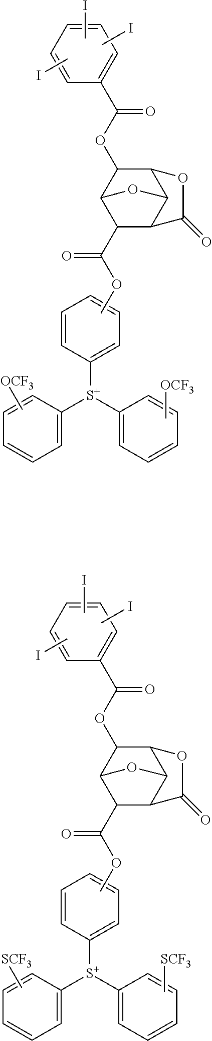

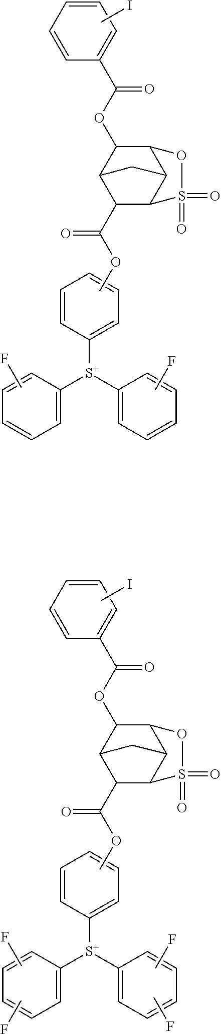

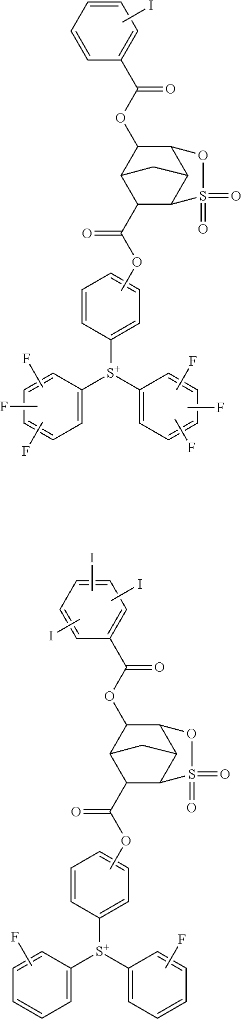

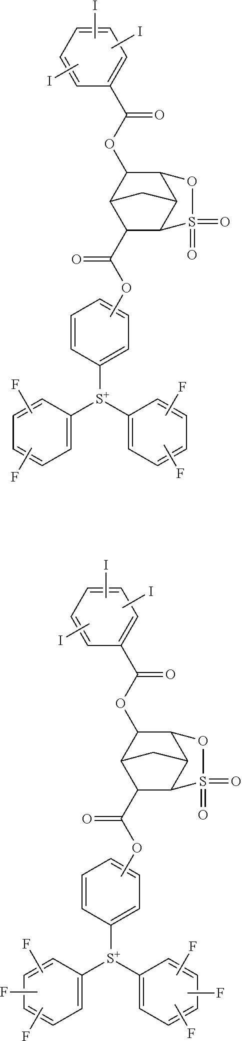

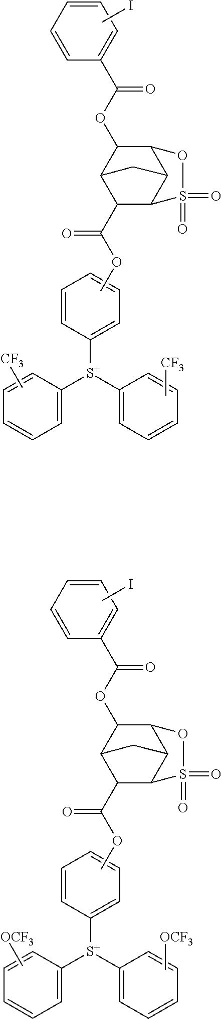

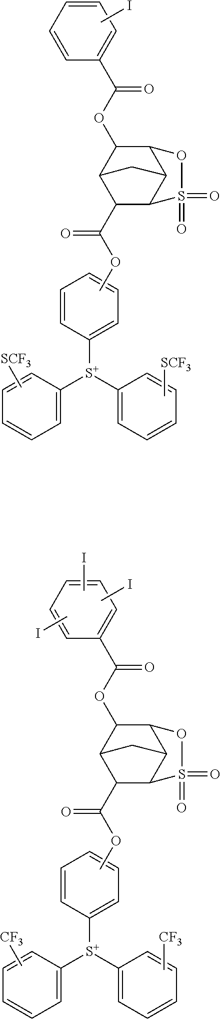

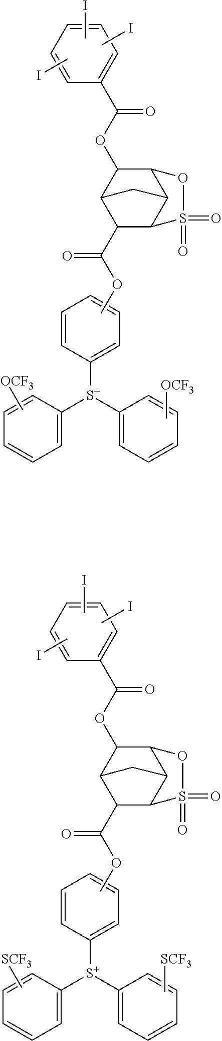

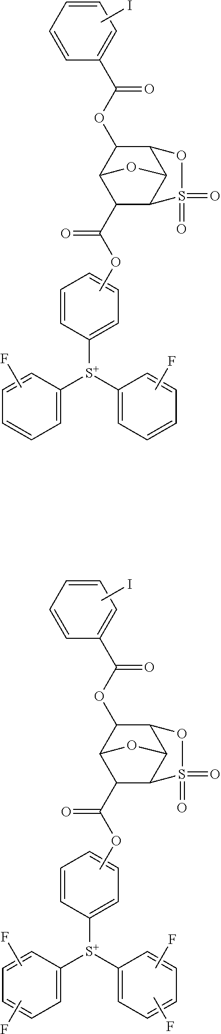

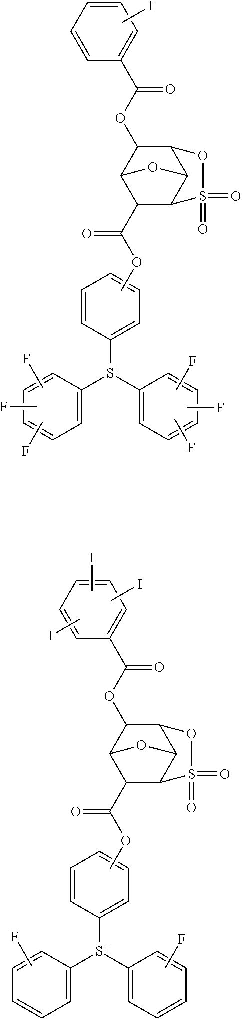

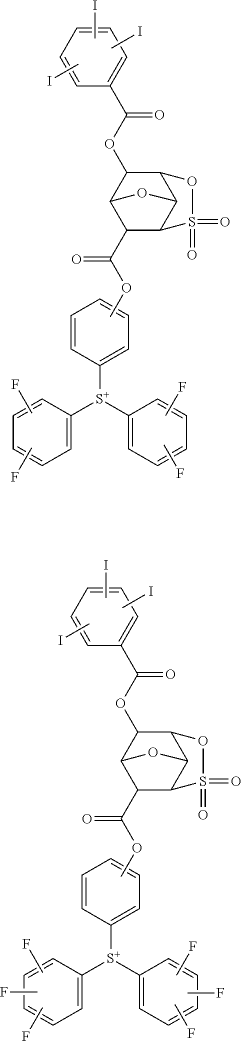

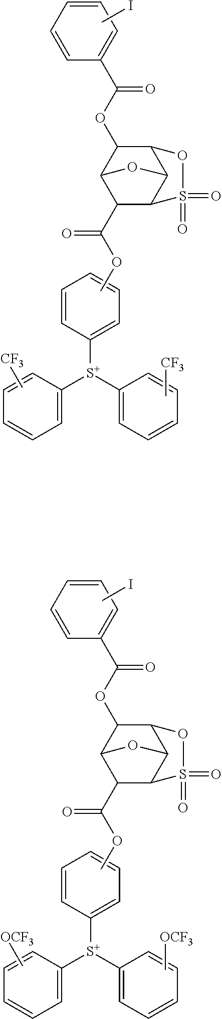

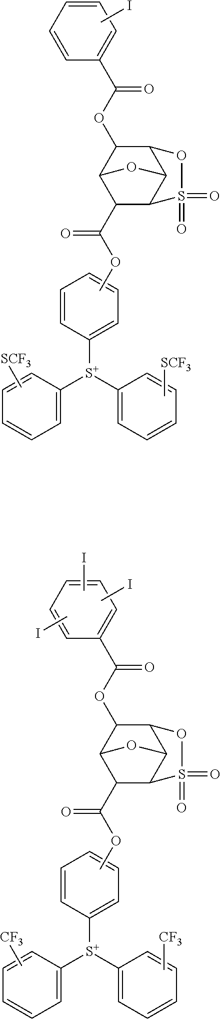

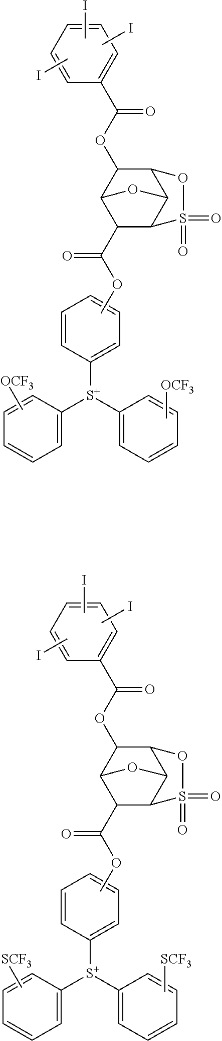

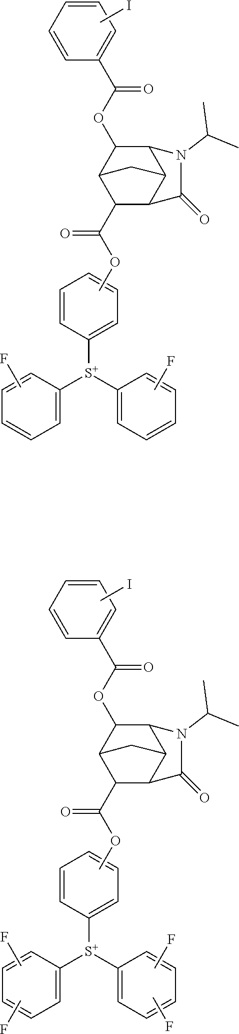

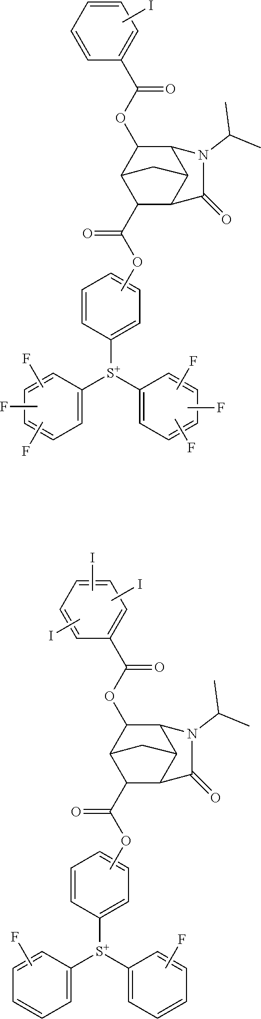

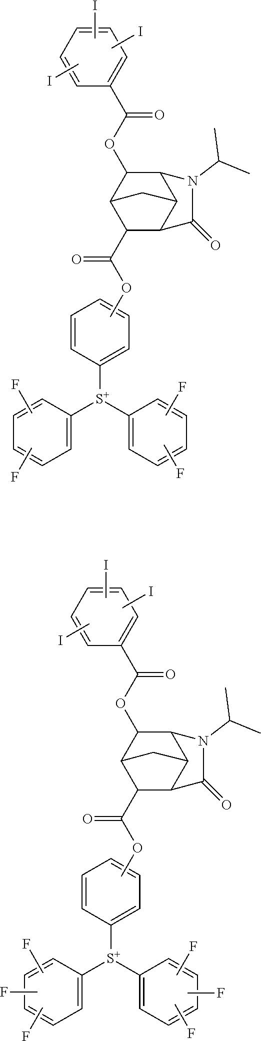

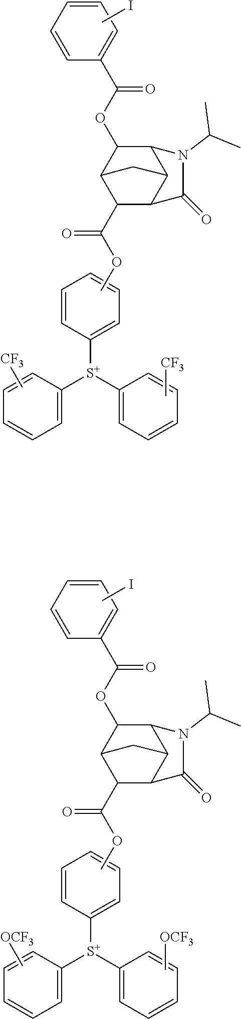

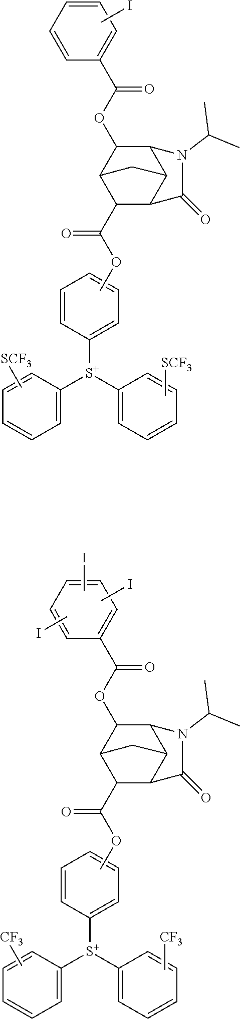

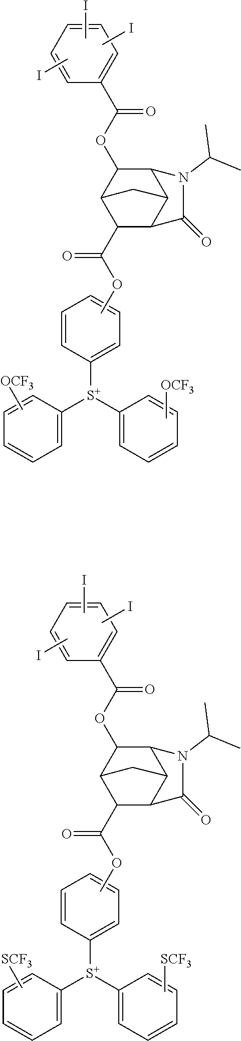

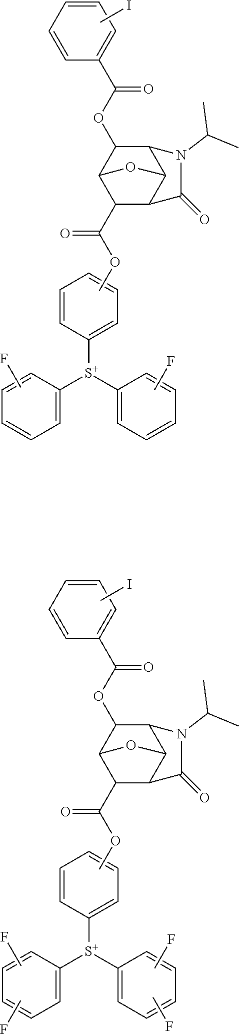

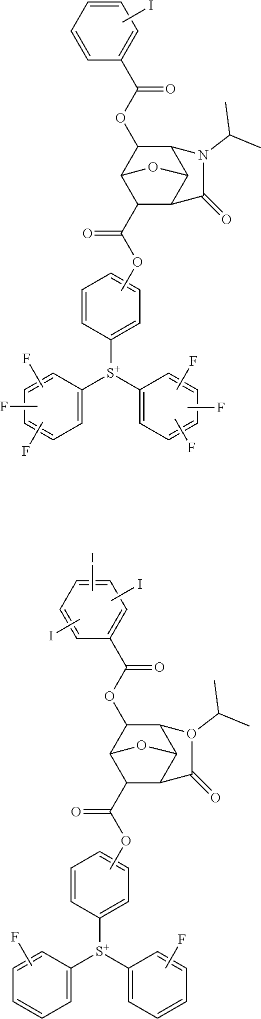

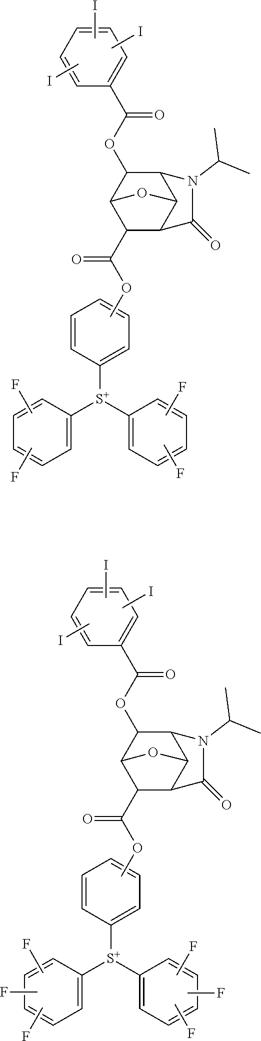

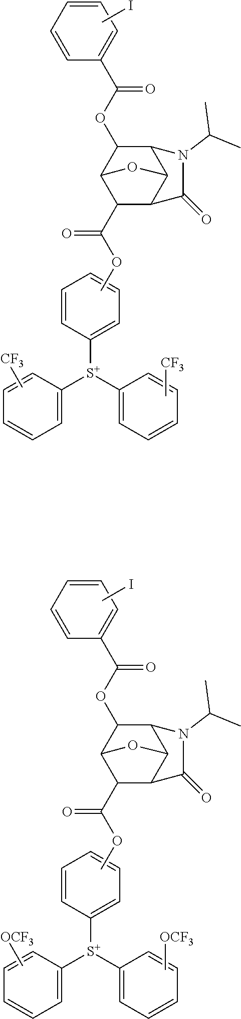

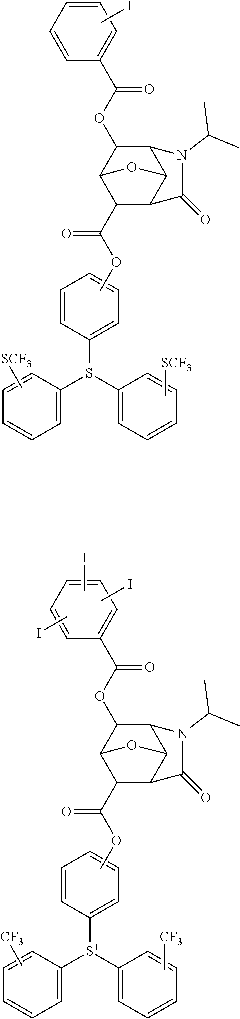

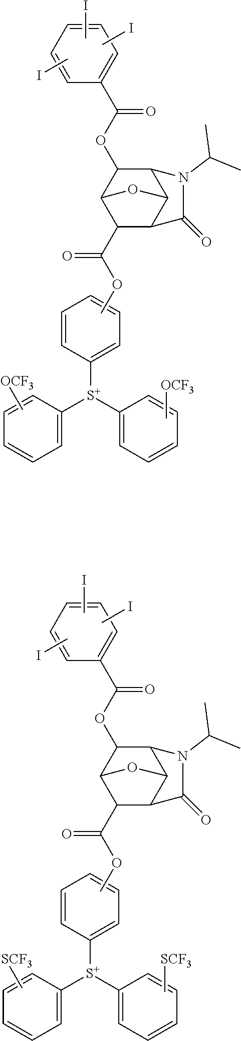

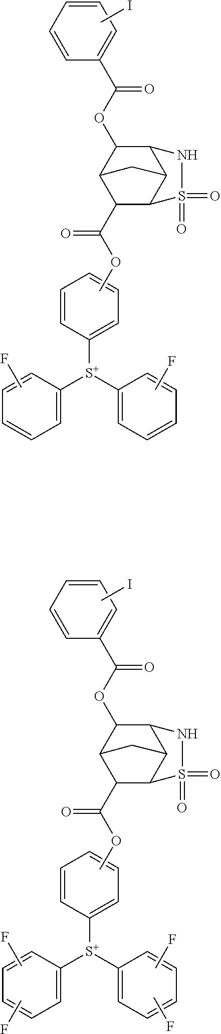

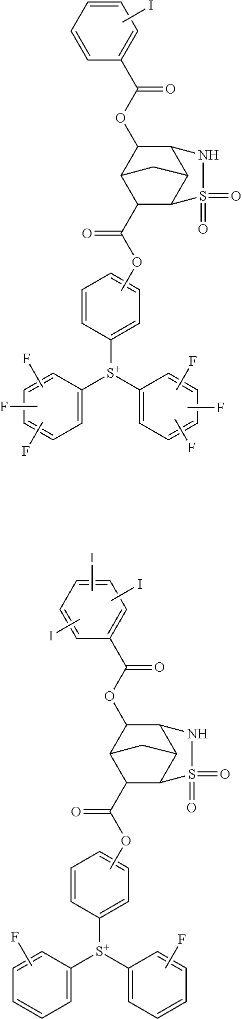

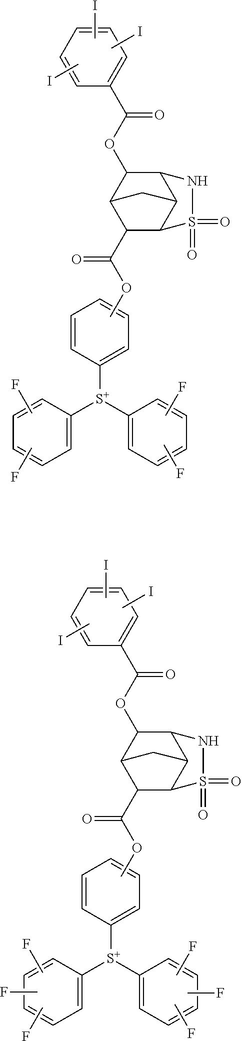

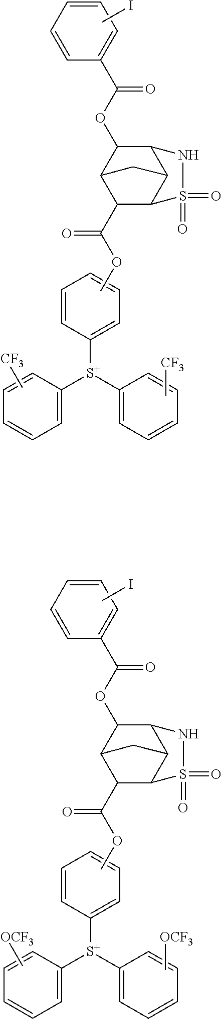

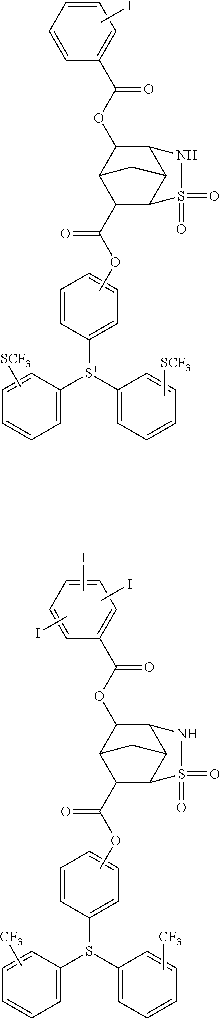

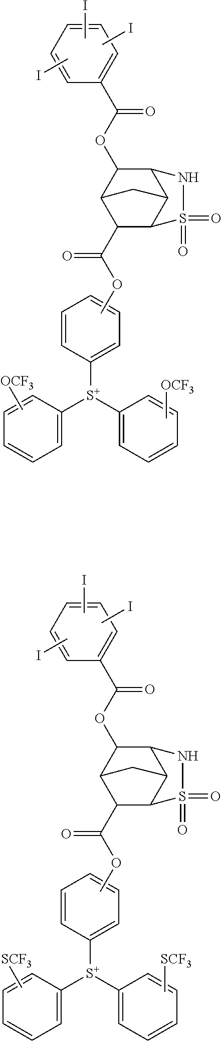

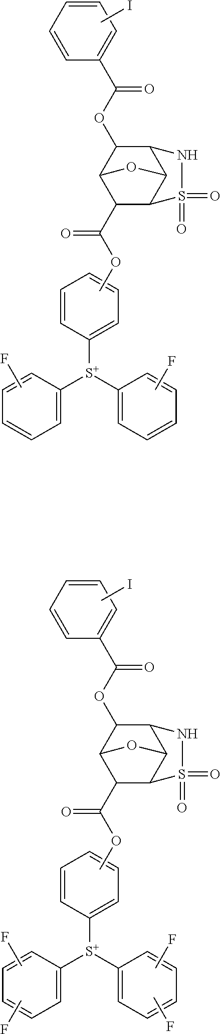

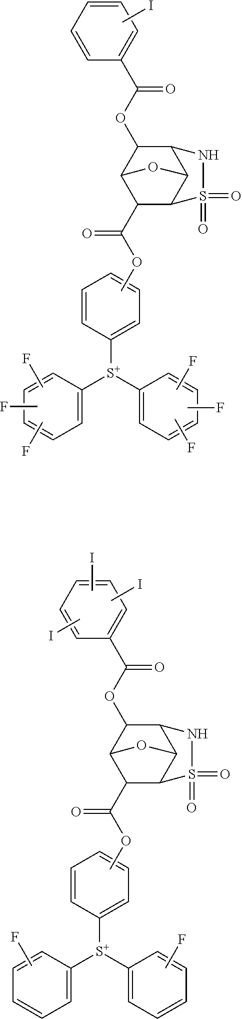

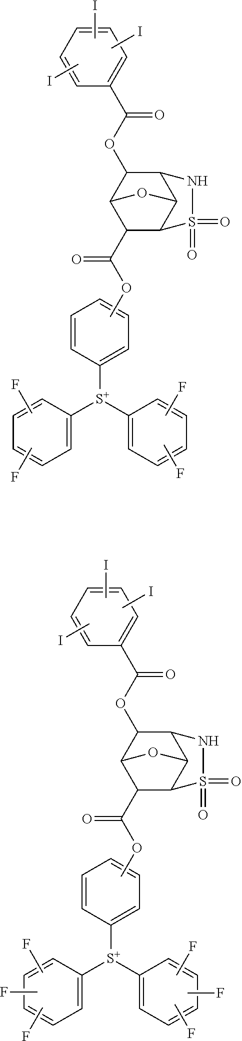

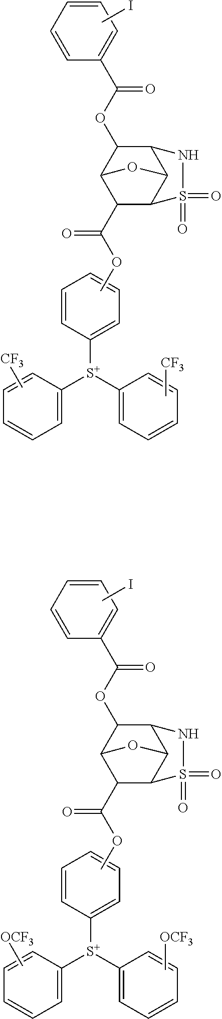

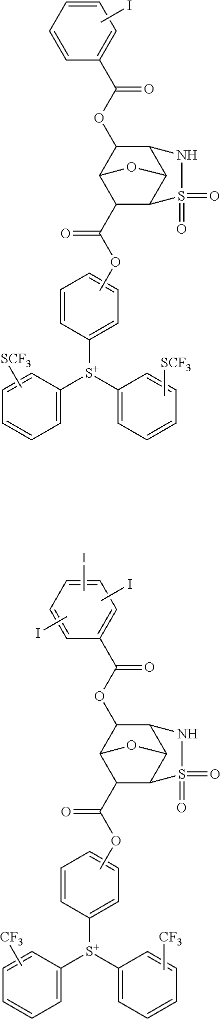

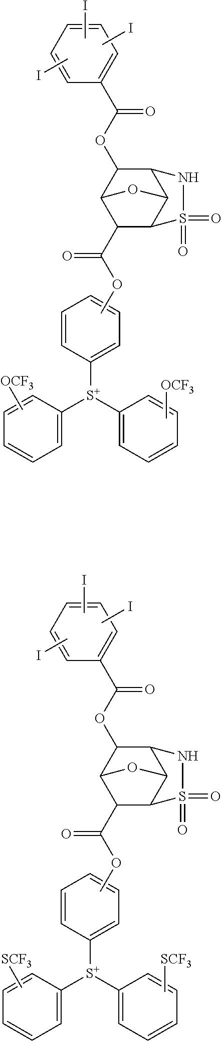

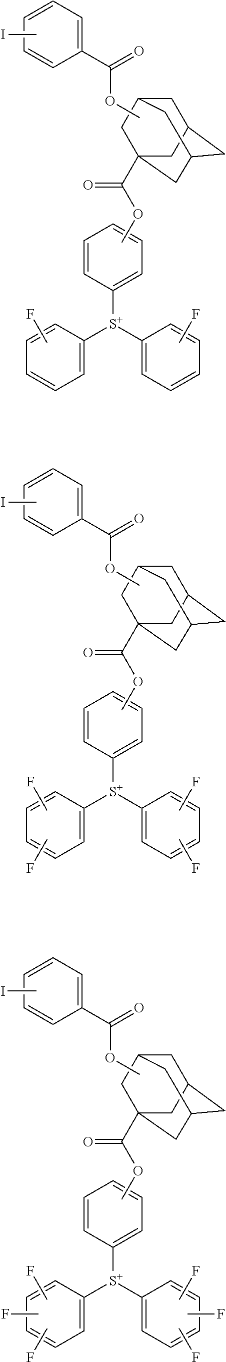

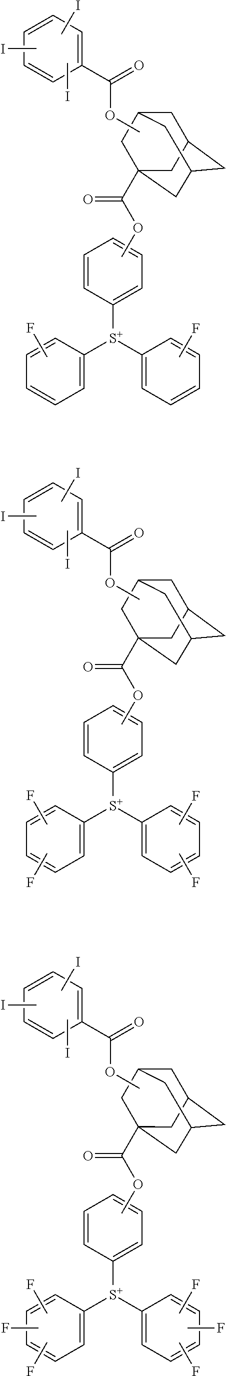

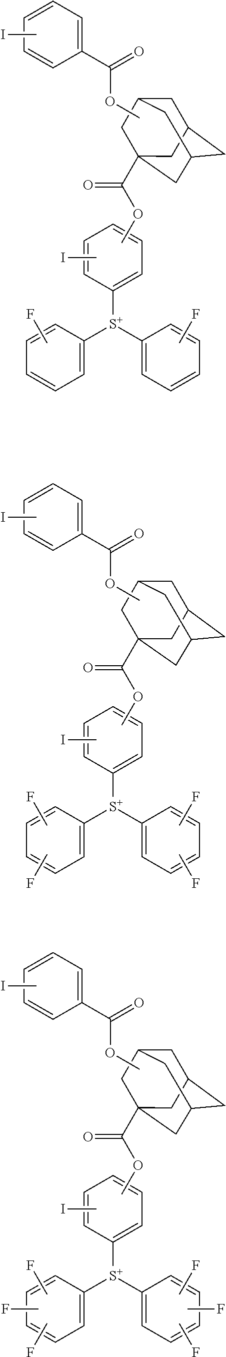

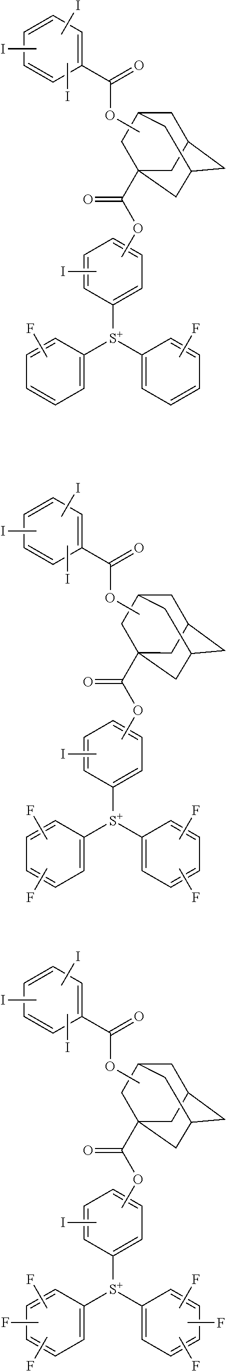

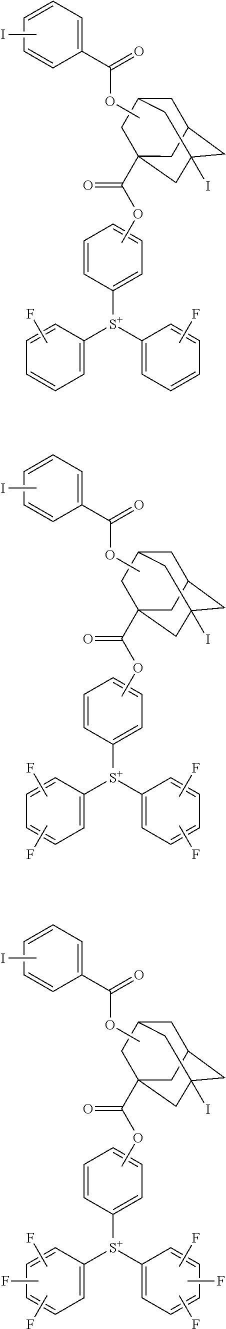

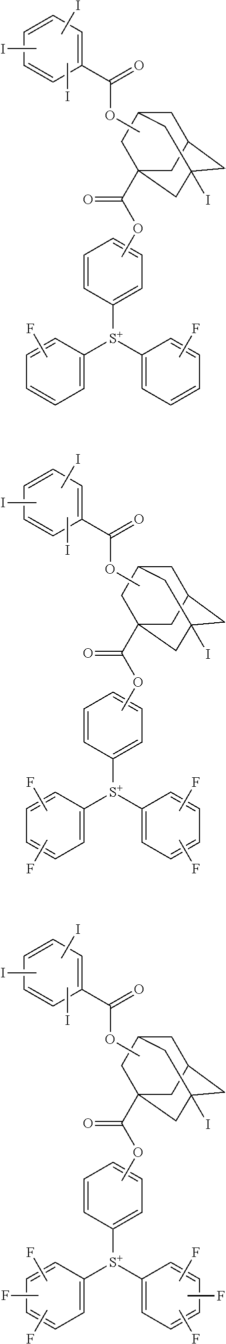

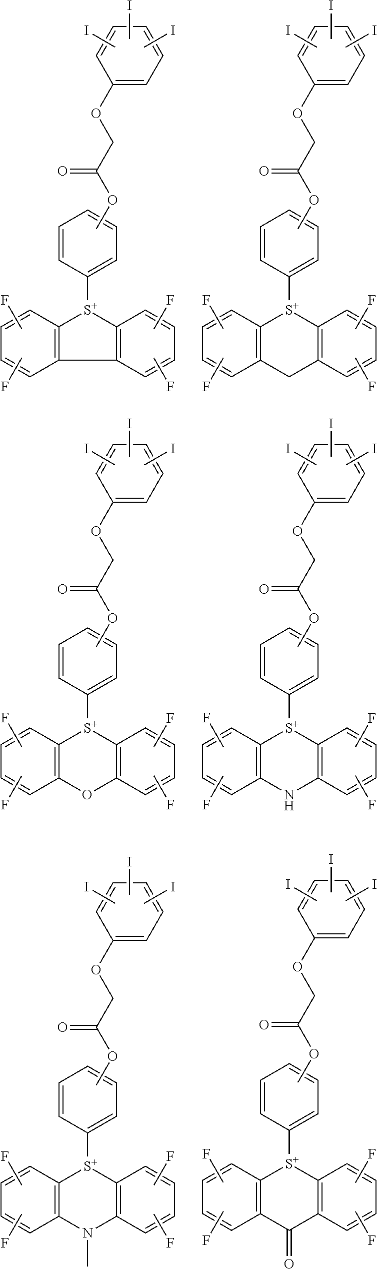

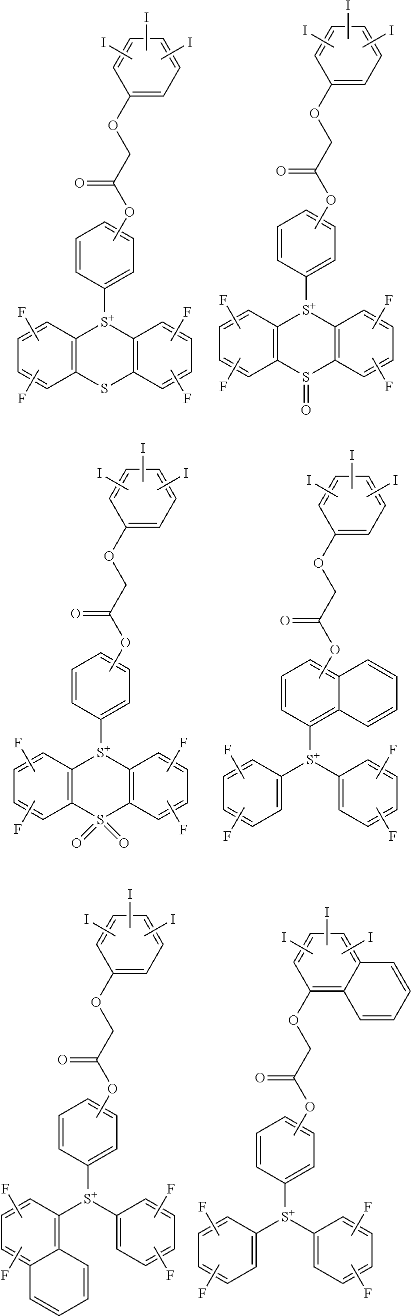

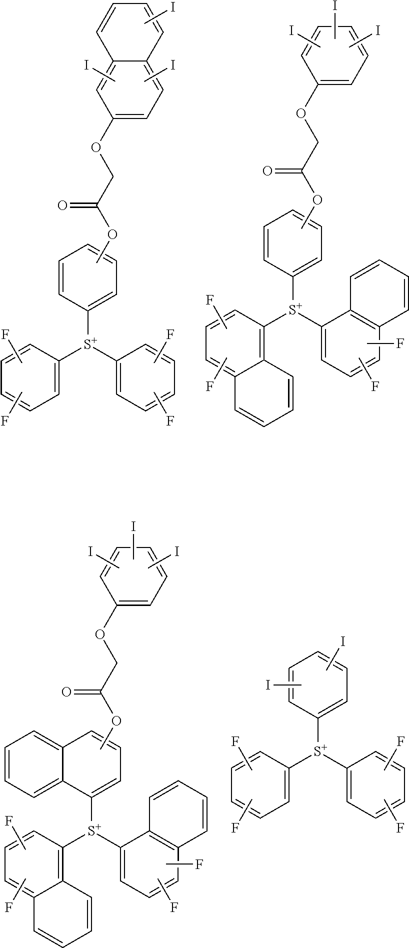

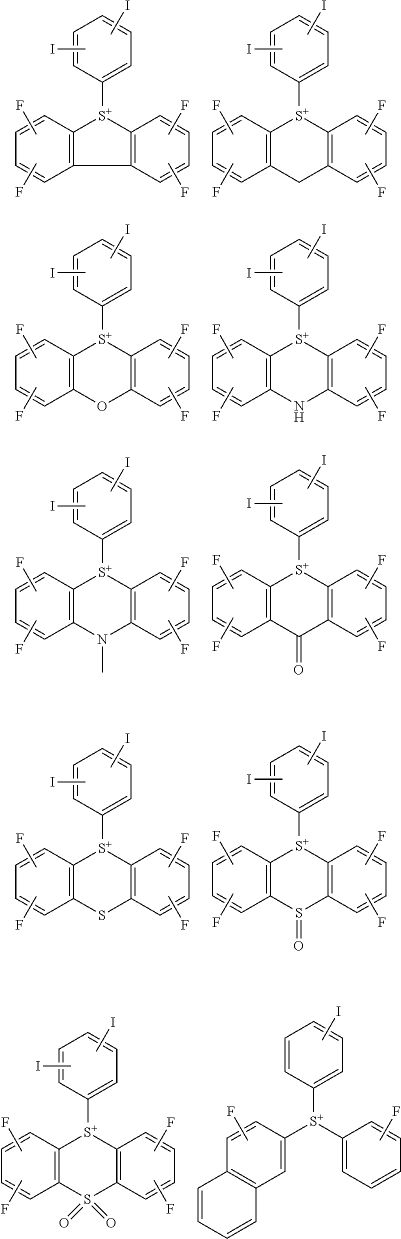

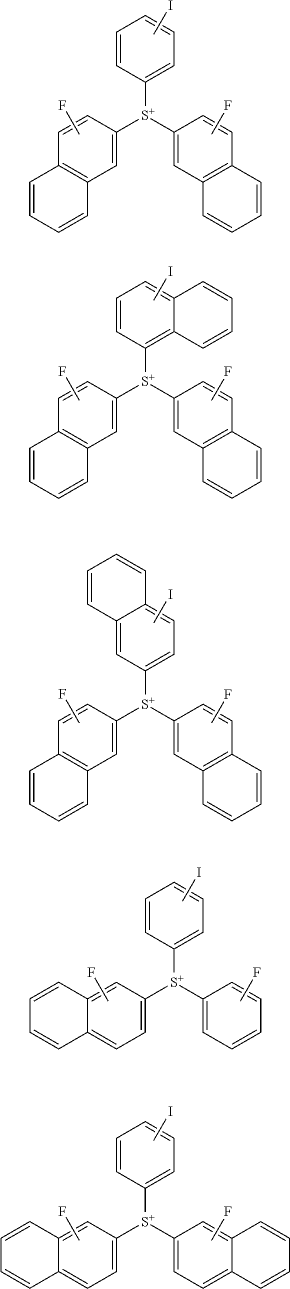

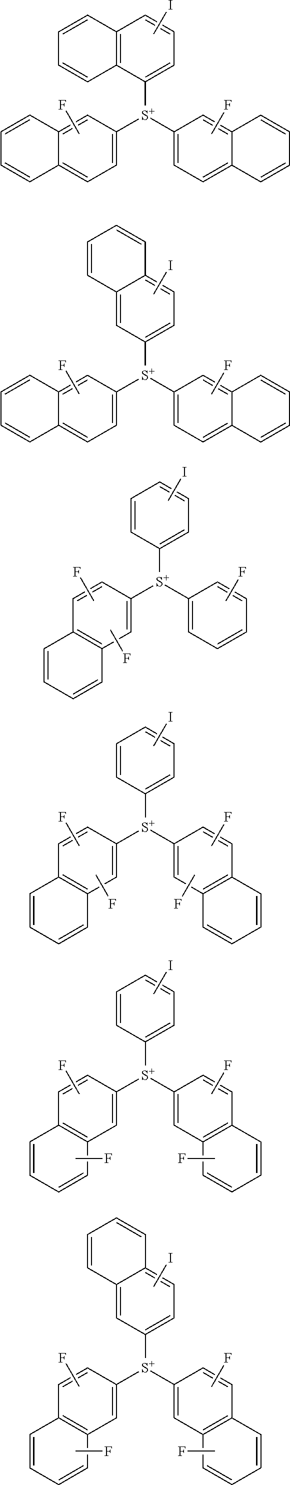

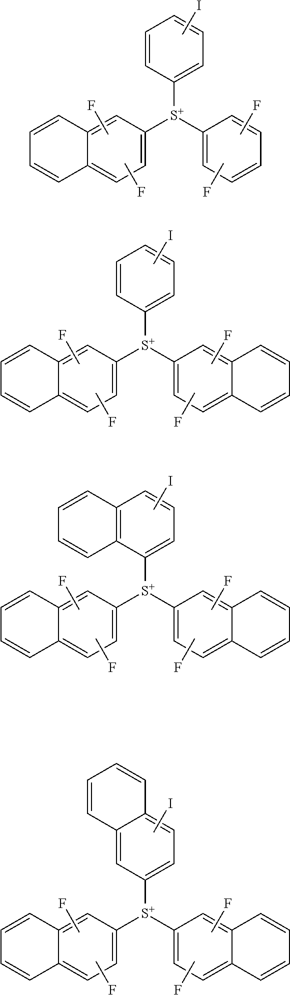

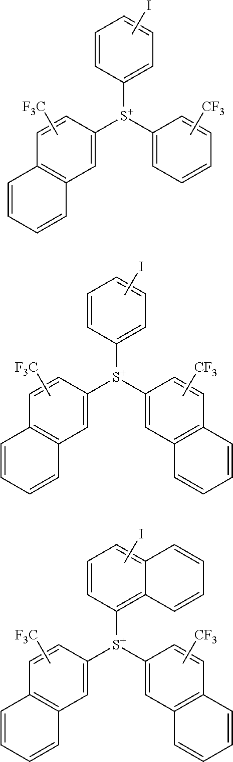

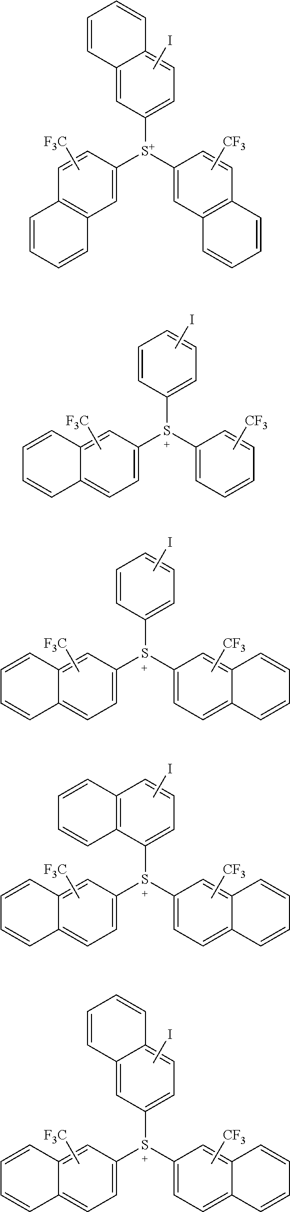

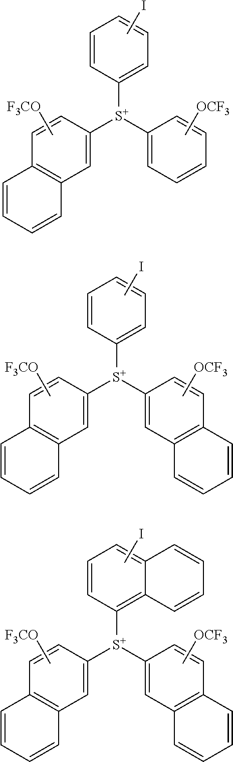

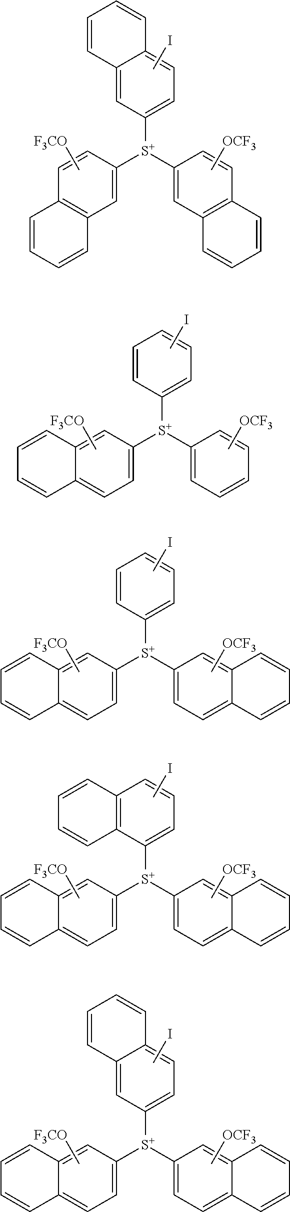

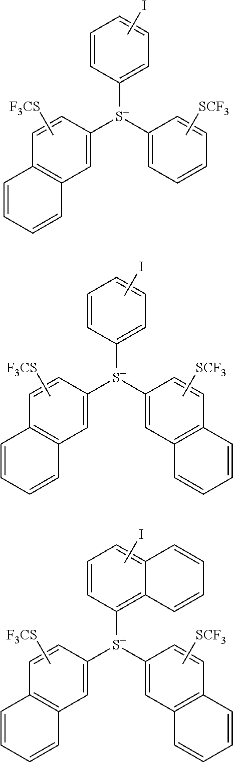

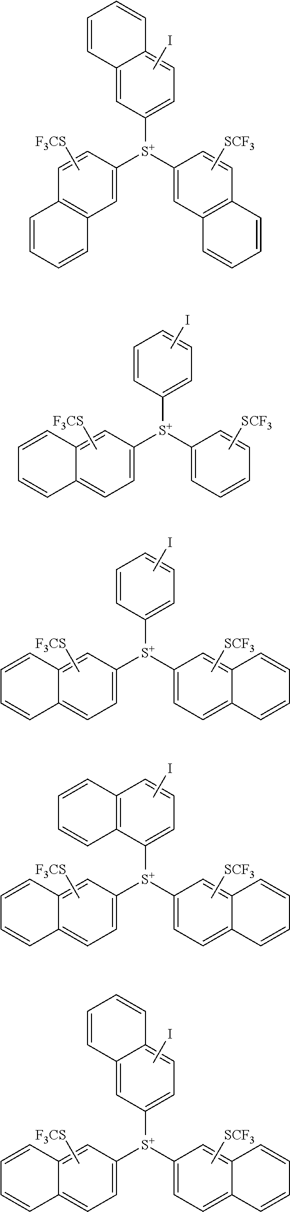

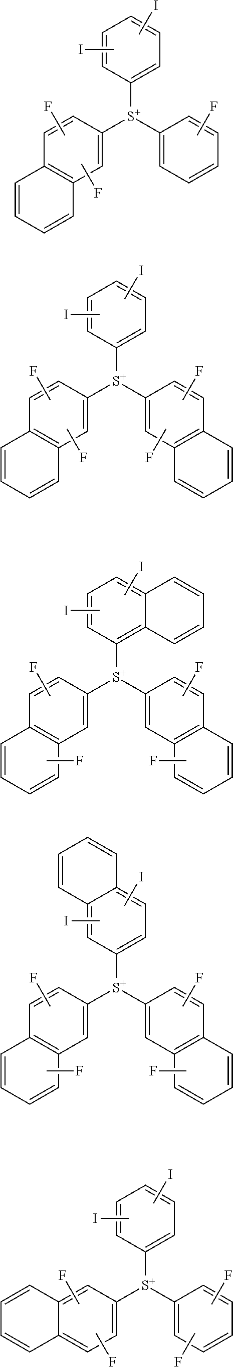

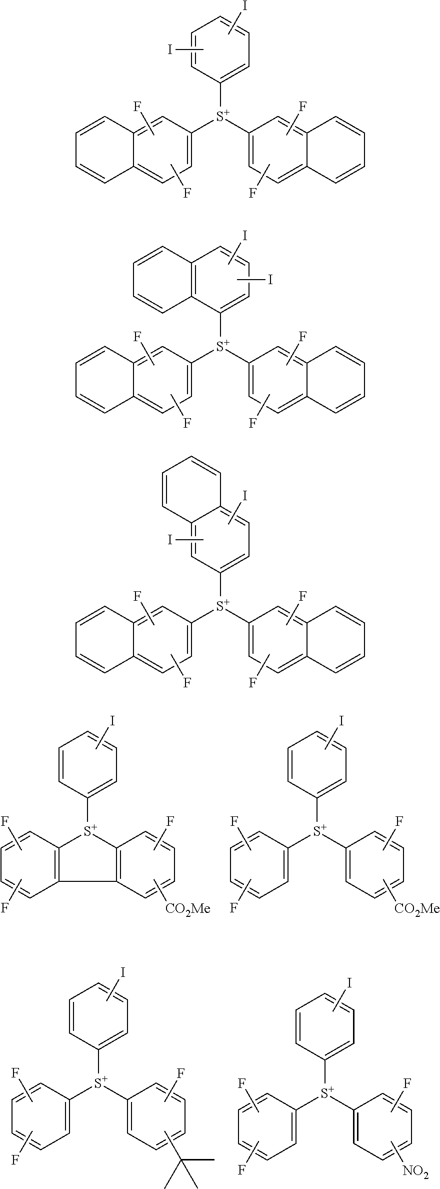

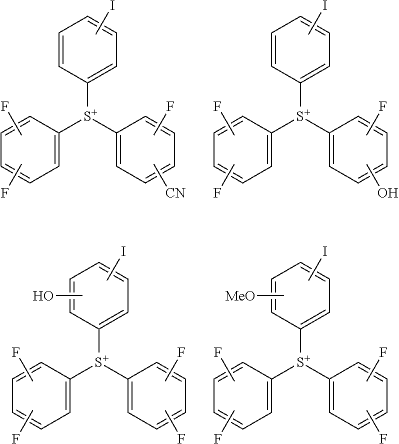

Examples of the PAG are arbitrary combinations of anions with cations, both as exemplified above.

For the synthesis of the PAG, reference should be made to JP-A 2010-155824 and JP 7067271. These methods are merely exemplary and the method for synthesis of the PAG used herein is not limited thereto.

The amount of PAG (B) used is preferably 0.1 to 40 parts, and more preferably 0.5 to 20 parts by weight per 80 parts by weight of the base polymer (A). An amount of PAG (B) in the range ensures good resolution and eliminates the risk of leaving foreign particles after development or during separation of resist film. The PAG may be used alone or in admixture of two or more.

### (C) Organic Solvent

The resist composition comprises (C) an organic solvent. The organic solvent used herein is not particularly limited as long as the foregoing and other components are soluble therein. Suitable solvents include ketones such as cyclopentanone, cyclohexanone, and methyl-2-n-pentyl ketone; alcohols such as 3-methoxybutanol, 3-methyl-3-methoxybutanol, 1-methoxy-2-propanol, and 1-ethoxy-2-propanol; keto-alcohols such as diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone (GBL), and mixtures thereof.

Of the foregoing organic solvents, it is recommended to use 1-ethoxy-2-propanol, PGMEA, cyclohexanone, GBL, DAA, and mixtures thereof because the base polymer (A) is most soluble therein.

The organic solvent (C) is preferably added in an amount of 200 to 5,000 parts by weight, and more preferably 400 to 3,500 parts by weight per 80 parts by weight of the base polymer (A). The organic solvent may be used alone or in admixture.

### (D) Quencher

The resist composition may further comprise (D) a quencher. As used herein, the “quencher” refers to a compound capable of trapping the strong acid generated by the PAG to prevent the acid from diffusing into the unexposed region of resist film, for forming the desired pattern. As used herein, the strong acid refers to an acid having a sufficient acidity to trigger the deprotection reaction of acid labile groups.

Preferred examples of the quencher include onium salts having the formulae (2) and (3).

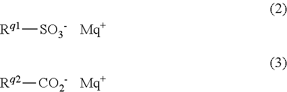

In formula (2), R^{q1} is hydrogen or a C₁-C₄₀ hydrocarbyl group which may contain a heteroatom, exclusive of the group wherein hydrogen bonded to the carbon atom at α-position relative to the sulfo group is substituted by fluorine or fluoroalkyl. In formula (3), R^{q2} is hydrogen or a C₁-C₄₀ hydrocarbyl group which may contain a heteroatom.

Examples of the C₁-C₄₀ hydrocarbyl group R^{q1} include C₁-C₄₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, and adamantyl; C₆-C₄₀ aryl groups such as phenyl, naphthyl and anthracenyl. In the hydrocarbyl group, some or all hydrogen may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy moiety, fluorine, chlorine, bromine, iodine, cyano moiety, carbonyl moiety, ether bond, ester bond, sulfonic ester bond, carbonate bond, lactone ring, sultone ring, carboxylic anhydride (—C(═O)—O—C(═O)—), or haloalkyl moiety.

Examples of the hydrocarbyl group R^{q2} include those exemplified above for R^{q1} and fluorinated saturated hydrocarbyl groups, for example, fluorinated alkyl groups such as trifluoromethyl and trifluoroethyl, and fluorinated aryl groups such as pentafluorophenyl and 4-trifluoromethylphenyl.

Examples of the anion in the onium salt having formula (2) are shown below, but not limited thereto.

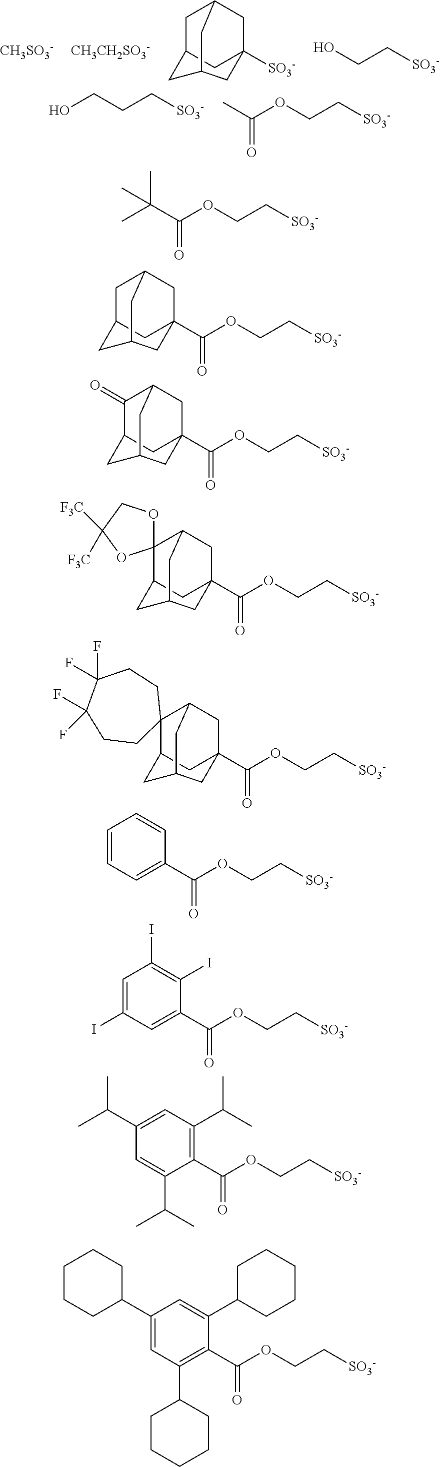

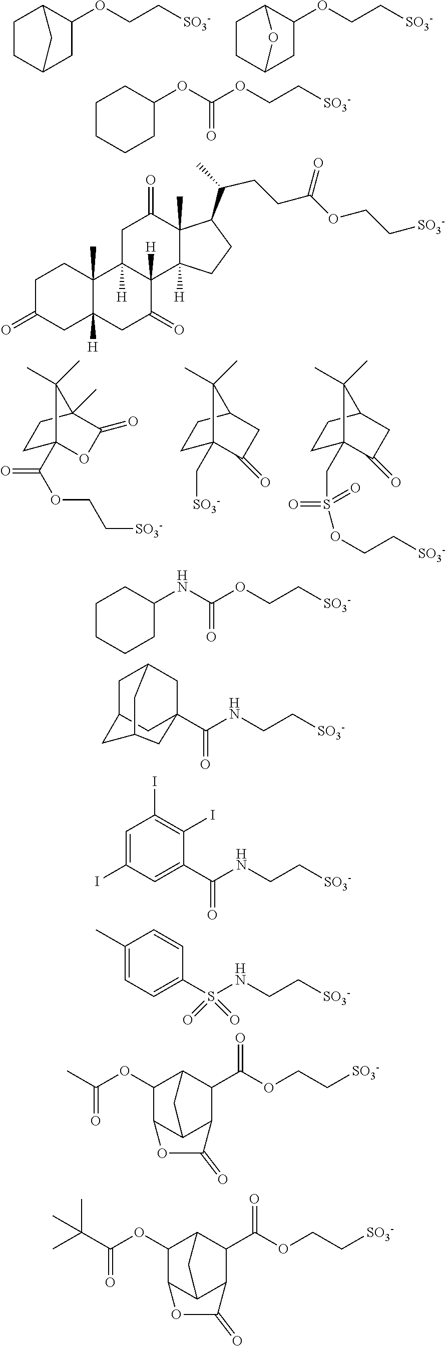

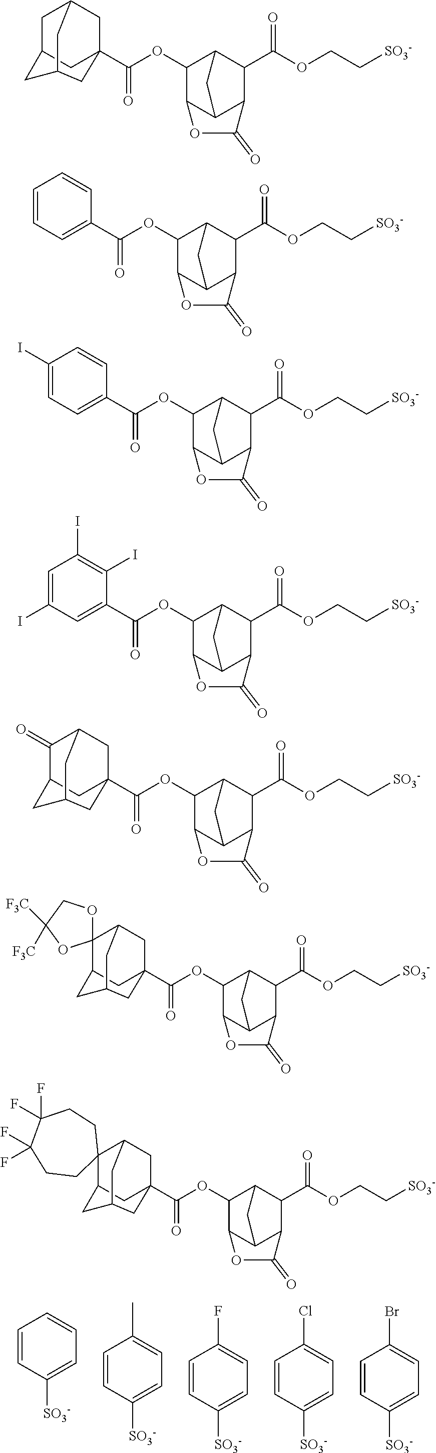

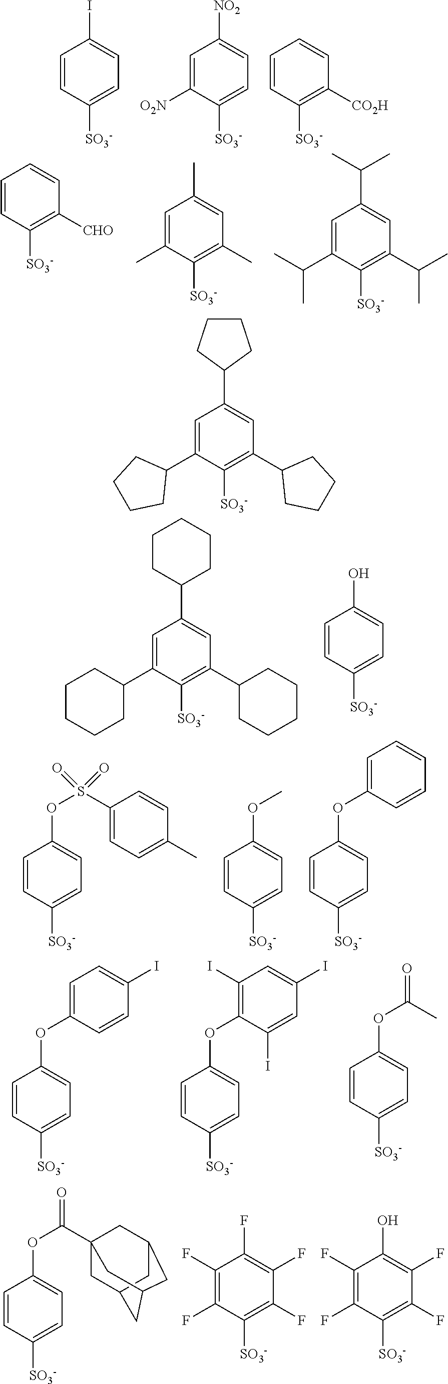

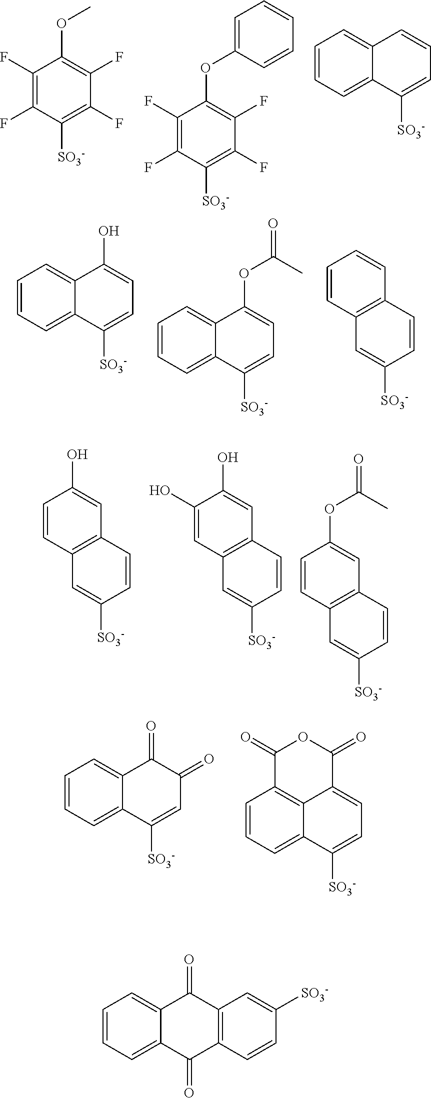

Examples of the anion in the onium salt having formula (3) are shown below, but not limited thereto.

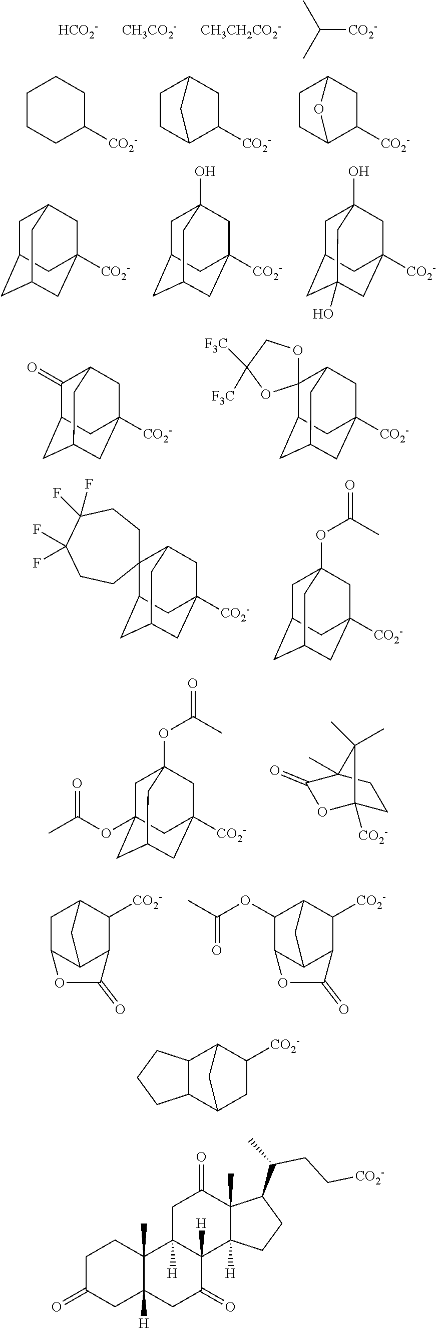

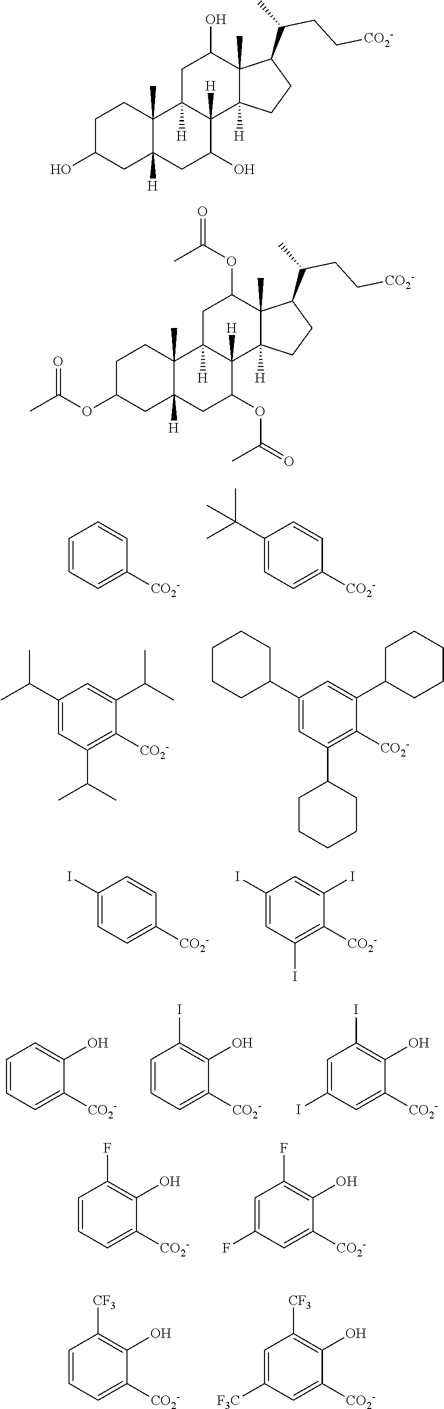

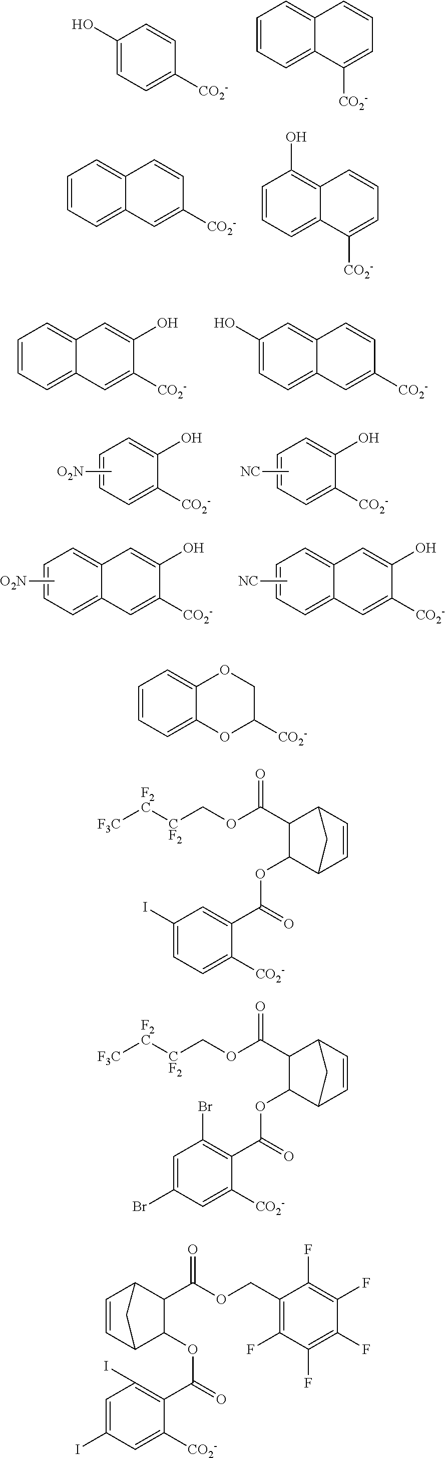

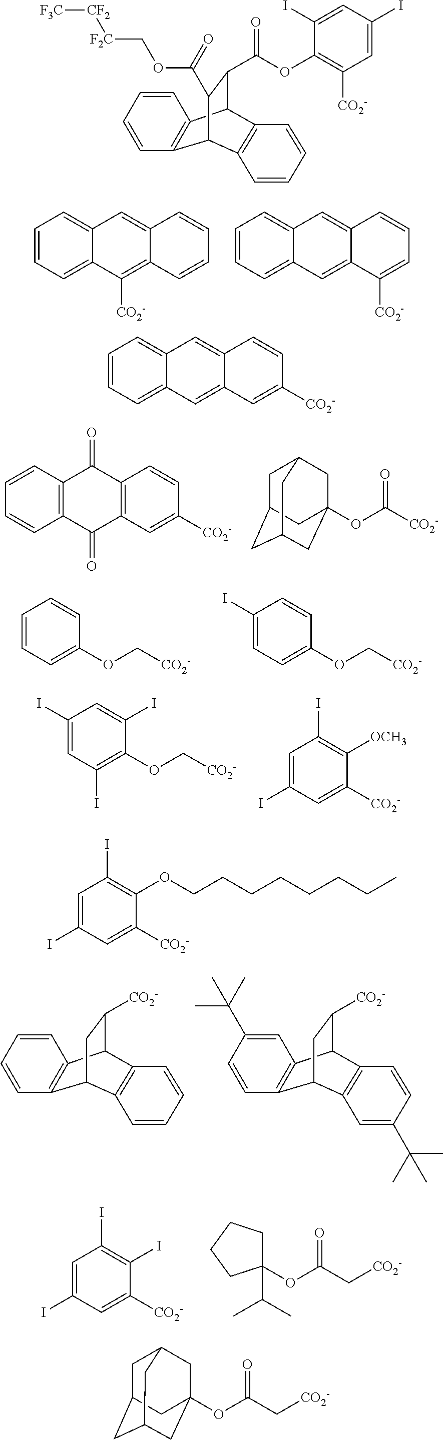

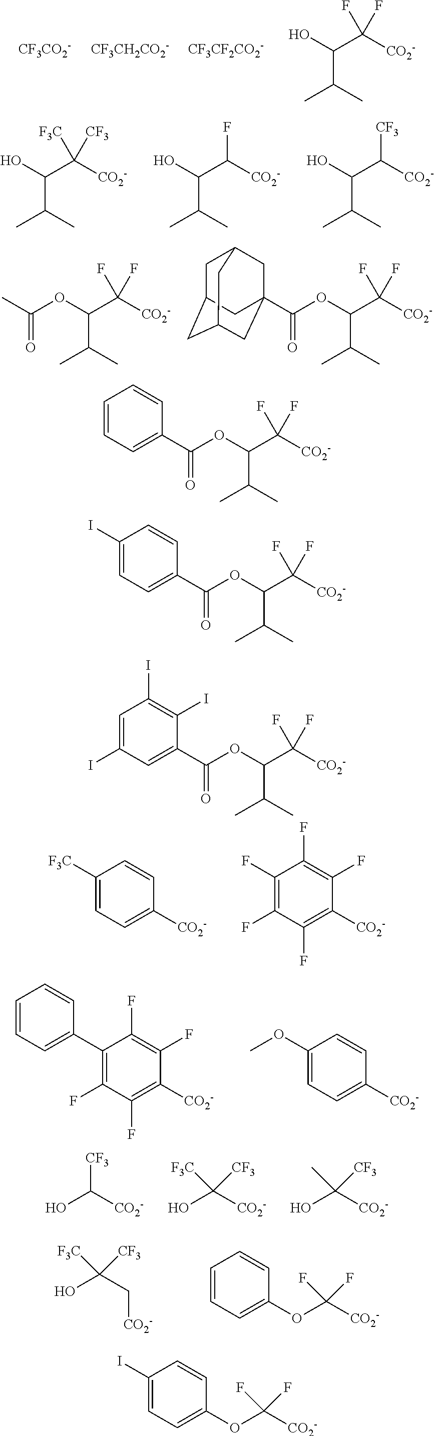

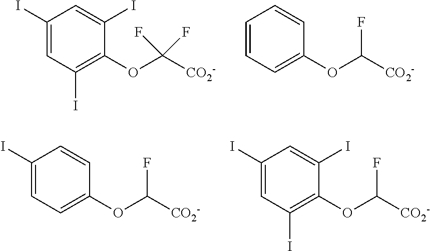

In formulae (2) and (3), Mq⁺ is an onium cation. Suitable onium cations include sulfonium, iodonium and ammonium cations. Non-limiting examples of the sulfonium cation include those exemplified above for the sulfonium cation having formulae (Z-1) and (Z-3), those described in JP-A 2024-003744, paragraphs [0102]-[0125], WO 2024/128017, paragraphs [0044]-[0049], and JP 7491173, paragraphs [0035]-[0046]. Non-limiting examples of the iodonium cation include those exemplified above for the iodonium cation having formula (Z-2). Preferred examples of the ammonium cation include ammonium cations having the following formula (Z-4).

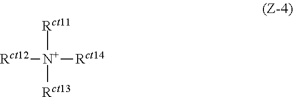

In formula (Z-4), R^{ct11} to R^{ct14} are each independently a C₁-C₄₀ hydrocarbyl group which may contain a heteroatom. A pair of R^{ct11} and R^{ct12} may bond together to form a ring with the nitrogen atom to which they are attached. Examples of the hydrocarbyl group are as exemplified above for the hydrocarbyl groups R^{ct1} to R^{ct5} in formulae (Z-1) and (Z-2).

Examples of the ammonium cation having formula (Z-4) are shown below, but not limited thereto.

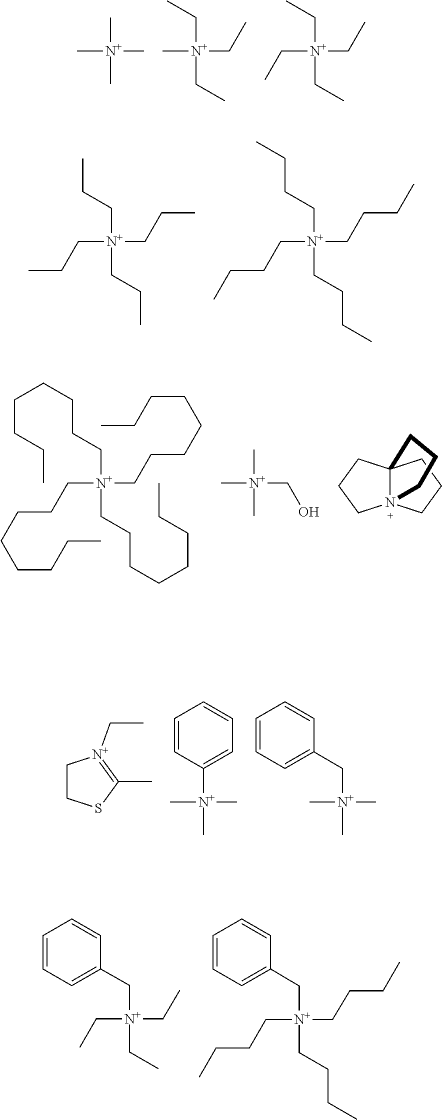

Examples of the onium salt having formula (2) or (3) include arbitrary combinations of anions with cations, both as exemplified above. These onium salts may be readily synthesized by ion exchange reaction according to any well-known organic chemistry technique. For the ion exchange reaction, reference may be made to JP-A 2007-145797, for example.

The onium salt having formula (2) or (3) functions as a quencher in the resist composition because the counter anion of the onium salt is a conjugated base of a weak acid. As used herein, the weak acid indicates an acidity insufficient to deprotect an acid labile group from an acid labile group-containing unit in the base polymer. The onium salt having formula (2) or (3) functions as a quencher when used in combination with an onium salt type PAG having a conjugated base of a strong acid (typically α-fluorinated sulfonic acid) as the counter anion. In a system using a mixture of an onium salt capable of generating a strong acid (e.g., α-fluorinated sulfonic acid) and an onium salt capable of generating a weak acid (e.g., non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a low catalysis, incurring apparent deactivation of the acid for enabling to control acid diffusion.

Also useful as the quencher (D) are onium salts having a sulfonium cation and a phenoxide anion site in a common molecule as described in JP 6848776, onium salts having a sulfonium cation and a carboxylate anion site in a common molecule as described in JP 6583136 and JP-A 2020-200311, and onium salts having an iodonium cation and a carboxylate anion site in a common molecule as described in JP 6274755.

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onium cation forming an ion pair with a stronger acid anion.

When the onium salt having formula (2) or (3) is used as the quencher (D), the amount of the onium salt used is preferably 0.1 to 20 parts by weight, more preferably 0.1 to 10 parts by weight per 80 parts by weight of the base polymer (A). As long as the amount of the quencher is in the range, a satisfactory resolution is available without a substantial lowering of sensitivity. The onium salt having formula (2) or (3) may be used alone or in admixture.

Nitrogen-containing compounds may also be used as the quencher (D). Suitable nitrogen-containing compounds include primary, secondary and tertiary amine compounds, specifically amine compounds having a hydroxy group, ether bond, ester bond, lactone ring, cyano group or sulfonic ester bond, as described in JP-A 2008-111103, paragraphs [0146]-[0164](U.S. Pat. No. 7,537,880), and primary or secondary amine compounds protected with a carbamate group, as described in JP 3790649. Also included are amine compounds having an acid labile group bonded to a lactone ring, sultone ring, lactam ring and sultam ring, as described in JP 7615989.

A sulfonic acid sulfonium salt having a nitrogen-containing substituent may also be used as the nitrogen-containing compound. This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595 and JP-A 2012-046501, for example.

When the nitrogen-containing compound is used as the quencher (D), the amount of the nitrogen-containing compound used is preferably 0.001 to 12 parts by weight, more preferably 0.01 to 8 parts by weight per 80 parts by weight of the base polymer (A). The nitrogen-containing compound may be used alone or in admixture.

### (E) Other Photoacid Generator

The chemically amplified resist composition may comprise (E) a photoacid generator other than component (B). The other PAG is not particularly limited as long as it is capable of generating a strong acid upon exposure to high-energy radiation.

The preferred PAG is a salt having the formula (4) or (5).

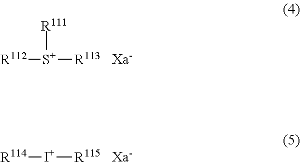

In formula (4), R¹¹¹ to R¹¹⁵ are each independently halogen or a C₁-C₂₀ hydrocarbyl group which may contain a heteroatom. Any two of R¹¹¹, R¹¹² and R¹¹³ may bond together to form a ring with the sulfur atom to which they are attached. Examples of the hydrocarbyl group are as exemplified above for the hydrocarbyl group R^{ct1} to R^{ct5} in formulae (Z-1) and (Z-2).

Non-limiting examples of the cation in the sulfonium salt having formula (4) include those described in JP-A 2024-003744, paragraphs [0102]-[0125], WO 2024/128017, paragraphs [0044]-[0049], and JP 7491173, paragraphs [0035]-[0046], and those exemplified as the sulfonium cation having formula (Z-3). Non-limiting examples of the cation in the iodonium salt having formula (5) include those described in JP-A 2024-000259, paragraph [0181].

In formulae (4) and (5), Xa is an anion of strong acid. Preferred examples of the anion of strong acid include anions having the formulae (Xa-1) to (Xa-4).

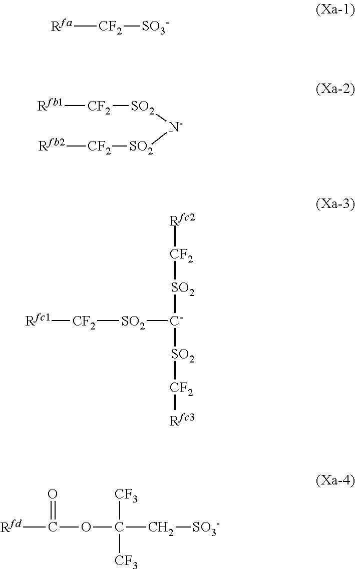

In formula (Xa-1), R^{fa} is fluorine or a C₁-C₆₀ hydrocarbyl group which may contain a heteroatom. The hydrocarbyl group may be saturated or unsaturated and straight, branched or cyclic. Examples thereof are as will be exemplified later for hydrocarbyl group R^{fa1} in formula (Xa-1-1). In the hydrocarbyl group, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety.

Of the anions of formula (Xa-1), a structure having formula (Xa-1-1) is preferred.

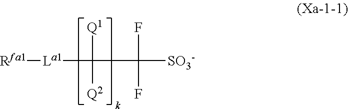

In formula (Xa-1-1), Q¹ and Q² are each independently hydrogen, fluorine or a C₁-C₆ fluorinated saturated hydrocarbyl group. It is preferred for improving solvent solubility that at least one of Q¹ and Q² be trifluoromethyl. The subscript k is 0, 1, 2, 3 or 4, preferably 1. R^{fa1} is a C₁-C₃₅ hydrocarbyl group which may contain a heteroatom. As the heteroatom, oxygen, nitrogen, sulfur and halogen atoms are preferred, with oxygen being most preferred. Of the hydrocarbyl groups, those groups of 6 to 35 carbon atoms, especially 6 to 30 carbon atoms are preferred from the aspect of achieving a high resolution in forming patterns of small feature size.

The C₁-C₄₀ hydrocarbyl group R^{fa1} may be saturated or unsaturated and straight, branched or cyclic. Examples thereof include C₁-C₄₀ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosyl; C₃-C₄₀ cyclic saturated hydrocarbyl groups such as cyclopentyl, cyclohexyl, 1-adamantyl, 2-adamantyl, 1-adamantylmethyl, norbornyl, norbornylmethyl, tricyclodecyl, tetracyclododecyl, tetracyclododecylmethyl, and dicyclohexylmethyl; C₂-C₄₀ unsaturated aliphatic hydrocarbyl groups such as 2-propenyl and 3-cyclohexenyl; C₆-C₄₀ aryl groups such as phenyl, 1-naphthyl, 2-naphthyl and 9-fluorenyl; C₇-C₄₀ aralkyl groups such as benzyl and diphenylmethyl; C₇-C₄₀ aromatic ring-containing polycyclic hydrocarbyl groups such as 9,10-ethano-9,10-dihydroanthryl and 6,13-ethano-6,13-dihydropentacenyl; C₁₇-C₄₀ hydrocarbyl groups having steroid skeleton, and combinations thereof.

In the foregoing hydrocarbyl groups, some or all hydrogen may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

In formula (Xa-1-1), L^{a1} is a single bond, ether bond, ester bond, sulfonate ester bond, carbonate bond or carbamate bond. From the aspect of synthesis, an ether bond or ester bond is preferred, with the ester bond being more preferred.

Examples of the anion having formula (Xa-1) are shown below, but not limited thereto. Herein Q¹ is as defined above.

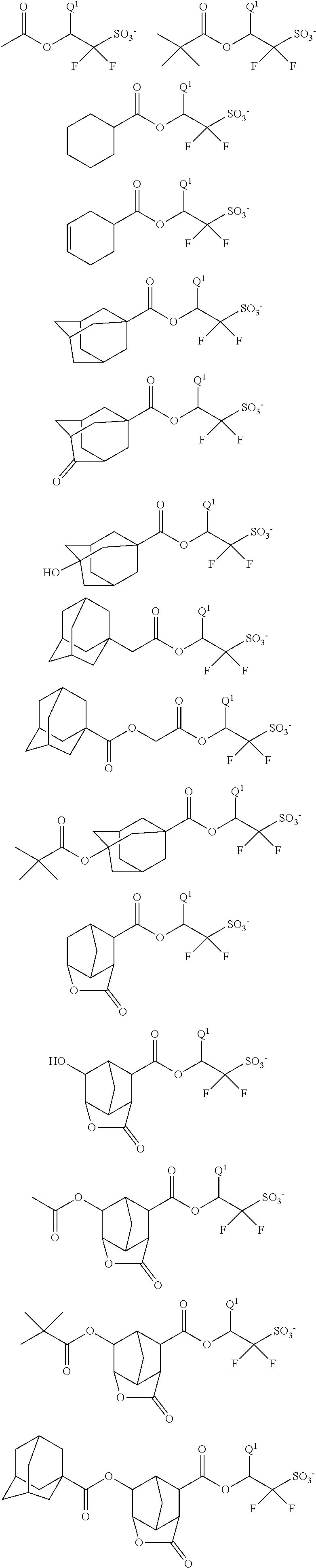

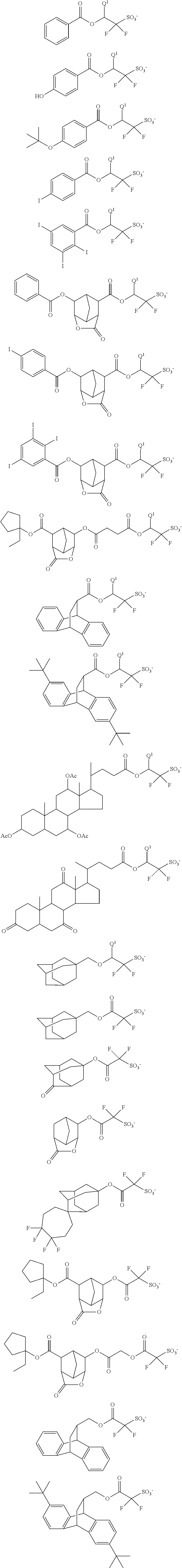

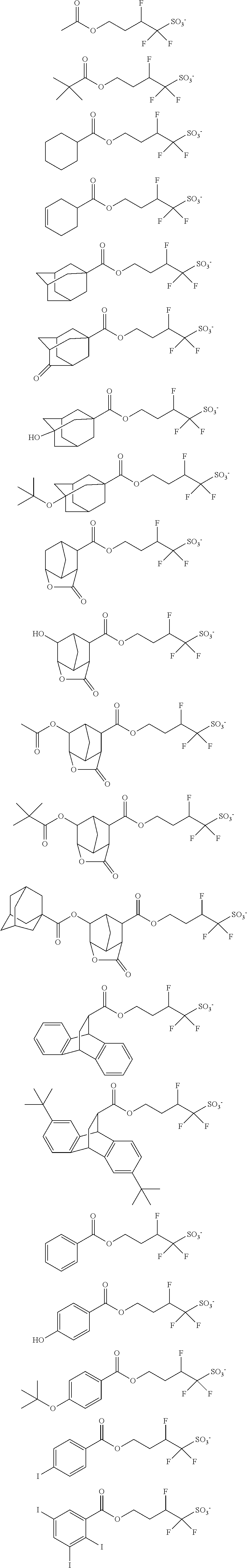

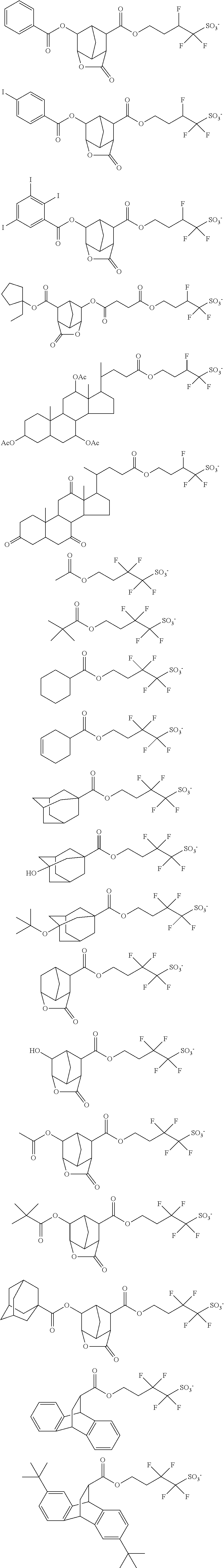

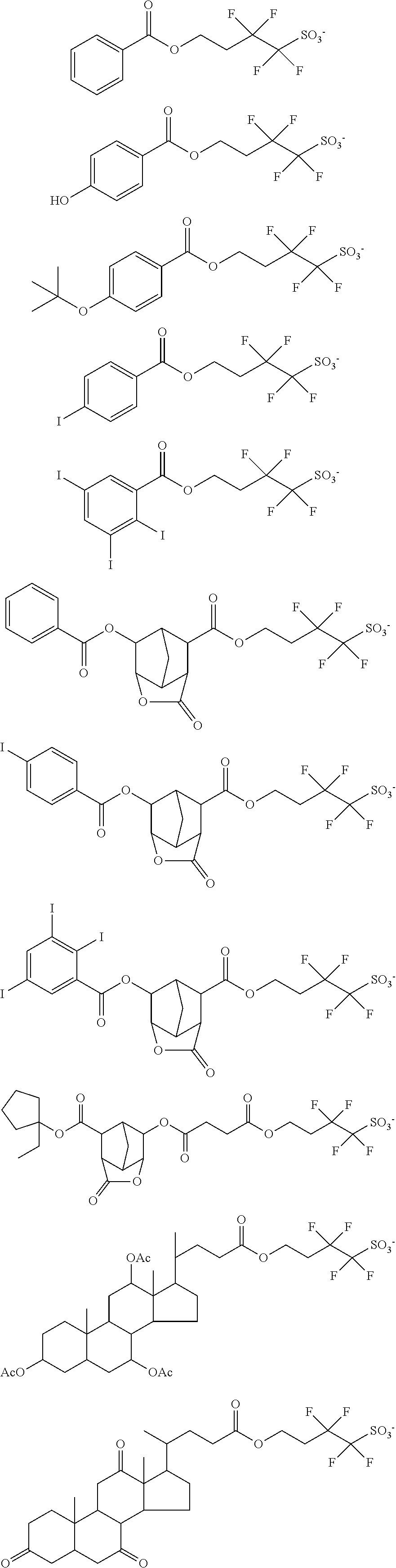

In formula (Xa-2), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Examples thereof are as exemplified above for the hydrocarbyl group R^{fa1} in formula (Xa-1-1). Preferably R^{fb1} and R^{fb2} are fluorine or C₁-C₄ straight fluorinated alkyl groups. Also, R^{fb1} and R^{fb2} may bond together to form a ring with the linkage: —CF₂—SO₂—N—SO₂—CF₂— to which they are attached. It is preferred that a combination of R^{fb1} and R^{fb2} be a fluorinated ethylene or fluorinated propylene group.

In formula (Xa-3), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Examples thereof are as exemplified above for the hydrocarbyl group R^{fa1} in formula (Xa-1-1). Preferably R^{fc1}, R^{fc2} and R^{fc3} are fluorine or C₁-C₄ straight fluorinated alkyl groups. Also, R^{fc1} and R^{fc2} may bond together to form a ring with the linkage: —CF₂—SO₂—C—SO₂—CF₂— to which they are attached. It is preferred that a combination of R^{fc1} and R^{fc2} be a fluorinated ethylene or fluorinated propylene group.

In formula (Xa-4), R^{fd} is a C₁-C₄₀ hydrocarbyl group which may contain a heteroatom. The hydrocarbyl group may be saturated or unsaturated and straight, branched or cyclic. Examples thereof are as exemplified above for R^{fa1}. In the hydrocarbyl group, some or all hydrogen may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, fluorine, chlorine, bromine, iodine, cyano, nitro, carbonyl, ether bond, ester bond, sulfonate ester bond, carbonate bond, lactone ring, sultone ring, carboxylic anhydride (—C(═O)—O—C(═O)—) or haloalkyl moiety.

Examples of the anion having formula (Xa-4) are shown below, but not limited thereto.

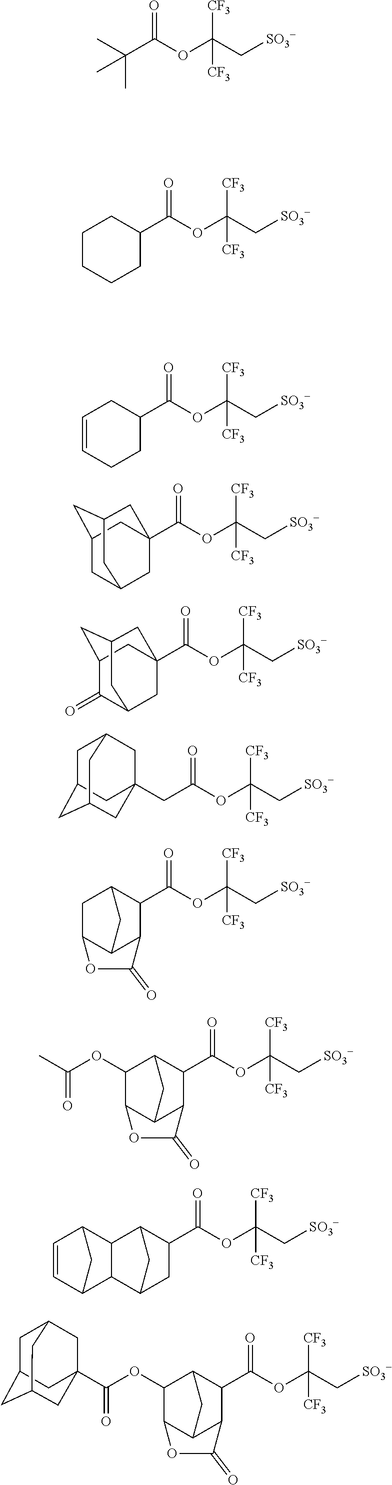

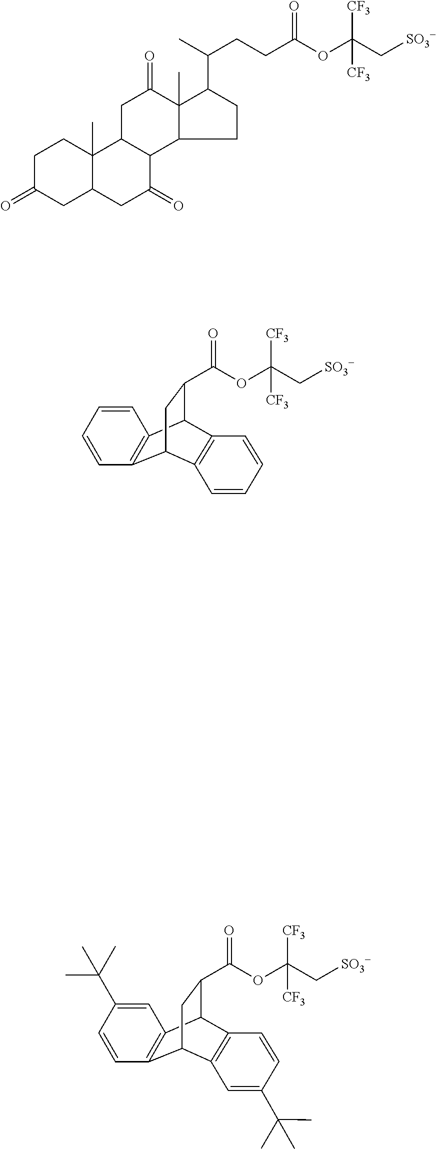

Useful examples of the non-nucleophilic counter ion include fluorobenzenesulfonic acid anions having an iodized aromatic ring bonded thereto as described in JP 6648726, anions having an acid-catalyzed decomposition mechanism as described in WO 2021/200056 and JP-A 2021-070692, anions having a cyclic ether group as described in JP-A 2018-180525 and JP-A 2021-035935, and anions as described in JP-A 2018-092159.

Further useful examples of the non-nucleophilic counter ion include bulky fluorine-free benzenesulfonic acid anions as described in JP-A 2006-276759, JP-A 2015-117200, JP-A 2016-065016, JP-A 2019-202974, and JP-A 2024-104830; fluorine-free benzenesulfonic acid or alkylsulfonic acid anions having an iodized aromatic group bonded thereto as described in JP 6645464. The anions described in JP-A 2024-077330, paragraphs [0229]-[0231] and JP-A 2024-140135, paragraphs [0033]-[0093] are also useful.

Also useful are the bissulfonic acid anions described in JP-A 2015-206932, the sulfonamide or sulfonimide anions having sulfonic acid side and different side, described in WO 2020/158366, and the anions having a sulfonic acid side and a carboxylic acid side, described in JP-A 2015-024989.

Compounds having the formula (6) are also preferred as the other PAG (E).

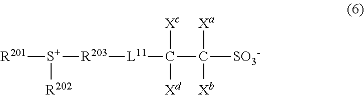

In formula (6), R²⁰¹ and R²⁰² are each independently a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atom to which they are attached.

The C₁-C₃₀ hydrocarbyl group represented by R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, oxanorbornyl, tricyclo[5.2.1.0^{2,6}]decyl, and adamantyl; and C₆-C₃₀ aryl groups such as phenyl, methylphenyl, ethylphenyl, n-propylphenyl, isopropylphenyl, n-butylphenyl, isobutylphenyl, sec-butylphenyl, tert-butylphenyl, naphthyl, methylnaphthyl, ethylnaphthyl, n-propylnaphthyl, isopropylnaphthyl, n-butylnaphthyl, isobutylnaphthyl, sec-butylnaphthyl, tert-butylnaphthyl, and anthracenyl, and combinations thereof. In these hydrocarbyl groups, some or all of the hydrogen atoms may be substituted by a moiety containing a heteroatom such as oxygen, sulfur, nitrogen or halogen, and some —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety.

The C₁-C₃₀ hydrocarbylene group R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; and arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene. In these hydrocarbylene groups, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, cyano, fluorine, chlorine, bromine, iodine, carbonyl, ether bond, ester bond, sulfonate ester bond, carbonate bond, lactone ring, sultone ring, carboxylic anhydride (—C(═O)—O—C(═O)—) or haloalkyl moiety. Of the heteroatoms, oxygen is preferred.

In formula (6), L¹¹ is a single bond, ether bond or a C₁-C₂₀ hydrocarbylene group which may contain a heteroatom. The hydrocarbylene group may be saturated or unsaturated and straight, branched or cyclic. Examples thereof are as exemplified above for the hydrocarbylene group R²⁰³.

In formula (6), X^{a}, X^{b}, X^{c} and X^{d} are each independently hydrogen, fluorine or trifluoromethyl, at least one of X^{a}, X^{b}, X^{c} and X^{d} being fluorine or trifluoromethyl.

Of the PAGs having formula (6), those having the formula (6′) are preferred.

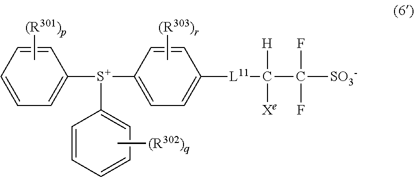

In formula (6′), L¹¹ is as defined above. X^{e} is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for R^{fa1} in formula (Xa-1-1). The subscripts p and q are each independently 0, 1, 2, 3, 4 or 5, and r is 0, 1, 2, 3 or 4.

Examples of the PAG having formula (6) include those exemplified for the PAG having formula (2) in JP-A 2017-026980.

Of the foregoing PAGs, those having an anion of formula (Xa-1-1) or (Xa-4) are especially preferred because of reduced acid diffusion and high solubility in solvents. Also those having formula (6′) are especially preferred because of extremely reduced acid diffusion.

When used, the other PAG (E) is preferably added in an amount of 0.1 to 40 parts, and more preferably 0.5 to 20 parts by weight per 80 parts by weight of the base polymer (A). As long as the amount of the other PAG is in the range, good resolution is achievable and the risk of foreign particles being formed after development or during stripping of resist film is avoided. The other PAG may be used alone or in admixture.

### (F) Surfactant

The resist composition may further include (F) a surfactant. Preferred are a surfactant which is insoluble or substantially insoluble in water and soluble in alkaline developer, and a surfactant which is insoluble or substantially insoluble in water and alkaline developer. For the surfactant, reference should be made to those compounds described in JP-A 2010-215608 and JP-A 2011-016746.

While many examples of the surfactant which is insoluble or substantially insoluble in water and alkaline developer are described in the patent documents cited herein, preferred examples are surfactants FC-4430 (3M), Olfine® E1004 (Nissin Chemical Co., Ltd.), Surflon® 5-381, KH-20 and KH-30 (AGC Seimi Chemical Co., Ltd.). Partially fluorinated oxetane ring-opened polymers having the formula (surf-1) are also useful.

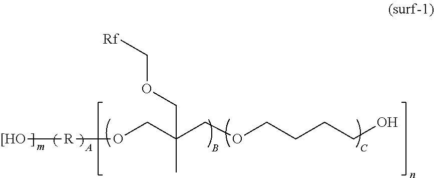

It is provided herein that R, Rf, A, B, C, m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

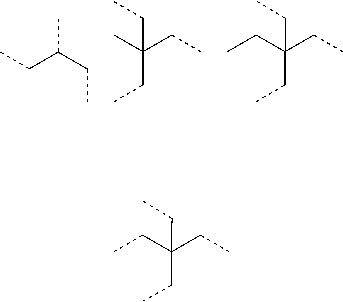

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3-propylene are preferably used.

Rf is trifluoromethyl or pentafluoroethyl, and preferably trifluoromethyl. The letter m is an integer of 0 to 3, n is an integer of 1 to 4, and the sum of m and n, which represents the valence of R, is an integer of 2 to 4. “A” is equal to 1, B is an integer of 2 to 25, and C is an integer of 0 to 10. Preferably, B is an integer of 4 to 20, and C is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the resist surface for achieving a function of minimizing water penetration or leaching. The surfactant is also effective for preventing water-soluble components from being leached out of the resist film for minimizing any damage to the exposure tool. The surfactant becomes solubilized during aqueous alkaline development following exposure and PEB, and thus forms few or no foreign particles which become defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Suitable polymeric surfactants include those containing repeat units of at least one type selected from repeat units having the formula (7A), repeat units having the formula (7B), repeat units having the formula (7C), repeat units having the formula (7D), and repeat units having the formula (7E), which are also referred to as repeat units 7A, 7B, 7C, 7D, and 7E, respectively.

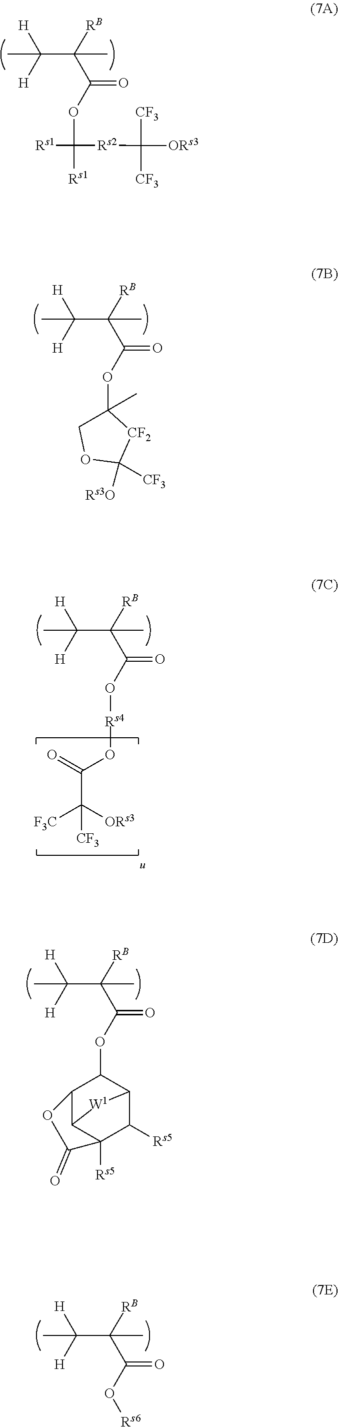

In formulae (7A) to (7E), R^{B} is hydrogen, fluorine, methyl or trifluoromethyl. W¹ is —CH₂—, —CH₂CH₂— or —O—, or two separate —H. R^{s1} is each independently hydrogen or a C₁-C₁₀ hydrocarbyl group. R^{s2} is a single bond or a C₁-C₅ straight or branched hydrocarbylene group. R^{s3} is each independently hydrogen, a C₁-C₁₅ hydrocarbyl or fluorinated hydrocarbyl group, or an acid labile group. When R^{s3} is a hydrocarbyl or fluorinated hydrocarbyl group, an ether bond or carbonyl moiety may intervene in a carbon-carbon bond. R^{s4} is a C₁-C₂₀ (u+1)-valent hydrocarbon or fluorinated hydrocarbon group, and u is 1, 2 or 3. R^{s5} is each independently hydrogen or a group: —C(═O)—O—R^{sa} wherein R^{sa} is a C₁-C₂₀ fluorinated hydrocarbyl group. R^{s6} is a C₁-C₁₅ hydrocarbyl or fluorinated hydrocarbyl group in which an ether bond or carbonyl moiety may intervene in a carbon-carbon bond.

The C₁-C₁₀ hydrocarbyl group represented by R^{s1} may be straight, branched or cyclic and is preferably saturated. Examples thereof include C₁-C₁₀ alkyl groups such as methyl, ethyl, n-propyl, isopropyl, n-butyl, isobutyl, sec-butyl, tert-butyl, n-pentyl, n-hexyl, n-heptyl, n-octyl, n-nonyl, n-decyl, and C₃-C₁₀ cyclic saturated hydrocarbyl groups such as cyclopropyl, cyclobutyl, cyclopentyl, cyclohexyl, adamantyl, and norbornyl. Inter alia, C₁-C₆ hydrocarbyl groups are preferred.

The hydrocarbylene group represented by R^{s2} may be straight, branched or cyclic and is preferably saturated. Examples thereof include methylene, ethylene, propylene, butylene and pentylene.

The hydrocarbyl group represented by R^{s3} or R^{s6} may be saturated or unsaturated and straight, branched or cyclic. Examples thereof include saturated hydrocarbyl groups, and aliphatic unsaturated hydrocarbyl groups such as alkenyl and alkynyl groups, with the saturated hydrocarbyl groups being preferred. Suitable saturated hydrocarbyl groups include those exemplified for the hydrocarbyl group represented by R^{s1} as well as undecyl, dodecyl, tridecyl, tetradecyl, and pentadecyl. Examples of the fluorinated hydrocarbyl group represented by R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group represented by R^{s3} include groups of the above formulae (AL-3) to (AL-5), trialkylsilyl groups in which each alkyl moiety has 1 to 6 carbon atoms, and C₄-C₂₀ oxoalkyl groups.

The (u+1)-valent hydrocarbon or fluorinated hydrocarbon group represented by R^{s4} may be straight, branched or cyclic and examples thereof include the foregoing hydrocarbyl or fluorinated hydrocarbyl groups from which “u” number of hydrogen atoms are eliminated.

The fluorinated hydrocarbyl group represented by R^{sa} may be straight, branched or cyclic and is preferably saturated. Examples thereof include the foregoing hydrocarbyl groups in which some or all hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl, 2-(perfluorohexyl)ethyl, 2-(perfluorooctyl)ethyl, and 2-(perfluorodecyl)ethyl.

Examples of the repeat units 7A to 7E are shown below, but not limited thereto. Herein R^{B} is as defined above.

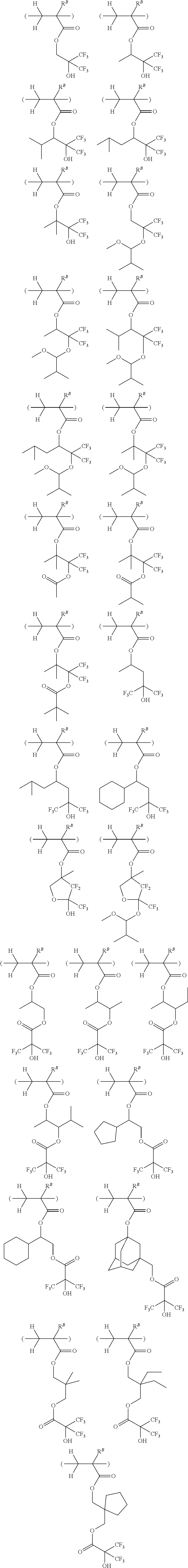

[chemical structure]

The polymeric surfactant may further contain repeat units other than the repeat units 7A to 7E. Typical other repeat units are those derived from methacrylic acid and α-trifluoromethyl acrylic acid derivatives. In the polymeric surfactant, the content of repeat units 7A to 7E is preferably at least 20 mol %, more preferably at least 60 mol %, most preferably 100 mol % of the overall repeat units.

The polymeric surfactant preferably has a Mw of 1,000 to 500,000, more preferably 3,000 to 100,000 and a Mw/Mn of 1.0 to 2.0, more preferably 1.0 to 1.6.

The polymeric surfactant may be synthesized by any desired method, for example, by dissolving an unsaturated bond-containing monomer or monomers providing repeat units 7A to 7E and optionally other repeat units in an organic solvent, adding a radical initiator, and heating for polymerization. Suitable organic solvents used herein include toluene, benzene, THF, diethyl ether, and dioxane. Examples of the polymerization initiator used herein include AIBN, 2,2′-azobis(2,4-dimethylvaleronitrile), dimethyl 2,2-azobis(2-methylpropionate), benzoyl peroxide, and lauroyl peroxide. Preferably the reaction temperature is 50 to 100° C. and the reaction time is 4 to 24 hours. The acid labile group that has been incorporated in the monomer may be kept as such, or the polymer may be protected or partially protected therewith at the end of polymerization.

During the synthesis of polymeric surfactant, any known chain transfer agent such as dodecyl mercaptan or 2-mercaptoethanol may be added for molecular weight control purpose. The amount of chain transfer agent added is preferably 0.01 to 10 mol % based on the total moles of monomers to be polymerized.

When the resist composition contains a surfactant (F), the amount thereof is preferably 0.1 to 50 parts by weight, and more preferably 0.5 to 10 parts by weight per 80 parts by weight of the base polymer (A). At least 0.1 part of the surfactant is effective in improving the receding contact angle with water of the resist film at its surface. Up to 50 parts of the surfactant is effective in forming a resist film having a low rate of dissolution in a developer and capable of maintaining the height of a small-size pattern formed therein. The surfactant (F) may be used alone or in admixture.

### (G) Dissolution Inhibitor

The resist composition may further include (G) a dissolution inhibitor. In the case of positive resist compositions, the inclusion of a dissolution inhibitor may lead to an increased difference in dissolution rate between exposed and unexposed areas and a further improvement in resolution.

The dissolution inhibitor which can be used herein is a compound having at least two phenolic hydroxy groups on the molecule, in which an average of from 0 to 100 mol % of all the hydrogen atoms on the phenolic hydroxy groups are replaced by acid labile groups or a compound having at least one carboxy group on the molecule, in which an average of 50 to 100 mol % of all the hydrogen atoms on the carboxy groups are replaced by acid labile groups, both the compounds having a molecular weight of 100 to 1,000, and preferably 150 to 800. Typical are bisphenol A, trisphenol, phenolphthalein, cresol novolac, naphthalenecarboxylic acid, adamantanecarboxylic acid, and cholic acid derivatives in which the hydrogen atom on the hydroxy or carboxy group is replaced by an acid labile group, as described in U.S. Pat. No. 7,771,914 (JP-A 2008-122932, paragraphs [0155]-[0178]).

In the resist composition, the dissolution inhibitor (G) is preferably added in an amount of 0 to 50 parts, more preferably 5 to 40 parts by weight per 80 parts by weight of the base polymer (A). The dissolution inhibitor may be used alone or in admixture of two or more.

### (H) Other Components

In addition to the foregoing components, the resist composition may further contain (H) another component, for example, a compound which is decomposed with an acid to generate another acid (i.e., acid amplifier compound), organic acid derivative, fluorinated alcohol, and water repellency improver. Each additional component may be used alone or in admixture of two or more.

The acid amplifier compound is described in JP-A 2009-269953 and JP-A 2010-215608. The acid amplifier compound is preferably used in an amount of 0 to 5 parts, more preferably 0 to 3 parts by weight per 80 parts by weight of the base polymer (A). An extra amount of the acid amplifier compound can make the acid diffusion control difficult and cause degradations to resolution and pattern profile. With respect to the organic acid derivative and fluorinated alcohol, reference should be made to JP-A 2009-269953 and JP-A 2010-215608.

The water repellency improver may be used in the topcoatless immersion lithography. Suitable water repellency improvers include polymers having a fluoroalkyl group and polymers having a specific structure with a 1,1,1,3,3,3-hexafluoro-2-propanol residue and are described in JP-A 2007-297590 and JP-A 2008-111103, for example. The water repellency improver to be added to the resist composition should be soluble in alkaline developers and organic solvent developers. The water repellency improver of specific structure with a 1,1,1,3,3,3-hexafluoro-2-propanol residue is well soluble in the developer. A polymer comprising repeat units having an amino group or amine salt serves as the water repellency improver and is effective for preventing evaporation of acid during PEB, thus preventing any hole pattern opening failure after development. An appropriate amount of the water repellency improver is 0 to 20 parts, preferably 0.5 to 10 parts by weight per 80 parts by weight of the base polymer (A).

### [Process]

The chemically amplified resist composition is used in the fabrication of various integrated circuits. Pattern formation using the resist composition may be performed by well-known lithography processes. The process generally involves the steps of applying the resist composition onto a substrate to form a resist film thereon, exposing the resist film to high-energy radiation, and developing the exposed resist film in a developer. If necessary, any additional steps may be added.

For example, the resist composition is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, MoSi₂, or SiO₂) by a suitable coating technique such as spin coating, roll coating, flow coating, dipping, spraying or doctor coating. The coating is prebaked on a hotplate at a temperature of preferably 60 to 150° C. for 10 seconds to 30 minutes, more preferably at 80 to 120° C. for 30 seconds to 20 minutes. The resulting resist film is generally 0.01 to 2.0 μm thick.

Then the resist film is exposed to high-energy radiation. Examples of the high-energy radiation include UV, deep-UV, EB, EUV of wavelength 3 to 15 nm, x-ray, soft x-ray, excimer laser light, γ-ray or synchrotron radiation. On use of UV, deep UV, EUV, x-ray, soft x-ray, excimer laser, γ-ray or synchrotron radiation, the resist film is exposed directly or through a mask having a desired pattern, preferably in a dose of about 1 to 200 mJ/cm², more preferably about 10 to 100 mJ/cm². On use of EB, a pattern may be written directly or through a mask having a desired pattern, preferably in a dose of about 0.1 to 100 μC/cm², more preferably about 0.5 to 50 μC/cm². The resist composition is suited for micropatterning using high-energy radiation such as KrF excimer laser of wavelength 248 nm, ArF excimer laser of wavelength 193 nm, EB, EUV of wavelength 3 to 15 nm, x-ray, soft x-ray, γ-ray or synchrotron radiation.

After the exposure, the resist film may be baked (PEB) on a hotplate at 60 to 150° C. for 10 seconds to 30 minutes, preferably at 80 to 120° C. for 30 seconds to 20 minutes.

After the exposure or PEB, the resist film is developed with a developer in the form of an aqueous base solution for 3 seconds to 3 minutes, preferably 5 seconds to 2 minutes by conventional techniques such as dip, puddle and spray techniques. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). The resist film in the exposed area is dissolved in the developer whereas the resist film in the unexposed area is not dissolved. In this way, the desired positive pattern is formed on the substrate.

In an alternative embodiment, a negative pattern may be formed via organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate, and mixtures thereof.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents. Specifically, suitable alcohols of 3 to 10 carbon atoms include n-propyl alcohol, isopropyl alcohol, 1-butyl alcohol, 2-butyl alcohol, isobutyl alcohol, t-butyl alcohol, 1-pentanol, 2-pentanol, 3-pentanol, t-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol. Suitable ether compounds of 8 to 12 carbon atoms include di-n-butyl ether, diisobutyl ether, di-s-butyl ether, di-n-pentyl ether, diisopentyl ether, di-s-pentyl ether, di-t-pentyl ether, and di-n-hexyl ether. Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne. Suitable aromatic solvents include toluene, xylene, ethylbenzene, isopropylbenzene, t-butylbenzene and mesitylene. The solvents may be used alone or in admixture.

Rinsing is effective for minimizing the risks of resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by coating a shrink agent thereto, and baking such that the shrink agent may undergo crosslinking at the resist surface as a result of the acid catalyst diffusing from the resist layer during bake, and the shrink agent may attach to the sidewall of the hole pattern. The bake is preferably at a temperature of 70 to 180° C., more preferably 80 to 170° C., for a time of 10 to 300 seconds. The extra shrink agent is stripped and the hole pattern is shrunk.

### EXAMPLES

Examples of the invention are given below by way of illustration and not by way of limitation. The abbreviation “pbw” is parts by weight.

### [1]Synthesis of Base Polymers

The monomers used in the synthesis of base polymers are shown below.

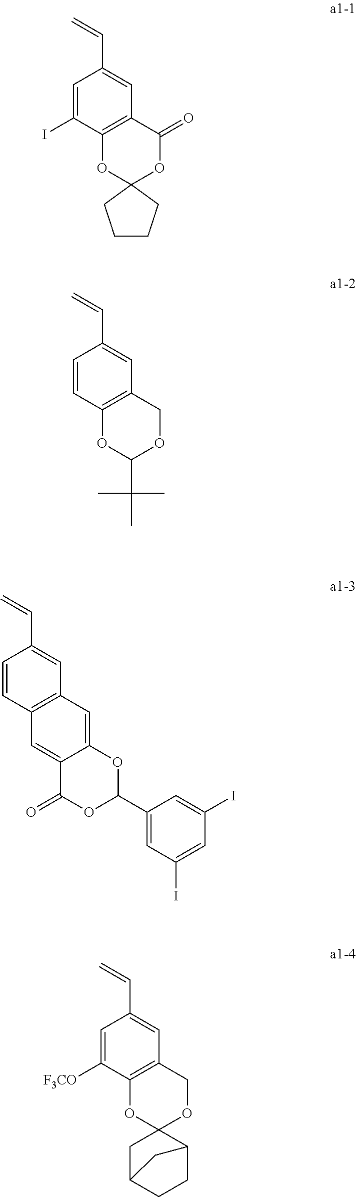 [SMILES: C=Cc1cc(I)c2c(c1)C(=O)OC1(CCCC1)O2 ; C=Cc1ccc2c(c1)COC(C(C)(C)C)O2 ; C=Cc1ccc2cc3c(cc2c1)OC(c1cc(I)cc(I)c1)OC3=O ; C=Cc1cc2c(c(OC(F)(F)F)c1)OC1(CC3CCC1C3)OC2]

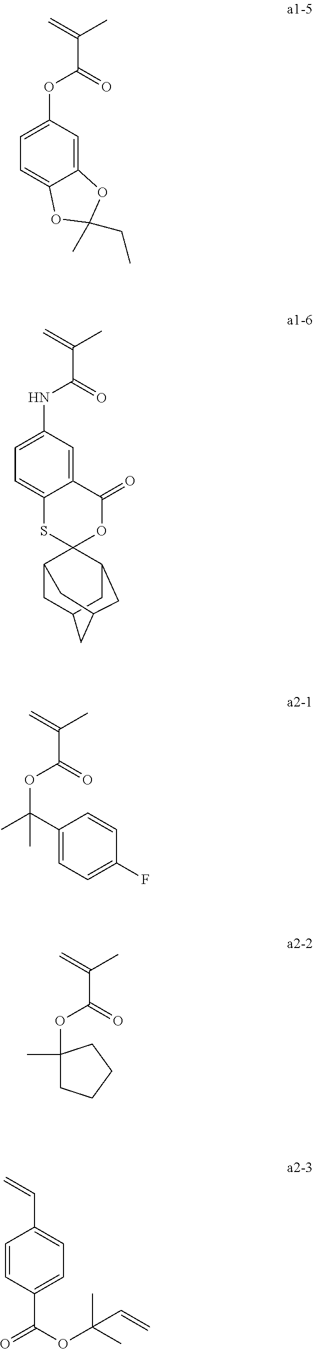

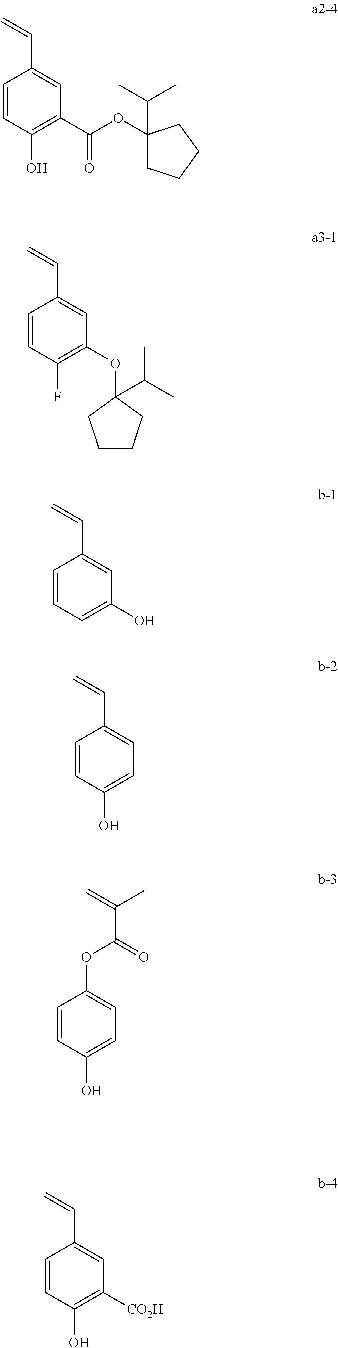

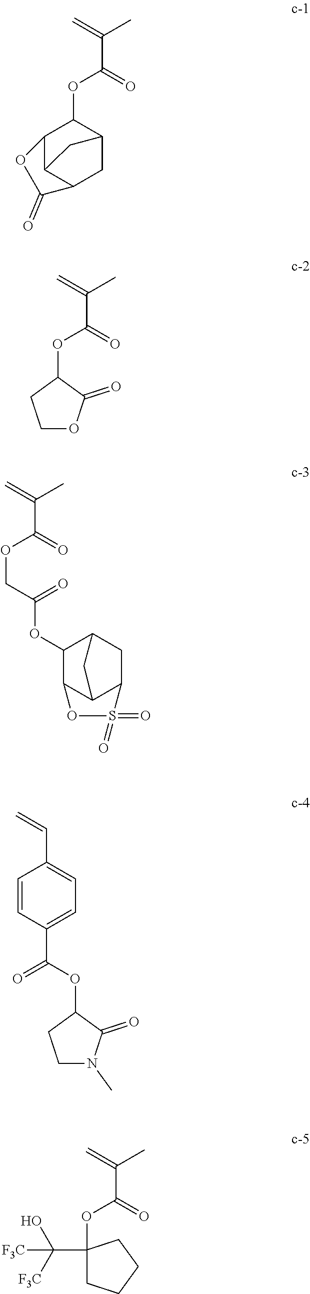

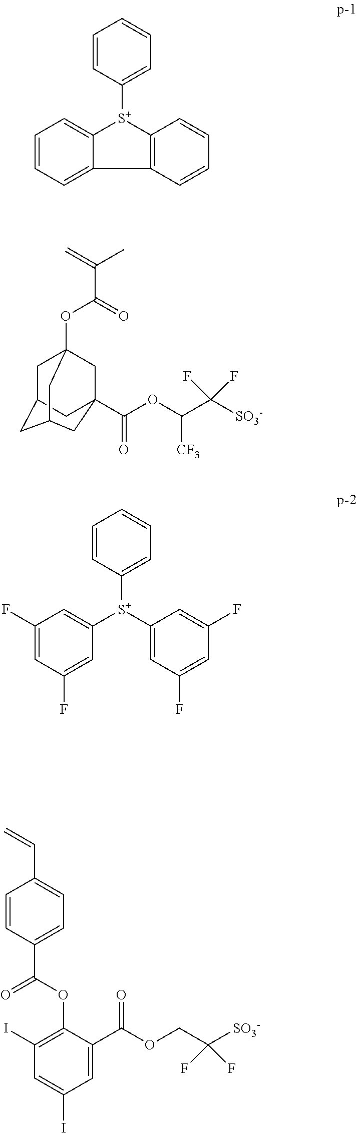

### Synthesis Example 1-1

### Synthesis of Polymer P-1

A flask under nitrogen atmosphere was charged with 53.1 g of Monomer a1-1, 35.8 g of Monomer b-1, 11.1 g of Monomer c-1, 5.72 g of V-601 (dimethyl 2,2′-azobis(2-methylpropionate) by Fujifilm Wako Pure Chemical Corp.), and 139 g of MEK to form a monomer/initiator solution. Another flask under nitrogen atmosphere was charged with 46 g of MEK, which was heated at 80° C. with stirring. The monomer/initiator solution was added dropwise to the MEK over 4 hours. At the end of addition, the polymerization solution was continuously stirred for 2 hours while maintaining the temperature at 80° C. The polymerization solution was cooled to room temperature, after which it was added dropwise to 3,000 g of hexane with vigorous stirring. The precipitate was collected by filtration. The precipitate was washed twice with 600 g of hexane and vacuum dried at 50° C. for 20 hours, obtaining Polymer P-1 as white powder. Amount 96.4 g, yield 96%. Polymer P-1 had a Mw of 5,800 and a Mw/Mn of 1.51. It is noted that Mw is measured by GPC versus polystyrene standards using THF solvent.

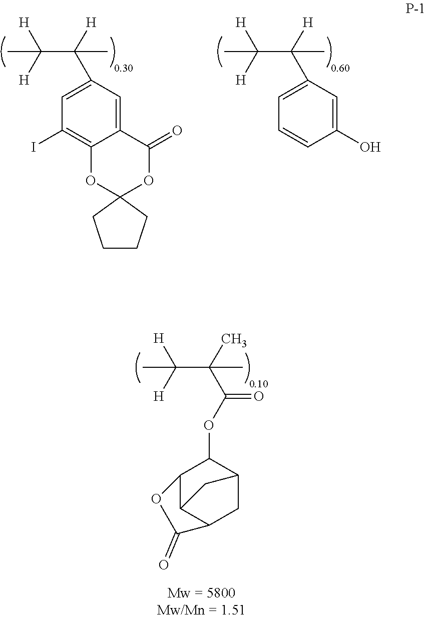

### Synthesis Examples 1-2 to 1-35 and Comparative Examples 1-1 to 1-22

### Synthesis of Polymers P-2 to P-35 and Comparative Polymers CP-1 to CP-22

Polymers shown in Tables 1 and 2 were synthesized by the same procedure as in Synthesis Example 1-1 except that the type and amount (blending ratio) of monomers were changed.

TABLE 1

| | | Incorporation | | Incorporation | | Incorporation |
|---|---|---|---|---|---|---|
| | | ratio | | ratio | | ratio |
| Polymer | Unit 1 | (mol %) | Unit 2 | (mol %) | Unit 3 | (mol %) |
| P-1 | a1-1 | 30 | b-1 | 60 | c-1 | 10 |
| P-2 | a1-2 | 30 | b-1 | 60 | c-1 | 10 |
| P-3 | a1-3 | 30 | b-1 | 60 | c-1 | 10 |
| P-4 | a1-4 | 30 | b-1 | 60 | c-1 | 10 |
| P-5 | a1-5 | 30 | b-1 | 60 | c-1 | 10 |
| P-6 | a1-6 | 30 | b-1 | 60 | c-1 | 10 |
| P-7 | a1-1 | 30 | b-2 | 60 | c-1 | 10 |
| P-8 | a1-2 | 30 | b-2 | 60 | c-1 | 10 |
| P-9 | a1-3 | 30 | b-2 | 60 | c-1 | 10 |
| P-10 | a1-4 | 30 | b-2 | 60 | c-1 | 10 |
| P-11 | a1-5 | 30 | b-2 | 60 | c-1 | 10 |
| P-12 | a1-6 | 30 | b-2 | 60 | c-1 | 10 |
| P-13 | a1-1 | 30 | b-1 | 70 | — | — |
| P-14 | a1-1 | 30 | b-2 | 70 | — | — |
| P-15 | a1-1 | 30 | b-3 | 70 | — | — |
| P-16 | a1-1 | 30 | b-4 | 70 | — | — |
| P-17 | a1-1 | 30 | b-1 | 60 | c-1 | 10 |
| P-18 | a1-1 | 30 | b-1 | 60 | c-2 | 10 |
| P-19 | a1-1 | 30 | b-1 | 60 | c-3 | 10 |
| P-20 | a1-1 | 30 | b-1 | 60 | c-4 | 10 |
| P-21 | a1-1 | 30 | a2-1 | 10 | b-1 | 50 |
| P-22 | a1-1 | 30 | a2-2 | 10 | b-1 | 50 |
| P-23 | a1-1 | 30 | a2-3 | 10 | b-1 | 50 |
| P-24 | a1-1 | 30 | a2-4 | 10 | b-1 | 50 |
| P-25 | a1-1 | 30 | a2-5 | 10 | b-1 | 50 |
| P-26 | a1-1 | 30 | a2-1 | 15 | b-1 | 50 |
| P-27 | a1-2 | 35 | a2-2 | 10 | b-3 | 50 |
| P-28 | a1-4 | 35 | a2-3 | 10 | b-2 | 45 |
| P-29 | a1-5 | 25 | a2-4 | 15 | b-1 | 50 |
| P-30 | a1-3 | 25 | a3-1 | 30 | b-4 | 35 |
| P-31 | a1-1 | 35 | a2-1 | 10 | b-1 | 40 |
| P-32 | a1-2 | 35 | a2-3 | 10 | b-2 | 45 |
| P-33 | a1-1 | 25 | a2-1 | 10 | a3-1 | 10 |
| P-34 | a1-2 | 35 | a2-4 | 15 | b-3 | 40 |
| P-35 | a1-4 | 35 | a3-1 | 15 | b-2 | 40 |

| | | Incorporation | | Incorporation | | |
|---|---|---|---|---|---|---|
| | | ratio | | ratio | | |
| Polymer | Unit 4 | (mol %) | Unit 5 | (mol %) | Mw | Mw/Mn |
| P-1 | — | — | — | — | 5,800 | 1.51 |
| P-2 | — | — | — | — | 5,600 | 1.52 |
| P-3 | — | — | — | — | 5,900 | 1.56 |
| P-4 | — | — | — | — | 6,000 | 1.52 |
| P-5 | — | — | — | — | 5,900 | 1.54 |
| P-6 | — | — | — | — | 6,100 | 1.55 |
| P-7 | — | — | — | — | 6,200 | 1.53 |
| P-8 | — | — | — | — | 5,800 | 1.55 |
| P-9 | — | — | — | — | 5,700 | 1.53 |
| P-10 | — | — | — | — | 6,100 | 1.52 |
| P-11 | — | — | — | — | 6,000 | 1.51 |
| P-12 | — | — | — | — | 6,300 | 1.53 |
| P-13 | — | — | — | — | 5,800 | 1.56 |
| P-14 | — | — | — | — | 5,700 | 1.54 |
| P-15 | — | — | — | — | 5,900 | 1.52 |
| P-16 | — | — | — | — | 6,000 | 1.53 |
| P-17 | — | — | — | — | 5,800 | 1.54 |
| P-18 | — | — | — | — | 6,200 | 1.55 |
| P-19 | — | — | — | — | 6,000 | 1.51 |
| P-20 | — | — | — | — | 6,100 | 1.52 |
| P-21 | c-1 | 10 | — | — | 5,900 | 1.54 |
| P-22 | c-1 | 10 | — | — | 5,800 | 1.51 |
| P-23 | c-1 | 10 | — | — | 5,600 | 1.54 |
| P-24 | c-1 | 10 | — | — | 6,300 | 1.53 |
| P-25 | c-1 | 10 | — | — | 6,100 | 1.54 |
| P-26 | c-5 | 5 | — | — | 5,700 | 1.51 |
| P-27 | — | — | — | — | 5,900 | 1.56 |
| P-28 | c-3 | 10 | — | — | 6,000 | 1.53 |
| P-29 | c-2 | 10 | — | — | 6,300 | 1.56 |
| P-30 | c-4 | 10 | — | — | 6,100 | 1.53 |
| P-31 | c-1 | 10 | c-5 | 5 | 5,900 | 1.52 |
| P-32 | c-2 | 5 | c-5 | 5 | 6,200 | 1.51 |
| P-33 | b-2 | 45 | c-1 | 10 | 5,800 | 1.50 |
| P-34 | c-4 | 10 | — | — | 6,000 | 1.51 |
| P-35 | c-3 | 10 | — | — | 6,100 | 1.51 |

TABLE 2

| | | Incorporation | | Incorporation | | Incorporation |
|---|---|---|---|---|---|---|
| | | ratio | | ratio | | ratio |
| Polymer | Unit 1 | (mol %) | Unit 2 | (mol %) | Unit 3 | (mol %) |
| CP-1 | a2-1 | 55 | b-1 | 30 | p-1 | 15 |
| CP-2 | a2-1 | 55 | b-1 | 30 | p-2 | 15 |
| CP-3 | a2-2 | 55 | b-1 | 30 | p-1 | 15 |
| CP-4 | a2-2 | 55 | b-1 | 30 | p-2 | 15 |
| CP-5 | a2-1 | 55 | b-2 | 30 | p-1 | 15 |
| CP-6 | a2-1 | 55 | b-2 | 30 | p-2 | 15 |
| CP-7 | a2-1 | 50 | b-1 | 30 | c-5 | 5 |
| CP-8 | a2-1 | 10 | a3-1 | 30 | b-3 | 30 |
| CP-9 | a1-1 | 35 | b-2 | 50 | p-1 | 15 |
| CP-10 | a1-1 | 35 | b-2 | 50 | p-2 | 15 |
| CP-11 | a2-3 | 50 | b-2 | 45 | c-1 | 15 |
| CP-12 | a2-4 | 50 | b-2 | 45 | c-2 | 15 |
| CP-13 | a3-1 | 50 | b-4 | 35 | c-4 | 15 |
| CP-14 | a2-1 | 50 | b-1 | 50 | — | — |
| CP-15 | a2-1 | 40 | b-2 | 60 | — | — |
| CP-16 | a2-2 | 50 | b-2 | 50 | — | — |
| CP-17 | a2-3 | 50 | b-3 | 35 | c-1 | 25 |
| CP-18 | a2-4 | 50 | b-4 | 25 | c-3 | 25 |
| CP-19 | a2-1 | 30 | a3-1 | 20 | b-1 | 35 |
| CP-20 | a2-3 | 25 | a3-1 | 25 | c-1 | 35 |
| CP-21 | a2-2 | 35 | a3-1 | 15 | b-2 | 30 |
| CP-22 | a3-1 | 50 | b-1 | 30 | c-1 | 15 |

| | | Incorporation | | Incorporation | | |
|---|---|---|---|---|---|---|
| | | ratio | | ratio | | |
| Polymer | Unit 4 | (mol %) | Unit 5 | (mol %) | Mw | Mw/Mn |
| CP-1 | — | — | — | — | 9,600 | 1.56 |
| CP-2 | — | — | — | — | 9,800 | 1.57 |
| CP-3 | — | — | — | — | 9,800 | 1.55 |
| CP-4 | — | — | — | — | 9,600 | 1.54 |
| CP-5 | — | — | — | — | 9,700 | 1.56 |
| CP-6 | — | — | — | — | 9,500 | 1.52 |
| CP-7 | p-1 | 15 | — | — | 9,400 | 1.53 |
| CP-8 | c-1 | 20 | p-2 | 10 | 9,700 | 1.54 |
| CP-9 | — | — | — | — | 9,800 | 1.54 |
| CP-10 | — | — | — | — | 9,500 | 1.55 |
| CP-11 | — | — | — | — | 6,100 | 1.55 |
| CP-12 | — | — | — | — | 6,000 | 1.51 |
| CP-13 | — | — | — | — | 5,800 | 1.54 |
| CP-14 | — | — | — | — | 6,200 | 1.51 |
| CP-15 | — | — | — | — | 6,000 | 1.56 |
| CP-16 | — | — | — | — | 6,100 | 1.53 |
| CP-17 | — | — | — | — | 5,900 | 1.56 |
| CP-18 | — | — | — | — | 5,800 | 1.53 |
| CP-19 | c-1 | 15 | — | — | 5,600 | 1.52 |
| CP-20 | c-4 | 15 | — | — | 6,300 | 1.51 |
| CP-21 | c-3 | 10 | c-5 | 10 | 6,100 | 1.50 |
| CP-22 | c-5 | 5 | — | — | 5,700 | 1.55 |

### [2]Synthesis of Photoacid Generator

### Synthesis Example 2-1

Synthesis of photoacid generator PAG-1

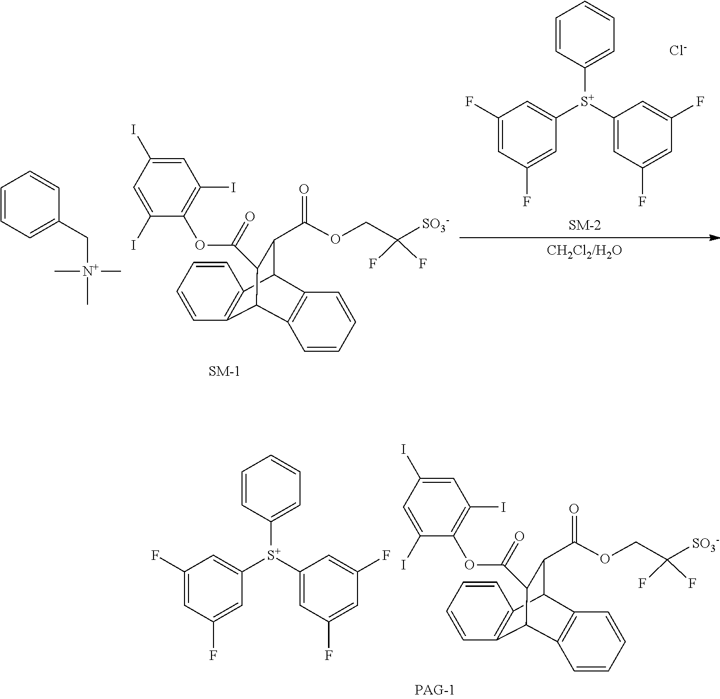

Under nitrogen atmosphere, 10.4 g of reactant SM-1, 4.5 g of reactant SM-2, 50 g of methylene chloride, and 30 g of water were combined and stirred for 15 minutes. The organic layer was taken out, washed with water, and concentrated under reduced pressure. Methyl isobutyl ketone, 50 g, was added to the concentrate, followed by azeotropic dewatering. The residue was purified by silica gel column chromatography. The target PAG-1 was obtained as oily matter (amount 11.5 g, yield 94%).

### MALDI TOF-MS:

positive M⁺ 335 (corresponding to C₁₈H₁₁F₄S⁺)
negative M⁻ 891 (corresponding to C₂₆H₁₆F₂I₃O₇S⁻)

### Examples 2-2 to 2-9

### Synthesis of PAG-2 to PAG-9

Photoacid generators PAG-2 to PAG-9, shown below, were synthesized using the corresponding reactants and well-known organic synthesis reaction.

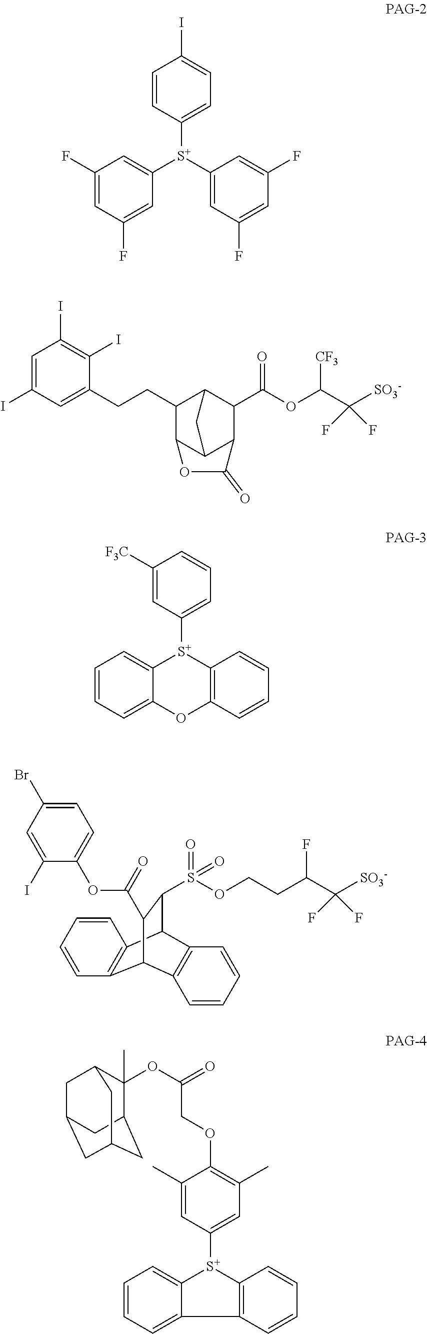

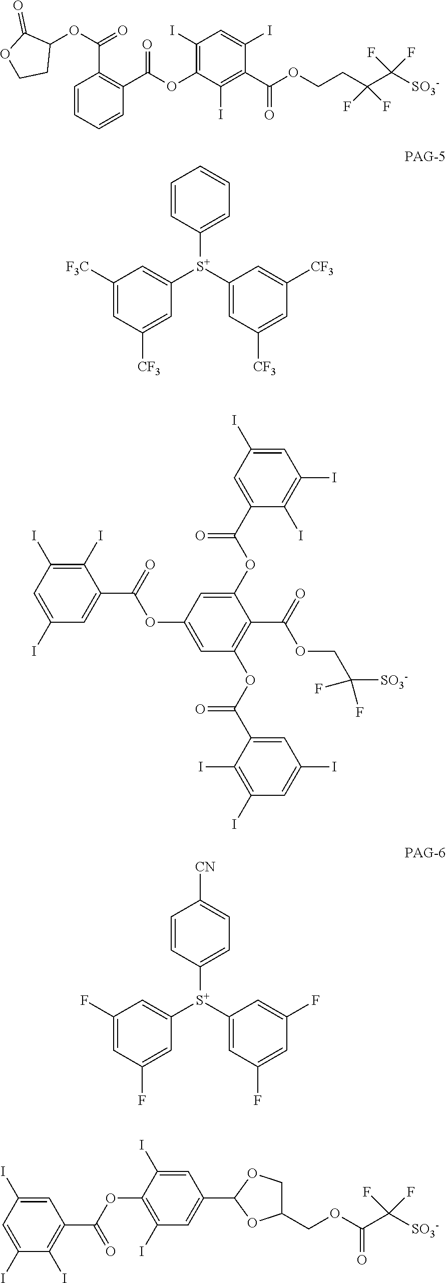

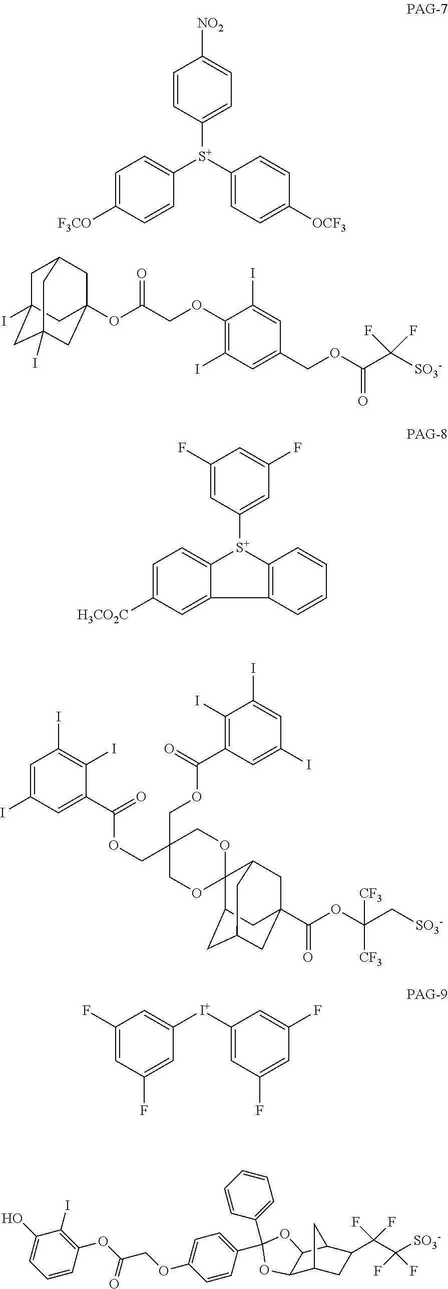

### Comparative Synthesis Examples 2-1 to 2-6

Synthesis of cPAG-1 to cPAG-6

Comparative photoacid generators cPAG-1 to cPAG-6, shown below, were synthesized using the corresponding reactants and well-known organic synthesis reaction.

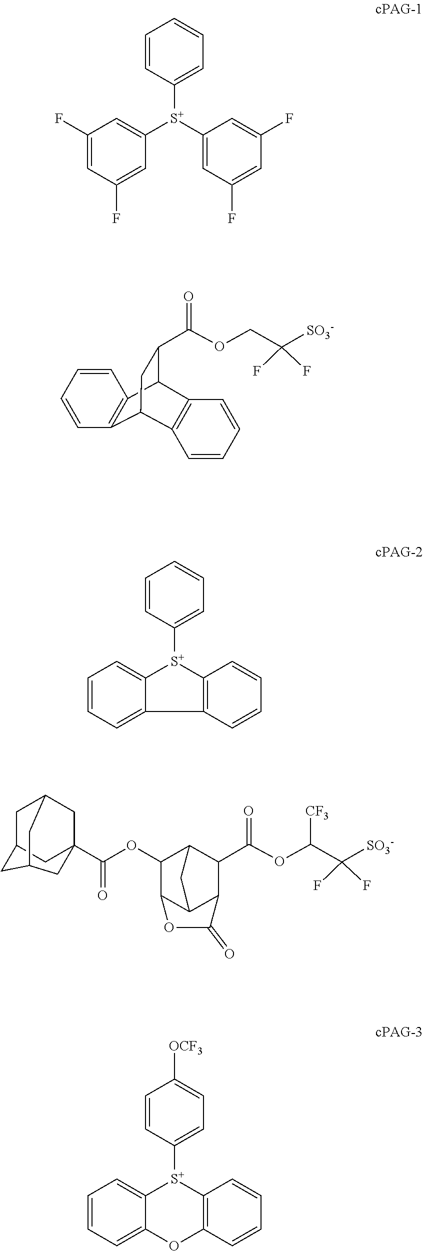

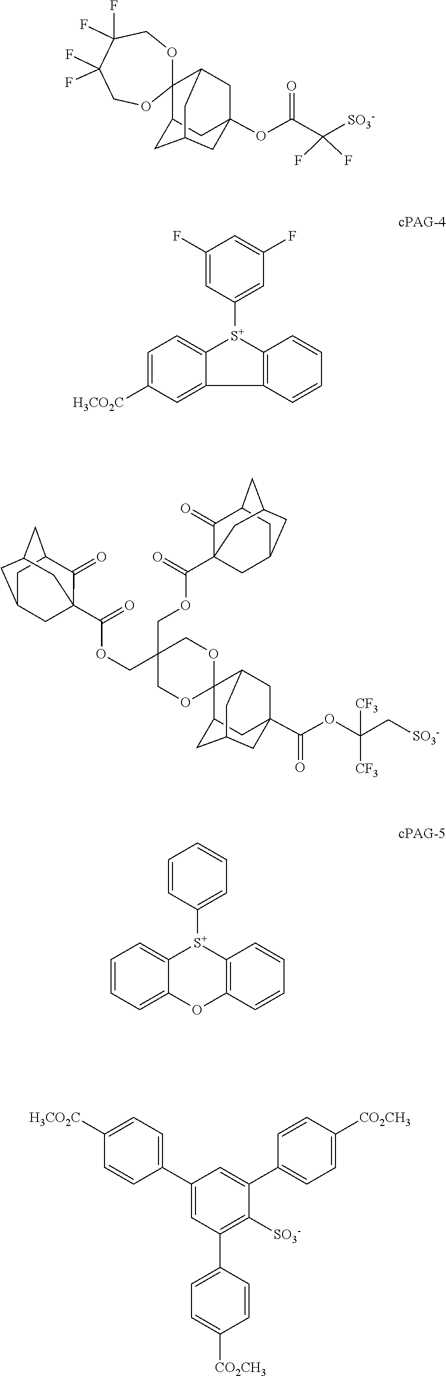

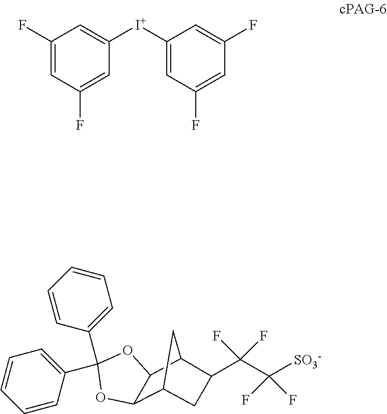

### [3]Preparation of Resist Composition

### Examples 1-1 to 1-43 and Comparative Examples 1-1 to 1-39

A chemically amplified resist composition (R-1 to R-43, CR-1 to CR-39) was prepared by dissolving an inventive base polymer (P-1 to P-35) or comparative base polymer (CP-1 to CP-22), photoacid generator (PAG-1 to PAG-9), comparative photoacid generator (cPAG-1 to cPAG-5), another photoacid generator (PAG-Z), and quencher (Q-1 to Q-4) in an organic solvent containing 0.01 wt % of surfactant FC-4430 (3M) in accordance with the formulation shown in Tables 3 to 6, and filtering the solution through a Teflon® filter with a pore size of 0.2 μm.

TABLE 3

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Example | 1-1 | R-1 | P-1 (80) | PAG-1 (18) | Q-1 (7.8) | PGMEA (2250) | EL (2800) | DAA (550) |
| | 1-2 | R-2 | P-1 (80) | PAG-2 (19) | Q-1 (7.8) | PGMEA (2250) | EL (2800) | DAA (550) |
| | 1-3 | R-3 | P-1 (80) | PAG-3 (18) | Q-1 (7.8) | PGMEA (2250) | EL (2800) | DAA (550) |
| | 1-4 | R-4 | P-1 (80) | PAG-4 (17) | Q-1 (7.6) | PGMEA (2250) | EL (2800) | DAA (550) |
| | 1-5 | R-5 | P-1 (80) | PAG-5 (18) | Q-1 (7.8) | PGMEA (2250) | EL (2800) | DAA (550) |
| | 1-6 | R-6 | P-1 (80) | PAG-6 (19) | Q-1 (7.8) | PGMEA (2250) | EL (2800) | DAA (550) |
| | 1-7 | R-7 | P-1 (80) | PAG-7 (18) | Q-1 (7.6) | PGMEA (2250) | EL (2800) | DAA (550) |
| | 1-8 | R-8 | P-1 (80) | PAG-8 (18) | Q-1 (7.8) | PGMEA (2250) | EL (2800) | DAA (550) |
| | 1-9 | R-9 | P-1 (80) | PAG-9 (19) | Q-1 (7.8) | PGMEA (2250) | EL (2800) | DAA (550) |
| | 1-10 | R-10 | P-2 (80) | PAG-1 (18) | Q-1 (7.8) | PGMEA (2250) | EL (2800) | DAA (550) |
| | 1-11 | R-11 | P-3 (80) | PAG-1 (17) | Q-1 (7.8) | PGMEA (2250) | EL (2800) | DAA (550) |
| | 1-12 | R-12 | P-4 (80) | PAG-1 (18) | Q-1 (7.8) | PGMEA (2250) | EL (2800) | DAA (550) |
| | 1-13 | R-13 | P-5 (80) | PAG-1 (18) | Q-1 (7.8) | PGMEA (2250) | EL (2800) | DAA (550) |
| | 1-14 | R-14 | P-6 (80) | PAG-1 (19) | Q-1 (7.6) | PGMEA (2250) | EL (2800) | DAA (550) |
| | 1-15 | R-15 | P-7 (80) | PAG-2 (18) | Q-1 (7.8) | PGMEA (2250) | EL (2800) | DAA (550) |
| | 1-16 | R-16 | P-8 (80) | PAG-2 (18) | Q-1 (7.6) | PGMEA (2250) | EL (2800) | DAA (550) |
| | 1-17 | R-17 | P-9 (80) | PAG-2 (18) | Q-1 (7.8) | PGMEA (2250) | EL (2800) | DAA (550) |
| | 1-18 | R-18 | P-10 (80) | PAG-2 (18) | Q-1 (7.8) | PGMEA (2250) | EL (2800) | DAA (550) |
| | 1-19 | R-19 | P-11 (80) | PAG-2 (18) | Q-1 (7.8) | PGMEA (2250) | EL (2800) | DAA (550) |
| | 1-20 | R-20 | P-12 (80) | PAG-2 (17) | Q-1 (7.8) | PGMEA (2250) | EL (2800) | DAA (550) |
| | 1-21 | R-21 | P-13 (80) | PAG-3 (18) | Q-2 (7.6) | PGMEA (2250) | EL (2800) | DAA (550) |
| | 1-22 | R-22 | P-14(80) | PAG-5 (18) | Q-1 (7.8) | PGMEA (2250) | EL (2800) | DAA (550) |
| | 1-23 | R-23 | P-15 (80) | PAG-6 (17) | Q-3 (7.8) | PGMEA (2250) | EL (2800) | DAA (550) |
| | 1-24 | R-24 | P-16 (80) | PAG-4 (18) | Q-2 (7.8) | PGMEA (2250) | EL (2800) | DAA (550) |
| | 1-25 | R-25 | P-17 (80) | PAG-8 (14) | Q-1 (7.8) | PGMEA (2250) | EL (2800) | DAA (550) |
| | | | | PAG-Z (6) | | | | |
| | 1-26 | R-26 | P-18 (80) | PAG-9 (19) | Q-3 (7.6) | PGMEA (2250) | EL (2800) | DAA (550) |
| | 1-27 | R-27 | P-19 (80) | PAG-7 (18) | Q-1 (7.8) | PGMEA (2250) | EL (2800) | DAA (550) |
| | 1-28 | R-28 | P-20 (80) | PAG-1 (12) | Q-1 (7.8) | PGMEA (2250) | EL (2800) | DAA (550) |
| | | | | PAG-Z (6) | | | | |
| | 1-29 | R-29 | P-21 (80) | PAG-2 (12) | Q-1 (7.8) | PGMEA (2250) | EL (2800) | DAA (550) |
| | | | | PAG-Z (6) | | | | |
| | 1-30 | R-30 | P-22 (80) | PAG-4 (17) | Q-1 (7.6) | PGMEA (2250) | EL (2800) | DAA (550) |

TABLE 4

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Example | 1-31 | R-31 | P-23 (80) | PAG-6 (18) | Q-3 (7.8) | PGMEA (2250) | EL (2800) | DAA (550) |
| | 1-32 | R-32 | P-24 (80) | PAG-5 (18) | Q-1 (4.8) | PGMEA (2250) | EL (2800) | DAA (550) |
| | | | | | Q-4 (3.0) | | | |
| | 1-33 | R-33 | P-25 (80) | PAG-7 (18) | Q-1 (7.8) | PGMEA (2250) | EL (2800) | DAA (550) |
| | 1-34 | R-34 | P-26 (80) | PAG-6 (18) | Q-1 (7.8) | PGMEA (2250) | EL (2800) | DAA (550) |
| | 1-35 | R-35 | P-27 (80) | PAG-3 (19) | Q-2 (4.5) | PGMEA (2250) | EL (2800) | DAA (550) |
| | | | | | Q-4 (3.2) | | | |
| | 1-36 | R-36 | P-28 (80) | PAG-8 (18) | Q-1 (7.8) | PGMEA (2250) | EL (2800) | DAA (550) |
| | 1-37 | R-37 | P-29 (80) | PAG-1 (18) | Q-1 (7.8) | PGMEA (2250) | EL (2800) | DAA (550) |
| | 1-38 | R-38 | P-30 (80) | PAG-3 (12) | Q-1 (7.8) | PGMEA (2250) | EL (2800) | DAA (550) |
| | | | | PAG-Z (6) | | | | |
| | 1-39 | R-39 | P-31 (80) | PAG-7 (18) | Q-1 (7.8) | PGMEA (2250) | EL (2800) | DAA (550) |
| | 1-40 | R-40 | P-32 (80) | PAG-5 (12) | Q-1 (7.6) | PGMEA (2250) | EL (2800) | DAA (550) |
| | | | | PAG-Z (6) | | | | |
| | 1-41 | R-41 | P-33 (80) | PAG-4 (17) | Q-3 (7.8) | PGMEA (2250) | EL (2800) | DAA (550) |
| | 1-42 | R-42 | P-34 (80) | PAG-1 (18) | Q-3 (4.5) | PGMEA (2250) | EL (2800) | DAA (550) |
| | | | | | Q-4 (3.3) | | | |
| | 1-43 | R-43 | P-35 (80) | PAG-2 (18) | Q-1 (7.8) | PGMEA (2250) | EL (2800) | DAA (550) |

TABLE 5

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Comparative | 1-1 | CR-1 | CP-1 (80) | — | Q-1 (7.8) | PGMEA (2250) | EL (2800) | DAA (550) |
| Example | 1-2 | CR-2 | CP-2 (80) | — | Q-1 (7.6) | PGMEA (2250) | EL (2800) | DAA (550) |
| | 1-3 | CR-3 | CP-1 (80) | PAG-1 (6) | Q-1 (7.8) | PGMEA (2250) | EL (2800) | DAA (550) |
| | 1-4 | CR-4 | CP-2 (80) | PAG-1 (6) | Q-1 (7.8) | PGMEA (2250) | EL (2800) | DAA (550) |
| | 1-5 | CR-5 | CP-1 (80) | cPAG-1 (6) | Q-1 (7.8) | PGMEA (2250) | EL (2800) | DAA (550) |
| | 1-6 | CR-6 | CP-2 (80) | cPAG-1 (6) | Q-1 (7.8) | PGMEA (2250) | EL (2800) | DAA (550) |
| | 1-7 | CR-7 | CP-3 (80) | — | Q-1 (7.6) | PGMEA (2250) | EL (2800) | DAA (550) |
| | 1-8 | CR-8 | CP-4 (80) | — | Q-1 (7.8) | PGMEA (2250) | EL (2800) | DAA (550) |
| | 1-9 | CR-9 | CP-3 (80) | PAG-2 (6) | Q-1 (7.8) | PGMEA (2250) | EL (2800) | DAA (550) |
| | 1-10 | CR-10 | CP-4 (80) | PAG-2 (6) | Q-1 (7.8) | PGMEA (2250) | EL (2800) | DAA (550) |
| | 1-11 | CR-11 | CP-3 (80) | cPAG-2 (6) | Q-1 (7.8) | PGMEA (2250) | EL (2800) | DAA (550) |
| | 1-12 | CR-12 | CP-4 (80) | cPAG-2 (6) | Q-1 (7.8) | PGMEA (2250) | EL (2800) | DAA (550) |
| | 1-13 | CR-13 | CP-5 (80) | — | Q-2 (7.6) | PGMEA (2250) | EL (2800) | DAA (550) |
| | 1-14 | CR-14 | CP-6 (80) | — | Q-1 (7.8) | PGMEA (2250) | EL (2800) | DAA (550) |
| | 1-15 | CR-15 | CP-7 (80) | — | Q-3 (7.6) | PGMEA (2250) | EL (2800) | DAA (550) |
| | 1-16 | CR-16 | CP-8 (80) | — | Q-2 (7.8) | PGMEA (2250) | EL (2800) | DAA (550) |
| | 1-17 | CR-17 | CP-9 (80) | — | Q-1 (7.8) | PGMEA (2250) | EL (2800) | DAA (550) |
| | 1-18 | CR-18 | CP-10 (80) | — | Q-3 (7.6) | PGMEA (2250) | EL (2800) | DAA (550) |
| | 1-19 | CR-19 | CP-11 (80) | cPAG-3 (18) | Q-1 (7.8) | PGMEA (2250) | EL (2800) | DAA (550) |
| | 1-20 | CR-20 | CP-12 (80) | cPAG-4 (18) | Q-3 (7.6) | PGMEA (2250) | EL (2800) | DAA (550) |

TABLE 6

| | | | Base | Photoacid | | | | |
|---|---|---|---|---|---|---|---|---|
| | | Resist | polymer | generator | Quencher | Solvent 1 | Solvent 2 | Solvent 3 |
| | | composition | (pbw) | (pbw) | (pbw) | (pbw) | (pbw) | (pbw) |
| Comparative | 1-21 | CR-21 | CP-11 (80) | PAG-3 (18) | Q-1 (7.8) | PGMEA (2250) | EL (2800) | DAA (550) |
| Example | 1-22 | CR-22 | CP-12 (80) | PAG-4 (18) | Q-3 (7.8) | PGMEA (2250) | EL (2800) | DAA (550) |
| | 1-23 | CR-23 | CP-13 (80) | cPAG-5 (18) | Q-1 (7.8) | PGMEA (2250) | EL (2800) | DAA (550) |
| | 1-24 | CR-24 | CP-14 (80) | cPAG-6 (18) | Q-2 (7.8) | PGMEA (2250) | EL (2800) | DAA (550) |
| | 1-25 | CR-25 | CP-15 (80) | cPAG-1 (18) | Q-1 (7.8) | PGMEA (2250) | EL (2800) | DAA (550) |
| | 1-26 | CR-26 | CP-15 (80) | PAG-1 (18) | Q-1 (7.8) | PGMEA (2250) | EL (2800) | DAA (550) |
| | 1-27 | CR-27 | CP-16 (80) | cPAG-2 (12) | Q-1 (7.6) | PGMEA (2250) | EL (2800) | DAA (550) |
| | | | | PAG-Z (6) | | | | |
| | 1-28 | CR-28 | CP-17 (80) | cPAG-4 (18) | Q-1 (7.8) | PGMEA (2250) | EL (2800) | DAA (550) |
| | 1-29 | CR-29 | CP-18 (80) | cPAG-6 (10) | Q-1 (7.8) | PGMEA (2250) | EL (2800) | DAA (550) |
| | | | | PAG-Z (8) | | | | |
| | 1-30 | CR-30 | CP-19 (80) | cPAG-3 (18) | Q-1 (4.8) | PGMEA (2250) | EL (2800) | DAA (550) |
| | | | | | Q-4 (3.0) | | | |
| | 1-31 | CR-31 | CP-20 (80) | cPAG-4 (14) | Q-1 (7.8) | PGMEA (2250) | EL (2800) | DAA (550) |
| | | | | PAG-Z (6) | | | | |
| | 1-32 | CR-32 | CP-21 (80) | cPAG-3 (18) | Q-2 (7.8) | PGMEA (2250) | EL (2800) | DAA (550) |
| | 1-33 | CR-33 | CP-22 (80) | cPAG-5 (18) | Q-3 (4.8) | PGMEA (2250) | EL (2800) | DAA (550) |
| | | | | | Q-4 (3.0) | | | |
| | 1-34 | CR-34 | P-1 (80) | cPAG-1 (18) | Q-1 (7.8) | PGMEA (2250) | EL (2800) | DAA (550) |
| | 1-35 | CR-35 | P-1 (80) | cPAG-2 (18) | Q-1 (7.8) | PGMEA (2250) | EL (2800) | DAA (550) |
| | 1-36 | CR-36 | P-1 (80) | cPAG-3 (18) | Q-1 (7.6) | PGMEA (2250) | EL (2800) | DAA (550) |
| | 1-37 | CR-37 | P-1 (80) | cPAG-4 (18) | Q-1 (7.6) | PGMEA (2250) | EL (2800) | DAA (550) |
| | 1-38 | CR-38 | P-1 (80) | cPAG-5 (18) | Q-1 (7.8) | PGMEA (2250) | EL (2800) | DAA (550) |
| | 1-39 | CR-39 | P-1 (80) | cPAG-6 (18) | Q-1 (7.6) | PGMEA (2250) | EL (2800) | DAA (550) |

The components in Tables 3 to 6 are identified below.

Organic solvent
PGMEA: propylene glycol monomethyl ether acetate
EL: ethyl lactate
DAA: diacetone alcohol

### Quenchers: Q-1 to Q-4

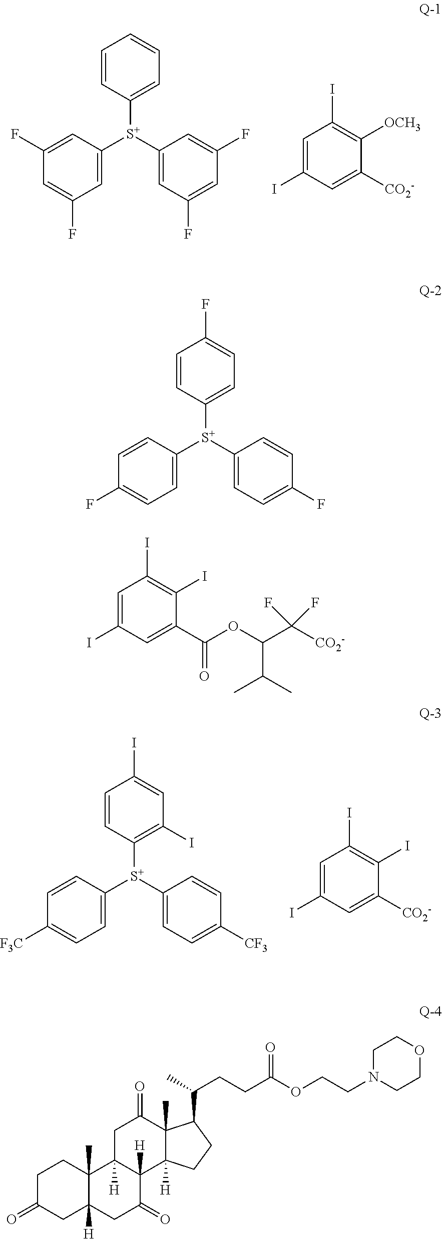

Other photoacid generator: PAG-Z

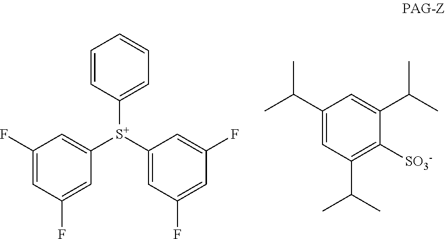

[4]EUV lithography test 1

### Examples 2-1 to 2-43 and Comparative Examples 2-1 to 2-39

Each of the chemically amplified resist compositions (R-1 to R-43, CR-1 to CR-39 in Tables 3 to 6) was spin coated on a silicon substrate having a 20-nm coating of silicon-containing spin-on hard mask SHB-A940 (Shin-Etsu Chemical Co., Ltd., silicon content 43 wt %) and prebaked on a hotplate at 100° C. for 60 seconds to form a resist film of 50 nm thick. Using an EUV scanner NXE3300 (ASML, NA 0.33, σ 0.9/0.6, dipole illumination), the resist film was exposed to EUV through a mask bearing a line-and-space (LS) pattern having a width of 18 nm and a pitch of 36 nm (on-wafer size) while changing the dose at a pitch of 1 mJ/cm² and the focus at a pitch of 0.020 μm. The resist film was baked (PEB) at the temperature shown in Tables 7 and 8 for 60 seconds. This was followed by puddle development in a 2.38 wt % TMAH aqueous solution for 30 seconds, rinsing with a surfactant-containing rinse fluid, and spin drying. A positive LS pattern was obtained.

The LS pattern was observed under CD-SEM (CG6300, Hitachi High-Technologies Corp.) and evaluated for sensitivity, exposure latitude (EL), LWR, depth of focus (DOF), and collapse limit by the following methods. The results are shown in Tables 7 and 8.

### [Evaluation of Sensitivity]

The optimum dose Eop (mJ/cm²) which provided an LS pattern with a line width of 18 nm and a pitch of 36 nm was determined and reported as sensitivity. A smaller value indicates a higher sensitivity.

### [Evaluation of EL]

The exposure dose which provided a LS pattern with a space width of 18 nm±10% (i.e., 16.2 to 19.8 nm) was determined. EL (%) is calculated from the exposure doses according to the following equation:

$$E L ( \% ) = ( \vert {E}_{1} - {E}_{2} \vert / Eop ) \times 100$$

wherein E1 is an optimum exposure dose which provides a LS pattern with a line width of 16.2 nm and a pitch of 36 nm, E2 is an optimum exposure dose which provides a LS pattern with a line width of 19.8 nm and a pitch of 36 nm, and Eop is an optimum exposure dose which provides a LS pattern with a line width of 18 nm and a pitch of 36 nm. A larger value indicates better performance.

### [Evaluation of LWR]

For the LS pattern formed by exposure at the optimum dose Eop, the line width was measured at 10 longitudinally spaced apart points, from which a 3-fold value (36) of the standard deviation (6) was determined and reported as LWR. A smaller value of 36 indicates a pattern having small roughness and uniform line width.

### [Evaluation of DOF]

As an index of DOF, a range of focus which provided a LS pattern with a size of 18 nm±10% (i.e., 16.2 to 19.8 nm) was determined. A greater value indicates a wider DOF.

### [Evaluation of Collapse Limit of Line Pattern]

For the LS pattern formed by exposure at the dose corresponding to the optimum focus, the line width was measured at 10 longitudinally spaced apart points. The minimum line size above which lines could be resolved without collapse was determined and reported as collapse limit. A smaller value indicates better collapse limit.

### [Evaluation of Development Defects]

The LS pattern of line width 18 nm and pitch 36 nm printed at the optimum dose was counted for defects using a defect inspection system (trade name KLA 2360 by KLA-Tencor Corp.). With a pixel size of 0.16 μm and a threshold of 20 set, the number of defects extracted from the difference obtained by overlapping a comparative image and a pixel unit was detected, from which the count of defects per unit area (count/cm²) was computed. On reviewing defects, development defects were classified and extracted from all the defects. The number of development defects per unit area (count/cm²) was computed. A sample is rated “A” for a count of less than 0.5, “B” for a count of 0.5 to less than 1.0, “C” for a count of 1.0 to less than 5.0, and “D” for a count of 5.0 or more. A smaller count indicates better performance.

TABLE 7

| | | | PEB | | | | | Collapse | |
|---|---|---|---|---|---|---|---|---|---|
| | | Resist | temp. | Eop | EL | LWR | DOF | limit | Development |
| | | composition | (° C.) | (mJ/cm²) | (%) | (nm) | (nm) | (nm) | defects |
| Example | 2-1 | R-1 | 100 | 34 | 19 | 2.2 | 120 | 10.6 | A |
| | 2-2 | R-2 | 90 | 34 | 18 | 2.4 | 110 | 10.7 | A |
| | 2-3 | R-3 | 100 | 35 | 19 | 2.3 | 110 | 10.9 | A |
| | 2-4 | R-4 | 90 | 34 | 17 | 2.4 | 110 | 10.8 | A |
| | 2-5 | R-5 | 95 | 35 | 17 | 2.3 | 120 | 11.1 | A |
| | 2-6 | R-6 | 100 | 33 | 18 | 2.2 | 100 | 10.5 | A |
| | 2-7 | R-7 | 100 | 34 | 19 | 2.4 | 120 | 10.8 | A |
| | 2-8 | R-8 | 90 | 35 | 18 | 2.5 | 110 | 11.3 | A |
| | 2-9 | R-9 | 100 | 34 | 17 | 2.2 | 120 | 10.9 | A |
| | 2-10 | R-10 | 95 | 35 | 19 | 2.3 | 110 | 10.6 | A |
| | 2-11 | R-11 | 90 | 34 | 18 | 2.4 | 120 | 10.8 | A |
| | 2-12 | R-12 | 100 | 34 | 17 | 2.3 | 120 | 10.6 | A |
| | 2-13 | R-13 | 95 | 35 | 18 | 2.4 | 110 | 11.1 | A |
| | 2-14 | R-14 | 90 | 34 | 19 | 2.3 | 120 | 10.8 | A |
| | 2-15 | R-15 | 90 | 35 | 17 | 2.4 | 110 | 11.2 | A |
| | 2-16 | R-16 | 100 | 34 | 17 | 2.4 | 100 | 10.9 | A |
| | 2-17 | R-17 | 100 | 35 | 18 | 2.3 | 110 | 11.2 | A |
| | 2-18 | R-18 | 100 | 35 | 19 | 2.2 | 110 | 10.6 | A |
| | 2-19 | R-19 | 95 | 34 | 17 | 2.3 | 120 | 10.8 | A |
| | 2-20 | R-20 | 100 | 35 | 18 | 2.4 | 120 | 10.6 | A |
| | 2-21 | R-21 | 95 | 34 | 19 | 2.3 | 120 | 11.1 | A |
| | 2-22 | R-22 | 95 | 35 | 19 | 2.4 | 110 | 11.3 | A |
| | 2-23 | R-23 | 100 | 36 | 17 | 2.3 | 100 | 10.6 | A |
| | 2-24 | R-24 | 100 | 34 | 18 | 2.5 | 120 | 10.9 | A |
| | 2-25 | R-25 | 95 | 35 | 19 | 2.4 | 100 | 11.4 | A |
| | 2-26 | R-26 | 95 | 34 | 18 | 2.3 | 110 | 11.2 | A |
| | 2-27 | R-27 | 90 | 36 | 18 | 2.2 | 110 | 10.8 | A |
| | 2-28 | R-28 | 100 | 35 | 17 | 2.3 | 100 | 11.2 | A |
| | 2-29 | R-29 | 95 | 34 | 19 | 2.4 | 120 | 11.4 | A |
| | 2-30 | R-30 | 95 | 34 | 18 | 2.3 | 110 | 11.2 | A |
| | 2-31 | R-31 | 100 | 35 | 18 | 2.2 | 110 | 10.8 | A |
| | 2-32 | R-32 | 90 | 34 | 18 | 2.5 | 110 | 11.3 | A |
| | 2-33 | R-33 | 100 | 36 | 17 | 2.3 | 100 | 11.1 | A |
| | 2-34 | R-34 | 95 | 35 | 19 | 2.4 | 120 | 11.4 | A |
| | 2-35 | R-35 | 95 | 34 | 18 | 2.3 | 110 | 11.2 | A |
| | 2-36 | R-36 | 100 | 35 | 17 | 2.3 | 100 | 11.2 | A |
| | 2-37 | R-37 | 95 | 34 | 19 | 2.4 | 120 | 11.4 | A |
| | 2-38 | R-38 | 95 | 34 | 18 | 2.3 | 110 | 11.2 | A |
| | 2-39 | R-39 | 100 | 35 | 18 | 2.2 | 110 | 10.8 | A |
| | 2-40 | R-40 | 90 | 34 | 18 | 2.5 | 110 | 11.3 | A |
| | 2-41 | R-41 | 100 | 36 | 17 | 2.4 | 100 | 11.1 | A |
| | 2-42 | R-42 | 95 | 35 | 19 | 2.3 | 120 | 11.4 | A |
| | 2-43 | R-43 | 95 | 34 | 18 | 2.4 | 110 | 11.2 | A |

TABLE 8

| | | | PEB | | | | | Collapse | |
|---|---|---|---|---|---|---|---|---|---|
| | | Resist | temp. | Eop | EL | LWR | DOF | limit | Development |
| | | composition | (° C.) | (mJ/cm²) | (%) | (nm) | (nm) | (nm) | defects |
| Comparative | 2-1 | CR-1 | 100 | 35 | 15 | 2.8 | 80 | 12.9 | B |
| Example | 2-2 | CR-2 | 95 | 35 | 14 | 2.9 | 80 | 13.3 | C |
| | 2-3 | CR-3 | 90 | 34 | 15 | 2.7 | 90 | 13.2 | B |
| | 2-4 | CR-4 | 95 | 35 | 14 | 2.8 | 90 | 12.9 | B |
| | 2-5 | CR-5 | 95 | 34 | 14 | 2.8 | 80 | 14.3 | C |
| | 2-6 | CR-6 | 100 | 35 | 13 | 2.7 | 80 | 12.8 | B |
| | 2-7 | CR-7 | 100 | 36 | 15 | 2.7 | 90 | 12.9 | B |
| | 2-8 | CR-8 | 100 | 34 | 13 | 2.9 | 90 | 12.7 | C |
| | 2-9 | CR-9 | 95 | 34 | 14 | 2.6 | 90 | 13.1 | B |
| | 2-10 | CR-10 | 95 | 35 | 15 | 2.8 | 80 | 13.1 | B |
| | 2-11 | CR-11 | 95 | 34 | 13 | 2.9 | 100 | 12.7 | C |
| | 2-12 | CR-12 | 90 | 34 | 13 | 2.8 | 90 | 13.4 | B |
| | 2-13 | CR-13 | 95 | 35 | 14 | 2.7 | 80 | 12.7 | C |
| | 2-14 | CR-14 | 95 | 35 | 14 | 2.8 | 90 | 12.5 | C |
| | 2-15 | CR-15 | 100 | 34 | 15 | 2.7 | 70 | 12.9 | B |
| | 2-16 | CR-16 | 90 | 34 | 14 | 2.8 | 80 | 12.6 | B |
| | 2-17 | CR-17 | 95 | 35 | 15 | 2.9 | 80 | 12.5 | C |
| | 2-18 | CR-18 | 95 | 35 | 14 | 2.8 | 70 | 12.8 | B |
| | 2-19 | CR-19 | 90 | 38 | 13 | 2.9 | 90 | 13.1 | C |
| | 2-20 | CR-20 | 95 | 37 | 14 | 3 | 80 | 13.1 | B |
| | 2-21 | CR-21 | 95 | 36 | 15 | 2.9 | 70 | 12.8 | B |
| | 2-22 | CR-22 | 100 | 37 | 13 | 2.9 | 100 | 13.2 | C |
| | 2-23 | CR-23 | 95 | 35 | 15 | 3.1 | 90 | 12.9 | B |
| | 2-24 | CR-24 | 95 | 36 | 13 | 2.7 | 80 | 14.3 | C |
| | 2-25 | CR-25 | 95 | 37 | 14 | 2.8 | 90 | 12.8 | B |
| | 2-26 | CR-26 | 90 | 36 | 15 | 2.7 | 70 | 12.7 | B |
| | 2-27 | CR-27 | 95 | 37 | 13 | 2.8 | 90 | 12.5 | C |
| | 2-28 | CR-28 | 100 | 38 | 14 | 2.6 | 80 | 12.9 | B |
| | 2-29 | CR-29 | 100 | 36 | 13 | 2.8 | 70 | 12.6 | B |
| | 2-30 | CR-30 | 100 | 37 | 14 | 2.7 | 100 | 12.5 | C |
| | 2-31 | CR-31 | 95 | 36 | 15 | 2.9 | 90 | 12.8 | C |
| | 2-32 | CR-32 | 95 | 36 | 13 | 2.8 | 80 | 13.1 | B |
| | 2-33 | CR-33 | 95 | 37 | 14 | 2.9 | 80 | 12.5 | C |
| | 2-34 | CR-34 | 95 | 37 | 15 | 2.7 | 80 | 12.7 | B |
| | 2-35 | CR-35 | 100 | 36 | 14 | 2.8 | 70 | 12.5 | C |
| | 2-36 | CR-36 | 100 | 37 | 15 | 2.7 | 100 | 12.9 | B |
| | 2-37 | CR-37 | 100 | 38 | 14 | 2.8 | 90 | 12.6 | B |
| | 2-38 | CR-38 | 95 | 36 | 13 | 2.6 | 80 | 12.5 | B |
| | 2-39 | CR-39 | 95 | 37 | 14 | 2.8 | 90 | 12.8 | B |

It is demonstrated in Tables 7 and 8 that chemically amplified resist compositions comprising polymers within the scope of the invention exhibit a high sensitivity and improved values of EL, LWR and DOF. Small values of collapse limit attest that in forming a small-size pattern, the pattern is resistant to collapse. The restraint of development defects is also confirmed. The resist compositions are useful in the EUV lithography process.

### [5]EUV Lithography Test 2

### Examples 3-1 to 3-43 and Comparative Examples 3-1 to 3-39

Each of the chemically amplified resist compositions (R-1 to R-43, CR-1 to CR-39) in Tables 3 to 6 was spin coated on a silicon substrate having a 20-nm coating of silicon-containing spin-on hard mask SHB-A940 (Shin-Etsu Chemical Co., Ltd., silicon content 43 wt %) and prebaked on a hotplate at 105° C. for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern having a pitch of 46 nm±20% bias (on-wafer size). The resist film was baked (PEB) on a hotplate at the temperature shown in Tables 9 and 10 for 60 seconds and developed in a 2.38 wt % TMAH aqueous solution for 30 seconds to form a hole pattern having a size of 23 nm.

The pattern as developed was observed under CD-SEM (CG6300, Hitachi High-Technologies Corp.). The dose (mJ/cm²) at which a pattern with a hole size of 23 nm was printed was determined as an index of sensitivity. The size of 50 holes was measured, from which a 3-fold value (36) of the standard deviation (6) was determined as a dimensional variation or CDU. The results are shown in Tables 9 and 10.

TABLE 9

| | | Resist | PEB temp. | Eop | CDU |
|---|---|---|---|---|---|
| | | composition | (° C.) | (mJ/cm²) | (nm) |
| Example | 3-1 | R-1 | 95 | 23 | 2.3 |
| | 3-2 | R-2 | 90 | 23 | 2.3 |
| | 3-3 | R-3 | 90 | 23 | 2.4 |
| | 3-4 | R-4 | 90 | 24 | 2.5 |
| | 3-5 | R-5 | 90 | 22 | 2.5 |
| | 3-6 | R-6 | 90 | 23 | 2.6 |
| | 3-7 | R-7 | 90 | 23 | 2.4 |
| | 3-8 | R-8 | 90 | 24 | 2.4 |
| | 3-9 | R-9 | 95 | 24 | 2.5 |
| | 3-10 | R-10 | 90 | 23 | 2.5 |
| | 3-11 | R-11 | 90 | 23 | 2.4 |
| | 3-12 | R-12 | 95 | 24 | 2.3 |
| | 3-13 | R-13 | 90 | 22 | 2.6 |
| | 3-14 | R-14 | 90 | 23 | 2.5 |
| | 3-15 | R-15 | 90 | 24 | 2.4 |
| | 3-16 | R-16 | 90 | 22 | 2.3 |
| | 3-17 | R-17 | 90 | 25 | 2.3 |
| | 3-18 | R-18 | 85 | 23 | 2.4 |
| | 3-19 | R-19 | 90 | 24 | 2.6 |
| | 3-20 | R-20 | 95 | 22 | 2.4 |
| | 3-21 | R-21 | 95 | 23 | 2.5 |
| | 3-22 | R-22 | 90 | 24 | 2.4 |
| | 3-23 | R-23 | 90 | 23 | 2.3 |
| | 3-24 | R-24 | 90 | 25 | 2.5 |
| | 3-25 | R-25 | 90 | 24 | 2.6 |
| | 3-26 | R-26 | 90 | 23 | 2.3 |
| | 3-27 | R-27 | 90 | 22 | 2.6 |
| | 3-28 | R-28 | 90 | 24 | 2.6 |
| | 3-29 | R-29 | 95 | 23 | 2.3 |
| | 3-30 | R-30 | 90 | 23 | 2.4 |
| | 3-31 | R-31 | 90 | 23 | 2.4 |
| | 3-32 | R-32 | 90 | 24 | 2.3 |
| | 3-33 | R-33 | 90 | 22 | 2.6 |
| | 3-34 | R-34 | 95 | 24 | 2.3 |
| | 3-35 | R-35 | 90 | 23 | 2.4 |
| | 3-36 | R-36 | 90 | 24 | 2.6 |
| | 3-37 | R-37 | 95 | 25 | 2.3 |
| | 3-38 | R-38 | 90 | 23 | 2.4 |
| | 3-39 | R-39 | 90 | 24 | 2.4 |
| | 3-40 | R-40 | 90 | 22 | 2.3 |
| | 3-41 | R-41 | 90 | 23 | 2.6 |
| | 3-42 | R-42 | 95 | 24 | 2.3 |
| | 3-43 | R-43 | 90 | 23 | 2.4 |

TABLE 10

| | | Resist | PEB temp. | Eop | CDU |
|---|---|---|---|---|---|
| | | composition | (° C.) | (mJ/cm²) | (nm) |
| Comparative | 3-1 | CR-1 | 95 | 24 | 2.9 |
| Example | 3-2 | CR-2 | 95 | 25 | 2.8 |
| | 3-3 | CR-3 | 90 | 24 | 2.9 |
| | 3-4 | CR-4 | 90 | 25 | 2.7 |
| | 3-5 | CR-5 | 90 | 26 | 3 |
| | 3-6 | CR-6 | 90 | 25 | 2.9 |
| | 3-7 | CR-7 | 95 | 24 | 3.1 |
| | 3-8 | CR-8 | 100 | 25 | 3.2 |
| | 3-9 | CR-9 | 95 | 26 | 2.7 |
| | 3-10 | CR-10 | 95 | 26 | 2.9 |
| | 3-11 | CR-11 | 90 | 25 | 3.2 |
| | 3-12 | CR-12 | 90 | 26 | 3.1 |
| | 3-13 | CR-13 | 95 | 25 | 3.2 |
| | 3-14 | CR-14 | 90 | 25 | 3.1 |
| | 3-15 | CR-15 | 90 | 26 | 2.9 |
| | 3-16 | CR-16 | 95 | 25 | 3 |
| | 3-17 | CR-17 | 90 | 24 | 3.1 |
| | 3-18 | CR-18 | 90 | 25 | 3.1 |
| | 3-19 | CR-19 | 95 | 27 | 3.2 |
| | 3-20 | CR-20 | 90 | 28 | 2.9 |
| | 3-21 | CR-21 | 95 | 27 | 2.8 |
| | 3-22 | CR-22 | 95 | 26 | 2.9 |
| | 3-23 | CR-23 | 100 | 28 | 2.7 |
| | 3-24 | CR-24 | 95 | 29 | 3 |
| | 3-25 | CR-25 | 95 | 28 | 2.9 |
| | 3-26 | CR-26 | 90 | 27 | 3.1 |
| | 3-27 | CR-27 | 90 | 27 | 3.2 |
| | 3-28 | CR-28 | 90 | 28 | 2.7 |
| | 3-29 | CR-29 | 95 | 26 | 2.9 |
| | 3-30 | CR-30 | 90 | 27 | 3.2 |
| | 3-31 | CR-31 | 90 | 26 | 2.7 |
| | 3-32 | CR-32 | 95 | 27 | 2.9 |
| | 3-33 | CR-33 | 95 | 26 | 2.7 |
| | 3-34 | CR-34 | 95 | 27 | 3.1 |
| | 3-35 | CR-35 | 95 | 28 | 3.1 |
| | 3-36 | CR-36 | 100 | 26 | 3.2 |
| | 3-37 | CR-37 | 95 | 27 | 2.9 |
| | 3-38 | CR-38 | 95 | 26 | 2.8 |
| | 3-39 | CR-39 | 90 | 27 | 2.9 |

It is demonstrated in Tables 9 and 10 that chemically amplified resist compositions comprising polymers within the scope of the invention exhibit a high sensitivity and satisfactory CDU.

### [6]Dry Etching Test

### Examples 4-1 to 4-35 and Comparative Examples 4-1 to 4-22

Each of the polymers (Polymers P-1 to P-35, Comparative Polymers CP-1 to CP-22 in Tables 1 and 2), 2 g, was dissolved in 10 g of cyclohexanone, and passed through a filter having a pore size of 0.2 μm, obtaining a polymer solution. The polymer solution was spin coated onto a silicon substrate and baked to form a polymer film of 300 nm thick. Using a dry etching instrument TE-8500P (Tokyo Electron Ltd.), the polymer film was etched with CHF₃/CF₄ gas under the following conditions.
Chamber pressure: 40 Pa
RF power: 1000 W
Gap: 9 mm
CHF₃ gas flow rate: 30 m1/min
CF₄ gas flow rate: 30 m1/min
Ar gas flow rate: 100 m1/min
Time: 60 sec

The difference in polymer film thickness before and after etching was determined, from which an etching rate per minute was computed. The results are shown in Tables 11 and 12. A smaller value of film thickness difference, i.e., a lower etching rate indicates better etch resistance.

TABLE 11

| | | Polymer | CHF₃/CF₄ gas etching rate (nm/min) |
|---|---|---|---|
| Example | 4-1 | P-1 | 95 |
| | 4-2 | P-2 | 96 |
| | 4-3 | P-3 | 94 |
| | 4-4 | P-4 | 95 |
| | 4-5 | P-5 | 96 |
| | 4-6 | P-6 | 94 |
| | 4-7 | P-7 | 94 |
| | 4-8 | P-8 | 94 |
| | 4-9 | P-9 | 95 |
| | 4-10 | P-10 | 96 |
| | 4-11 | P-11 | 95 |
| | 4-12 | P-12 | 97 |
| | 4-13 | P-13 | 95 |
| | 4-14 | P-14 | 95 |
| | 4-15 | P-15 | 94 |
| | 4-16 | P-16 | 94 |
| | 4-17 | P-17 | 95 |
| | 4-18 | P-18 | 96 |
| | 4-19 | P-19 | 97 |
| | 4-20 | P-20 | 96 |
| | 4-21 | P-21 | 95 |
| | 4-22 | P-22 | 94 |
| | 4-23 | P-23 | 96 |
| | 4-24 | P-24 | 94 |
| | 4-25 | P-25 | 97 |
| | 4-26 | P-26 | 96 |
| | 4-27 | P-27 | 97 |
| | 4-28 | P-28 | 96 |
| | 4-29 | P-29 | 95 |
| | 4-30 | P-30 | 94 |
| | 4-31 | P-31 | 96 |
| | 4-32 | P-32 | 94 |
| | 4-33 | P-33 | 96 |
| | 4-34 | P-34 | 97 |
| | 4-35 | P-35 | 94 |

TABLE 12

| | | Polymer | CHF₃/CF₄ gas etching rate (nm/min) |
|---|---|---|---|
| Comparative | 4-1 | CP-1 | 101 |
| Example | 4-2 | CP-2 | 99 |
| | 4-3 | CP-3 | 102 |
| | 4-4 | CP-4 | 103 |
| | 4-5 | CP-5 | 100 |
| | 4-6 | CP-6 | 103 |
| | 4-7 | CP-7 | 104 |
| | 4-8 | CP-8 | 102 |
| | 4-9 | CP-9 | 101 |
| | 4-10 | CP-10 | 102 |
| | 4-11 | CP-11 | 99 |
| | 4-12 | CP-12 | 104 |
| | 4-13 | CP-13 | 101 |
| | 4-14 | CP-14 | 103 |
| | 4-15 | CP-15 | 107 |
| | 4-16 | CP-16 | 103 |
| | 4-17 | CP-17 | 102 |
| | 4-18 | CP-18 | 101 |
| | 4-19 | CP-19 | 100 |
| | 4-20 | CP-20 | 99 |
| | 4-21 | CP-21 | 103 |
| | 4-22 | CP-22 | 102 |

It is evident from Tables 11 and 12 that the inventive polymers have good dry etch resistance, i.e., resistance to CHF₃/CF₄ gas etching.

Japanese Patent Application No. 2025-021264 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A chemically amplified resist composition comprising
(A) a polymer comprising repeat units having the formula (a1) and being free of repeat units adapted to generate acid upon light exposure,
(B) a photoacid generator containing a fluoroalkane sulfonic acid anion having an aromatic ring structure substituted with iodine or iodine and bromine, and
(C) an organic solvent, 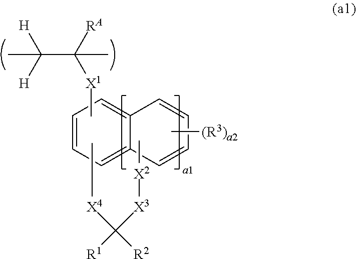
wherein a1 is 0 or 1, a2 is 0, 1, 2 or 3 when a1=0 and a2 is 0, 1, 2, 3, 4 or 5 when a1=1,
R^{A} is hydrogen, fluorine, methyl or trifluoromethyl,
X¹ is a single bond, *—C(═O)—O— or *—C(═O)—N(H)—, * designates a point of attachment to the carbon atom in the backbone,
X² is a single bond, a C₁-C₄ aliphatic hydrocarbylene group, carbonyl, sulfonyl or a group obtained by combining the foregoing,
X³ and X⁴ are each independently oxygen or sulfur, with the proviso that X² and X⁴ are attached to adjacent carbon atoms on the aromatic ring,
R¹ and R² are each independently hydrogen or a C₁-C₂₀ hydrocarbyl group which may contain a heteroatom, R¹ and R² may bond together to form a ring with the carbon atom to which they are attached,
R³ is halogen, hydroxy, cyano, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbyloxycarbonyl group which may contain a heteroatom, C₁-C₂₀ hydrocarbylthio group which may contain a heteroatom, or —N(R^{3A})(R^{3B}), wherein R^{3A} and R^{3B} are each independently hydrogen or a C₁-C₆ hydrocarbyl group; when a2 is 2 or more, a plurality of R³ may be identical or different and a plurality of R³ may bond together to form a ring with the carbon atoms in the aromatic ring to which they are attached.

2. The resist composition of claim 1 wherein both X³ and X⁴ are oxygen.

3. The resist composition of claim 1 wherein X² is carbonyl.

4. The resist composition of claim 1 wherein the photoacid generator has the formula (1): 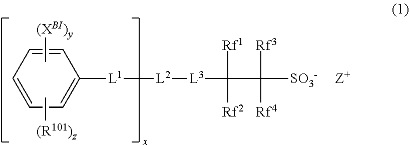
wherein x is 1, 2 or 3, y is 1, 2, 3, 4 or 5, z is 0, 1, 2 or 3, and 1≤y+z 5,
X^{BI} is iodine when y is 1, and X^{BI} is iodine or bromine, at least one being iodine, when y is 2, 3, 4 or 5,
L¹ is a single bond, ether bond, ester bond, sulfonate ester bond, sulfonamide bond, amide bond, carbonate bond, carbamate bond, or a C₁-C₆ saturated hydrocarbylene group, some —CH₂— in the hydrocarbylene group may be replaced by an ether bond, ester bond, sulfonate ester bond, sulfonamide bond, amide bond, carbonate bond, or carbamate bond,
L² is a single bond or a C₁-C₂₀ hydrocarbylene group which may contain a heteroatom when x is 1, L² is a C₁-C₂₀ (x+1)-valent hydrocarbon group which may contain a heteroatom when x is 2 or 3,
L³ is a single bond, ether bond, ester bond, sulfonate ester bond, carbonate bond or carbamate bond,
R¹⁰¹ is hydroxy, carboxy, fluorine, chlorine, pentafluorosulfanyl, a C₁-C₂₀ hydrocarbyl group, C₁-C₂₀ hydrocarbyloxy group, C₁-C₂₀ hydrocarbylthio group, C₂-C₂₀ hydrocarbylcarbonyl group, C₂-C₂₀ hydrocarbyloxycarbonyl group, C₂-C₂₀ hydrocarbylcarbonyloxy group, C₁-C₂₀ hydrocarbylsulfonyloxy group, —N(R^{101A})(R^{101B}), —N(R^{101C})—C(═O)—R^{101D} or —N(R^{101C})—C(═O)—O—R^{101D}, the hydrocarbyl, hydrocarbyloxy, hydrocarbylthio, hydrocarbylcarbonyl, hydrocarbyloxycarbonyl, hydrocarbylcarbonyloxy, and hydrocarbylsulfonyloxy groups may contain at least one moiety selected from fluorine, chlorine, bromine, iodine, hydroxy, amino, ester bond and ether bond, R^{101A} and R^{101B} are each independently hydrogen or a C₁-C₆ saturated hydrocarbyl group, R^{101C} is hydrogen or a C₁-C₆ saturated hydrocarbyl group which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety, R^{101D} is a C₁-C₁₆ aliphatic hydrocarbyl group, C₆-C₁₂ aryl group or C₇-C₁₅ aralkyl group, which may contain halogen, hydroxy, a C₁-C₆ saturated hydrocarbyloxy moiety, C₂-C₆ saturated hydrocarbylcarbonyl moiety, or C₂-C₆ saturated hydrocarbylcarbonyloxy moiety,
Rf¹ to Rf⁴ are each independently hydrogen, fluorine or trifluoromethyl, at least one being fluorine or trifluoromethyl, Rf¹ and Rf² may bond together to form a carbonyl group, and
Z⁺ is an onium cation.

5. The resist composition of claim 1 wherein Z⁺ is a sulfonium cation having the formula (Z-1) or iodonium cation having the formula (Z-2): 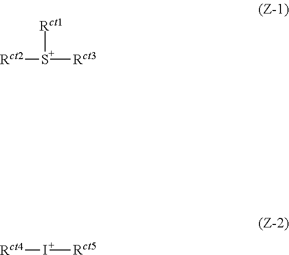
wherein R^{ct1} to R^{ct5} are each independently halogen or a C₁-C₃₀ hydrocarbyl group which may contain a heteroatom, R^{ct1} and R^{ct2} may bond together to form a ring with the sulfur atom to which they are attached.

6. The resist composition of claim 1 wherein Z⁺ is a sulfonium cation having the formula (Z-3): 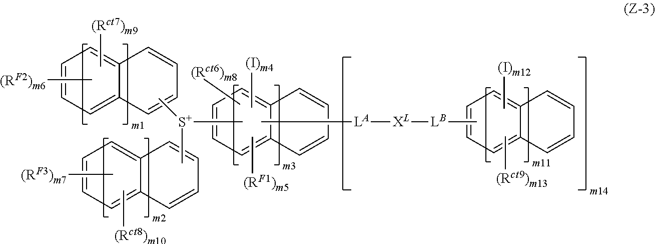
wherein m1 is 0 or 1, m2 is 0 or 1, m3 is 0 or 1, m4 is 0, 1, 2, 3 or 4, m5 is 0, 1, 2, 3 or 4, m6 is 0, 1, 2, 3, 4, 5 or 6, m7 is 0, 1, 2, 3, 4, 5 or 6, m8 is 0, 1 or 2, m9 is 0, 1 or 2, m10 is 0, 1 or 2, m11 is 0 or 1, m12 is 0, 1, 2, 3 or 4, m13 is 0, 1 or 2, m14 is 0, 1 or 2, m1 to m14 are in the range: 0≤m6+m9≤4 when m1=0, 0≤m6+m9≤6 when m1=1, 0≤m7+m10≤4 when m2=0, 0≤m7+m10≤6 when m2=1, 1≤m4+m5+m8+m14≤4 when m3=0, 1≤m4+m5+m8+m14≤6 when m3=1, 0<m12+m13≤4 when m11=0, 0 m12+m13≤6 when m11=1, and m4+m12≥1,
R^{F1} to R^{F3} are each independently fluorine, a C₁-C₆ fluorinated saturated hydrocarbyl group, C₁-C₆ fluorinated saturated hydrocarbyloxy group, or C₁-C₆ fluorinated saturated hydrocarbylthio group; when m5 is 2, 3 or 4, a plurality of R^{F1} may be identical or different; when m6 is 2, 3, 4, 5 or 6, a plurality of R^{F2} may be identical or different; when m7 is 2, 3, 4, 5 or 6, a plurality of R^{F3} may be identical or different,
R^{ct6} to R^{ct9} are halogen other than iodine and fluorine, nitro, cyano, a C₁-C₂₀ hydrocarbyl group which may contain a heteroatom, C₁-C₂₀ hydrocarbyloxy group which may contain a heteroatom, or C₁-C₂₀ hydrocarbylthio group which may contain a heteroatom; when m8=2, two R^{ct6} may be identical or different and bond together to form a ring with the carbon atoms to which they are attached; when m9=2, two R^{ct7} may be identical or different and bond together to form a ring with the carbon atoms to which they are attached; when m10=2, two R^{ct8} may be identical or different and bond together to form a ring with the carbon atoms to which they are attached; when m13=2, two R^{ct9} may be identical or different and bond together to form a ring with the carbon atoms to which they are attached,
the aromatic rings directly bonded to S⁺ in the sulfonium cation may bond together to form a ring with S⁺,
L^{A} and L^{B} are each independently a single bond, ether bond, ester bond, amide bond, sulfonate ester bond, sulfonamide bond, carbonate bond or carbamate bond, and
X^{L} is a single bond or a C₁-C₄₀ hydrocarbylene group which may contain a heteroatom.

7. The resist composition of claim 1 wherein the polymer comprises repeat units of at least one type selected from repeat units having the formula (a2) and repeat units having the formula (a3): 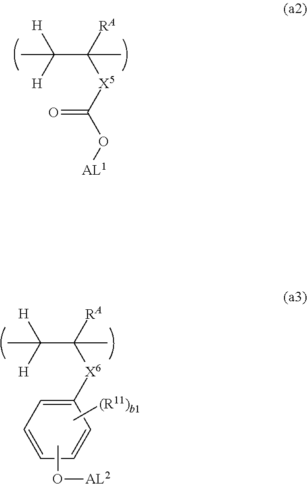
wherein R^{A} is each independently hydrogen, fluorine, methyl or trifluoromethyl,
X⁵ is a single bond, phenylene group, naphthylene group or *—C(═O)—O—X⁵—, the phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen, X⁵¹ is a C₁-C₁₀ saturated hydrocarbylene group, phenylene group or naphthylene group, the saturated hydrocarbylene group may contain hydroxy, ether bond, ester bond or lactone ring,
X⁶ is a single bond, *—C(═O)—O— or *—C(═O)—N(H)—,
* designates a point of attachment to the carbon atom in the backbone,
R¹¹ is halogen, cyano, hydroxy, nitro, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when b1 is 2, 3 or 4, a plurality of R¹¹ may be identical or different,
AL¹ and AL² are each independently an acid labile group, and
b1 is 0, 1, 2, 3 or 4.

8. The resist composition of claim 1 wherein the polymer further comprises repeat units having the formula (b): 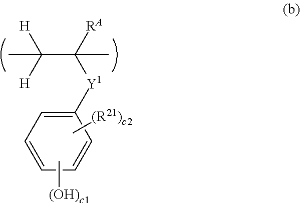
wherein R^{A} is hydrogen, fluorine, methyl or trifluoromethyl,
Y¹ is a single bond, *—C(═O)—O— or *—C(═O)—N(H)—,
* designates a point of attachment to the carbon atom in the backbone,
R²¹ is halogen, carboxy, nitro, cyano, pentafluorosulfanyl, a C₁-C₂₀ hydrocarbyl group which may contain a heteroatom, C₁-C₂₀ hydrocarbyloxy group which may contain a heteroatom, C₂-C₂₀ hydrocarbylcarbonyl group which may contain a heteroatom, C₂-C₂₀ hydrocarbylcarbonyloxy group which may contain a heteroatom, or C₂-C₂₀ hydrocarbyloxycarbonyl group which may contain a heteroatom; when c2 is 2, 3 or 4, a plurality of R²¹ may be identical or different,
c1 is 1, 2, 3 or 4, c2 is 0, 1, 2, 3 or 4, and 1≤c1+c2≤5.

9. The resist composition of claim 1 wherein the polymer further comprises repeat units having the formula (c): 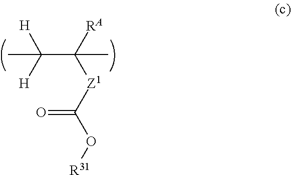
wherein R^{A} is hydrogen, fluorine, methyl or trifluoromethyl,
Z¹ is a single bond, phenylene group, naphthylene group, *—C(═O)—O—Z¹¹— or *—C(═O)—N(H)—Z¹¹—, the phenylene and naphthylene groups may be substituted with hydroxy, nitro, cyano, a C₁-C₁₀ saturated hydrocarbyl moiety which may contain fluorine, C₁-C₁₀ saturated hydrocarbyloxy moiety which may contain fluorine, or halogen, * designates a point of attachment to the carbon atom in the backbone, Z¹¹ is a C₁-C₁₀ saturated hydrocarbylene group, phenylene group or naphthylene group, the saturated hydrocarbylene group may contain hydroxy, ether bond, ester bond or lactone ring, and
R³¹ is hydrogen or a C₁-C₂₀ group containing at least one structure selected from hydroxy other than phenolic hydroxy, cyano, carbonyl, carboxy, ether bond, ester bond, sulfonate ester bond, carbonate bond, lactone ring, sultone ring and carboxylic anhydride (—C(═O)—O—C(═O)—).

10. The resist composition of claim 1, further comprising (D) a quencher.

11. The resist composition of claim 1, further comprising (E) another acid generator.

12. The resist composition of claim 1, further comprising (F) a surfactant.

13. A pattern forming process comprising the steps of applying the chemically amplified resist composition of claim 1 onto a substrate to form a resist film thereon, exposing the resist film to high-energy radiation, and developing the exposed resist film in a developer.

14. The process of claim 13 wherein the high-energy radiation is ArF excimer laser of wavelength 193 nm, KrF excimer laser of wavelength 248 nm, EB or EUV of wavelength 3 to 15 nm.
